(19) United States
(12) Patent Application Publication
(10) Pub. No.: US 2025/0393475 A1
(43) Pub. Date: Dec. 25, 2025

(54) LIGHT-EMITTING DEVICE INCLUDING CONDENSED CYCLIC COMPOUND, ELECTRONIC APPARATUS INCLUDING THE LIGHT-EMITTING DEVICE, AND THE CONDENSED CYCLIC COMPOUND

(71) Applicant: Samsung Display Co., Ltd., Yongin-si (KR)

(72) Inventor: Hirokazu Kuwabara, Yokohama (JP)

(73) Assignee: Samsung Display Co., Ltd., Yongin-si (KR)

(21) Appl. No.: 19/240,250

(22) Filed: Jun. 17, 2025

(30) Foreign Application Priority Data
Jun. 20, 2024 (KR) 10-2024-0080433

(51) Int. Cl. H10K 85/60; C09K 11/06; H10K 50/11; H10K 101/20

(52) U.S. Cl. CPC H10K 85/658; C09K 11/06; H10K 85/6572; C09K 2211/1007; C09K 2211/1018; H10K 50/11; H10K 2101/20

(57) ABSTRACT

Embodiments provide a condensed cyclic compound, a light-emitting device including the condensed cyclic compound, and an electronic apparatus including the light-emitting device. The light-emitting device includes a first electrode, a second electrode facing the first electrode, and an interlayer between the first electrode and the second electrode, wherein the interlayer includes an emission layer, and the condensed cyclic compound. The condensed cyclic compound is represented by Formula 1, which is explained in the specification:

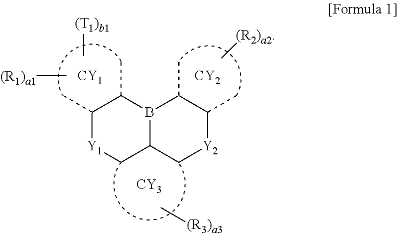

### CROSS-REFERENCE TO RELATED APPLICATION(S)

This application claims priority to and benefits of Korean Patent Application No. 10-2024-0080433 under 35 U.S.C. § 119, filed on Jun. 20, 2024, in the Korean Intellectual Property Office, the entire contents of which are incorporated herein by reference herein.

### BACKGROUND

### 1. Technical Field

Embodiments relate to a light-emitting device including a condensed cyclic compound, an electronic apparatus including the light-emitting device, and the condensed cyclic compound.

### 2. Description of the Related Art

Organic light-emitting devices are self-emissive devices that, as compared with devices of the related art, have wide viewing angles, high contrast ratios, short response times, and excellent characteristics in terms of luminance, driving voltage, and response speed, and produce full-color images.

In an example, an organic light-emitting device may have a structure in which a first electrode is arranged on a substrate, and a hole transport region, an emission layer, an electron transport region, and a second electrode are sequentially formed on the first electrode. Holes provided from the first electrode move toward the emission layer through the hole transport region, and electrons provided from the second electrode move toward the emission layer through the electron transport region. Carriers, such as the holes and electrons, recombine in the emission layer to produce excitons. The excitons transition from an excited state to a ground state, thereby generating light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a light-emitting device including a condensed cyclic compound, an electronic apparatus including the light-emitting device, and the condensed cyclic compound.

Additional aspects will be set forth in part in the description which follows and, in part, will be apparent from the description, or may be learned by practice of the embodiments of the disclosure.

According to embodiments, a light-emitting device may include a first electrode, a second electrode facing the first electrode, and an interlayer between the first electrode and the second electrode, wherein the interlayer may include an emission layer, and a condensed cyclic compound represented by Formula 1:

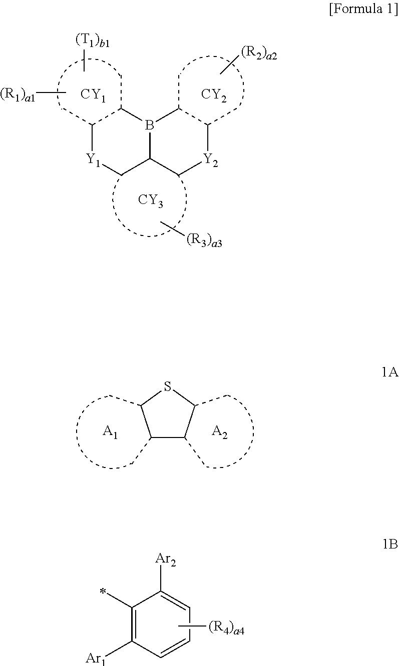

In Formulae 1, 1A, and 1B,
ring CY₁ to ring CY₃, ring A₁, and ring A₂ may each independently be a C₅-C₆₀ carbocyclic group or a C₁-C₆₀ heterocyclic group,
at least one of ring CY₂ and ring CY₃ may each independently be a group represented by Formula 1 A,
when ring CY₂ is a group represented by Formula 1A and ring CY₃ is not a group represented by Formula 1A, ring A₂ in Formula 1A may be a condensed polycyclic group in which two or more rings are condensed with each other,
Y₁ may be O, S, or N(R₁ₐ),
Y₂ may be O, S, or N(R₃₂ₐ),
R₁ₐ and R₂ₐ may each independently be a group represented by Formula 1B, hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
T₁ may be a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ,
b1 may be an integer from 1 to 10,
R₁ to R₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
Ar₁ and Ar₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
a1 to a3 may each independently be an integer from 0 to 10,
a4 may be an integer from 0 to 3,
* indicates a binding site to a neighboring atom,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof, and
the condensed cyclic compound may satisfy at least one of Conditions 1 and 2:

Y₁ is N(R₁ₐ), and R₁ₐ is a group represented by Formula 1B [Condition 1]

Y₂ is N(R₂ₐ), and R₂ₐ is a group represented by Formula 1B. [Condition 2]

In an embodiment, the first electrode may be an anode; the second electrode may be a cathode; the interlayer may further include a hole transport region between the first electrode and the emission layer, and an electron transport region between the emission layer and the second electrode; the hole transport region may include a hole injection layer, a hole transport layer, an emission auxiliary layer, an electron-blocking layer, or any combination thereof; and the electron transport region may include a hole-blocking layer, an electron transport layer, an electron injection layer, or any combination thereof.

In an embodiment, the emission layer may include the condensed cyclic compound.

In an embodiment, the condensed cyclic compound in the emission layer may be a thermally activated delayed fluorescence (TADF) emitter, and the emission layer may emit delayed fluorescence.

In an embodiment, the emission layer may emit blue light.

In an embodiment, the emission layer may further include a host, the condensed cyclic compound in the emission layer may be a dopant, and an amount of the host in the emission layer may be greater than an amount of the condensed cyclic compound in the emission layer.

According to embodiments, an electronic apparatus may include the light-emitting device.

In an embodiment, the electronic apparatus, may further include a thin-film transistor, wherein the thin-film transistor may include a source electrode and a drain electrode, and the first electrode of the light-emitting device may be electrically connected to the source electrode or the drain electrode.

In an embodiment, the electronic apparatus may further include a color filter, a color conversion layer, a touch screen layer, a polarizing layer, or any combination thereof.

According to embodiments, a condensed cyclic compound may be represented by Formula 1, which is explained herein.

In an embodiment, ring CY₁ to ring CY₃ may each independently be a group represented by Formula 1A, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, ring A₁ and ring A₂ may each independently be a benzene group, a pyridine group, a pyrimidine group, a pyrazine group, a pyridazine group, a naphthalene group, a quinoline group, an isoquinoline group, a quinoxaline group, a quinazoline group, an anthracene group, or a phenanthrene group.

In an embodiment, the group represented by Formula 1A may be a group represented by one of Formulae 1A-1 to 1A-4, which are explained below.

In an embodiment, the condensed cyclic compound may be represented by one of Formulae 1(1) to 1(3), which are explained below.

In an embodiment, the condensed cyclic compound may be represented by one of Formulae 1(1)-1 to 1(1)-6 and 1(2)-1 to 1(2)-4, which are explained below.

In an embodiment, Y₁ may be O or S, Y₂ may be N(R₂ₐ), and R₂ₐ may be a group represented by Formula 1B; or Y₁ may be N(R₁ₐ), Y₂ may be O or S, and R₁ₐ may be a group represented by Formula 1B; or Y₁ may be N(R₁ₐ), Y₂ may be N(R₂ₐ), and R₁ₐ and R₂ₐ may each independently be a group represented by Formula 1B.

In an embodiment, Ar₁ and Ar₂ in Formula 1B may each independently be a C₆-C₆₀ aryl group unsubstituted or substituted with at least one R₁₀ₐ or a C₁-C₆₀ heteroaryl group unsubstituted or substituted with at least one R₁₀ₐ.

In an embodiment, the group represented by Formula 1B may be a group represented by Formula 1B(1), which is explained below.

In an embodiment, T₁ may be a group represented by one of Formulae 1T-1 to 1T-9, which are explained below.

In an embodiment, R₁ to R₄ may each independently be:

hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂); or
—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, and a triazinyl group.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification.

The drawings illustrate embodiments of the disclosure and principles thereof. The above and other aspects and features the disclosure will become more apparent by describing in detail embodiments thereof with reference to the accompanying drawings, in which:

FIG. 1 is a schematic cross-sectional view of a light-emitting device according to an embodiment;

FIG. 2 is a schematic cross-sectional view of an electronic apparatus according to an embodiment;

FIG. 3 is a schematic cross-sectional view of an electronic apparatus according to another embodiment;

FIG. 4 is a schematic perspective view of an electronic equipment including a light-emitting device according to an embodiment;

FIG. 5 is a schematic perspective view of an exterior of a vehicle as an electronic equipment including a light-emitting device according to an embodiment; and

FIGS. 6A to 6C are each a schematic diagram of an interior of a vehicle according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

According to an embodiment, a light-emitting device (e.g., an organic light-emitting device) may include: a first electrode; a second electrode facing the first electrode; and an interlayer between the first electrode and the second electrode, wherein the interlayer may include an emission layer, and a condensed cyclic compound represented by Formula 1.

Hereinafter, the condensed cyclic compound represented by Formula 1 will be described in detail.

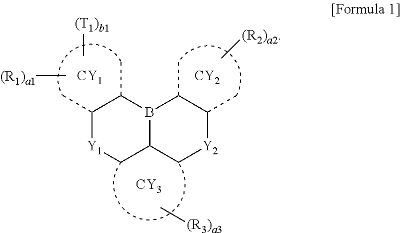

In Formula 1, ring CY₁ to ring CY₃ may each independently be a C₅-C₆₀ carbocyclic group or a C₁-C₆₀ heterocyclic group, and
at least one of ring CY₂ and ring CY₃ may each independently be a group represented by Formula 1A.

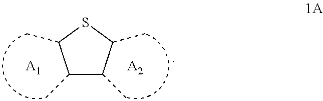

In Formula 1A, ring A₁ and ring A₂ may each independently be a C₅-C₆₀ carbocyclic group or a C₁-C₆₀ heterocyclic group.

In Formula 1, when ring CY₂ is a group represented by Formula 1A and ring CY₃ is not a group represented by Formula 1A, ring A₂ in Formula 1A may be a condensed polycyclic group in which two or more rings are condensed with each other.

In an embodiment, ring CY₁ to ring CY₃ may each independently be a group represented by Formula 1A, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, ring A₁ and ring A₂ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, ring CY₁ may be a benzene group or a naphthalene group.

In an embodiment, ring A₁ and ring A₂ may each independently be a benzene group, a pyridine group, a pyrimidine group, a pyrazine group, a pyridazine group, a naphthalene group, a quinoline group, an isoquinoline group, a quinoxaline group, a quinazoline group, an anthracene group, or a phenanthrene group.

In an embodiment, the group represented by Formula 1A may be a group represented by one of Formulae 1A-1 to 1A-4.

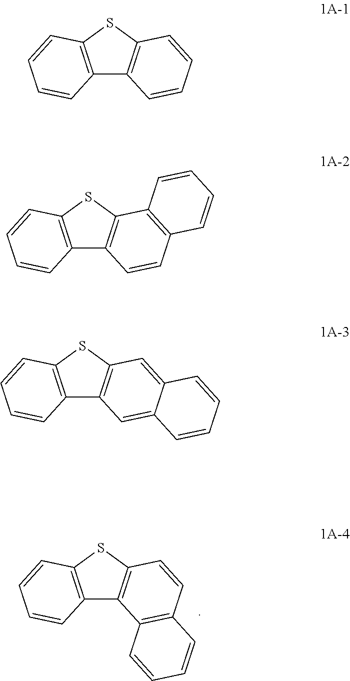 [SMILES: c1ccc2c(c1)sc1ccccc12 ; c1ccc2c(c1)ccc1c3ccccc3sc21 ; c1ccc2cc3c(cc2c1)sc1ccccc13 ; c1ccc2c(c1)ccc1sc3ccccc3c12]

In an embodiment, in Formula 1A, ring A₁ may be condensed with a ring including B and Y₂ in Formula 1.

In an embodiment, the condensed cyclic compound may be represented by one of Formulae 1(1) to 1(3).

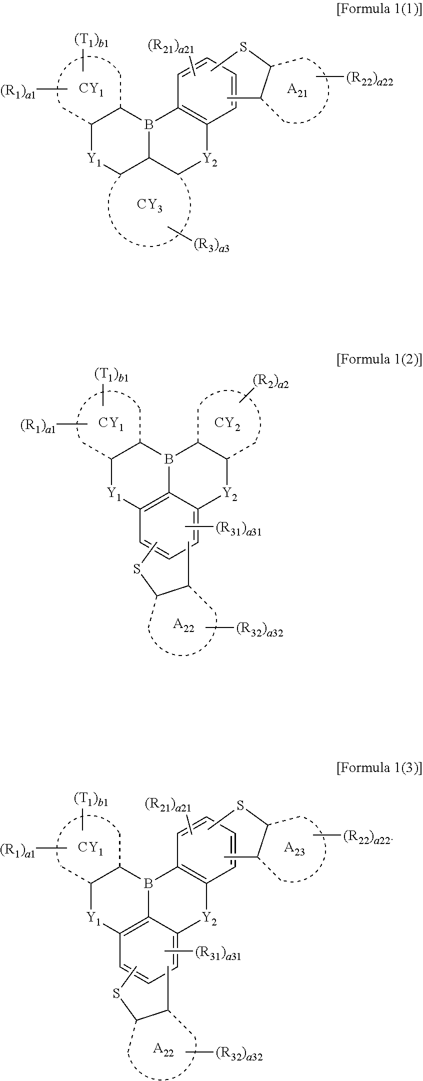

In Formulae 1(1) to 1(3),
ring CY₁ to ring CY₃, T₁, b1, Y₁, Y₂, R₁ to R₃, and a1 to a3 may each be the same as described herein,
ring A₂₁ may be a C₅-C₆₀ carbocyclic group or a C₁-C₆₀ heterocyclic group, and may be a condensed polycyclic group in which two or more rings are condensed with each other,
ring A₂₂ and ring A₂₃ may each independently be a C₅-C₆₀ carbocyclic group or a C₁-C₆₀ heterocyclic group,
R₂₁ and R₂₂ may each independently be the same as described in connection with R₂,
R₃₁ and R₃₂ may each independently be the same as described in connection with R₃,
a21 may be an integer from 0 to 2,
a31 may be 0 or 1, and
a22 and a32 may each independently be an integer from 0 to 10.

In an embodiment, ring A₂₁ in Formula 1(1) may be a naphthalene group, a quinoline group, an isoquinoline group, a quinoxaline group, or a quinazoline group.

In an embodiment, ring A₂₂ in Formula 1(2) may be a benzene group, a pyridine group, a pyrimidine group, a pyrazine group, a pyridazine group, a naphthalene group, a quinoline group, an isoquinoline group, a quinoxaline group, or a quinazoline group.

In an embodiment, ring A₂₂ and ring A₂₃ in Formula 1(3) may each independently be a benzene group, a pyridine group, a pyrimidine group, a pyrazine group, a pyridazine group, a naphthalene group, a quinoline group, an isoquinoline group, a quinoxaline group, or a quinazoline group.

In an embodiment, the condensed cyclic compound may be represented by one of Formulae 1(1)-1 to 1(1)-6 and 1(2)-1 to 1(2)-4.

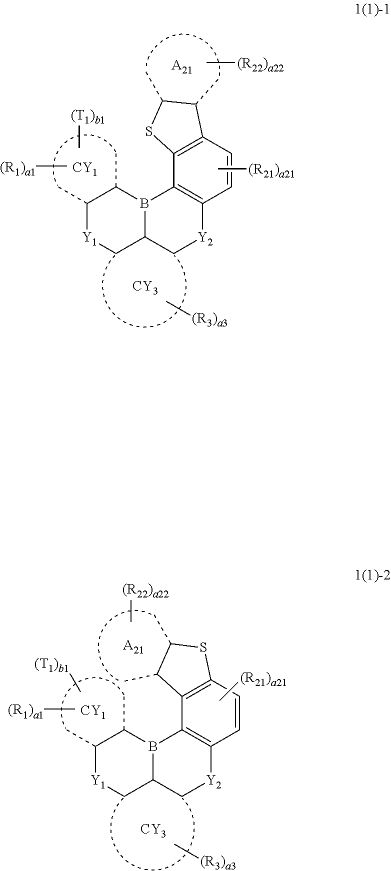

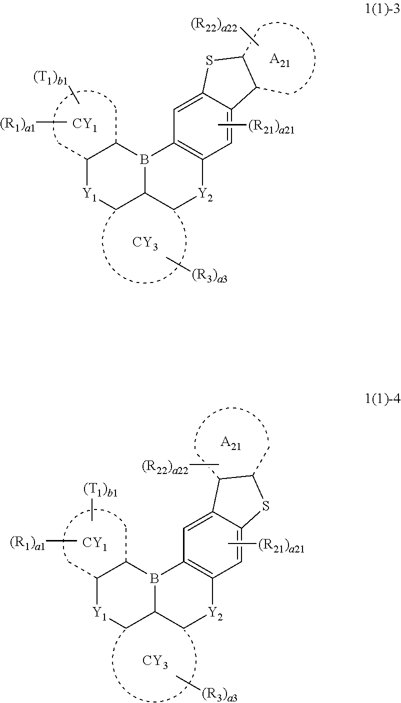

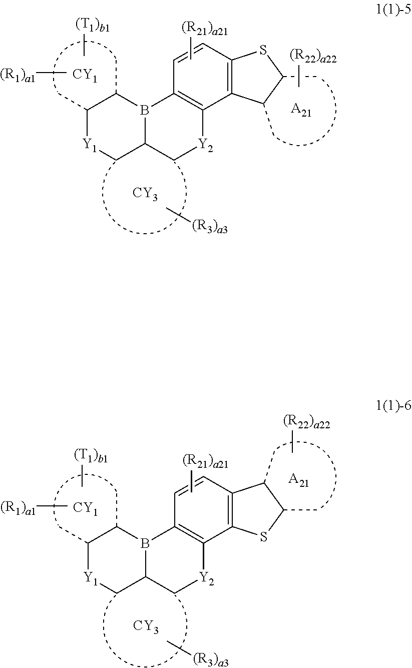

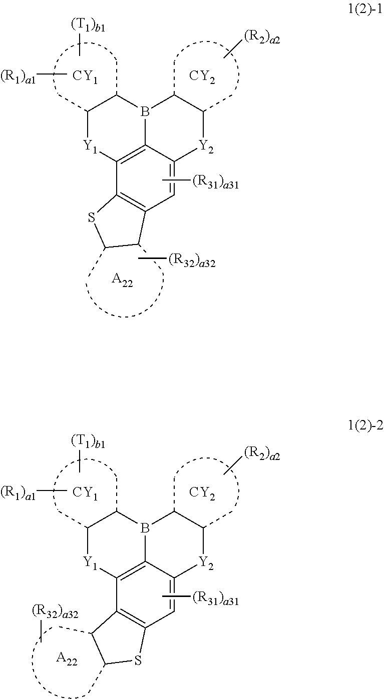

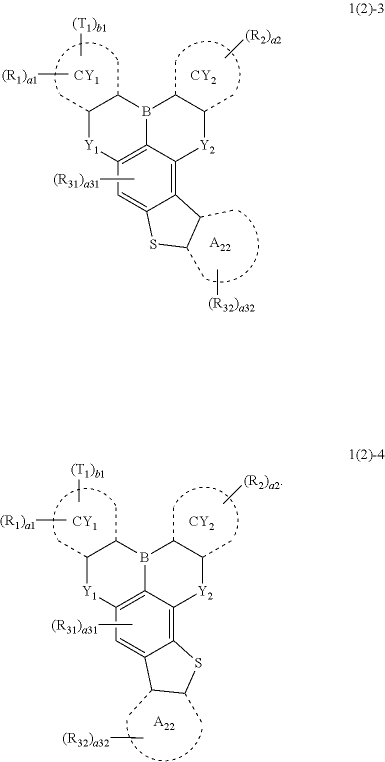

In Formulae 1(1)-1 to 1(1)-6 and 1(2)-1 to 1(2)-4,
ring CY₁ to ring CY₃, T₁, b1, Y₁, Y₂, R₁ to R₃, and a1 to a3 may each be the same as described herein,
ring A₂₁ may be a C₅-C₆₀ carbocyclic group or a C₁-C₆₀ heterocyclic group, and may be a condensed polycyclic group in which two or more rings are condensed with each other,
ring A₂₂ may be a C₅-C₆₀ carbocyclic group or a C₁-C₆₀ heterocyclic group,
R₂₁ and R₂₂ may each independently be the same as described in connection with R₂,
R₃₁ and R₃₂ may each independently be the same as described in connection with R₃,
a21 may be an integer from 0 to 2,
a31 may be 0 or 1, and
a22 and a32 may each independently be an integer from 0 to 10.

In an embodiment, in Formulae 1(1)-1 to 1(1)-6 and 1(2)-1 to 1(2)-4, ring A₂₁ may be a naphthalene group, a quinoline group, an isoquinoline group, a quinoxaline group, or a quinazoline group, and
ring A₂₂ may be a benzene group, a pyridine group, a pyrimidine group, a pyrazine group, a pyridazine group, a naphthalene group, a quinoline group, an isoquinoline group, a quinoxaline group, or a quinazoline group.

In an embodiment, ring CY₂ in Formulae 1(2)-1 to 1(2)-4 may be a group represented by Formula 1A. For example, ring CY₂ in Formulae 1(2)-1 to 1(2)-4 may be a dibenzothiophene group or a benzonaphthodibenzothiophene group.

In Formula 1, Y₁ may be O, S, or N(Ria).

In Formula 1, Y₂ may be O, S, or N(R₂ₐ).

In Formula 1, Ria and R₂ₐ may each independently be a group represented by Formula 1B, hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ.

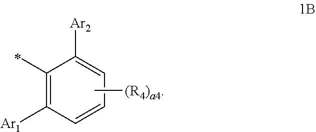

Formula 1B may be the same as described herein.

In an embodiment, Ria and R₂ₐ may each independently be:
a group represented by Formula 1B, hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂); or
Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, and a triazinyl group.

In an embodiment, Ria and R₂ₐ may each independently be:
a group represented by Formula 1B, hydrogen, deuterium, —F, —Cl, —Br, —I, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, or a C₁-C₆₀ alkoxy group; or
a group represented by one of Formulae 9-1 to 9-61, 9-201 to 9-240, 10-1 to 10-129, and 10-201 to 10-355. Formulae 9-1 to 9-61, 9-201 to 9-240, 10-1 to 10-129, and 10-201 to 10-355 may be the same as described herein.

In Formulae 1, 1A, and 1B, the condensed cyclic compound may satisfy at least one of Conditions 1 and 2:

Y₁ is N(R₁ₐ), and R₁ₐ is a group represented by Formula 1B [Condition 1]

Y₂ is N(R₂ₐ), and R₂ₐ is a group represented by Formula 1B. [Condition 2]

In an embodiment, in Formula 1,
Y₁ may be O or S, Y₂ may be N(R₂ₐ), and R₂ₐ may be a group represented by Formula 1B; or
Y₁ may be N(R₁ₐ), Y₂ may be O or S, and R₁ₐ may be a group represented by Formula 1B; or
Y₁ may be N(R₁ₐ), Y₂ may be N(R₂ₐ), and R₁ₐ and R₂ₐ may each independently be a group represented by Formula 1B.

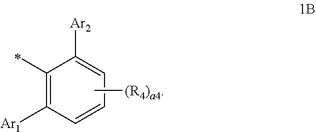

In Formula 1B, Ar₁ and Ar₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ.

In Formula 1B, * indicates a binding site to a neighboring atom.

In an embodiment, in Formula 1B, Ar₁ and Ar₂ may each independently be a C₆-C₆₀ aryl group unsubstituted or substituted with at least one R₁₀ₐ or a C₁-C₆₀ heteroaryl group unsubstituted or substituted with at least one R₁₀ₐ.

In an embodiment, in Formula 1B, Ar₁ and Ar₂ may each independently be a phenyl group, a naphthyl group, a pyridinyl group, a pyrazinyl group, a pyrimidinyl group, a pyridazinyl group, or a triazinyl group, each unsubstituted or substituted with at least one R₁₀ₐ.

In an embodiment, the group represented by Formula 1B may be a group represented by Formula 1B(1).

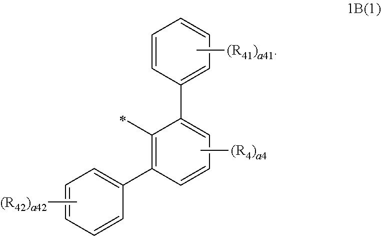

In Formula 1B(1),
R₄ and a4 may each be the same as described herein,
R₄₁ and R₄₂ may each independently be hydrogen or the same as described in connection with R₁₀ₐ, and
a41 and a42 may each independently be an integer from 1 to 5.

In an embodiment, in Formula 1B(1), R₄, R₄₁, and R₄₂ may each independently be:

hydrogen, deuterium, —F, —Cl, —Br, —I, a cyano group, a C₁-C₂₀ alkyl group, a C₆-C₆₀ aryl group, or a C₁-C₃₀ heteroaryl group; or
a C₁-C₂₀ alkyl group, a C₆-C₆₀ aryl group, or a C₁-C₃₀ heteroaryl group, each substituted with deuterium, —F, —Cl, —Br, —I, a cyano group, —CD₃, —CD₂H, —CDH₂, —CF₃, —CF₂H, —CFH₂, a C₁-C₁₀ alkyl group, a phenyl group, a biphenyl group, or any combination thereof.

In Formula 1, T₁ may be a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ.

In Formula 1, b1 may be an integer from 1 to 10.

In an embodiment, T₁ may be a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂).

In an embodiment, T₁ may be a group represented by one of Formulae 1T-1 to 1T-9.

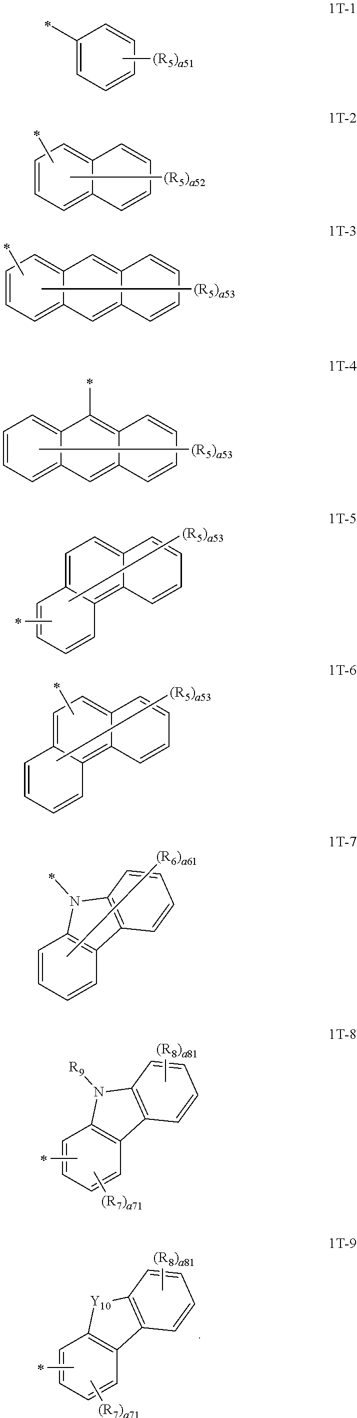

Y₁₀ may be O, S, or Se,
R₅ to R₉ may each independently be hydrogen or the same as described in connection with R₁₀ₐ,
a51 may be an integer from 1 to 5,
a52 may be an integer from 1 to 7,
a53 may be an integer from 1 to 9,
a61 may be an integer from 1 to 8,
a71 may be an integer from 1 to 3,
a81 may be an integer from 1 to 4, and
* indicates a binding site to a neighboring atom.

In Formula 1, R₁ to R₄ may each independently be hydrogen, deuterium, —F, —C₁, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

In an embodiment, R₁ to R₄ may each independently be:
hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂); or
Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, and a triazinyl group.

In an embodiment, R₁ to R₄ may each independently be:
hydrogen, deuterium, —F, —Cl, —Br, —I, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, or a C₁-C₆₀ alkoxy group; or
a group represented by one of Formulae 9-1 to 9-61, 9-201 to 9-240, 10-1 to 10-129, and 10-201 to 10-355.

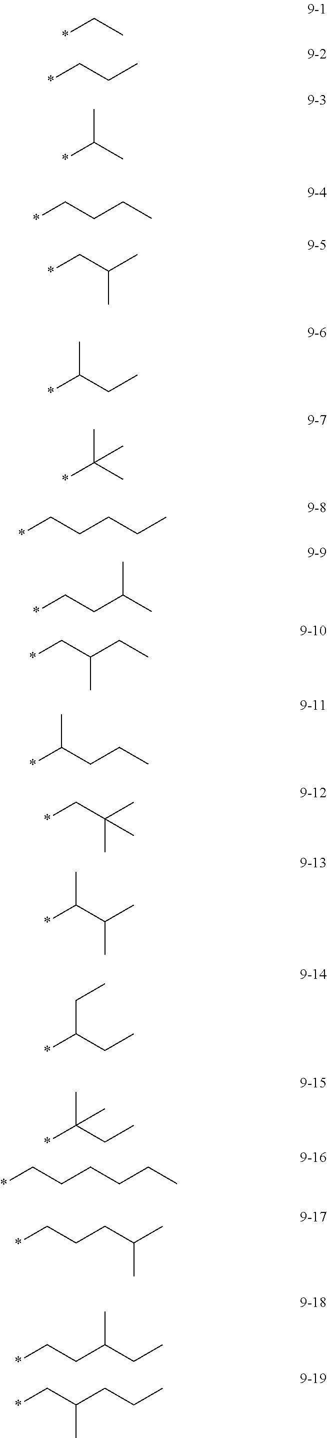

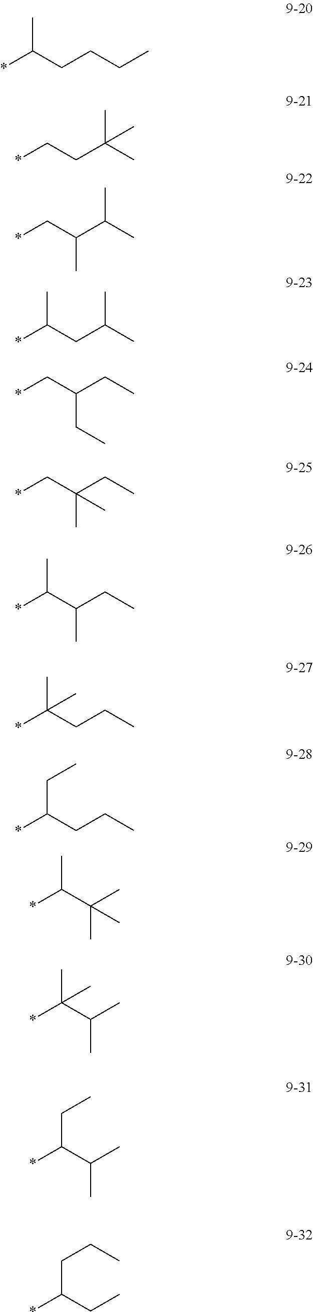

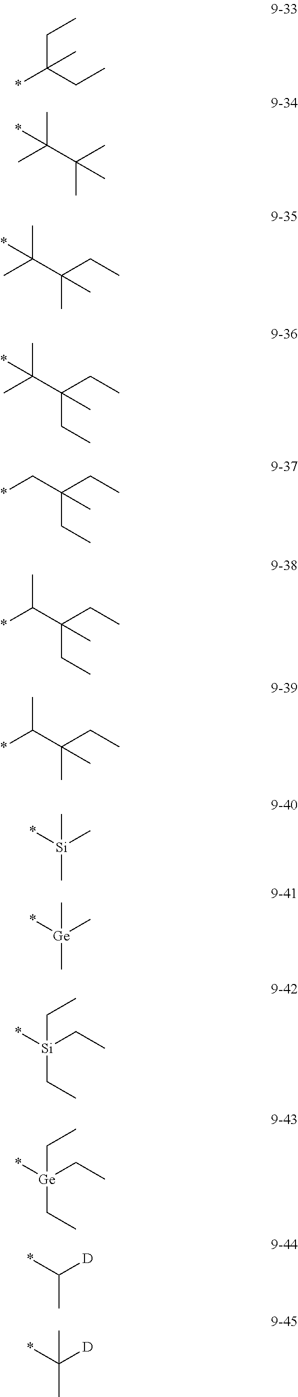

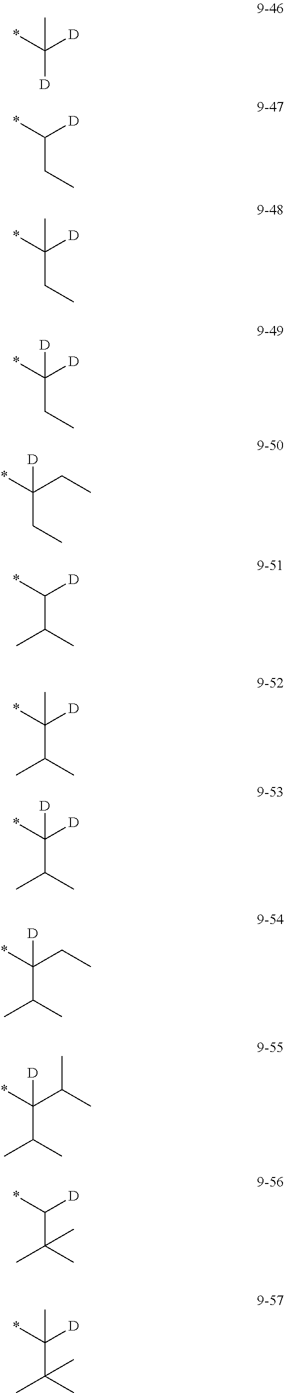

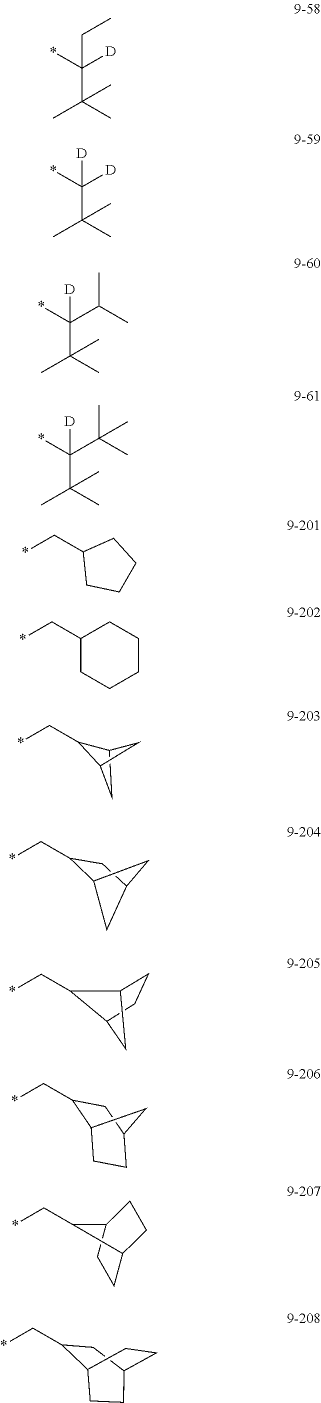

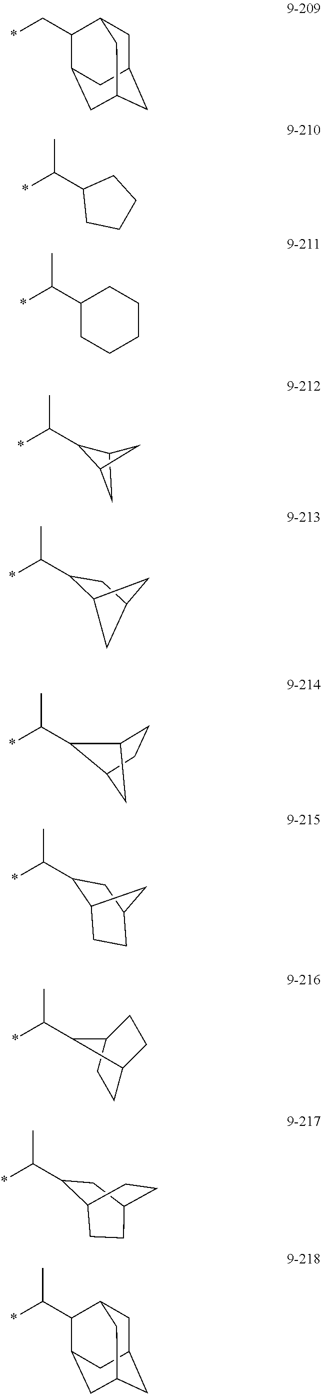

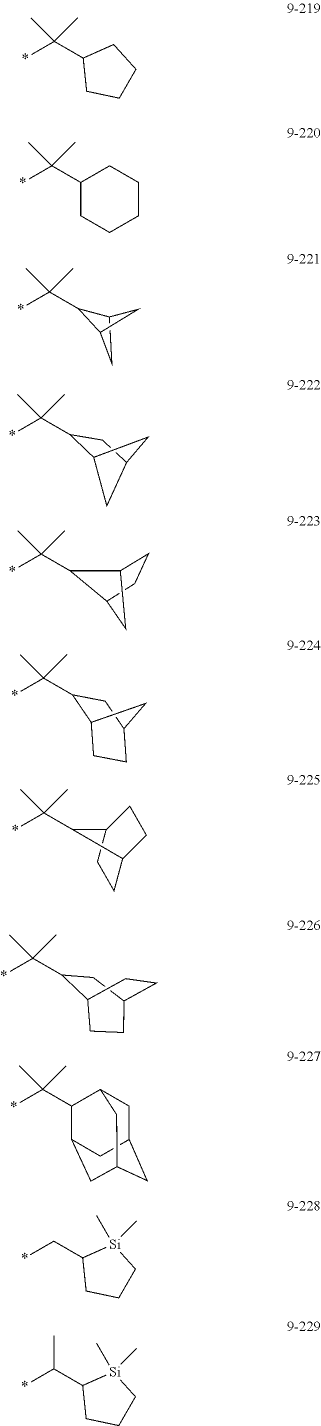

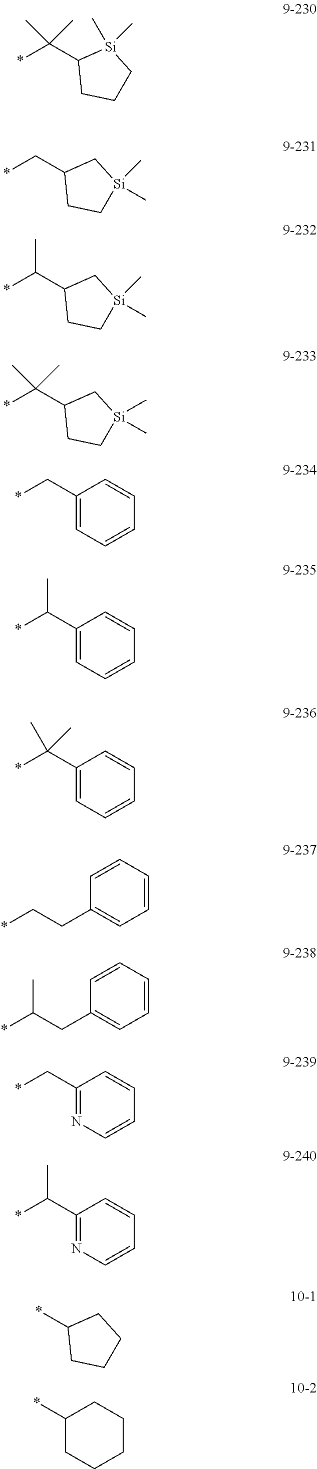

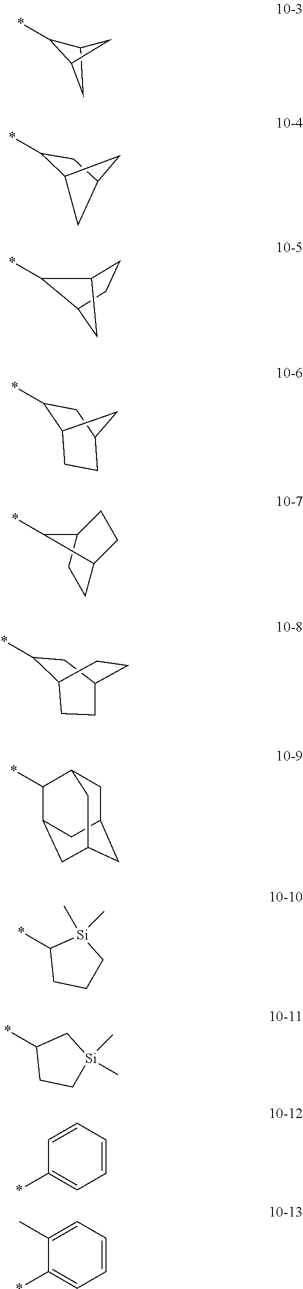

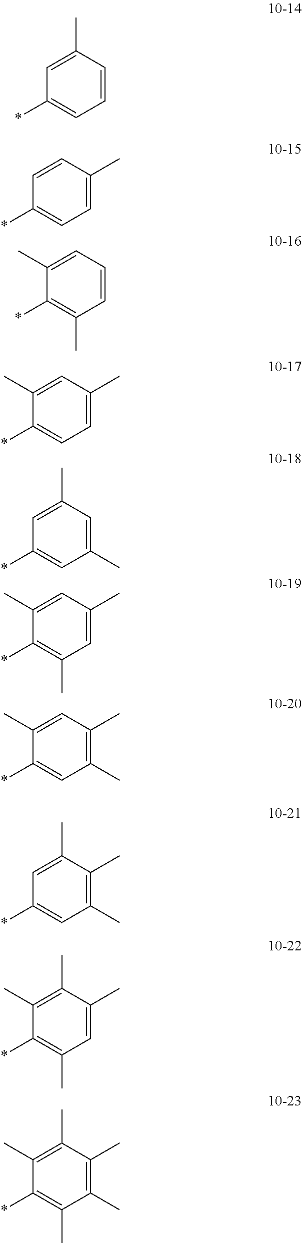

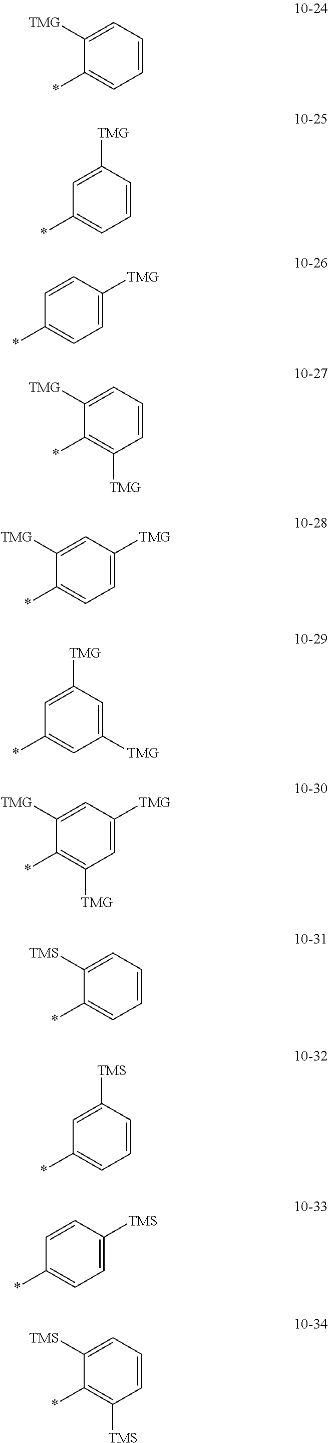

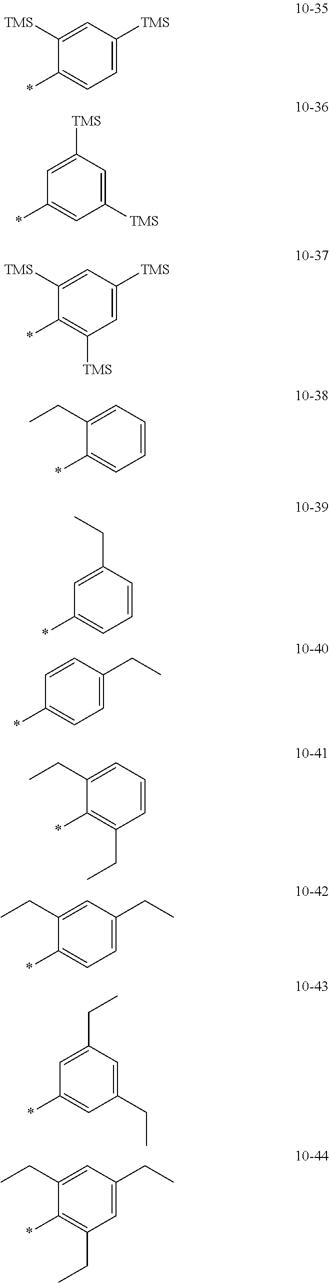

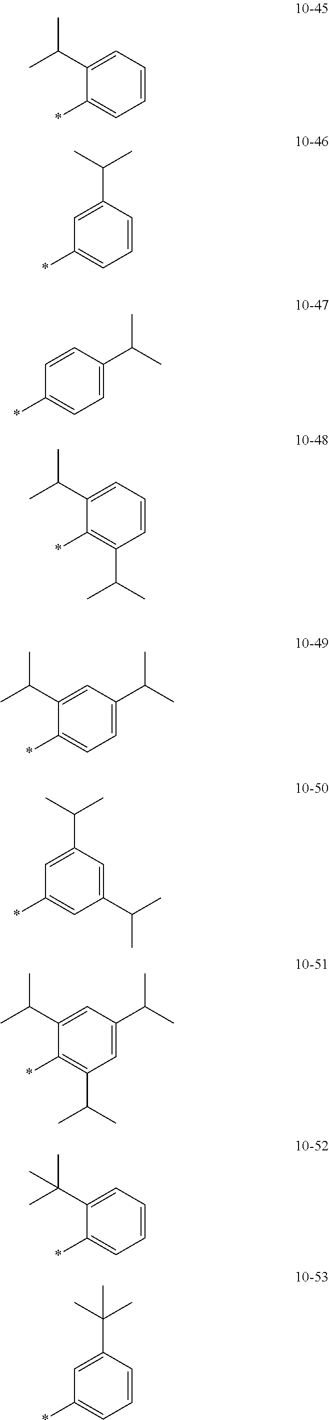

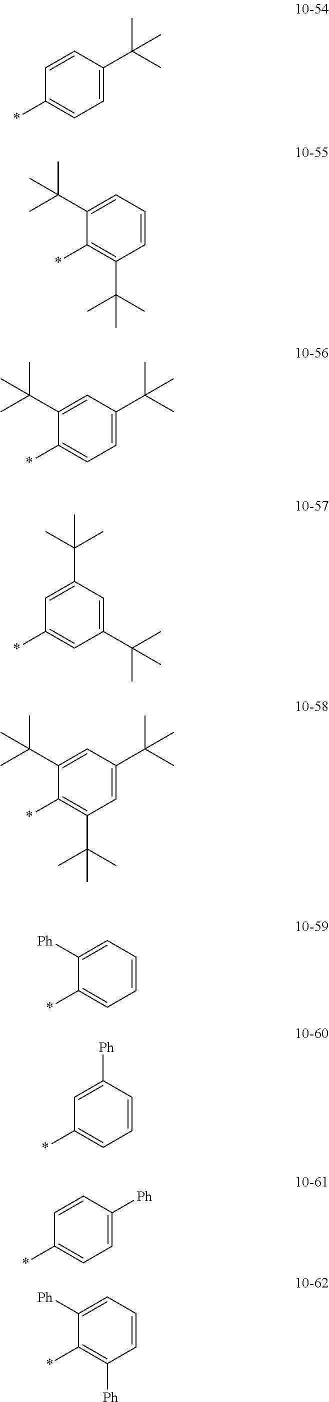

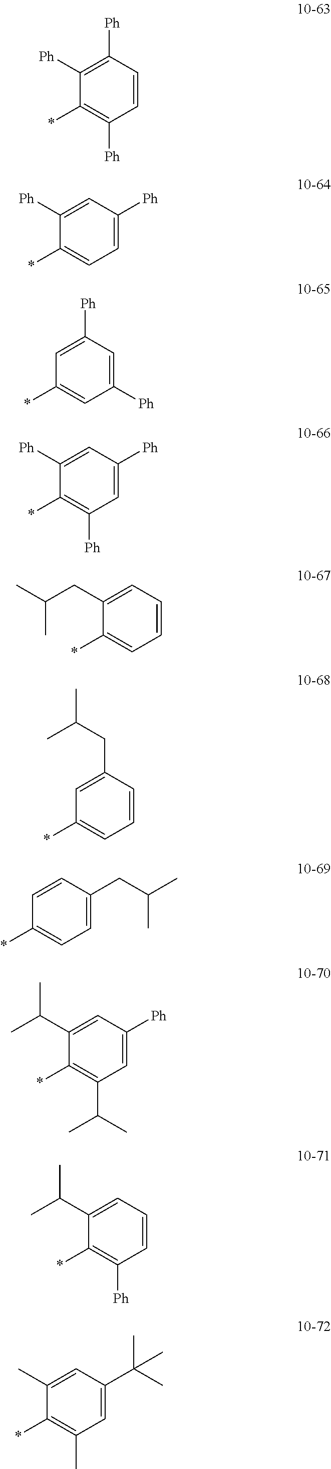

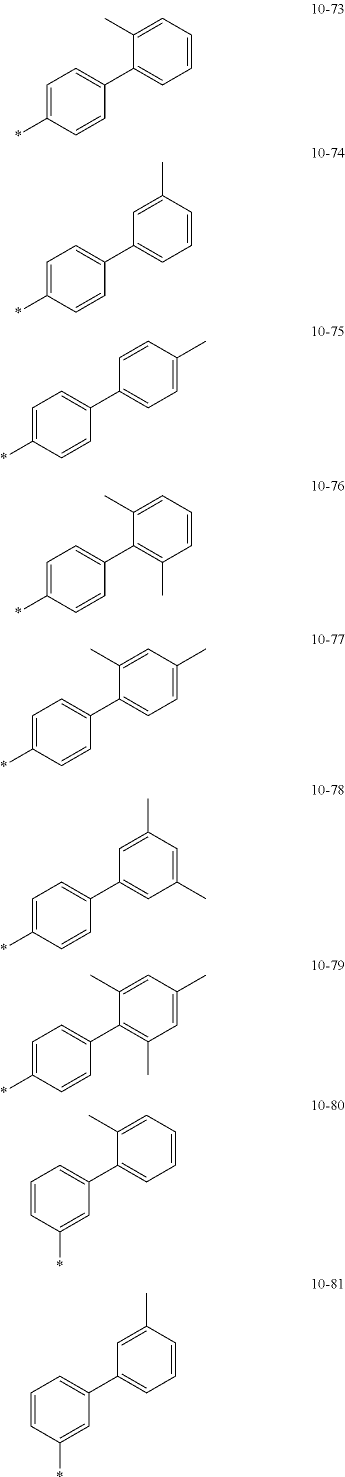

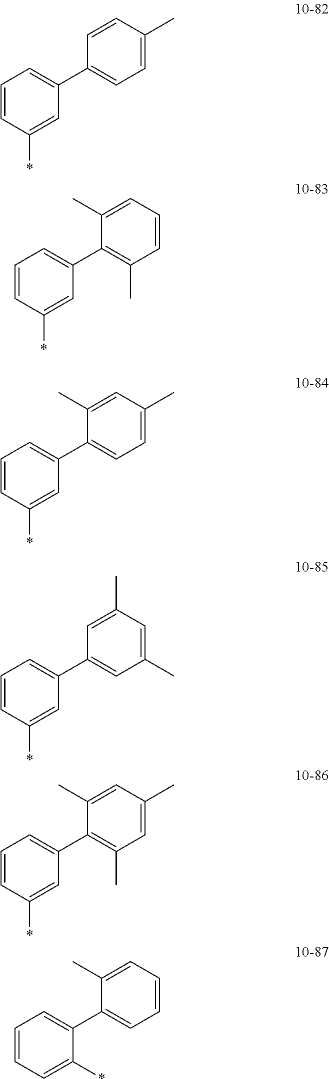

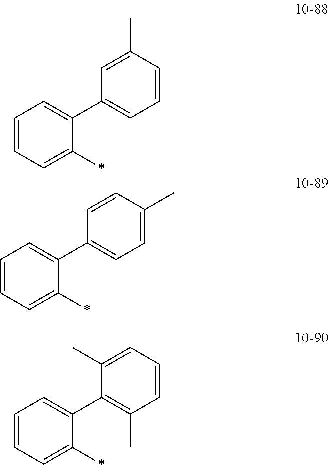

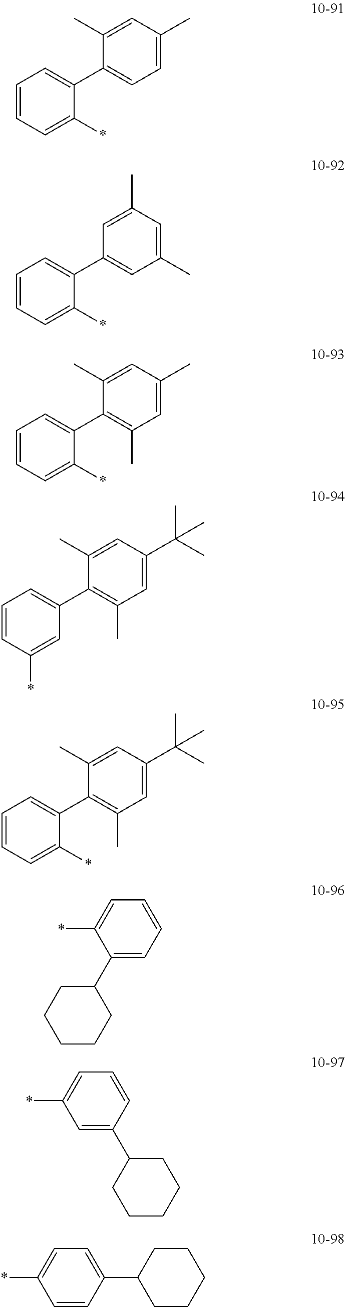

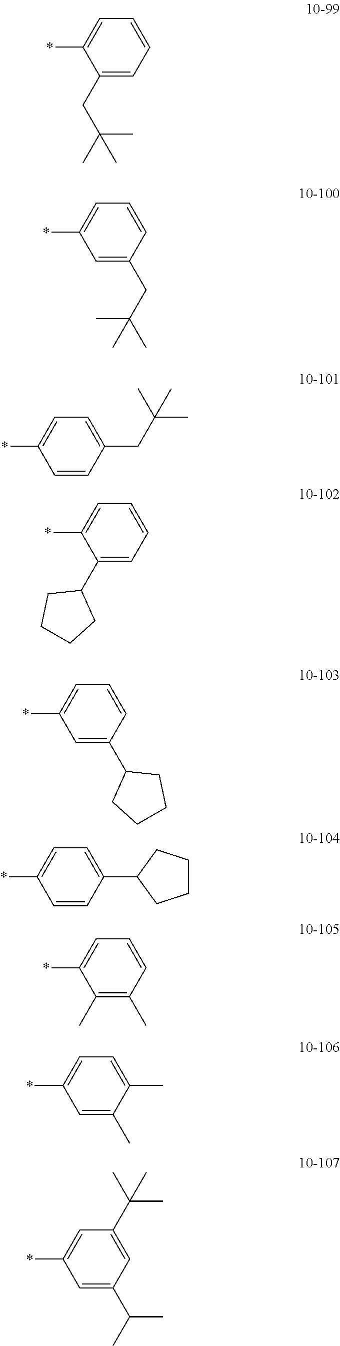

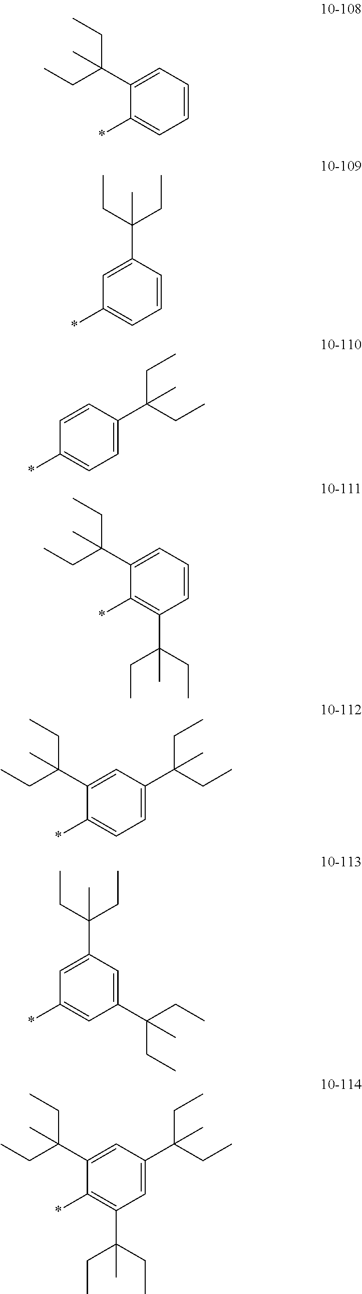

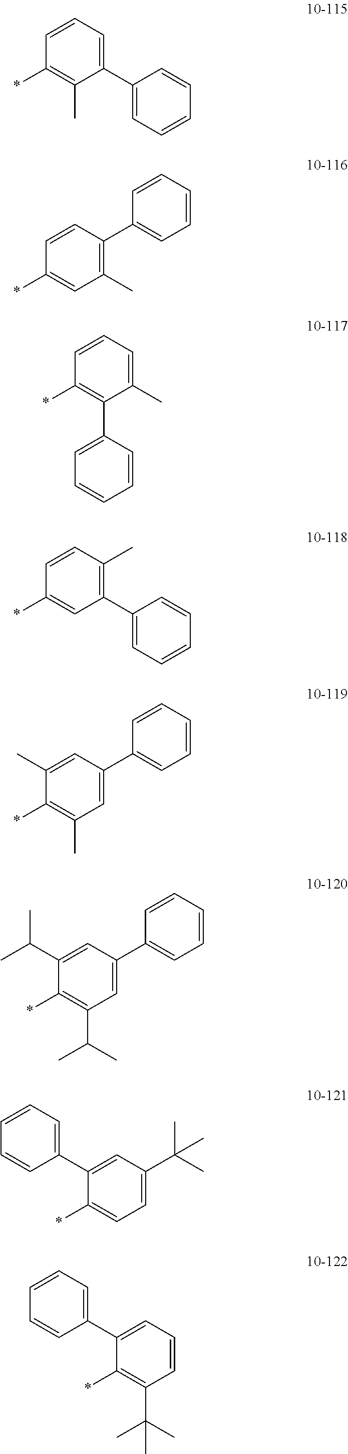

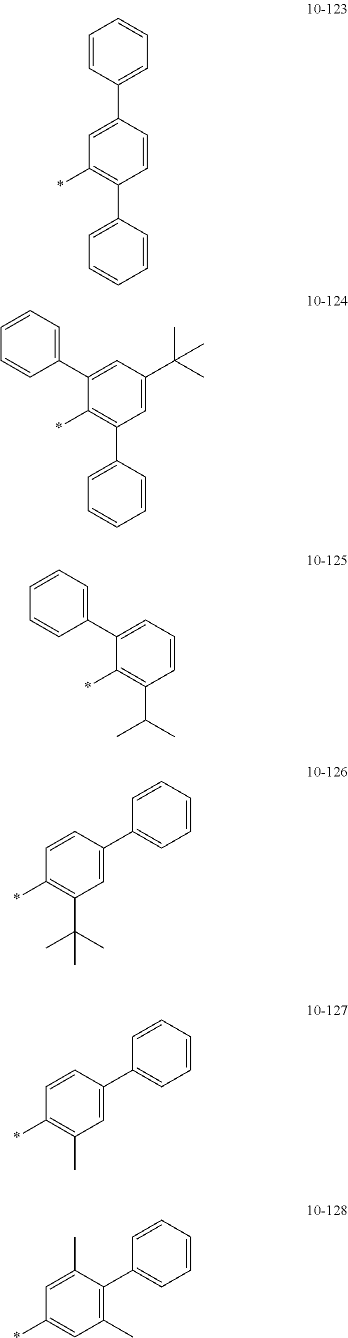

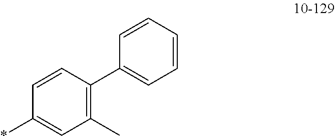 [SMILES: *c1ccc(-c2ccccc2)c(C)c1]

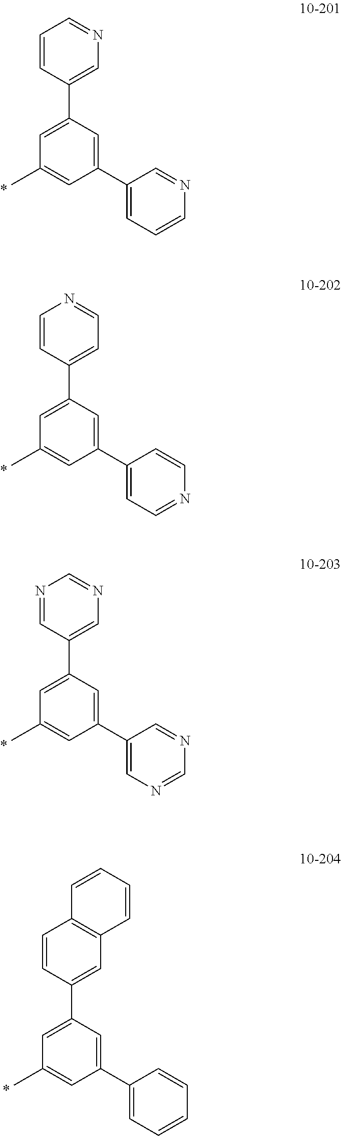

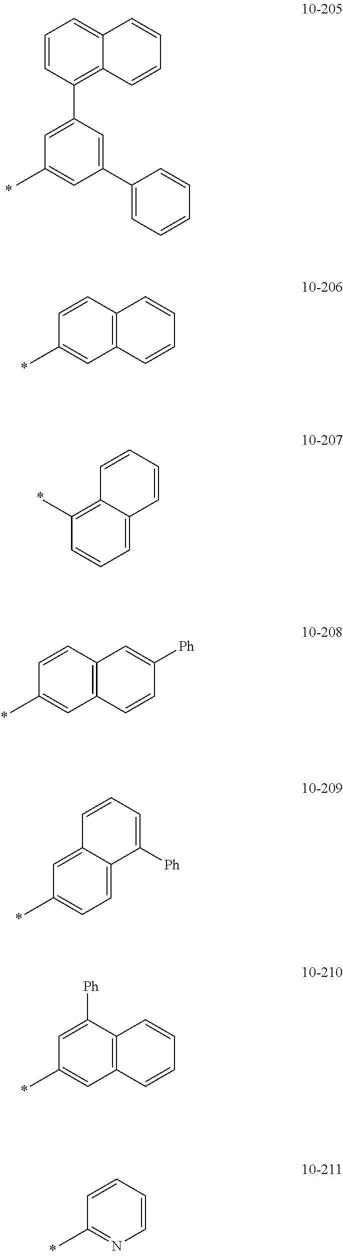

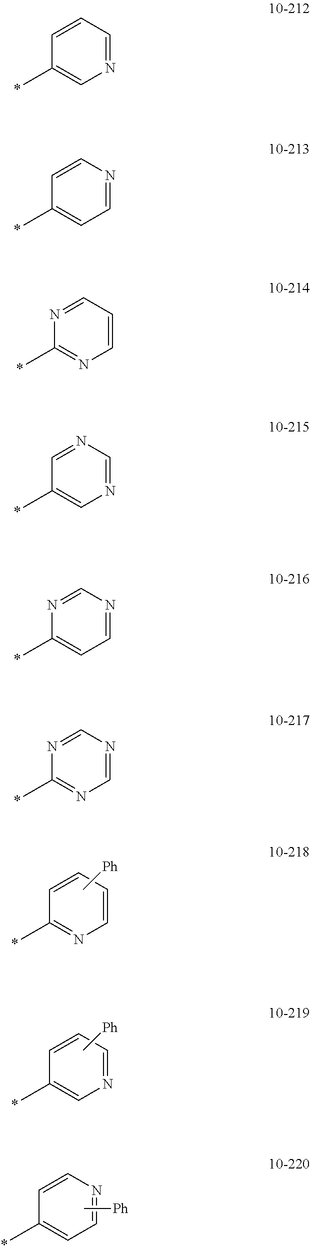

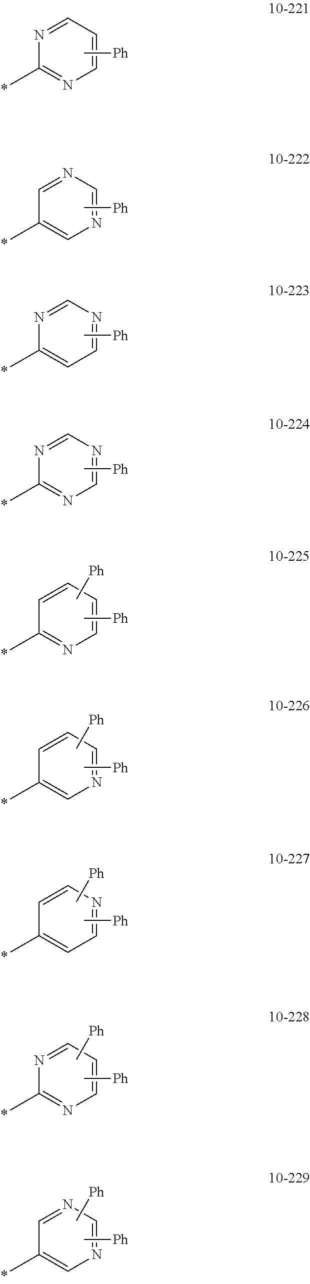

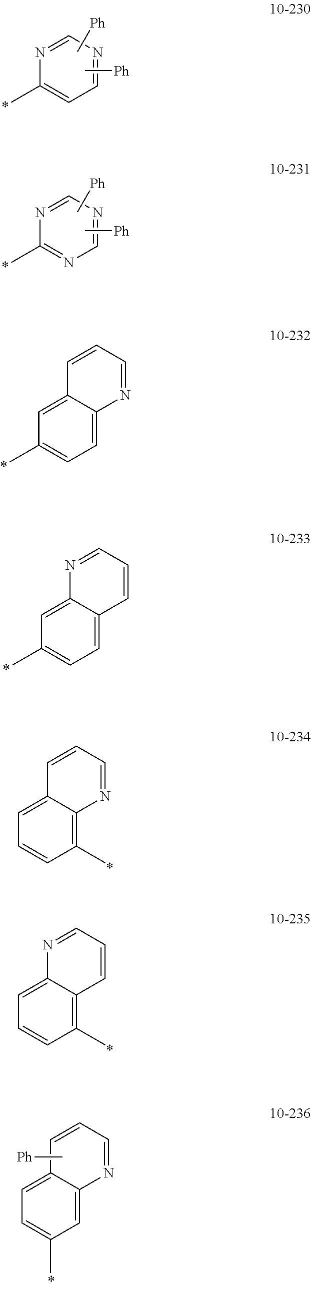

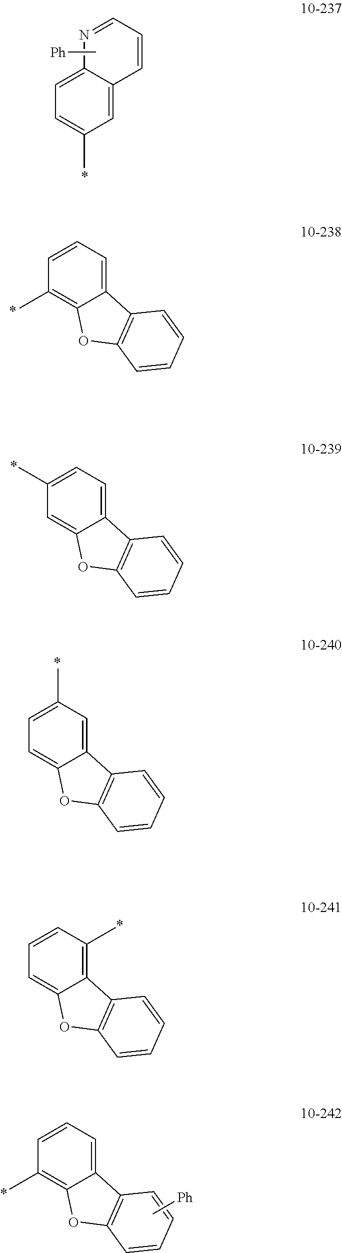

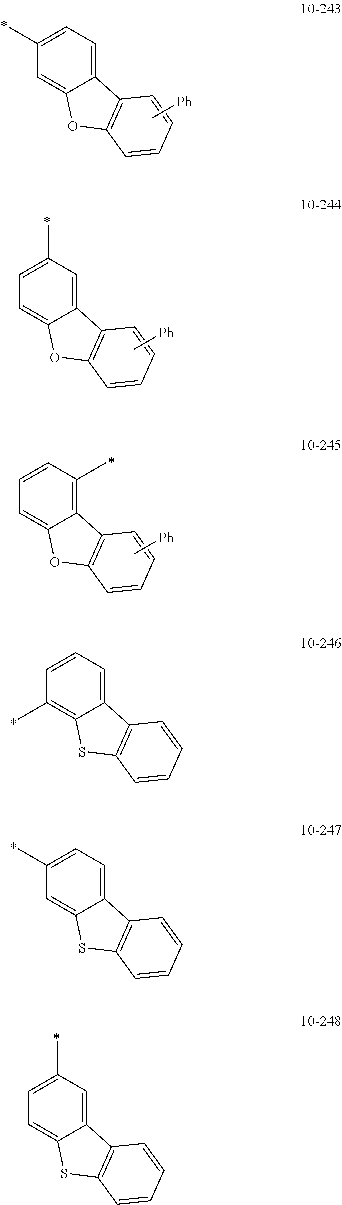

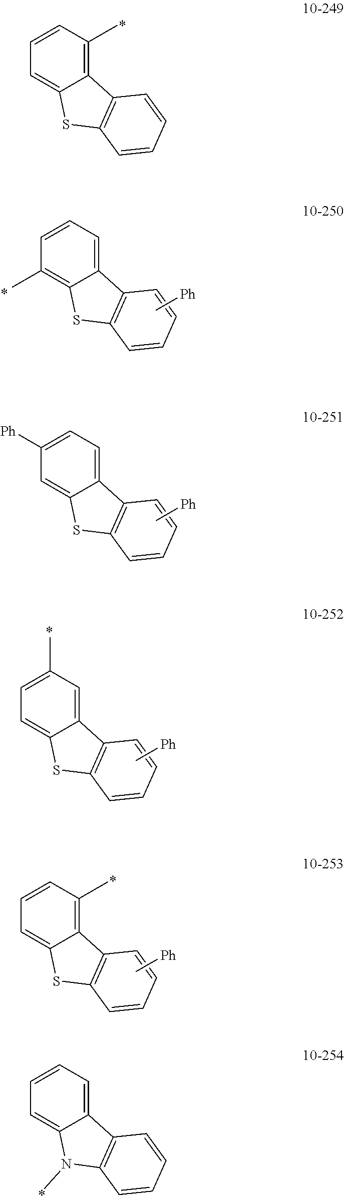

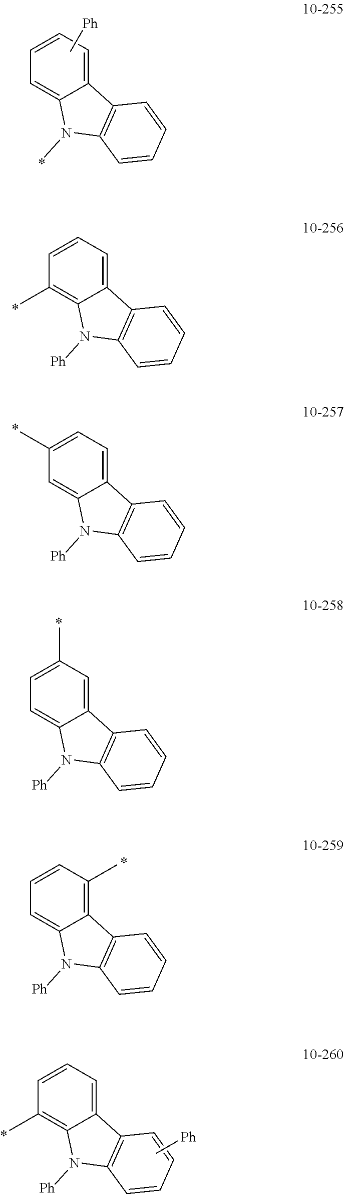

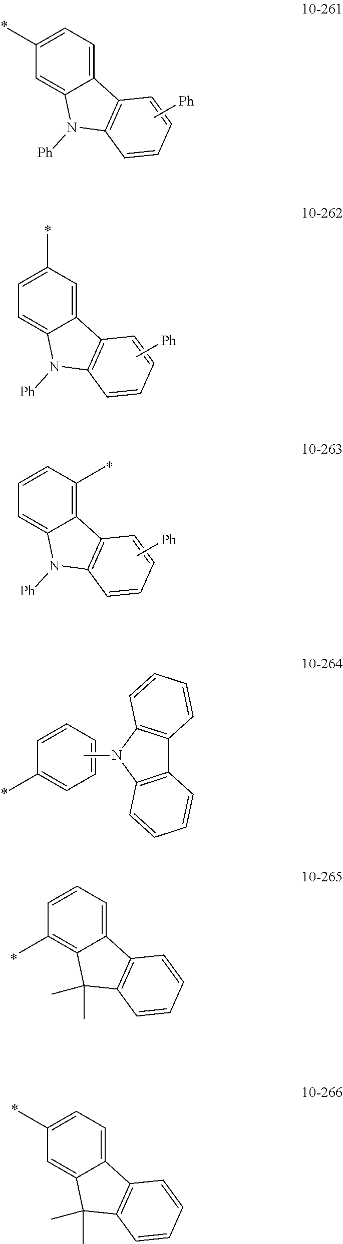

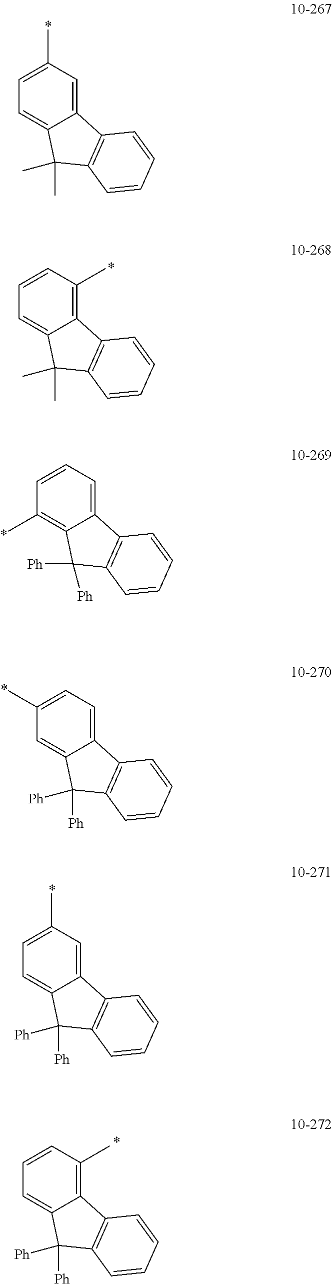

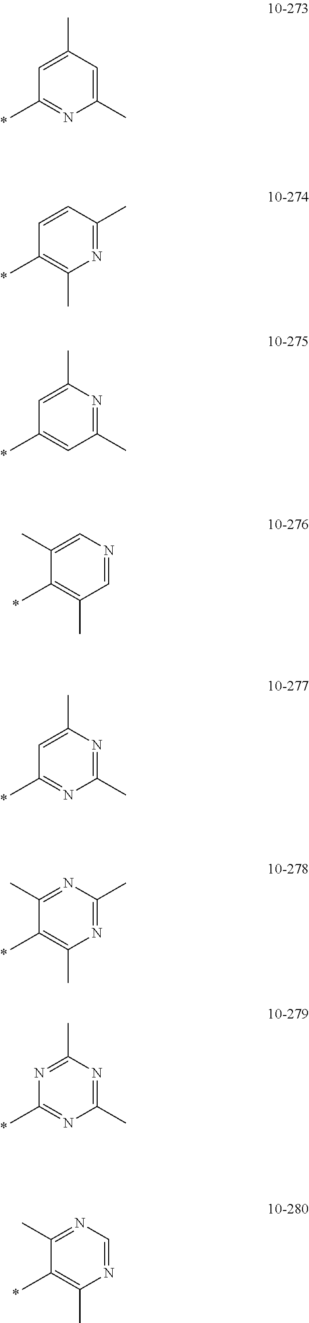

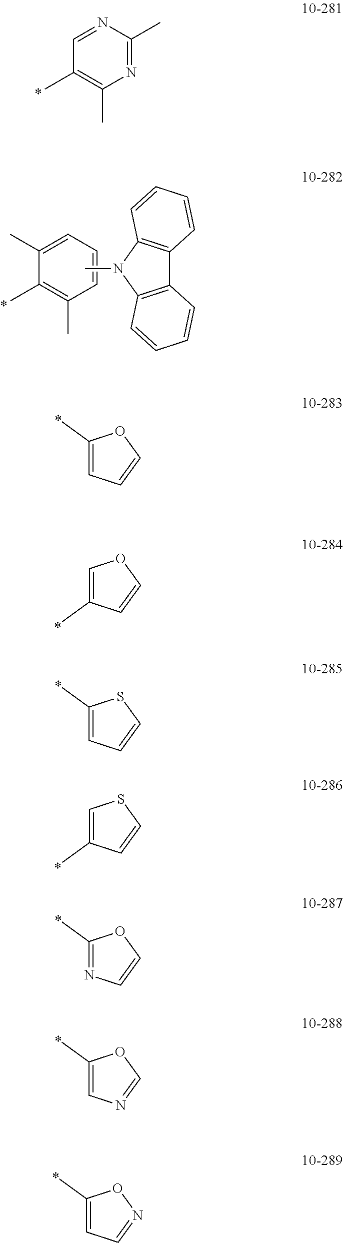

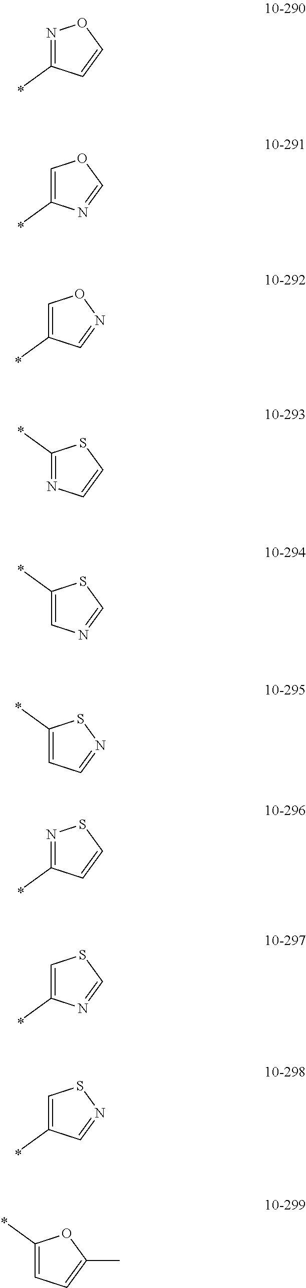

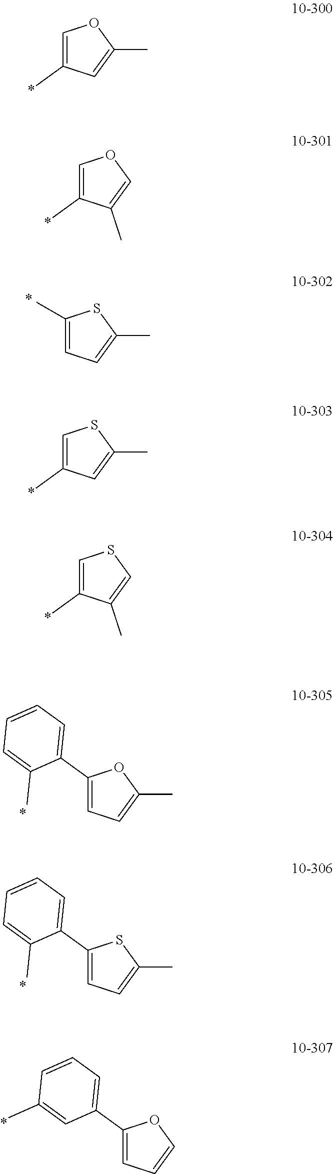

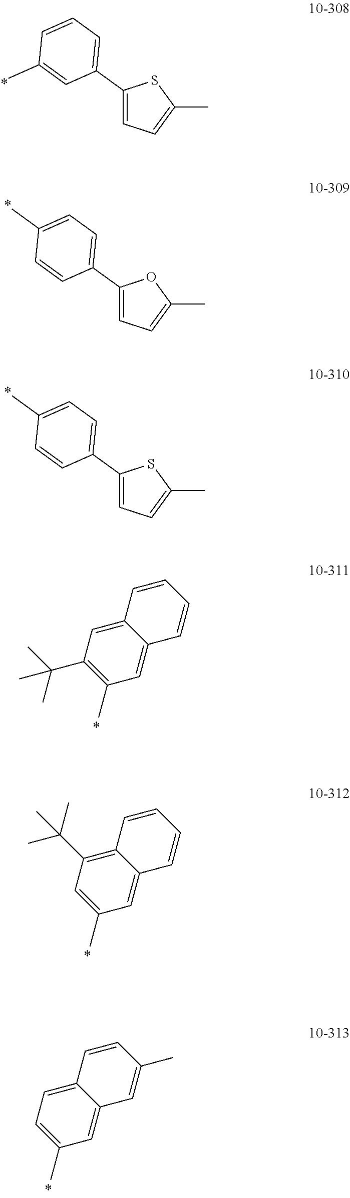

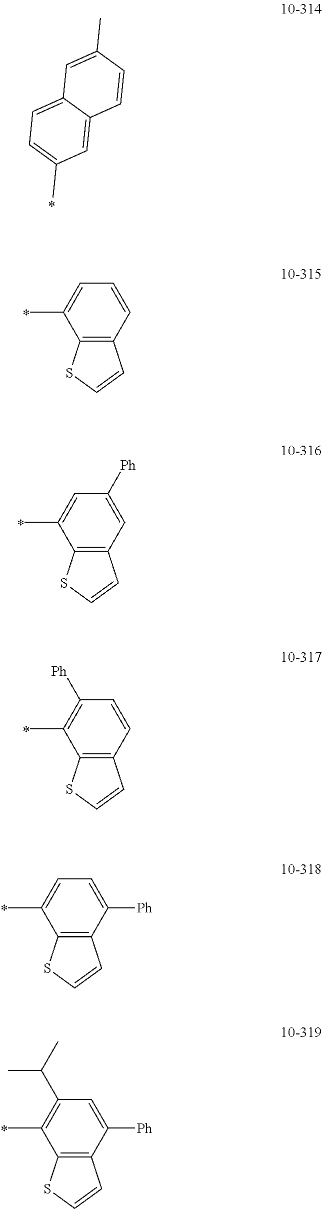

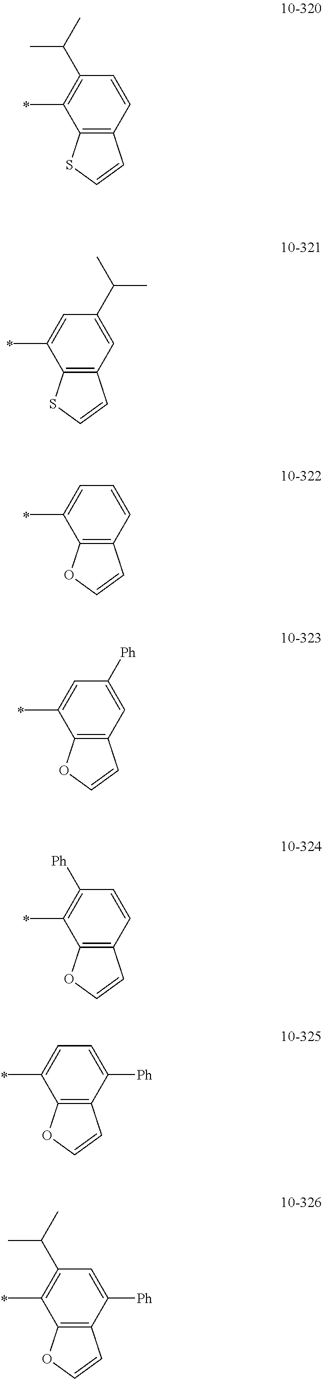

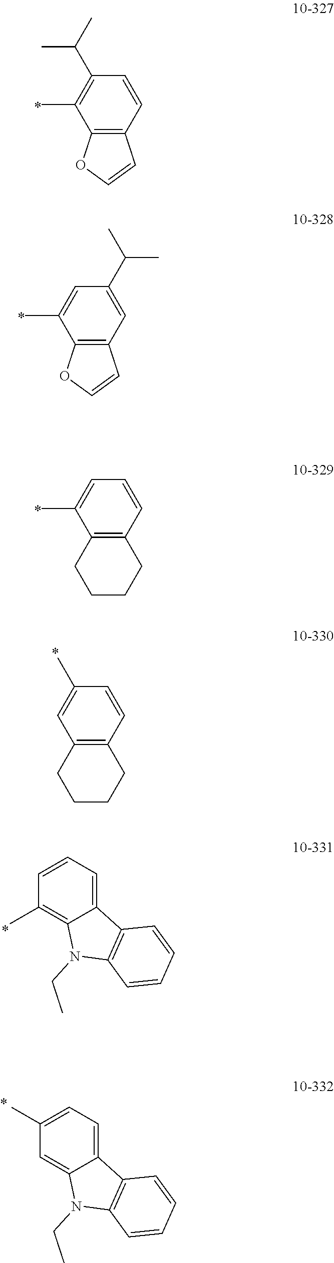

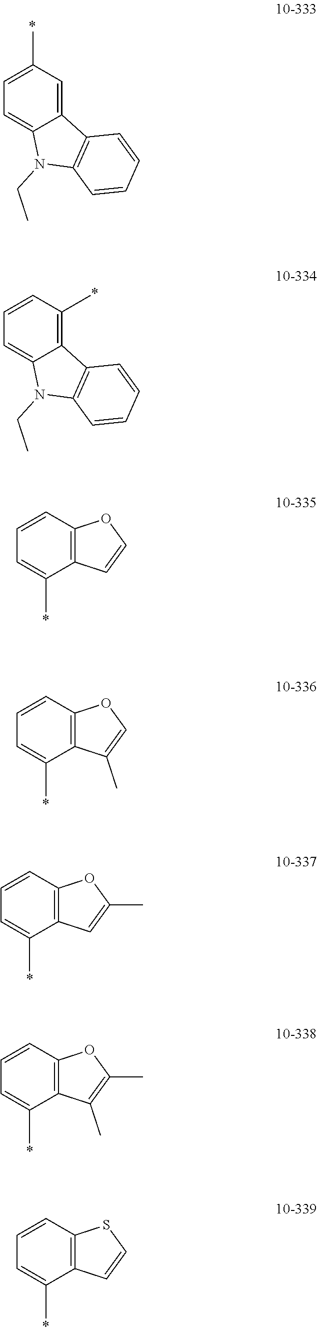

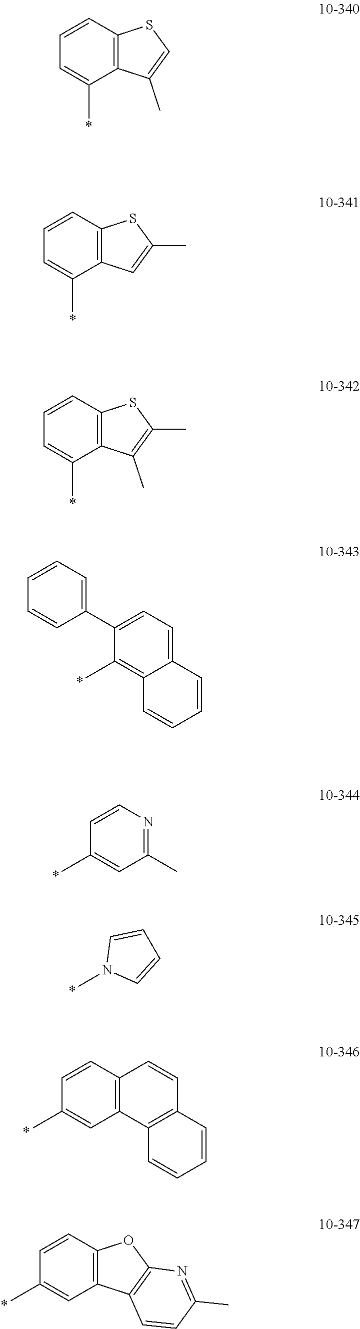

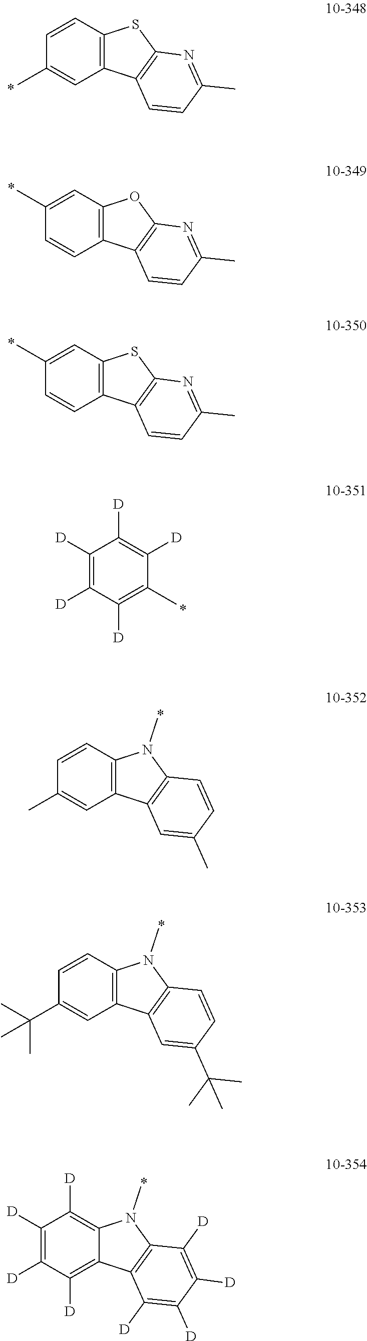

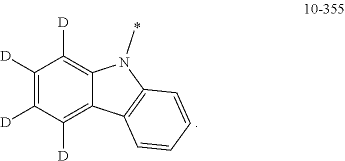 [SMILES: [2H]c1c([2H])c([2H])c2c(c1[2H])c1ccccc1n2C]

In Formulae 9-1 to 9-61, 9-201 to 9-240, 10-1 to 10-129, and 10-201 to 10-355, * indicates a binding site to a neighboring atom, Ph represents a phenyl group, TMS represents a trimethylsilyl group, TMG represents a trimethylgermyl group, and D represents a deuterium atom.

In Formula 1, a1 to a3 may each independently be an integer from 0 to 10.

In Formula 1, a4 may be an integer from 0 to 3.

In an embodiment, the condensed cyclic compound may be one of Compounds 1 to 546.

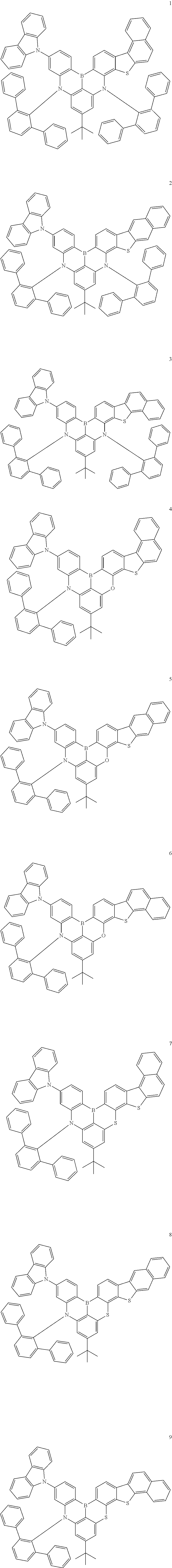

[chemical structure]

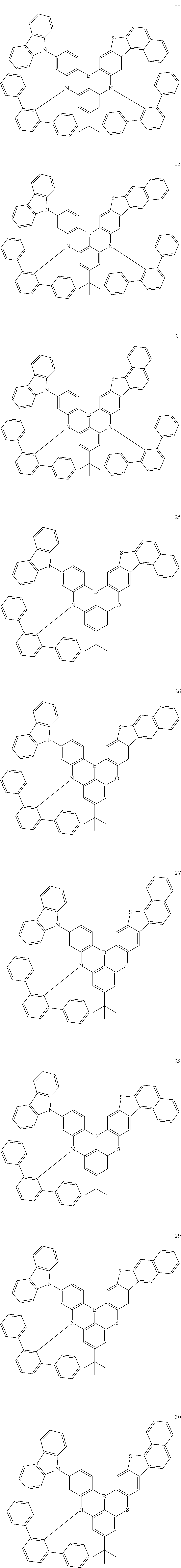

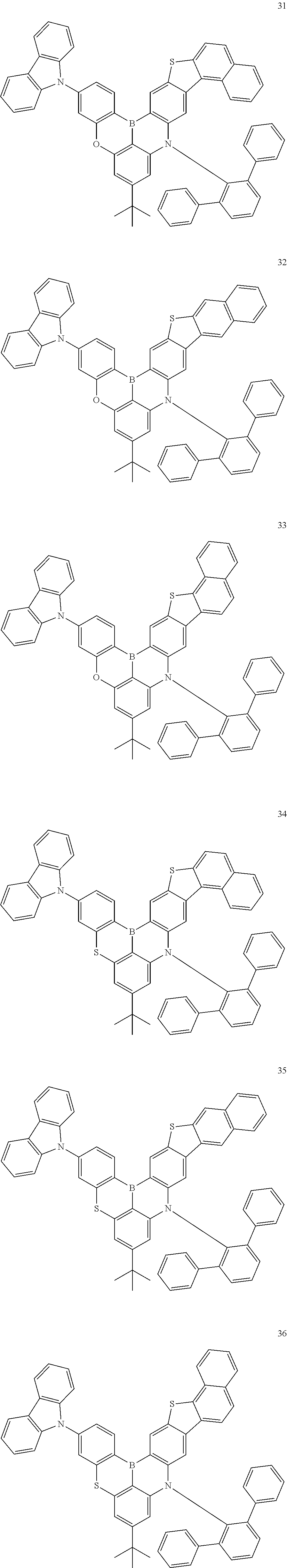

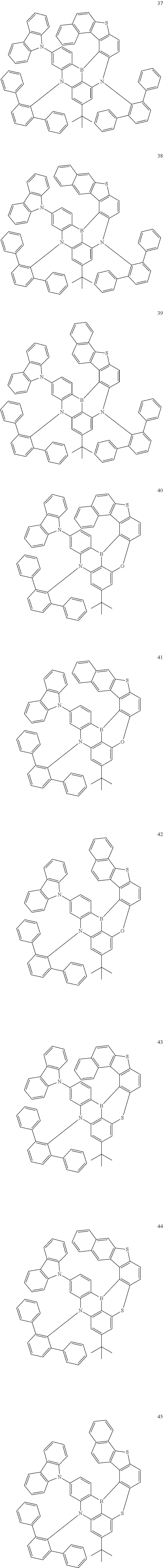

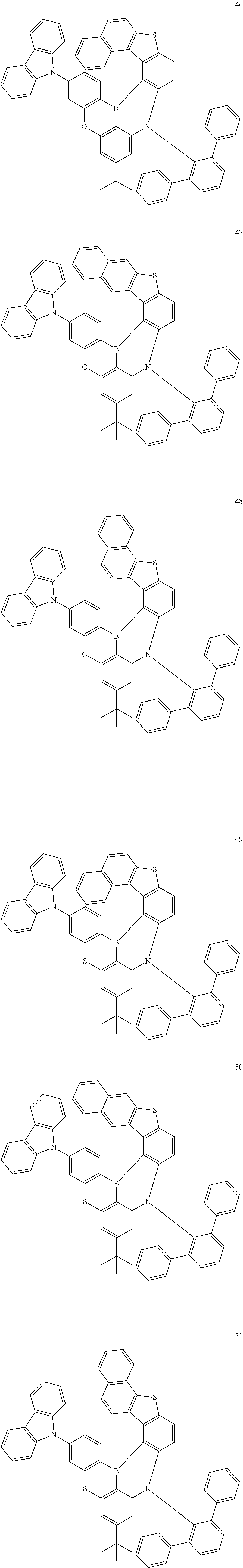

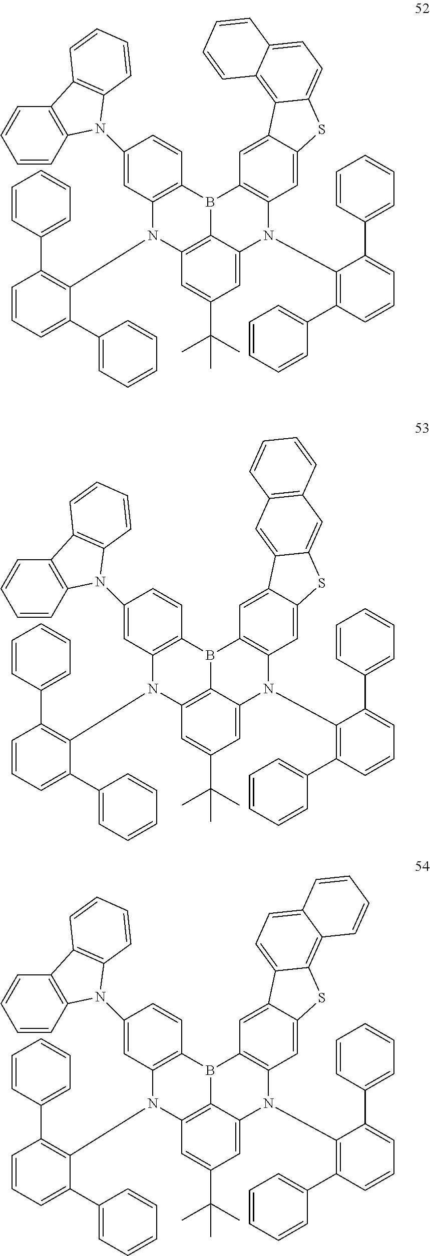 [SMILES: CC(C)(C)c1cc2c3c(c1)N(c1c(-c4ccccc4)cccc1-c1ccccc1)c1cc4sc5ccc6ccccc6c5c4cc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc4sc5cc6ccccc6cc5c4cc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc4sc5c6ccccc6ccc5c4cc1B3c1ccc(-n3c4ccccc4c4ccccc43)cc1N2c1c(-c2ccccc2)cccc1-c1ccccc1]

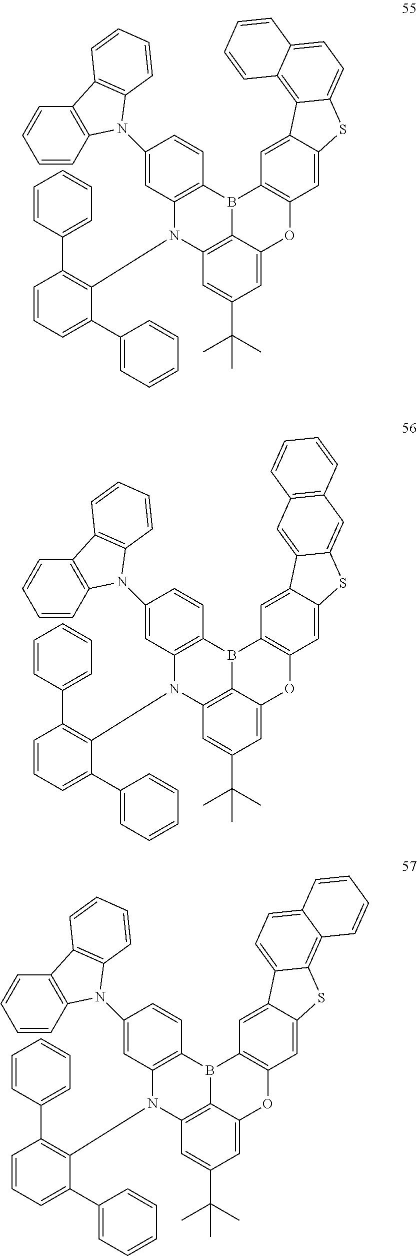 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)sc1ccc2ccccc2c13 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)sc1cc2ccccc2cc13 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)sc1c2ccccc2ccc31]

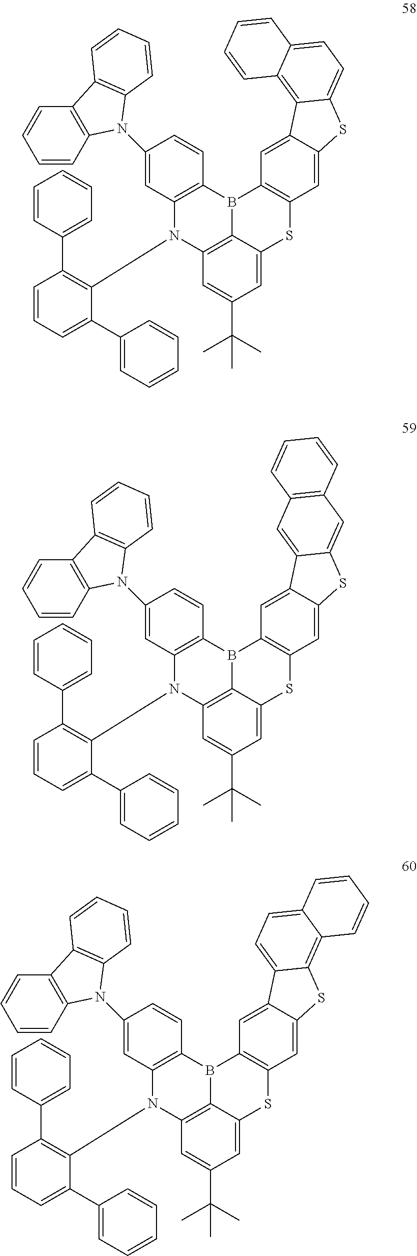 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1S2)sc1ccc2ccccc2c13 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1S2)sc1cc2ccccc2cc13 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1S2)sc1c2ccccc2ccc31]

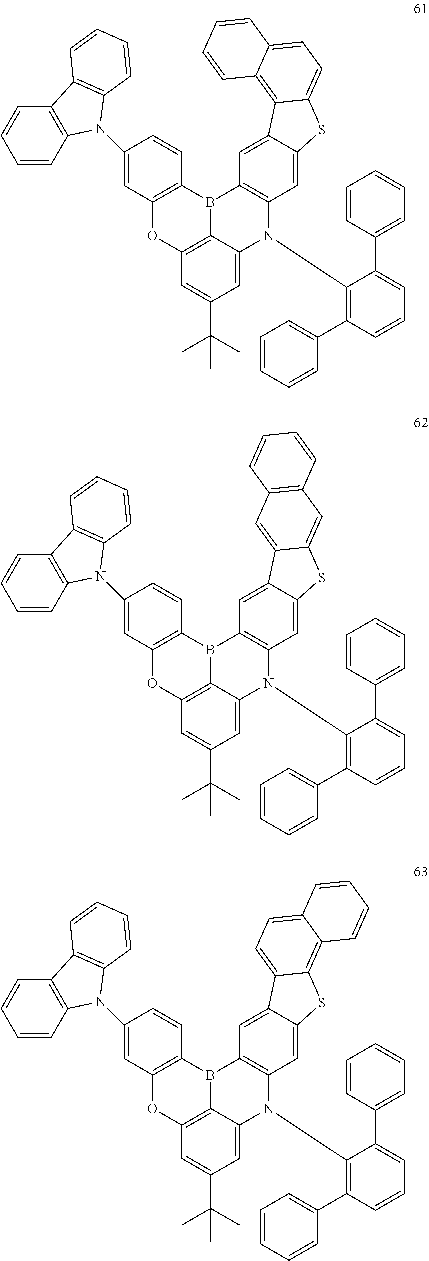

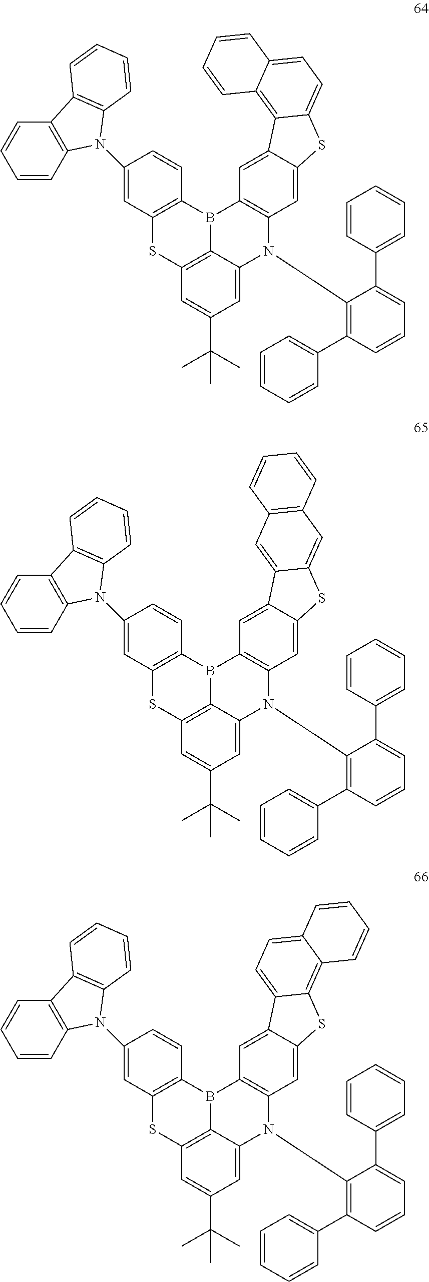 [SMILES: CC(C)(C)c1cc2c3c(c1)N(c1c(-c4ccccc4)cccc1-c1ccccc1)c1cc4sc5ccc6ccccc6c5c4cc1B3c1ccc(-n3c4ccccc4c4ccccc43)cc1S2 ; CC(C)(C)c1cc2c3c(c1)N(c1c(-c4ccccc4)cccc1-c1ccccc1)c1cc4sc5cc6ccccc6cc5c4cc1B3c1ccc(-n3c4ccccc4c4ccccc43)cc1S2 ; CC(C)(C)c1cc2c3c(c1)N(c1c(-c4ccccc4)cccc1-c1ccccc1)c1cc4sc5c6ccccc6ccc5c4cc1B3c1ccc(-n3c4ccccc4c4ccccc43)cc1S2]

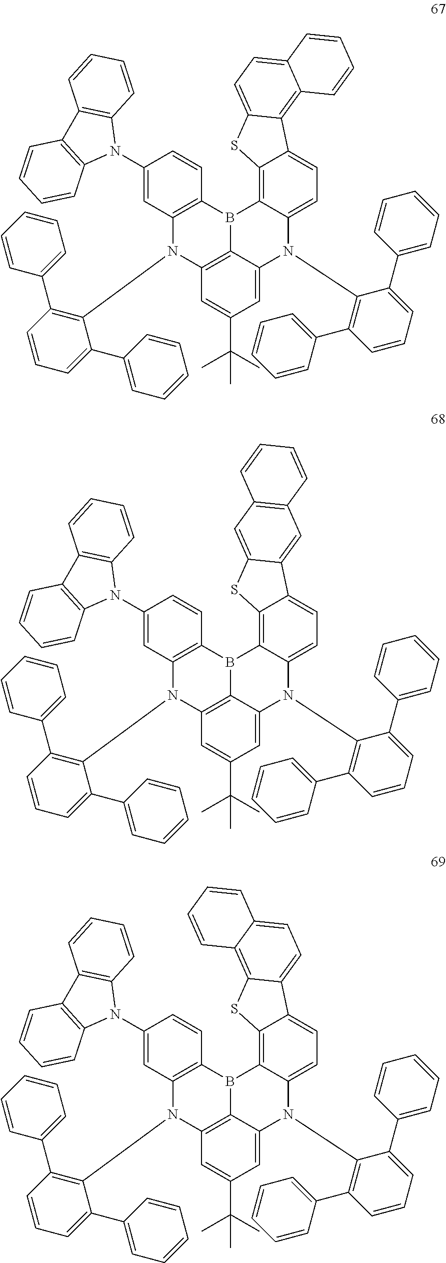 [SMILES: CC(C)(C)c1cc2c3c(c1)N(c1c(-c4ccccc4)cccc1-c1ccccc1)c1ccc4c(sc5ccc6ccccc6c54)c1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1ccc4c(sc5cc6ccccc6cc54)c1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1ccc4c(sc5c6ccccc6ccc45)c1B3c1ccc(-n3c4ccccc4c4ccccc43)cc1N2c1c(-c2ccccc2)cccc1-c1ccccc1]

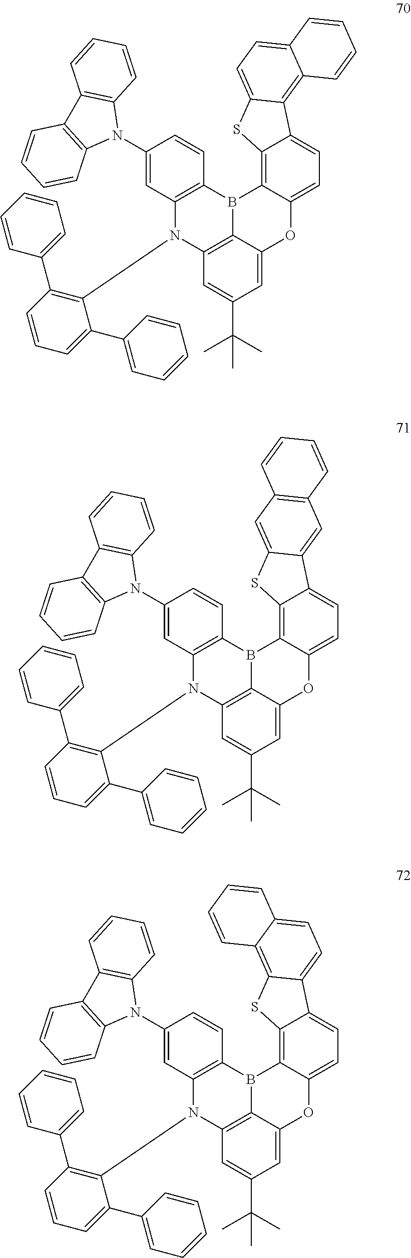 [SMILES: CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1ccc4ccccc4c13)O2 ; CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1cc4ccccc4cc13)O2 ; CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1c4ccccc4ccc31)O2]

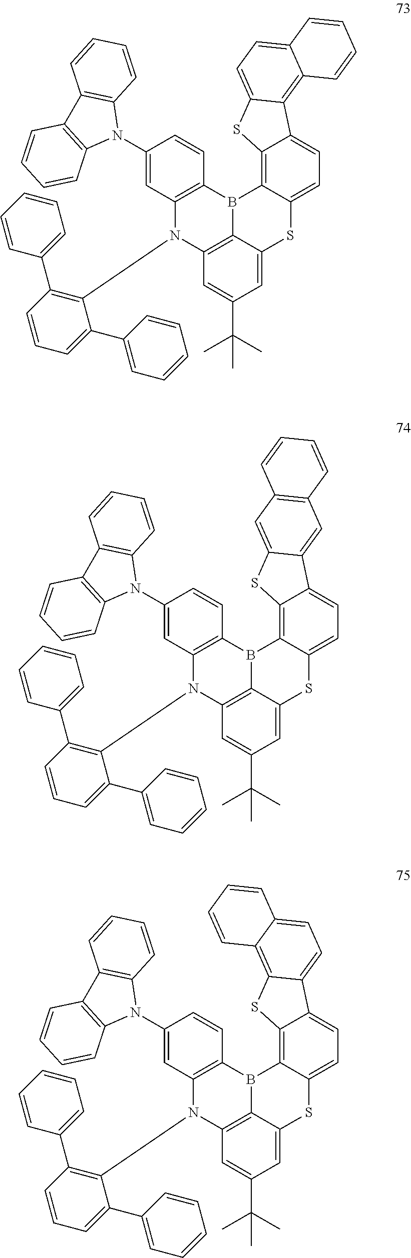 [SMILES: CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1ccc4ccccc4c13)S2 ; CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1cc4ccccc4cc13)S2 ; CC(C)(C)c1cc2c3c(c1)N(c1c(-c4ccccc4)cccc1-c1ccccc1)c1cc(-n4c5ccccc5c5ccccc54)ccc1B3c1c(ccc3c1sc1c4ccccc4ccc31)S2]

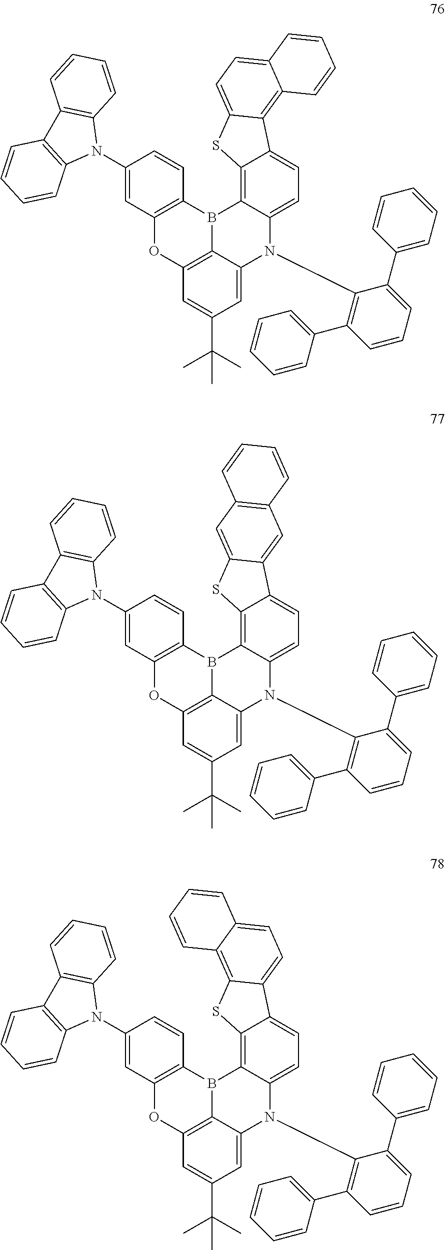 [SMILES: CC(C)(C)c1cc2c3c(c1)N(c1c(-c4ccccc4)cccc1-c1ccccc1)c1ccc4c(sc5ccc6ccccc6c54)c1B3c1ccc(-n3c4ccccc4c4ccccc43)cc1O2 ; CC(C)(C)c1cc2c3c(c1)N(c1c(-c4ccccc4)cccc1-c1ccccc1)c1ccc4c(sc5cc6ccccc6cc54)c1B3c1ccc(-n3c4ccccc4c4ccccc43)cc1O2 ; CC(C)(C)c1cc2c3c(c1)N(c1c(-c4ccccc4)cccc1-c1ccccc1)c1ccc4c(sc5c6ccccc6ccc45)c1B3c1ccc(-n3c4ccccc4c4ccccc43)cc1O2]

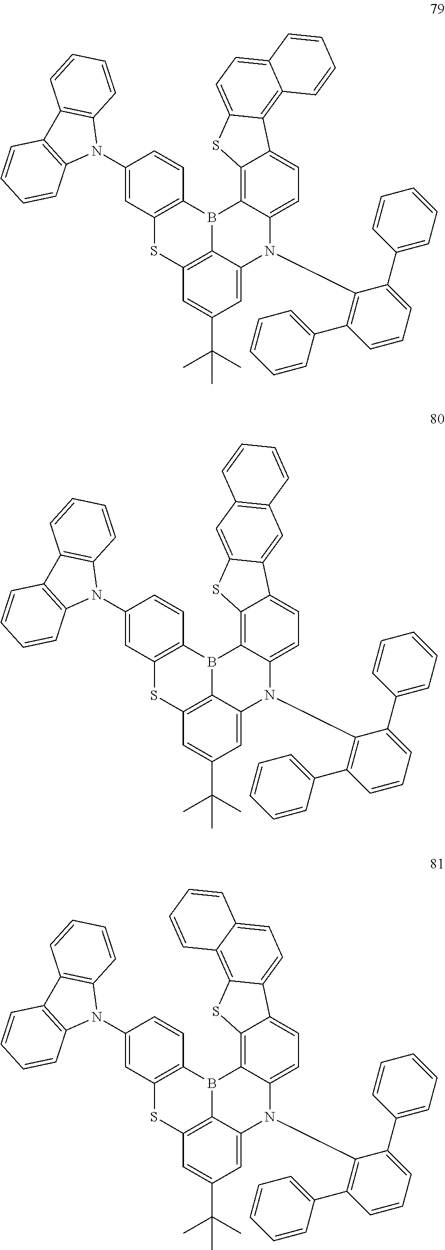 [SMILES: CC(C)(C)c1cc2c3c(c1)N(c1c(-c4ccccc4)cccc1-c1ccccc1)c1ccc4c(sc5ccc6ccccc6c54)c1B3c1ccc(-n3c4ccccc4c4ccccc43)cc1S2 ; CC(C)(C)c1cc2c3c(c1)N(c1c(-c4ccccc4)cccc1-c1ccccc1)c1ccc4c(sc5cc6ccccc6cc54)c1B3c1ccc(-n3c4ccccc4c4ccccc43)cc1S2 ; CC(C)(C)c1cc2c3c(c1)N(c1c(-c4ccccc4)cccc1-c1ccccc1)c1ccc4c(sc5c6ccccc6ccc45)c1B3c1ccc(-n3c4ccccc4c4ccccc43)cc1S2]

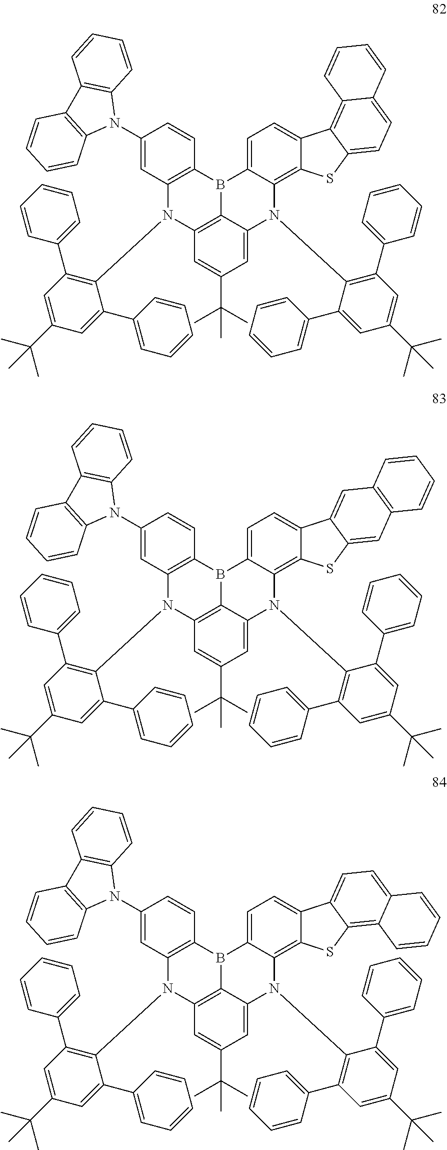

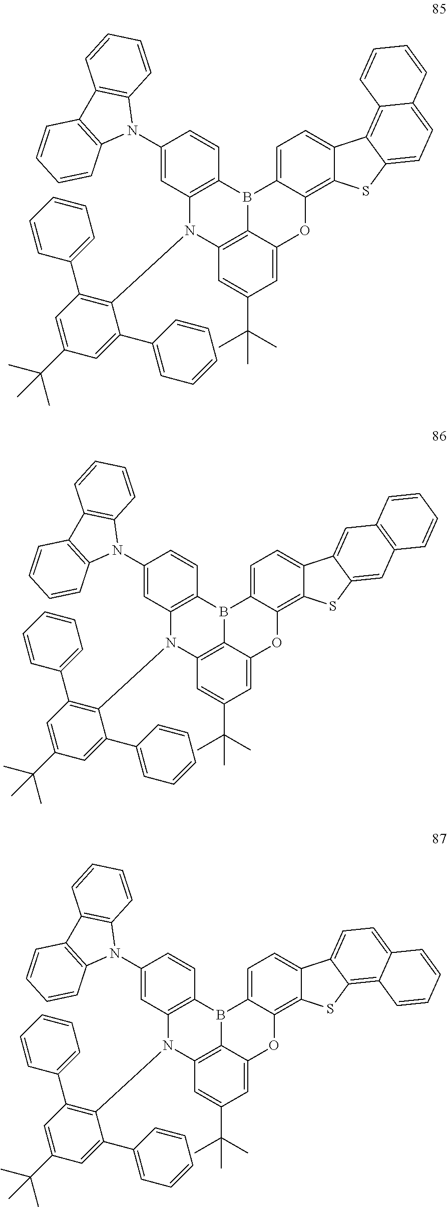 [SMILES: CC(C)(C)c1cc(-c2ccccc2)c(N2c3cc(-n4c5ccccc5c5ccccc54)ccc3B3c4ccc5c(sc6ccc7ccccc7c65)c4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5c(sc6cc7ccccc7cc65)c4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5c(sc6c7ccccc7ccc56)c4Oc4cc(C(C)(C)C)cc2c43)c(-c2ccccc2)c1]

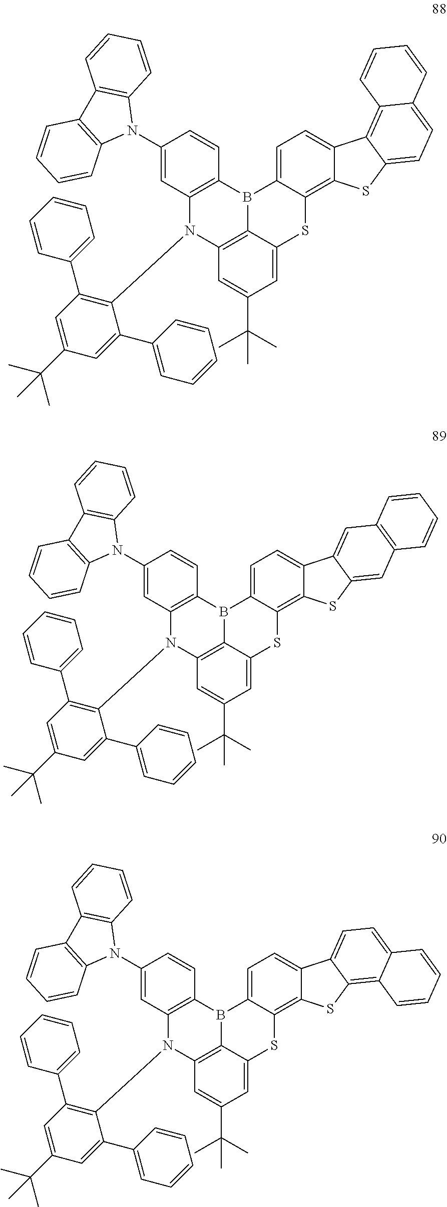 [SMILES: CC(C)(C)c1cc(-c2ccccc2)c(N2c3cc(-n4c5ccccc5c5ccccc54)ccc3B3c4ccc5c(sc6ccc7ccccc7c65)c4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5c(sc6cc7ccccc7cc65)c4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5c(sc6c7ccccc7ccc56)c4Sc4cc(C(C)(C)C)cc2c43)c(-c2ccccc2)c1]

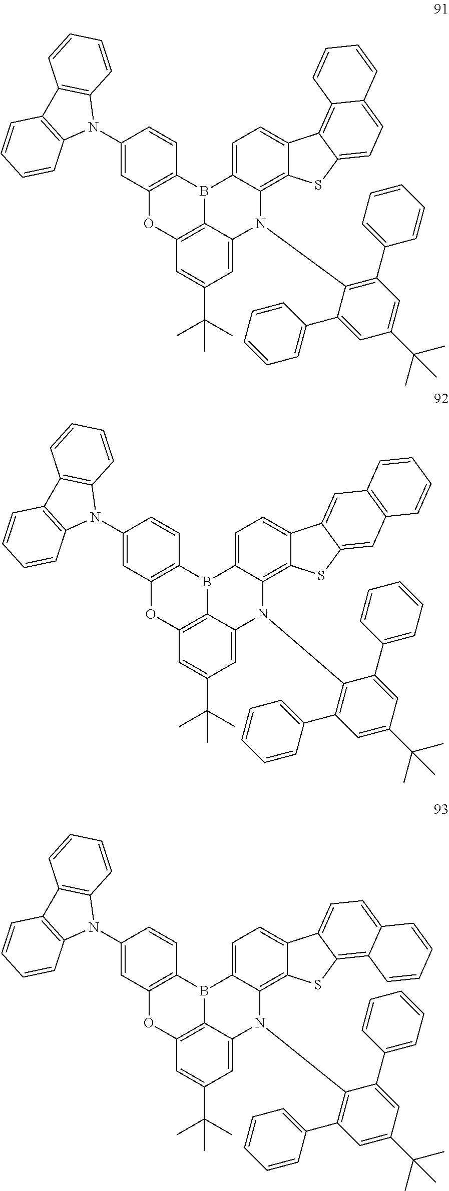 [SMILES: CC(C)(C)c1cc(-c2ccccc2)c(N2c3cc(C(C)(C)C)cc4c3B(c3ccc(-n5c6ccccc6c6ccccc65)cc3O4)c3ccc4c(sc5ccc6ccccc6c54)c32)c(-c2ccccc2)c1 ; CC(C)(C)c1cc(-c2ccccc2)c(N2c3cc(C(C)(C)C)cc4c3B(c3ccc(-n5c6ccccc6c6ccccc65)cc3O4)c3ccc4c(sc5cc6ccccc6cc54)c32)c(-c2ccccc2)c1 ; CC(C)(C)c1cc(-c2ccccc2)c(N2c3cc(C(C)(C)C)cc4c3B(c3ccc(-n5c6ccccc6c6ccccc65)cc3O4)c3ccc4c(sc5c6ccccc6ccc45)c32)c(-c2ccccc2)c1]

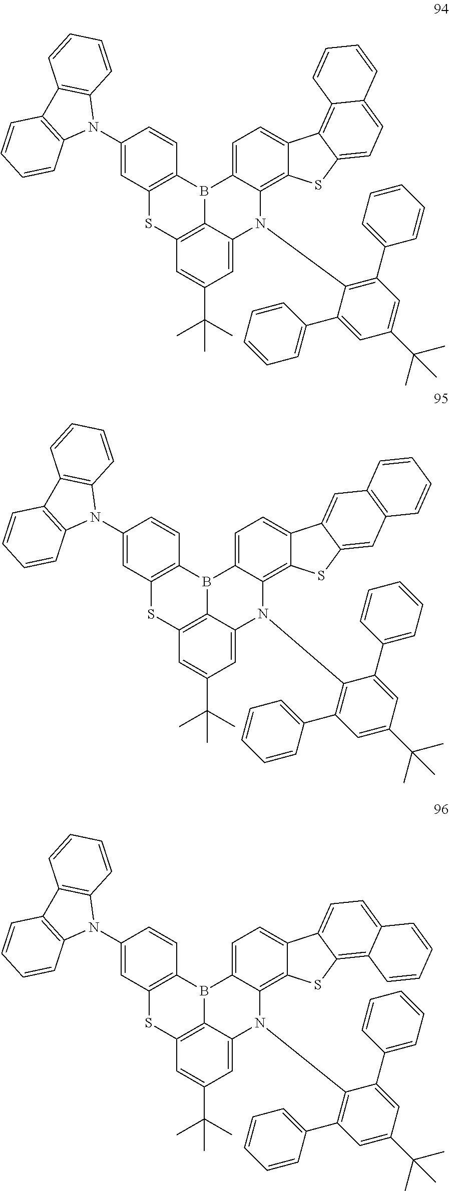 [SMILES: CC(C)(C)c1cc(-c2ccccc2)c(N2c3cc(C(C)(C)C)cc4c3B(c3ccc(-n5c6ccccc6c6ccccc65)cc3S4)c3ccc4c(sc5ccc6ccccc6c54)c32)c(-c2ccccc2)c1 ; CC(C)(C)c1cc(-c2ccccc2)c(N2c3cc(C(C)(C)C)cc4c3B(c3ccc(-n5c6ccccc6c6ccccc65)cc3S4)c3ccc4c(sc5cc6ccccc6cc54)c32)c(-c2ccccc2)c1 ; CC(C)(C)c1cc(-c2ccccc2)c(N2c3cc(C(C)(C)C)cc4c3B(c3ccc(-n5c6ccccc6c6ccccc65)cc3S4)c3ccc4c(sc5c6ccccc6ccc45)c32)c(-c2ccccc2)c1]

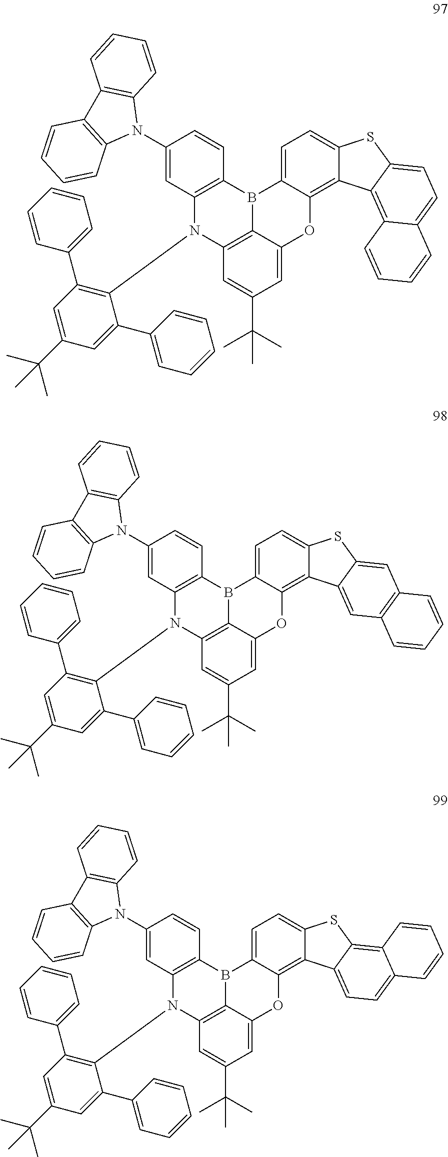 [SMILES: CC(C)(C)c1cc(-c2ccccc2)c(N2c3cc(-n4c5ccccc5c5ccccc54)ccc3B3c4ccc5sc6ccc7ccccc7c6c5c4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5sc6cc7ccccc7cc6c5c4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5sc6c7ccccc7ccc6c5c4Oc4cc(C(C)(C)C)cc2c43)c(-c2ccccc2)c1]

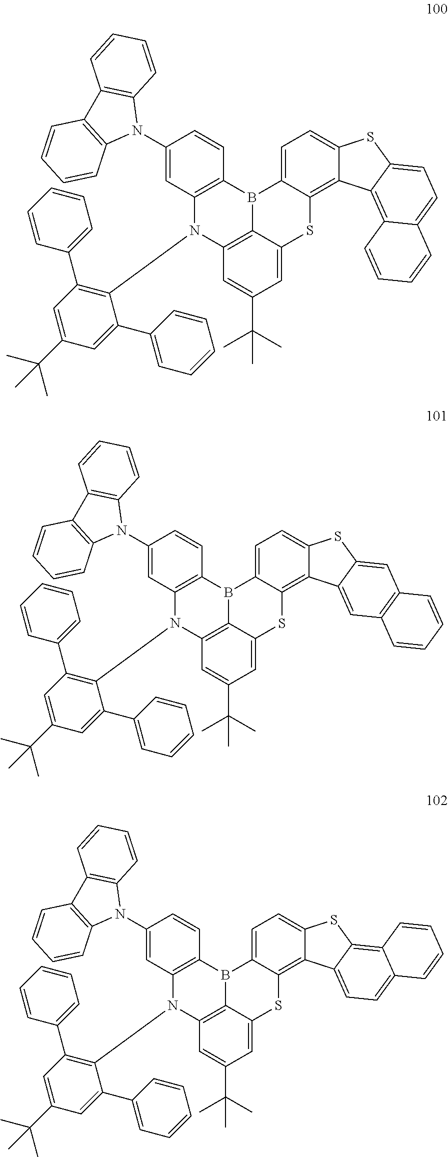 [SMILES: CC(C)(C)c1cc(-c2ccccc2)c(N2c3cc(-n4c5ccccc5c5ccccc54)ccc3B3c4ccc5sc6ccc7ccccc7c6c5c4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5sc6cc7ccccc7cc6c5c4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc5sc6c7ccccc7ccc6c5c4Sc4cc(C(C)(C)C)cc2c43)c(-c2ccccc2)c1]

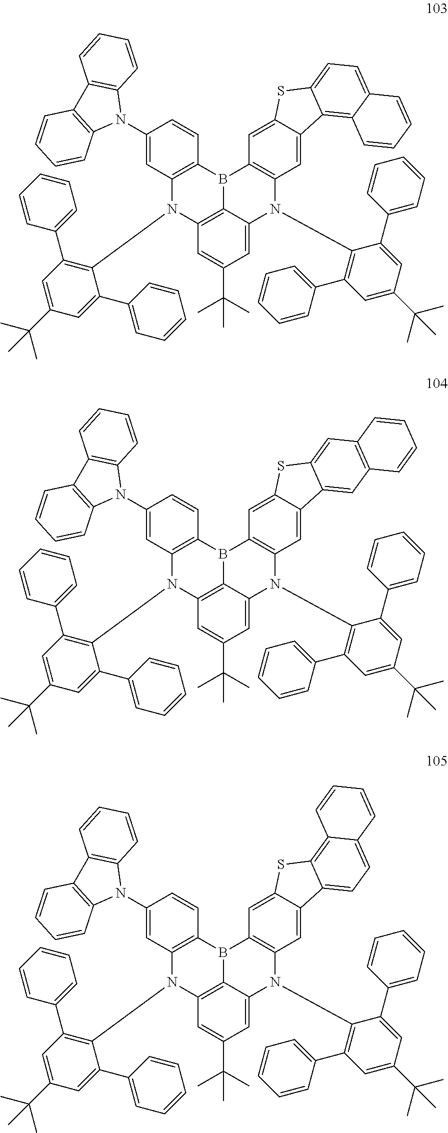

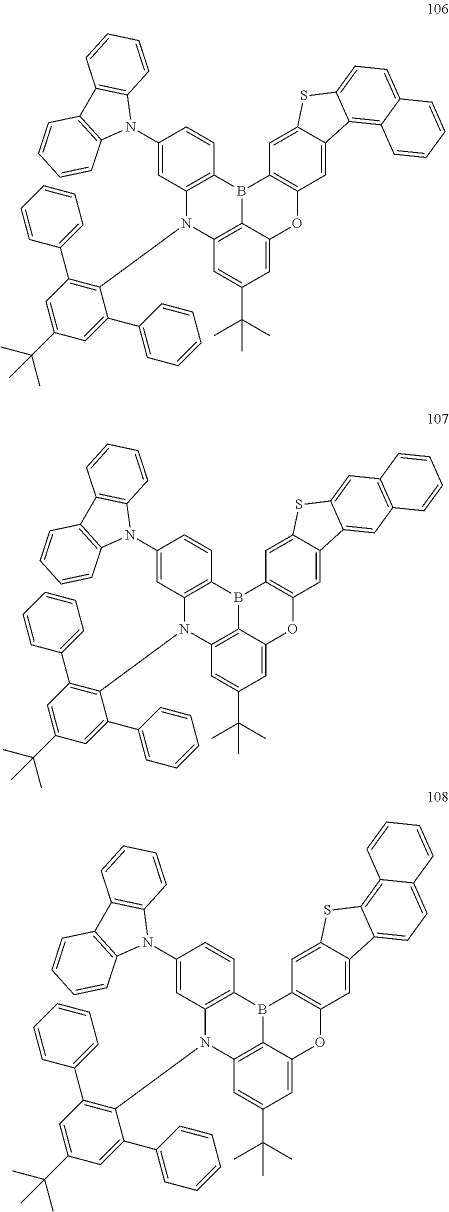 [SMILES: CC(C)(C)c1cc(-c2ccccc2)c(N2c3cc(-n4c5ccccc5c5ccccc54)ccc3B3c4cc5sc6ccc7ccccc7c6c5cc4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc5sc6cc7ccccc7cc6c5cc4Oc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc5sc6c7ccccc7ccc6c5cc4Oc4cc(C(C)(C)C)cc2c43)c(-c2ccccc2)c1]

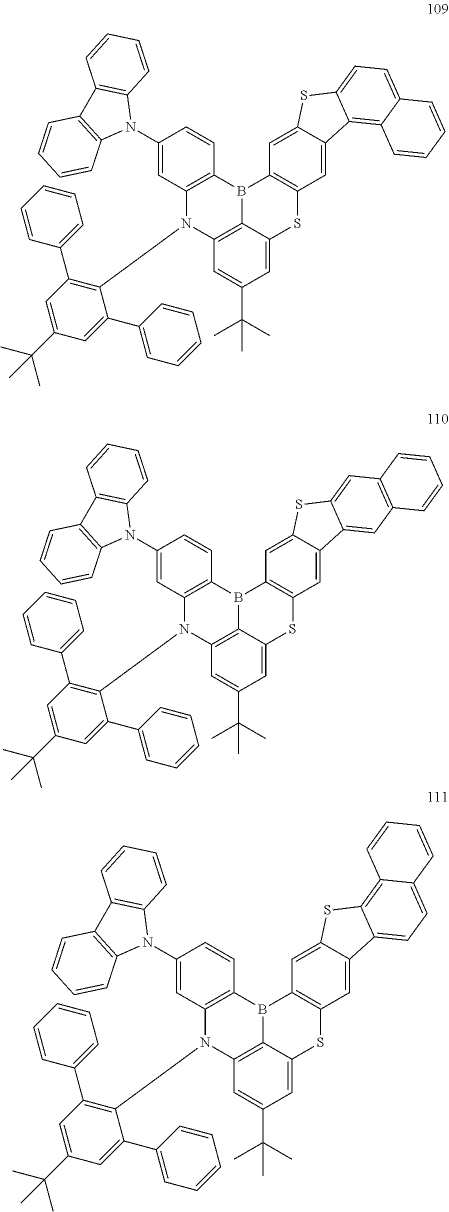 [SMILES: CC(C)(C)c1cc(-c2ccccc2)c(N2c3cc(-n4c5ccccc5c5ccccc54)ccc3B3c4cc5sc6ccc7ccccc7c6c5cc4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc5sc6cc7ccccc7cc6c5cc4Sc4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4cc5sc6c7ccccc7ccc6c5cc4Sc4cc(C(C)(C)C)cc2c43)c(-c2ccccc2)c1]

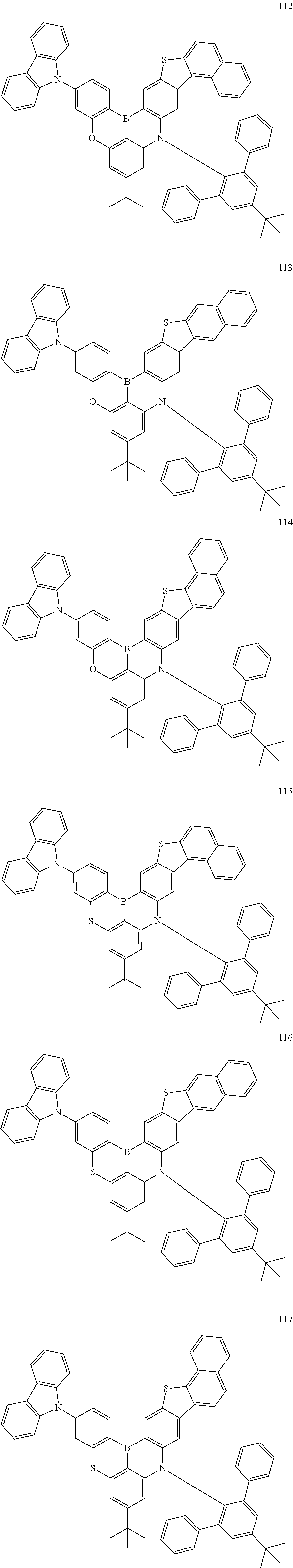

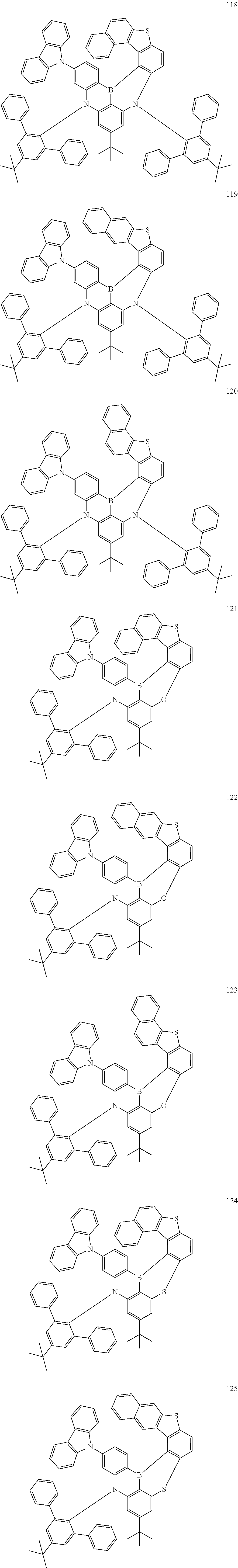

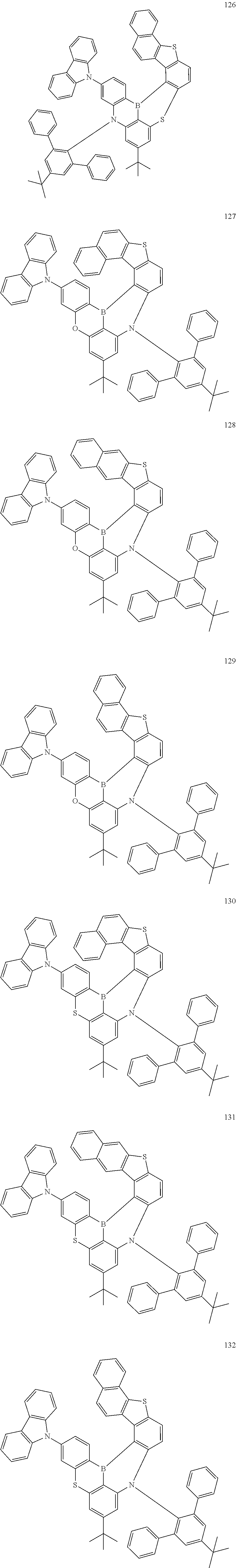

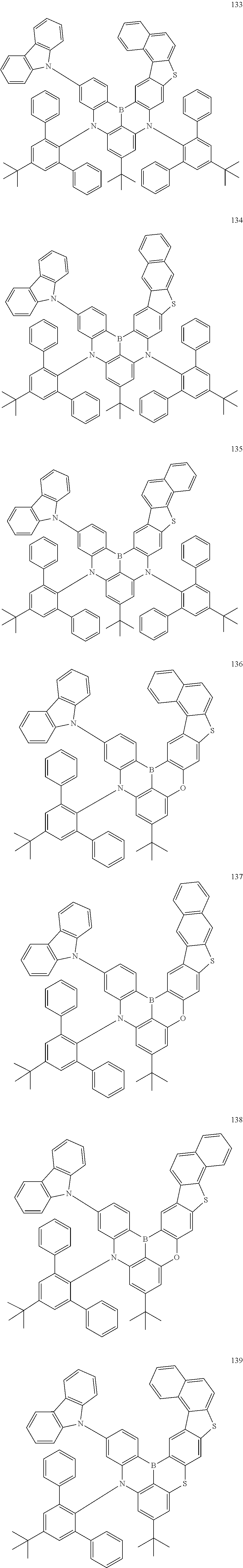

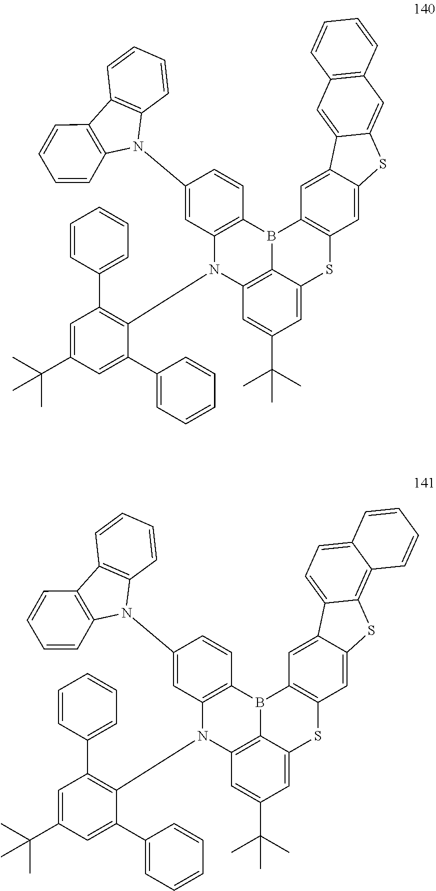 [SMILES: CC(C)(C)c1cc(-c2ccccc2)c(N2c3cc(-n4c5ccccc5c5ccccc54)ccc3B3c4cc5c(cc4Sc4cc(C(C)(C)C)cc2c43)sc2cc3ccccc3cc25)c(-c2ccccc2)c1 ; CC(C)(C)c1cc(-c2ccccc2)c(N2c3cc(-n4c5ccccc5c5ccccc54)ccc3B3c4cc5c(cc4Sc4cc(C(C)(C)C)cc2c43)sc2c3ccccc3ccc52)c(-c2ccccc2)c1]

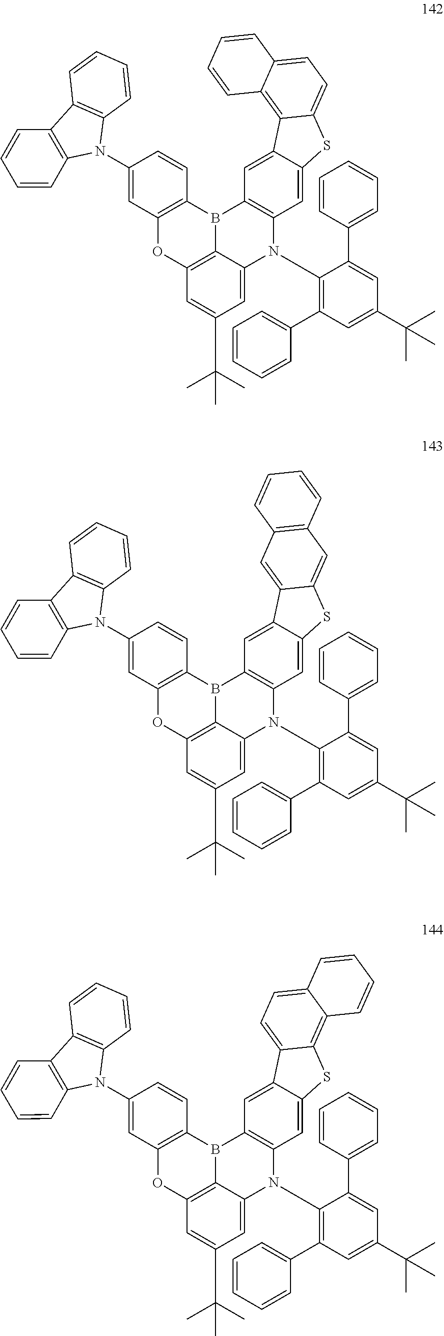 [SMILES: CC(C)(C)c1cc(-c2ccccc2)c(N2c3cc4sc5ccc6ccccc6c5c4cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4ccc(-n5c6ccccc6c6ccccc65)cc4Oc4cc(C(C)(C)C)cc2c43)c(-c2ccccc2)c1]

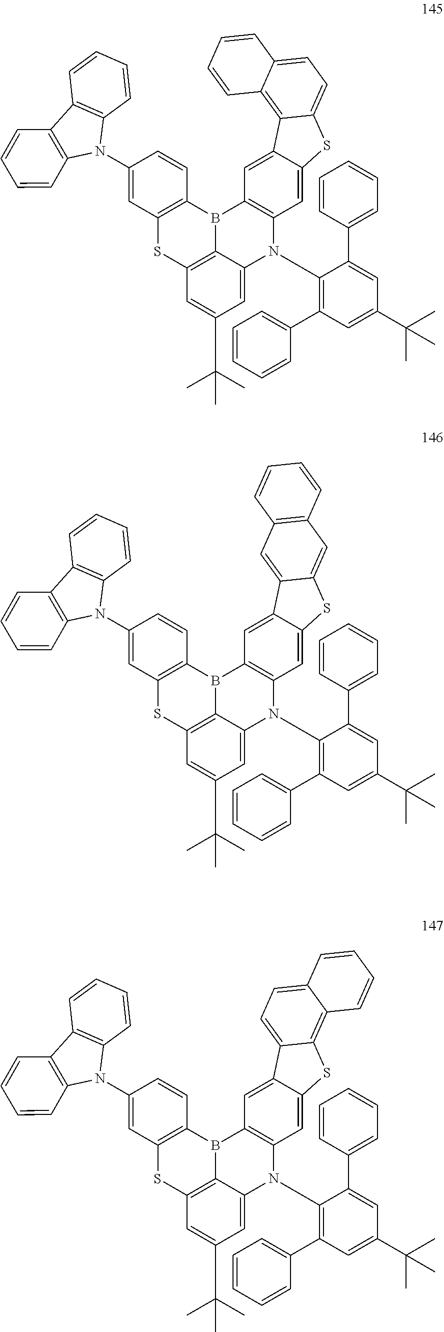 [SMILES: CC(C)(C)c1cc(-c2ccccc2)c(N2c3cc4sc5ccc6ccccc6c5c4cc3B3c4ccc(-n5c6ccccc6c6ccccc65)cc4Sc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4ccc(-n5c6ccccc6c6ccccc65)cc4Sc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4ccc(-n5c6ccccc6c6ccccc65)cc4Sc4cc(C(C)(C)C)cc2c43)c(-c2ccccc2)c1]

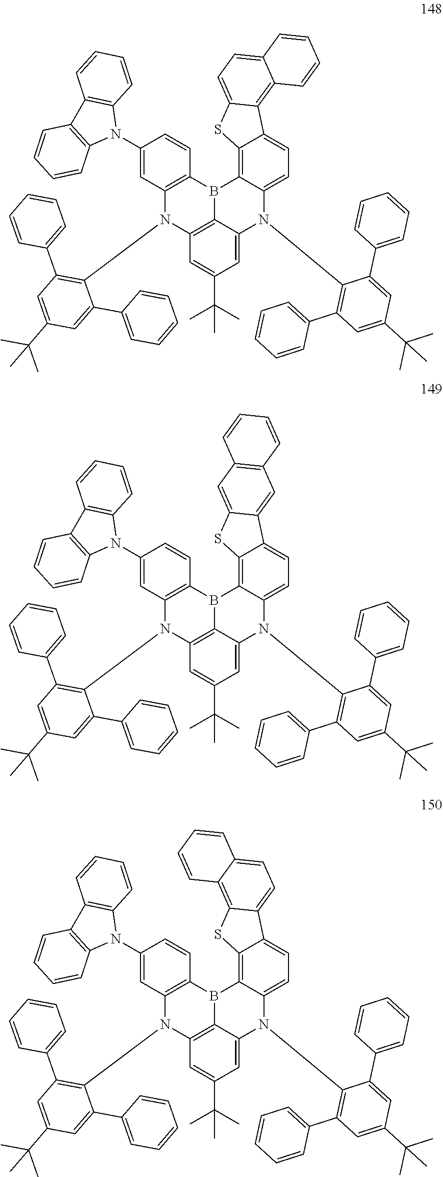

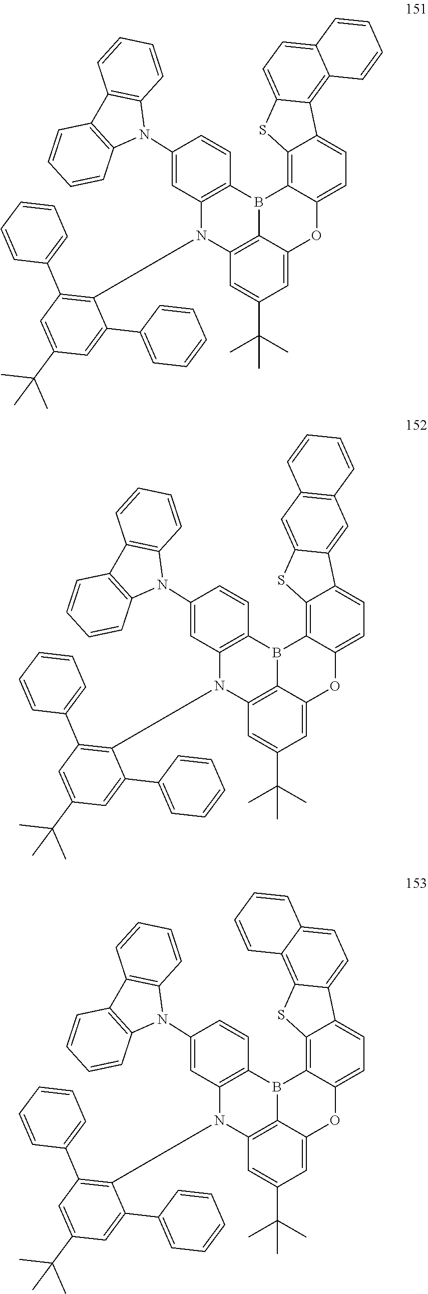 [SMILES: CC(C)(C)c1cc(-c2ccccc2)c(N2c3cc(-n4c5ccccc5c5ccccc54)ccc3B3c4c(cc(C(C)(C)C)cc42)Oc2ccc4c(sc5ccc6ccccc6c54)c23)c(-c2ccccc2)c1 ; CC(C)(C)c1cc(-c2ccccc2)c(N2c3cc(-n4c5ccccc5c5ccccc54)ccc3B3c4c(cc(C(C)(C)C)cc42)Oc2ccc4c(sc5cc6ccccc6cc54)c23)c(-c2ccccc2)c1 ; CC(C)(C)c1cc(-c2ccccc2)c(N2c3cc(-n4c5ccccc5c5ccccc54)ccc3B3c4c(cc(C(C)(C)C)cc42)Oc2ccc4c(sc5c6ccccc6ccc45)c23)c(-c2ccccc2)c1]

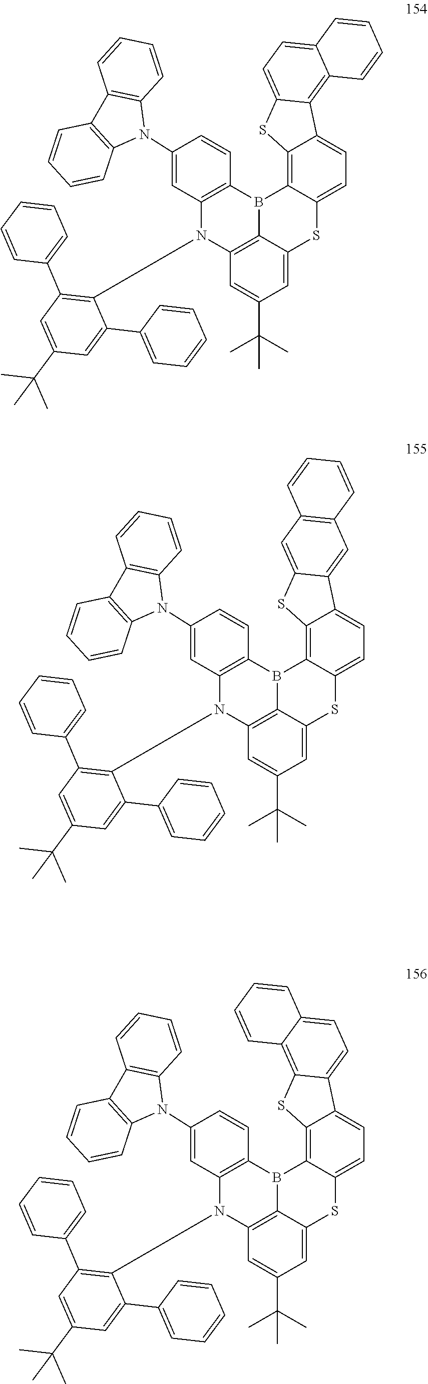 [SMILES: CC(C)(C)c1cc(-c2ccccc2)c(N2c3cc(-n4c5ccccc5c5ccccc54)ccc3B3c4c(cc(C(C)(C)C)cc42)Sc2ccc4c(sc5ccc6ccccc6c54)c23)c(-c2ccccc2)c1 ; CC(C)(C)c1cc(-c2ccccc2)c(N2c3cc(-n4c5ccccc5c5ccccc54)ccc3B3c4c(cc(C(C)(C)C)cc42)Sc2ccc4c(sc5cc6ccccc6cc54)c23)c(-c2ccccc2)c1 ; CC(C)(C)c1cc(-c2ccccc2)c(N2c3cc(-n4c5ccccc5c5ccccc54)ccc3B3c4c(cc(C(C)(C)C)cc42)Sc2ccc4c(sc5c6ccccc6ccc45)c23)c(-c2ccccc2)c1]

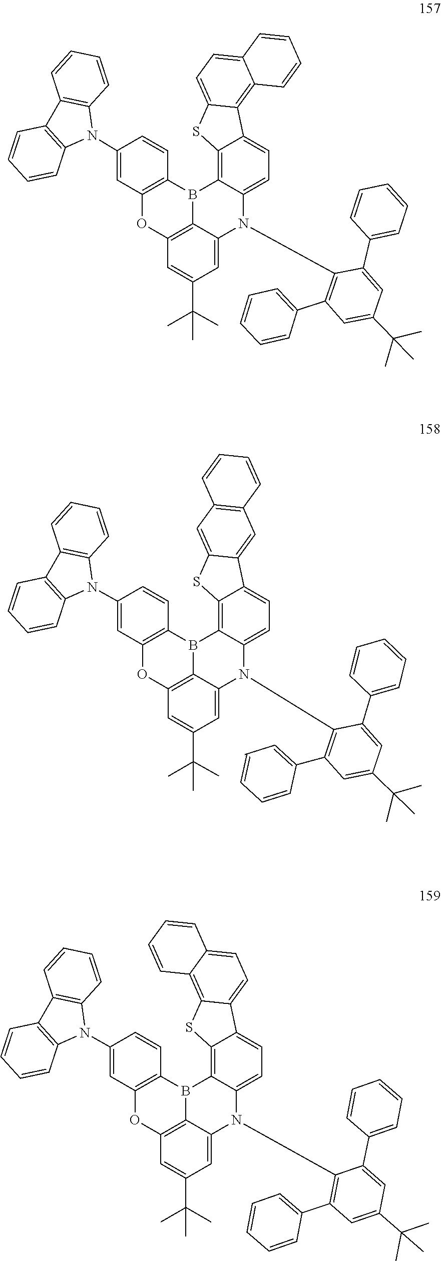 [SMILES: CC(C)(C)c1cc(-c2ccccc2)c(N2c3cc(C(C)(C)C)cc4c3B(c3ccc(-n5c6ccccc6c6ccccc65)cc3O4)c3c2ccc2c3sc3ccc4ccccc4c32)c(-c2ccccc2)c1 ; Cc1cccc(-c2cc(C(C)(C)C)cc(-c3ccccc3)c2N2c3cc(C(C)(C)C)cc4c3B(c3ccc(-n5c6ccccc6c6ccccc65)cc3O4)c3c2ccc2c3sc3cc4ccccc4cc32)c1 ; CC(C)(C)c1cc(-c2ccccc2)c(N2c3cc(C(C)(C)C)cc4c3B(c3ccc(-n5c6ccccc6c6ccccc65)cc3O4)c3c2ccc2c3sc3c4ccccc4ccc23)c(-c2ccccc2)c1]

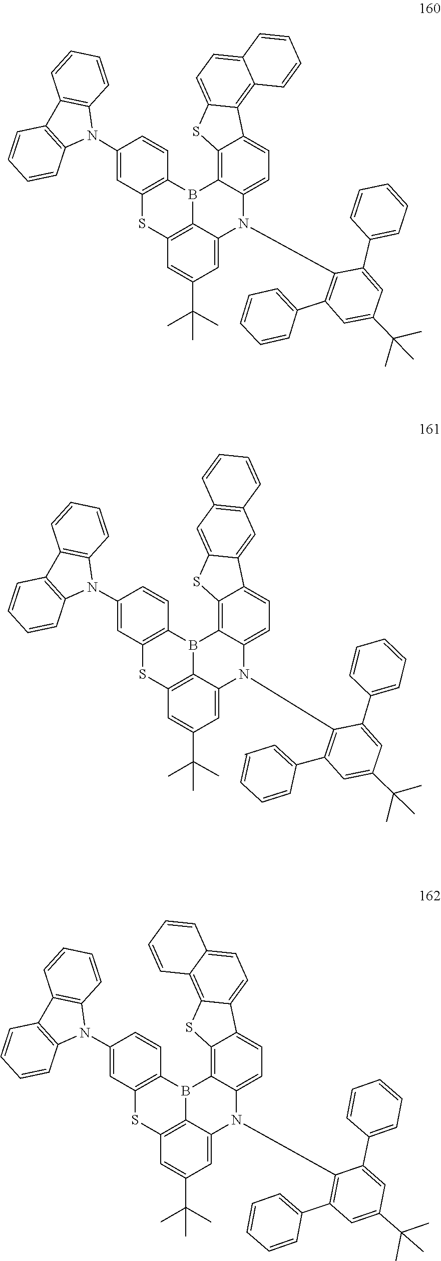 [SMILES: CC(C)(C)c1cc(-c2ccccc2)c(N2c3cc(C(C)(C)C)cc4c3B(c3ccc(-n5c6ccccc6c6ccccc65)cc3S4)c3c2ccc2c3sc3ccc4ccccc4c32)c(-c2ccccc2)c1 ; Cc1cccc(-c2cc(C(C)(C)C)cc(-c3ccccc3)c2N2c3cc(C(C)(C)C)cc4c3B(c3ccc(-n5c6ccccc6c6ccccc65)cc3S4)c3c2ccc2c3sc3cc4ccccc4cc32)c1 ; CC(C)(C)c1cc(-c2ccccc2)c(N2c3cc(C(C)(C)C)cc4c3B(c3ccc(-n5c6ccccc6c6ccccc65)cc3S4)c3c2ccc2c3sc3c4ccccc4ccc23)c(-c2ccccc2)c1]

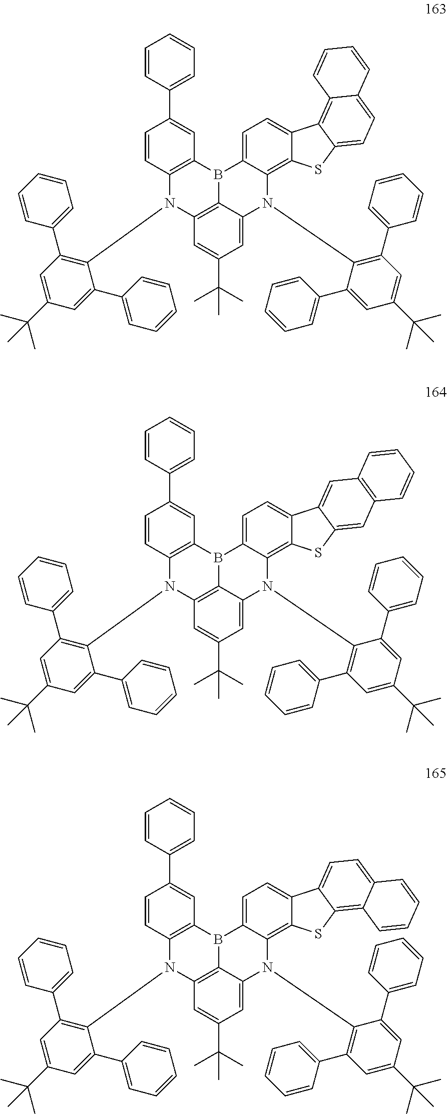

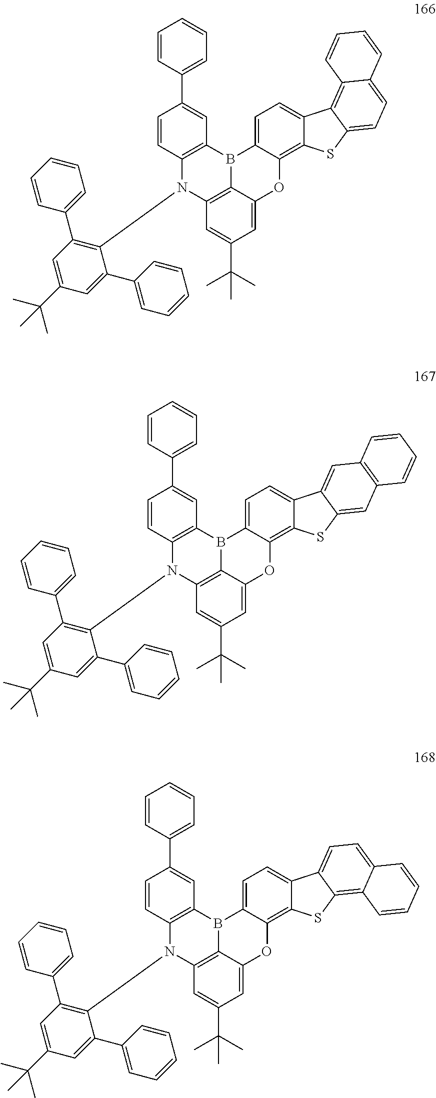 [SMILES: CC(C)(C)c1cc(-c2ccccc2)c(N2c3ccc(-c4ccccc4)cc3B3c4ccc5c(sc6ccc7ccccc7c65)c4Oc4cc(C(C)(C)C)cc2c43)c(-c2ccccc2)c1 ; CC(C)(C)c1cc(-c2ccccc2)c(N2c3ccc(-c4ccccc4)cc3B3c4ccc5c(sc6cc7ccccc7cc65)c4Oc4cc(C(C)(C)C)cc2c43)c(-c2ccccc2)c1 ; CC(C)(C)c1cc(-c2ccccc2)c(N2c3ccc(-c4ccccc4)cc3B3c4ccc5c(sc6c7ccccc7ccc56)c4Oc4cc(C(C)(C)C)cc2c43)c(-c2ccccc2)c1]

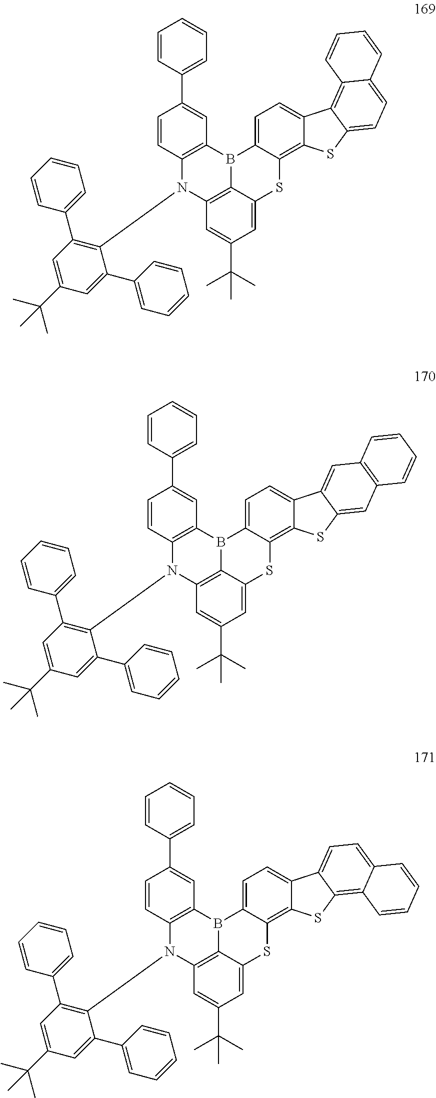 [SMILES: CC(C)(C)c1cc(-c2ccccc2)c(N2c3ccc(-c4ccccc4)cc3B3c4ccc5c(sc6ccc7ccccc7c65)c4Sc4cc(C(C)(C)C)cc2c43)c(-c2ccccc2)c1 ; CC(C)(C)c1cc(-c2ccccc2)c(N2c3ccc(-c4ccccc4)cc3B3c4ccc5c(sc6cc7ccccc7cc65)c4Sc4cc(C(C)(C)C)cc2c43)c(-c2ccccc2)c1 ; CC(C)(C)c1cc(-c2ccccc2)c(N2c3ccc(-c4ccccc4)cc3B3c4ccc5c(sc6c7ccccc7ccc56)c4Sc4cc(C(C)(C)C)cc2c43)c(-c2ccccc2)c1]

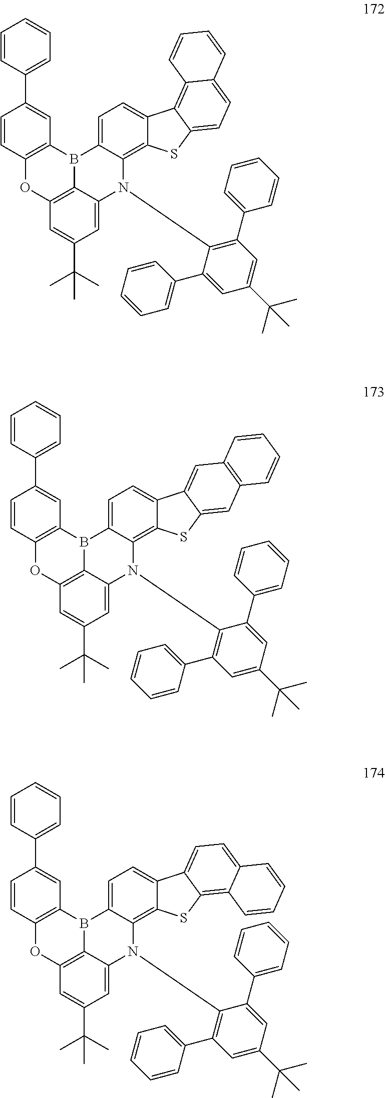 [SMILES: CC(C)(C)c1cc(-c2ccccc2)c(N2c3cc(C(C)(C)C)cc4c3B(c3cc(-c5ccccc5)ccc3O4)c3ccc4c(sc5ccc6ccccc6c54)c32)c(-c2ccccc2)c1 ; CC(C)(C)c1cc(-c2ccccc2)c(N2c3cc(C(C)(C)C)cc4c3B(c3cc(-c5ccccc5)ccc3O4)c3ccc4c(sc5cc6ccccc6cc54)c32)c(-c2ccccc2)c1 ; CC(C)(C)c1cc(-c2ccccc2)c(N2c3cc(C(C)(C)C)cc4c3B(c3cc(-c5ccccc5)ccc3O4)c3ccc4c(sc5c6ccccc6ccc45)c32)c(-c2ccccc2)c1]

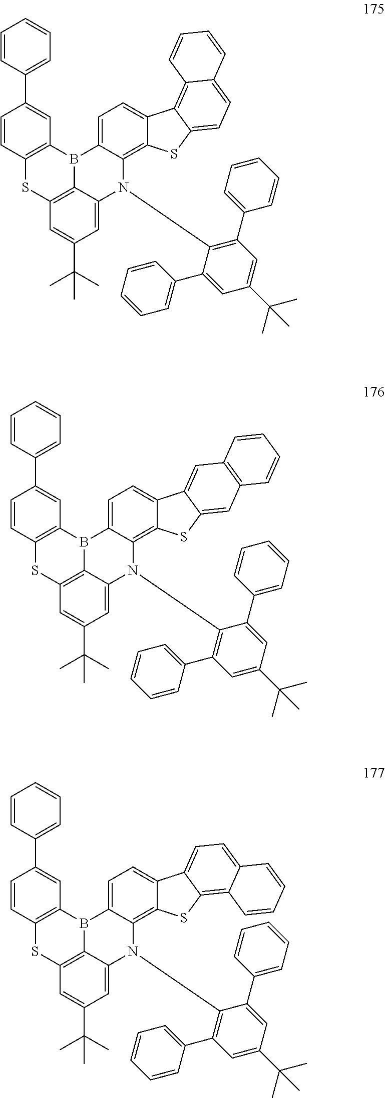 [SMILES: CC(C)(C)c1cc(-c2ccccc2)c(N2c3cc(C(C)(C)C)cc4c3B(c3cc(-c5ccccc5)ccc3S4)c3ccc4c(sc5ccc6ccccc6c54)c32)c(-c2ccccc2)c1 ; CC(C)(C)c1cc(-c2ccccc2)c(N2c3cc(C(C)(C)C)cc4c3B(c3cc(-c5ccccc5)ccc3S4)c3ccc4c(sc5cc6ccccc6cc54)c32)c(-c2ccccc2)c1 ; CC(C)(C)c1cc(-c2ccccc2)c(N2c3cc(C(C)(C)C)cc4c3B(c3cc(-c5ccccc5)ccc3S4)c3ccc4c(sc5c6ccccc6ccc45)c32)c(-c2ccccc2)c1]

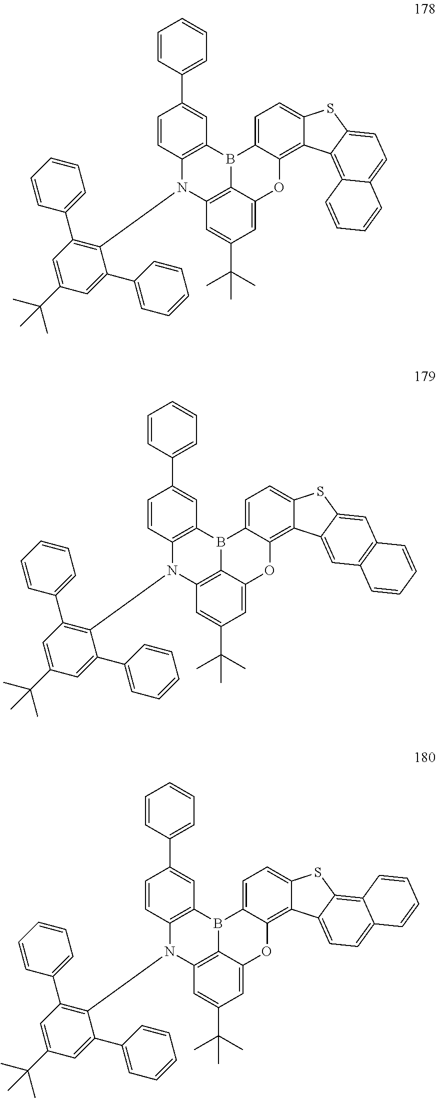 [SMILES: CC(C)(C)c1cc(-c2ccccc2)c(N2c3ccc(-c4ccccc4)cc3B3c4ccc5sc6ccc7ccccc7c6c5c4Oc4cc(C(C)(C)C)cc2c43)c(-c2ccccc2)c1 ; CC(C)(C)c1cc(-c2ccccc2)c(N2c3ccc(-c4ccccc4)cc3B3c4ccc5sc6cc7ccccc7cc6c5c4Oc4cc(C(C)(C)C)cc2c43)c(-c2ccccc2)c1 ; CC(C)(C)c1cc(-c2ccccc2)c(N2c3ccc(-c4ccccc4)cc3B3c4ccc5sc6c7ccccc7ccc6c5c4Oc4cc(C(C)(C)C)cc2c43)c(-c2ccccc2)c1]

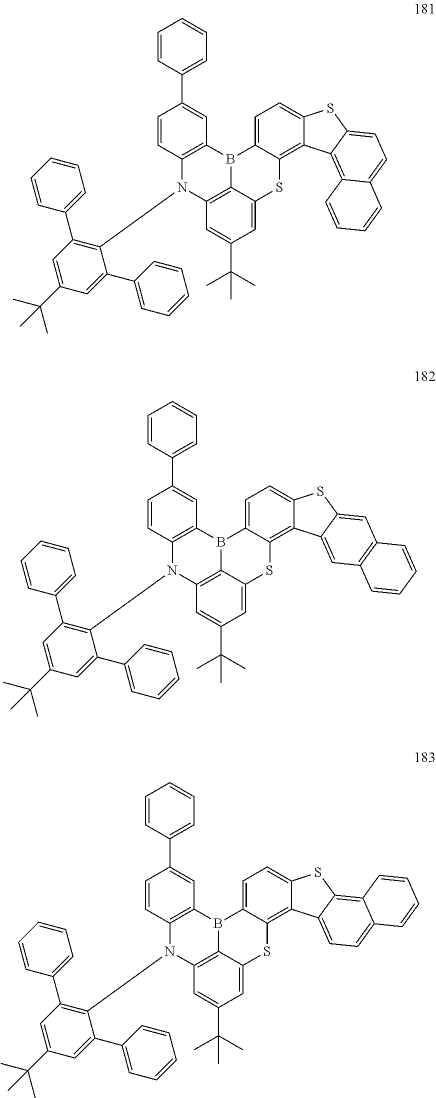 [SMILES: CC(C)(C)c1cc(-c2ccccc2)c(N2c3ccc(-c4ccccc4)cc3B3c4ccc5sc6ccc7ccccc7c6c5c4Sc4cc(C(C)(C)C)cc2c43)c(-c2ccccc2)c1 ; CC(C)(C)c1cc(-c2ccccc2)c(N2c3ccc(-c4ccccc4)cc3B3c4ccc5sc6cc7ccccc7cc6c5c4Sc4cc(C(C)(C)C)cc2c43)c(-c2ccccc2)c1 ; CC(C)(C)c1cc(-c2ccccc2)c(N2c3ccc(-c4ccccc4)cc3B3c4ccc5sc6c7ccccc7ccc6c5c4Sc4cc(C(C)(C)C)cc2c43)c(-c2ccccc2)c1]

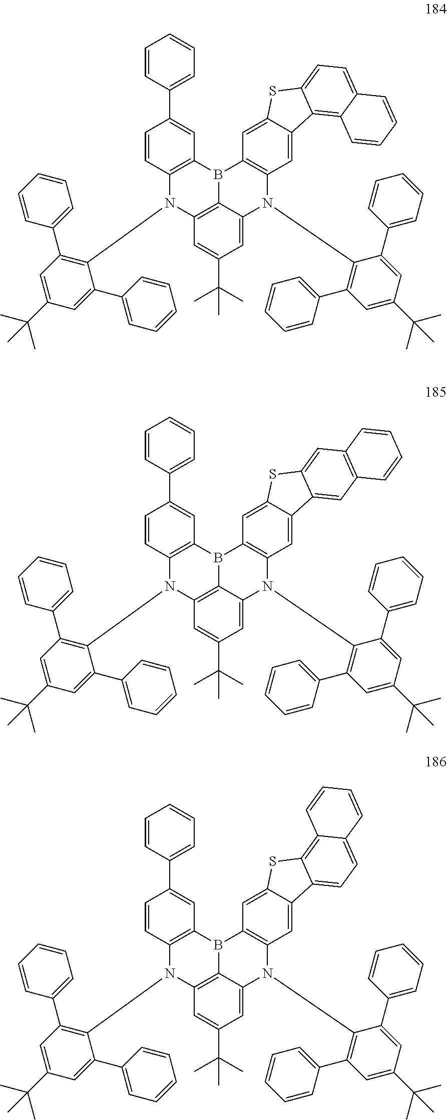

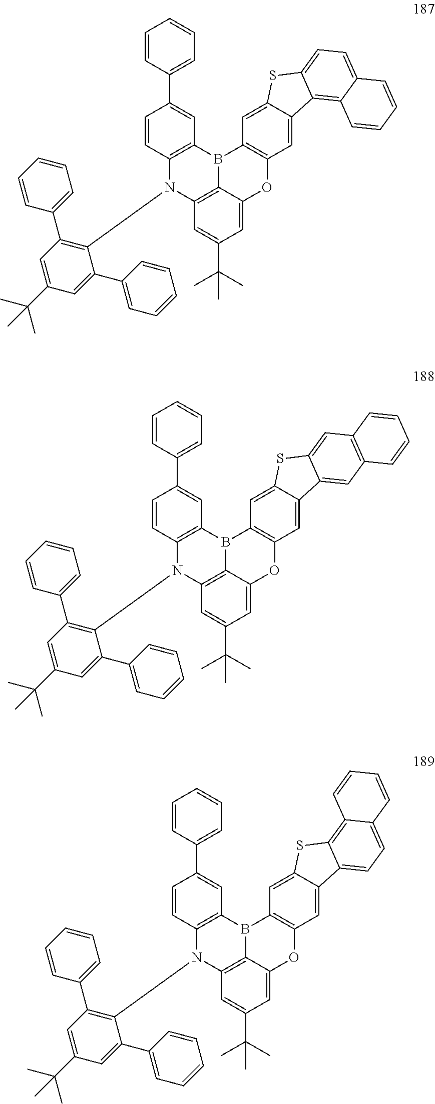 [SMILES: CC(C)(C)c1cc(-c2ccccc2)c(N2c3ccc(-c4ccccc4)cc3B3c4cc5sc6ccc7ccccc7c6c5cc4Oc4cc(C(C)(C)C)cc2c43)c(-c2ccccc2)c1 ; CC(C)(C)c1cc(-c2ccccc2)c(N2c3ccc(-c4ccccc4)cc3B3c4cc5sc6cc7ccccc7cc6c5cc4Oc4cc(C(C)(C)C)cc2c43)c(-c2ccccc2)c1 ; CC(C)(C)c1cc(-c2ccccc2)c(N2c3ccc(-c4ccccc4)cc3B3c4cc5sc6c7ccccc7ccc6c5cc4Oc4cc(C(C)(C)C)cc2c43)c(-c2ccccc2)c1]

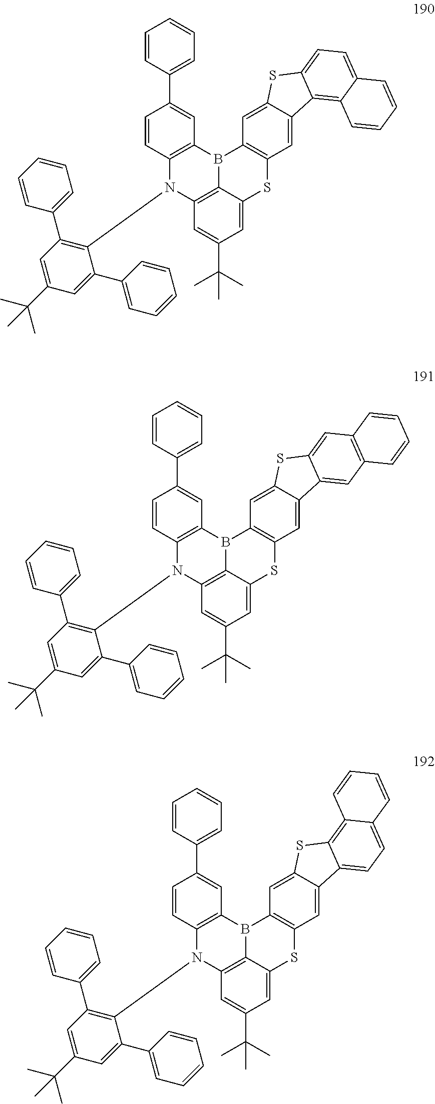 [SMILES: CC(C)(C)c1cc(-c2ccccc2)c(N2c3ccc(-c4ccccc4)cc3B3c4cc5sc6ccc7ccccc7c6c5cc4Sc4cc(C(C)(C)C)cc2c43)c(-c2ccccc2)c1 ; CC(C)(C)c1cc(-c2ccccc2)c(N2c3ccc(-c4ccccc4)cc3B3c4cc5sc6cc7ccccc7cc6c5cc4Sc4cc(C(C)(C)C)cc2c43)c(-c2ccccc2)c1 ; CC(C)(C)c1cc(-c2ccccc2)c(N2c3ccc(-c4ccccc4)cc3B3c4cc5sc6c7ccccc7ccc6c5cc4Sc4cc(C(C)(C)C)cc2c43)c(-c2ccccc2)c1]

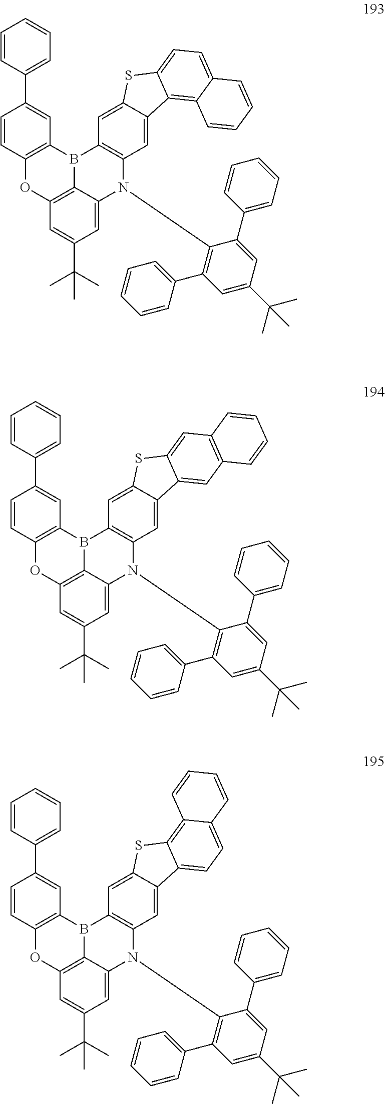 [SMILES: CC(C)(C)c1cc(-c2ccccc2)c(N2c3cc4c(cc3B3c5cc(-c6ccccc6)ccc5Oc5cc(C(C)(C)C)cc2c53)sc2ccc3ccccc3c24)c(-c2ccccc2)c1 ; CC(C)(C)c1cc(-c2ccccc2)c(N2c3cc4c(cc3B3c5cc(-c6ccccc6)ccc5Oc5cc(C(C)(C)C)cc2c53)sc2cc3ccccc3cc24)c(-c2ccccc2)c1 ; CC(C)(C)c1cc(-c2ccccc2)c(N2c3cc4c(cc3B3c5cc(-c6ccccc6)ccc5Oc5cc(C(C)(C)C)cc2c53)sc2c3ccccc3ccc42)c(-c2ccccc2)c1]

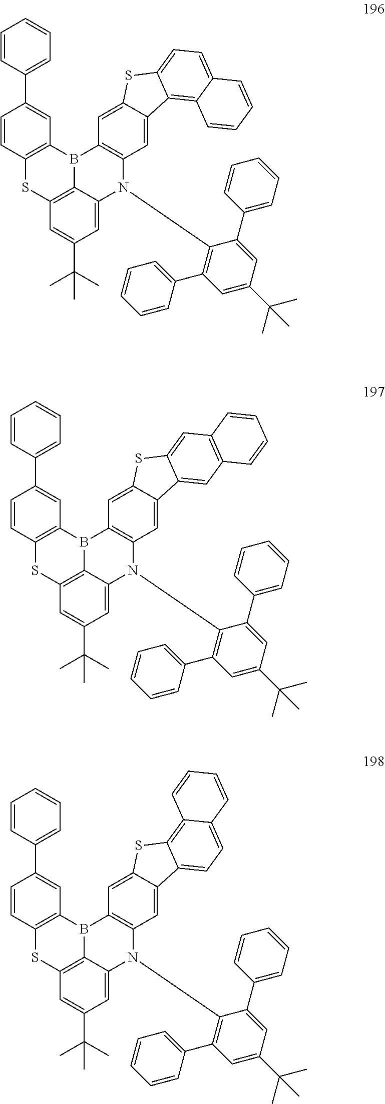 [SMILES: CC(C)(C)c1cc(-c2ccccc2)c(N2c3cc4c(cc3B3c5cc(-c6ccccc6)ccc5Sc5cc(C(C)(C)C)cc2c53)sc2ccc3ccccc3c24)c(-c2ccccc2)c1 ; CC(C)(C)c1cc(-c2ccccc2)c(N2c3cc4c(cc3B3c5cc(-c6ccccc6)ccc5Sc5cc(C(C)(C)C)cc2c53)sc2cc3ccccc3cc24)c(-c2ccccc2)c1 ; CC(C)(C)c1cc(-c2ccccc2)c(N2c3cc4c(cc3B3c5cc(-c6ccccc6)ccc5Sc5cc(C(C)(C)C)cc2c53)sc2c3ccccc3ccc42)c(-c2ccccc2)c1]

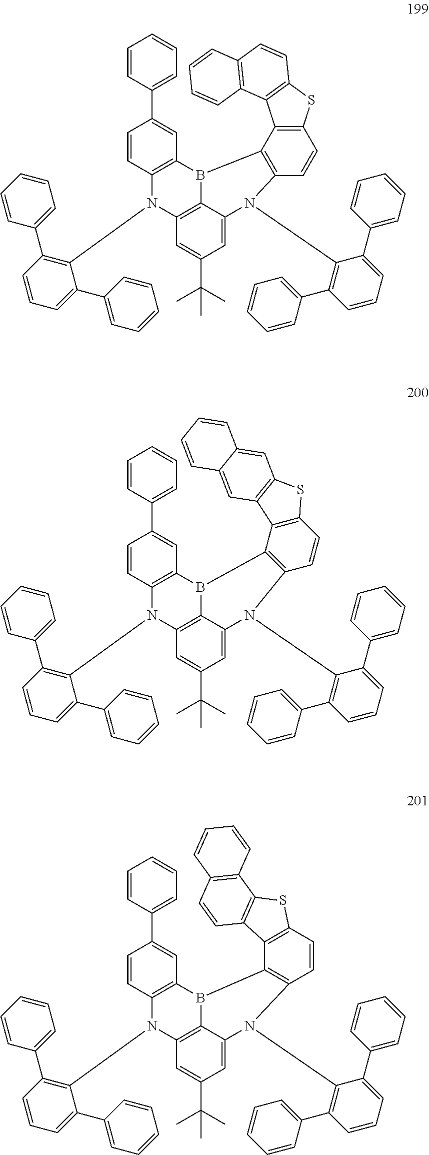 [SMILES: CC(C)(C)c1cc2c3c(c1)N(c1c(-c4ccccc4)cccc1-c1ccccc1)c1ccc4sc5ccc6ccccc6c5c4c1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc4sc5cc6ccccc6cc5c4c1B3c1cc(-c3ccccc3)ccc1N2c1c(-c2ccccc2)cccc1-c1ccccc1 ; CC(C)(C)c1cc2c3c(c1)N(c1c(-c4ccccc4)cccc1-c1ccccc1)c1ccc4sc5c6ccccc6ccc5c4c1B3c1cc(-c3ccccc3)ccc1N2c1c(-c2ccccc2)cccc1-c1ccccc1]

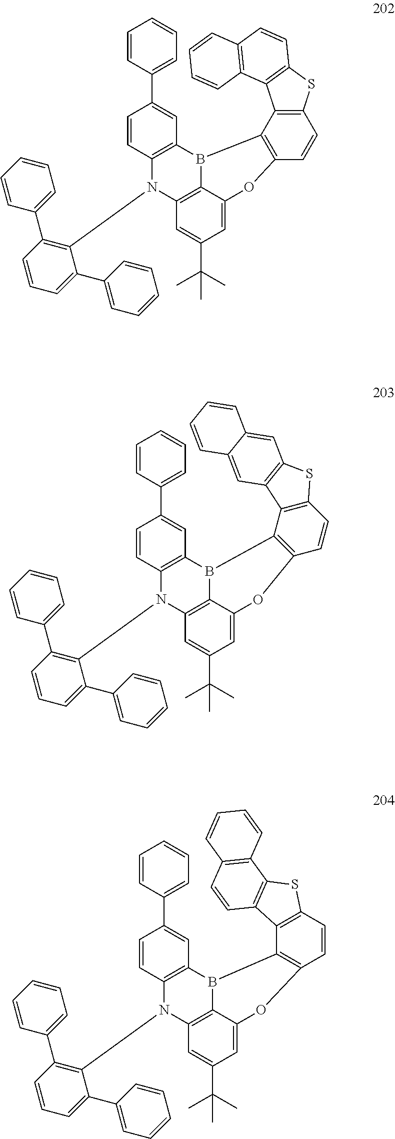 [SMILES: CC(C)(C)c1cc2c3c(c1)N(c1c(-c4ccccc4)cccc1-c1ccccc1)c1ccc(-c4ccccc4)cc1B3c1c(ccc3sc4ccc5ccccc5c4c13)O2 ; CC(C)(C)c1cc2c3c(c1)N(c1c(-c4ccccc4)cccc1-c1ccccc1)c1ccc(-c4ccccc4)cc1B3c1c(ccc3sc4cc5ccccc5cc4c13)O2 ; CC(C)(C)c1cc2c3c(c1)N(c1c(-c4ccccc4)cccc1-c1ccccc1)c1ccc(-c4ccccc4)cc1B3c1c(ccc3sc4c5ccccc5ccc4c13)O2]

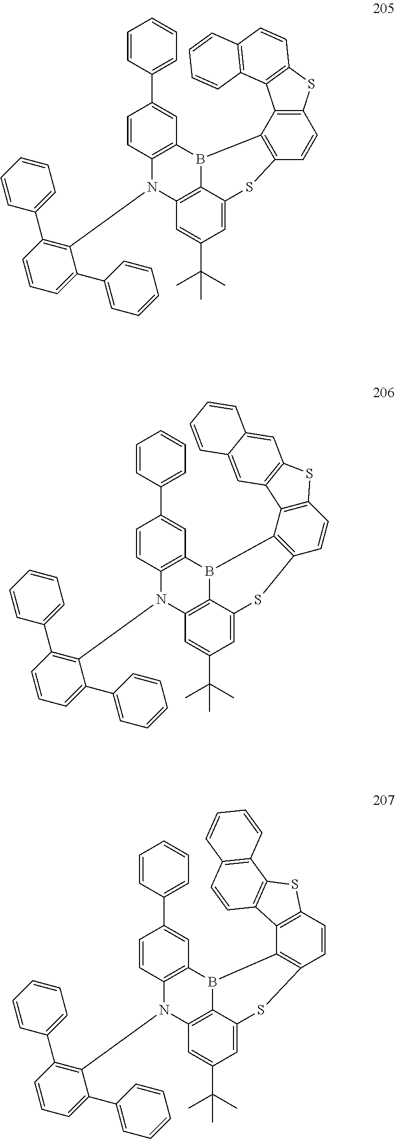 [SMILES: CC(C)(C)c1cc2c3c(c1)N(c1c(-c4ccccc4)cccc1-c1ccccc1)c1ccc(-c4ccccc4)cc1B3c1c(ccc3sc4ccc5ccccc5c4c13)S2 ; CC(C)(C)c1cc2c3c(c1)N(c1c(-c4ccccc4)cccc1-c1ccccc1)c1ccc(-c4ccccc4)cc1B3c1c(ccc3sc4cc5ccccc5cc4c13)S2 ; CC(C)(C)c1cc2c3c(c1)N(c1c(-c4ccccc4)cccc1-c1ccccc1)c1ccc(-c4ccccc4)cc1B3c1c(ccc3sc4c5ccccc5ccc4c13)S2]

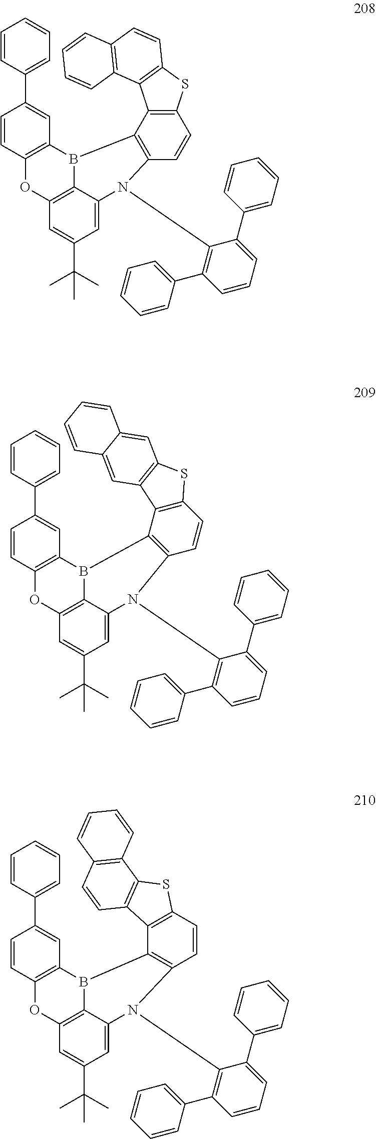 [SMILES: CC(C)(C)c1cc2c3c(c1)N(c1c(-c4ccccc4)cccc1-c1ccccc1)c1ccc4sc5ccc6ccccc6c5c4c1B3c1cc(-c3ccccc3)ccc1O2 ; CC(C)(C)c1cc2c3c(c1)N(c1c(-c4ccccc4)cccc1-c1ccccc1)c1ccc4sc5cc6ccccc6cc5c4c1B3c1cc(-c3ccccc3)ccc1O2 ; CC(C)(C)c1cc2c3c(c1)N(c1c(-c4ccccc4)cccc1-c1ccccc1)c1ccc4sc5c6ccccc6ccc5c4c1B3c1cc(-c3ccccc3)ccc1O2]

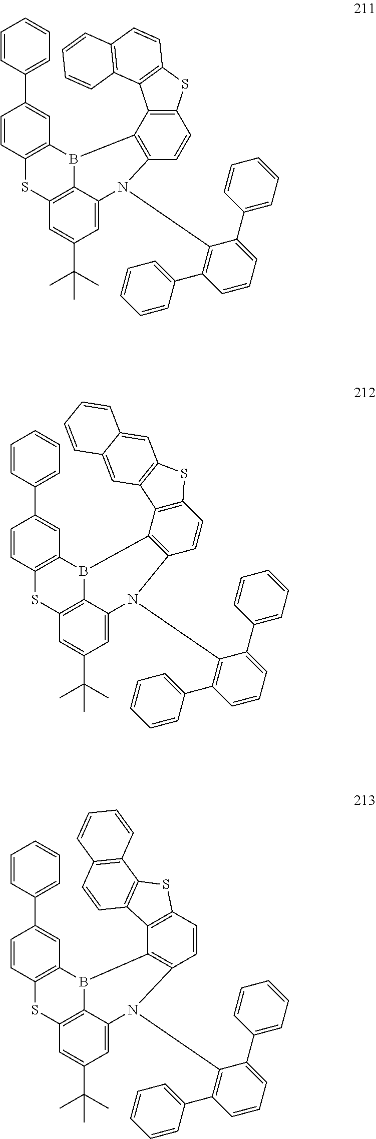 [SMILES: CC(C)(C)c1cc2c3c(c1)N(c1c(-c4ccccc4)cccc1-c1ccccc1)c1ccc4sc5ccc6ccccc6c5c4c1B3c1cc(-c3ccccc3)ccc1S2 ; CC(C)(C)c1cc2c3c(c1)N(c1c(-c4ccccc4)cccc1-c1ccccc1)c1ccc4sc5cc6ccccc6cc5c4c1B3c1cc(-c3ccccc3)ccc1S2 ; CC(C)(C)c1cc2c3c(c1)N(c1c(-c4ccccc4)cccc1-c1ccccc1)c1ccc4sc5c6ccccc6ccc5c4c1B3c1cc(-c3ccccc3)ccc1S2]

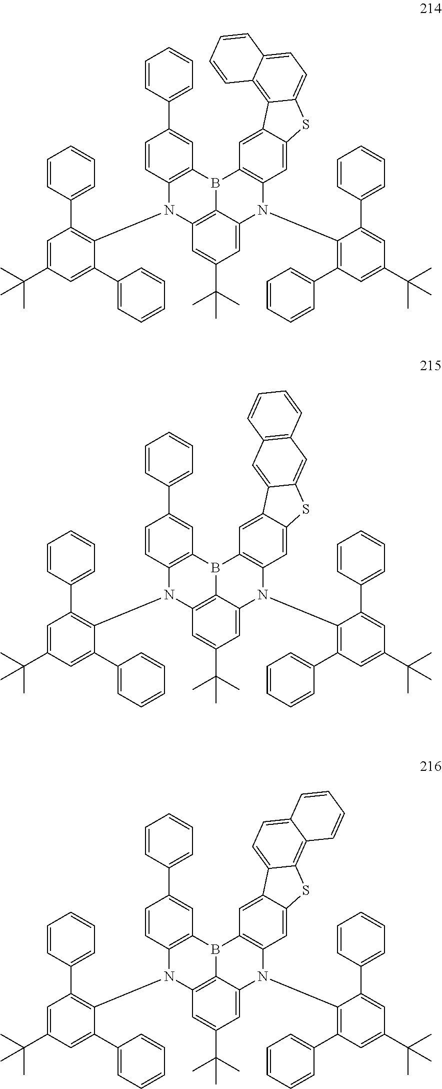

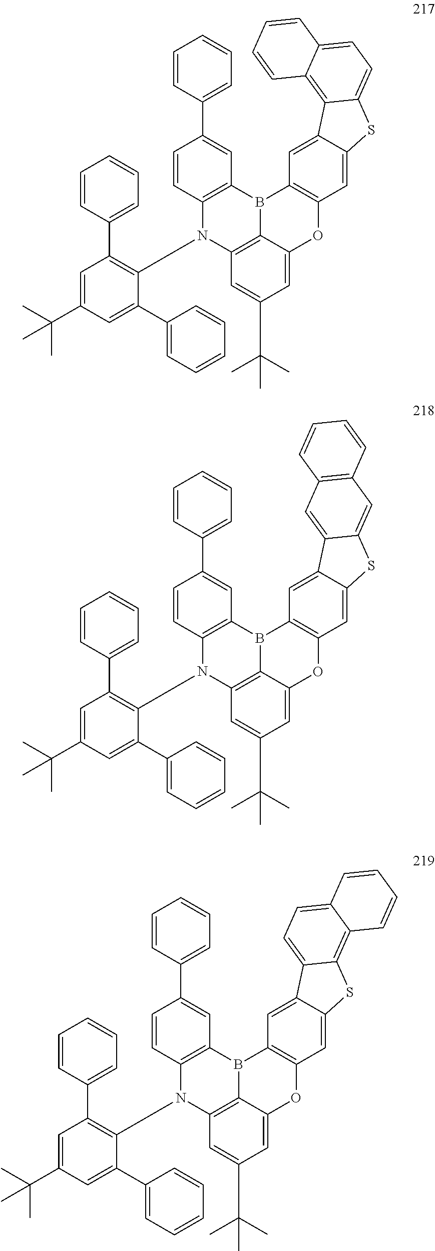 [SMILES: CC(C)(C)c1cc(-c2ccccc2)c(N2c3ccc(-c4ccccc4)cc3B3c4cc5c(cc4Oc4cc(C(C)(C)C)cc2c43)sc2ccc3ccccc3c25)c(-c2ccccc2)c1 ; CC(C)(C)c1cc(-c2ccccc2)c(N2c3ccc(-c4ccccc4)cc3B3c4cc5c(cc4Oc4cc(C(C)(C)C)cc2c43)sc2cc3ccccc3cc25)c(-c2ccccc2)c1 ; CC(C)(C)c1cc(-c2ccccc2)c(N2c3ccc(-c4ccccc4)cc3B3c4cc5c(cc4Oc4cc(C(C)(C)C)cc2c43)sc2c3ccccc3ccc52)c(-c2ccccc2)c1]

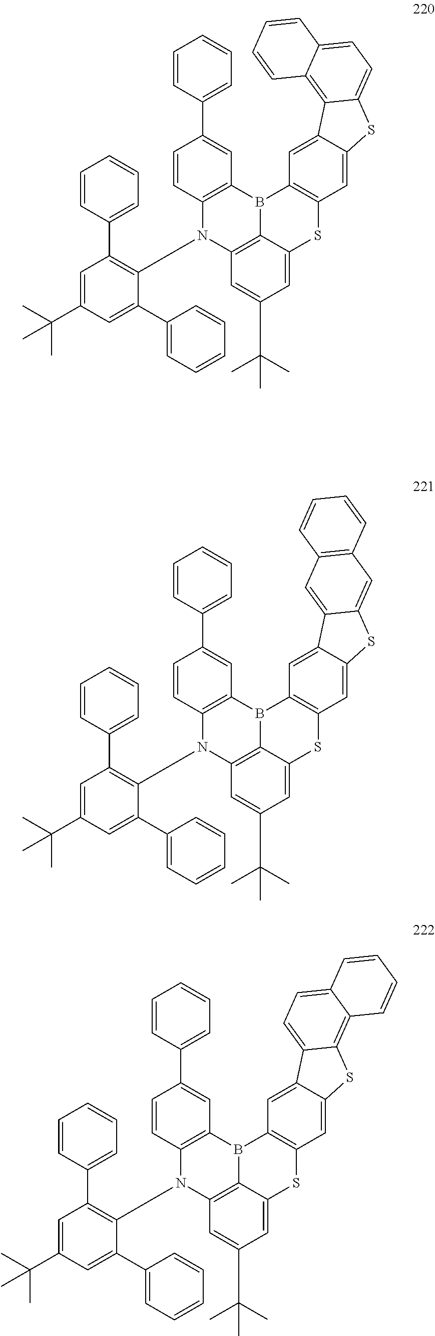 [SMILES: CC(C)(C)c1cc(-c2ccccc2)c(N2c3ccc(-c4ccccc4)cc3B3c4cc5c(cc4Sc4cc(C(C)(C)C)cc2c43)sc2ccc3ccccc3c25)c(-c2ccccc2)c1 ; CC(C)(C)c1cc(-c2ccccc2)c(N2c3ccc(-c4ccccc4)cc3B3c4cc5c(cc4Sc4cc(C(C)(C)C)cc2c43)sc2cc3ccccc3cc25)c(-c2ccccc2)c1 ; CC(C)(C)c1cc(-c2ccccc2)c(N2c3ccc(-c4ccccc4)cc3B3c4cc5c(cc4Sc4cc(C(C)(C)C)cc2c43)sc2c3ccccc3ccc52)c(-c2ccccc2)c1]

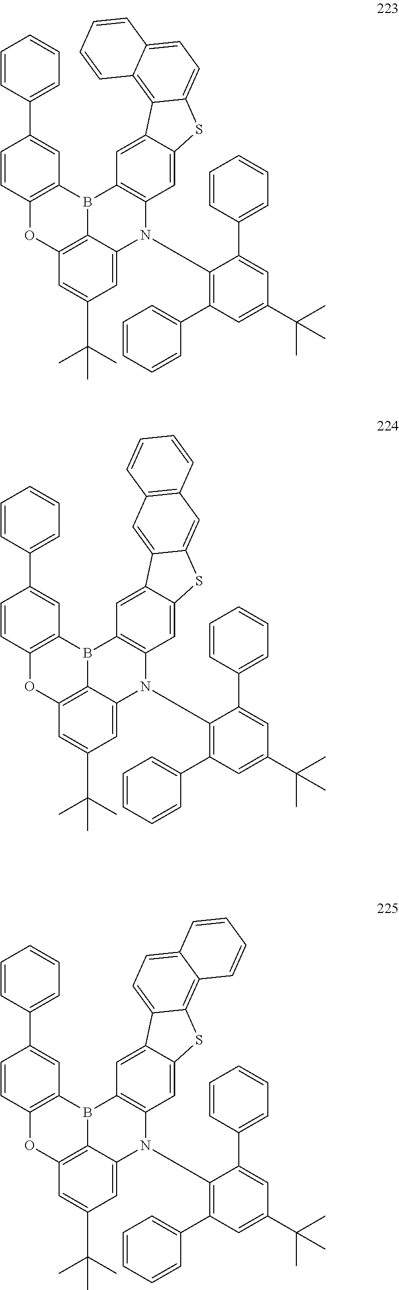 [SMILES: CC(C)(C)c1cc(-c2ccccc2)c(N2c3cc4sc5ccc6ccccc6c5c4cc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4cc(-c5ccccc5)ccc4Oc4cc(C(C)(C)C)cc2c43)c(-c2ccccc2)c1]

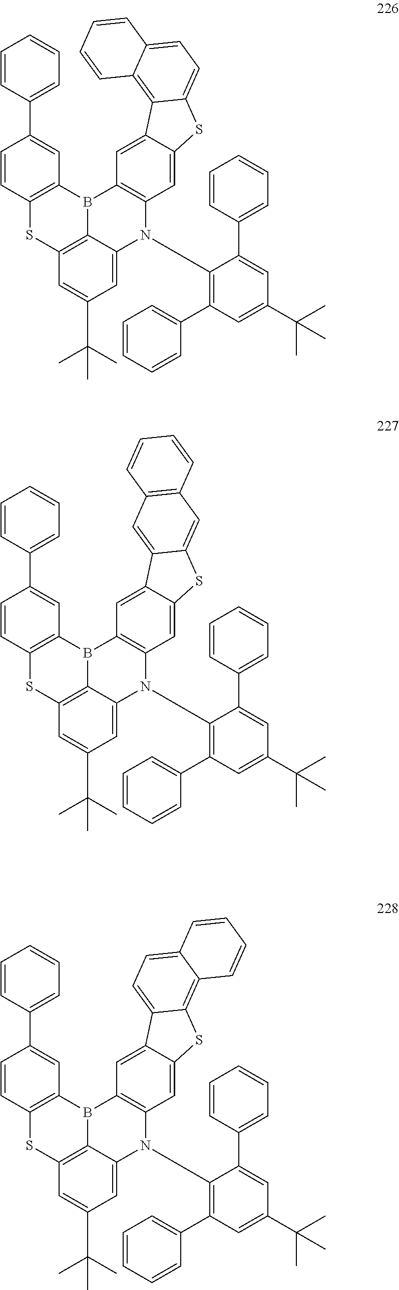 [SMILES: CC(C)(C)c1cc(-c2ccccc2)c(N2c3cc4sc5ccc6ccccc6c5c4cc3B3c4cc(-c5ccccc5)ccc4Sc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4cc(-c5ccccc5)ccc4Sc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4cc(-c5ccccc5)ccc4Sc4cc(C(C)(C)C)cc2c43)c(-c2ccccc2)c1]

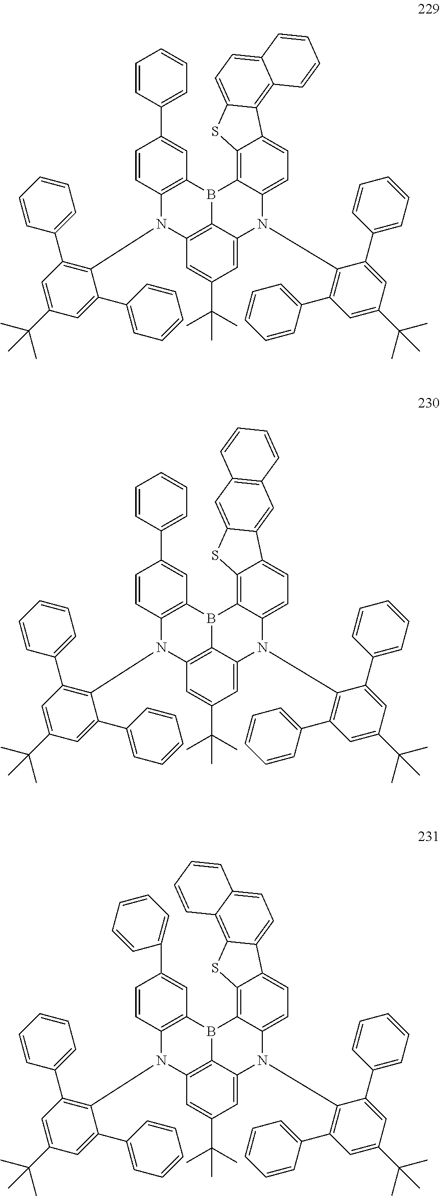

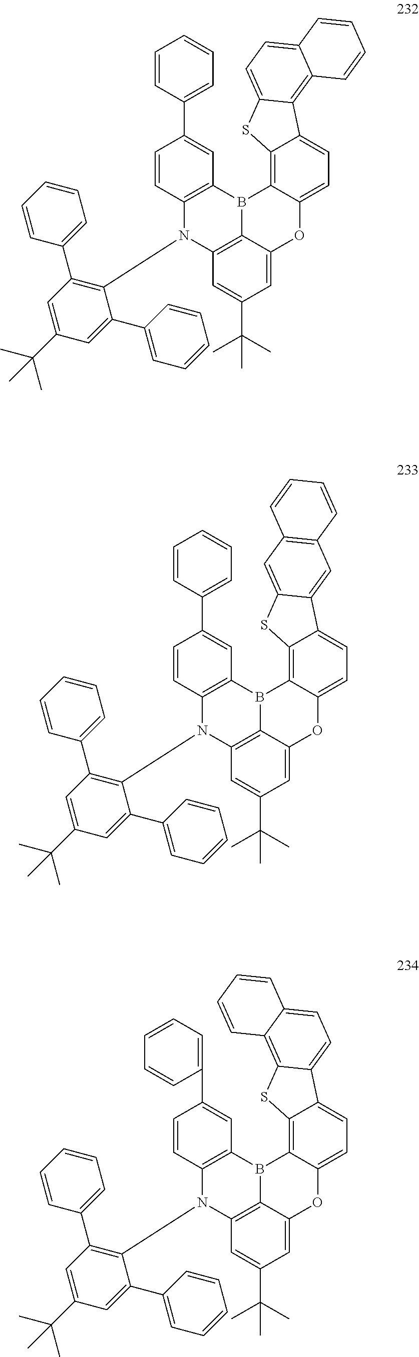 [SMILES: CC(C)(C)c1cc(-c2ccccc2)c(N2c3ccc(-c4ccccc4)cc3B3c4c(cc(C(C)(C)C)cc42)Oc2ccc4c(sc5ccc6ccccc6c54)c23)c(-c2ccccc2)c1 ; CC(C)(C)c1cc(-c2ccccc2)c(N2c3ccc(-c4ccccc4)cc3B3c4c(cc(C(C)(C)C)cc42)Oc2ccc4c(sc5cc6ccccc6cc54)c23)c(-c2ccccc2)c1 ; CC(C)(C)c1cc(-c2ccccc2)c(N2c3ccc(-c4ccccc4)cc3B3c4c(cc(C(C)(C)C)cc42)Oc2ccc4c(sc5c6ccccc6ccc45)c23)c(-c2ccccc2)c1]

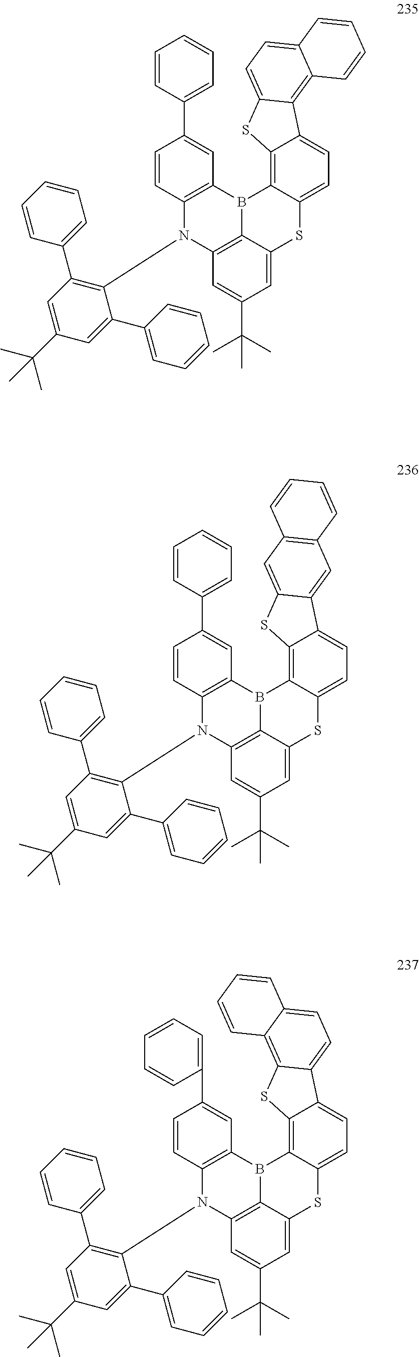 [SMILES: CC(C)(C)c1cc(-c2ccccc2)c(N2c3ccc(-c4ccccc4)cc3B3c4c(cc(C(C)(C)C)cc42)Sc2ccc4c(sc5ccc6ccccc6c54)c23)c(-c2ccccc2)c1 ; CC(C)(C)c1cc(-c2ccccc2)c(N2c3ccc(-c4ccccc4)cc3B3c4c(cc(C(C)(C)C)cc42)Sc2ccc4c(sc5cc6ccccc6cc54)c23)c(-c2ccccc2)c1 ; CC(C)(C)c1cc(-c2ccccc2)c(N2c3ccc(-c4ccccc4)cc3B3c4c(cc(C(C)(C)C)cc42)Sc2ccc4c(sc5c6ccccc6ccc45)c23)c(-c2ccccc2)c1]

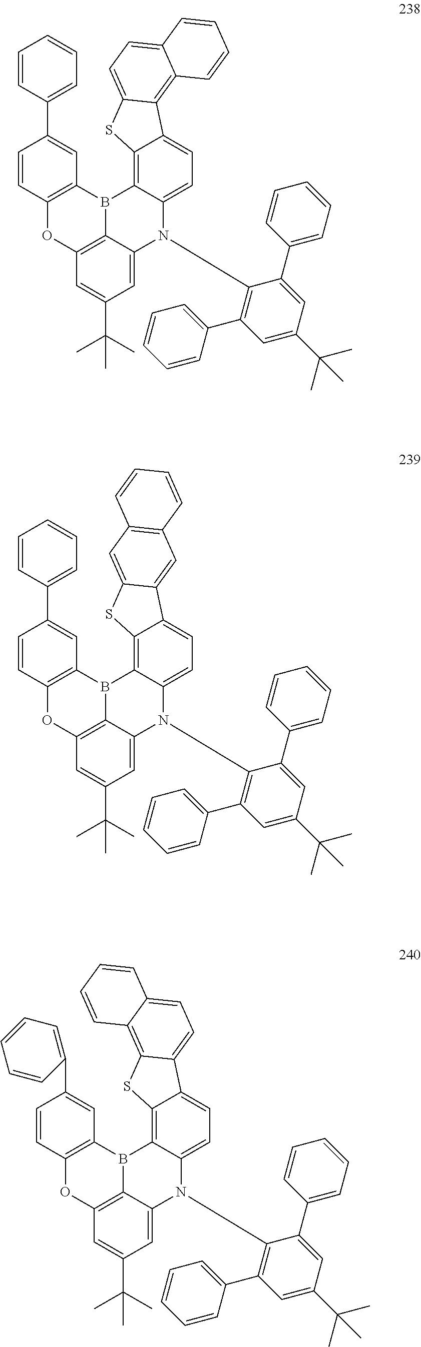 [SMILES: CC(C)(C)c1cc(-c2ccccc2)c(N2c3cc(C(C)(C)C)cc4c3B(c3cc(-c5ccccc5)ccc3O4)c3c2ccc2c3sc3ccc4ccccc4c32)c(-c2ccccc2)c1 ; CC(C)(C)c1cc(-c2ccccc2)c(N2c3cc(C(C)(C)C)cc4c3B(c3cc(-c5ccccc5)ccc3O4)c3c2ccc2c3sc3cc4ccccc4cc32)c(-c2ccccc2)c1 ; CC(C)(C)c1cc(-c2ccccc2)c(N2c3cc(C(C)(C)C)cc4c3B(c3cc(-c5ccccc5)ccc3O4)c3c2ccc2c3sc3c4ccccc4ccc23)c(-c2ccccc2)c1]

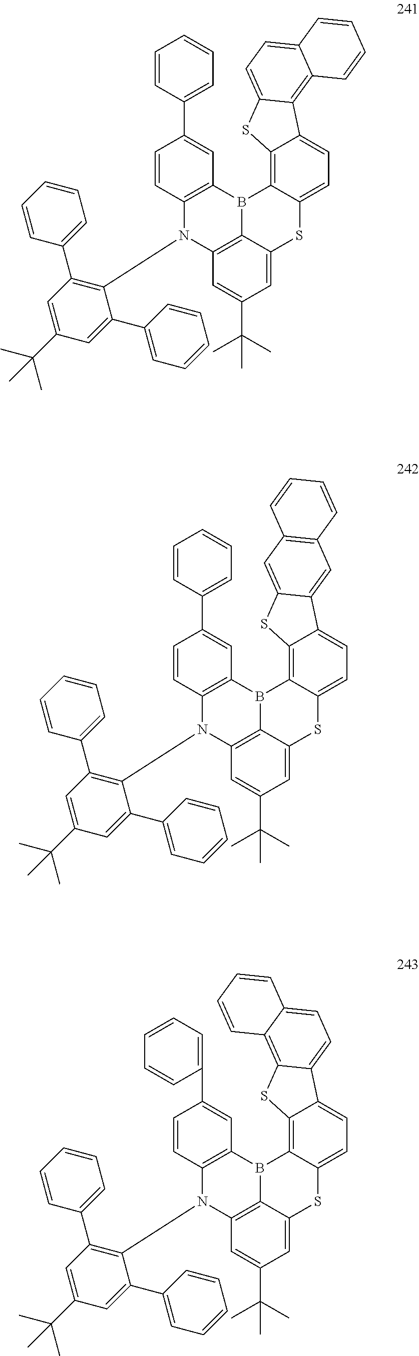 [SMILES: CC(C)(C)c1cc(-c2ccccc2)c(N2c3ccc(-c4ccccc4)cc3B3c4c(cc(C(C)(C)C)cc42)Sc2ccc4c(sc5ccc6ccccc6c54)c23)c(-c2ccccc2)c1 ; CC(C)(C)c1cc(-c2ccccc2)c(N2c3ccc(-c4ccccc4)cc3B3c4c(cc(C(C)(C)C)cc42)Sc2ccc4c(sc5cc6ccccc6cc54)c23)c(-c2ccccc2)c1 ; CC(C)(C)c1cc(-c2ccccc2)c(N2c3ccc(-c4ccccc4)cc3B3c4c(cc(C(C)(C)C)cc42)Sc2ccc4c(sc5c6ccccc6ccc45)c23)c(-c2ccccc2)c1]

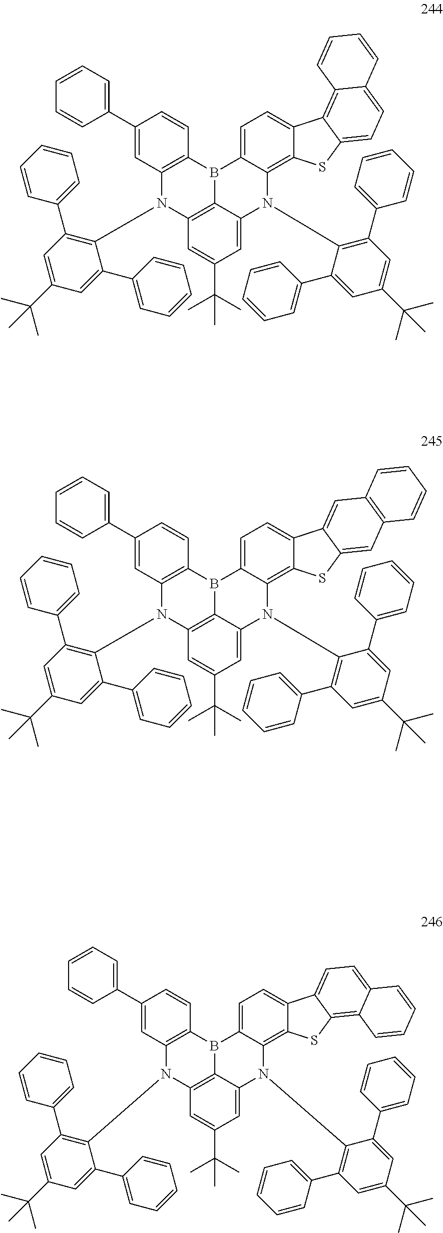

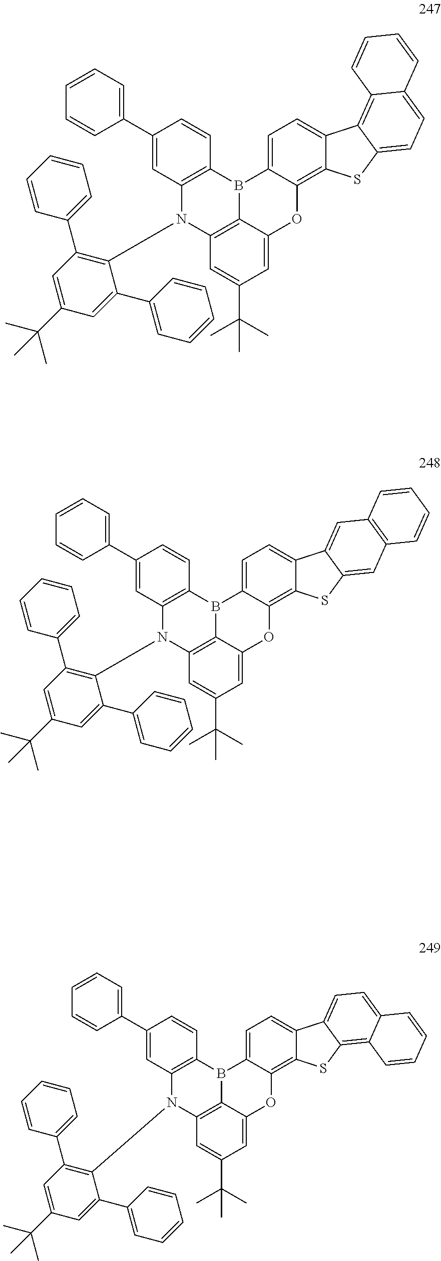

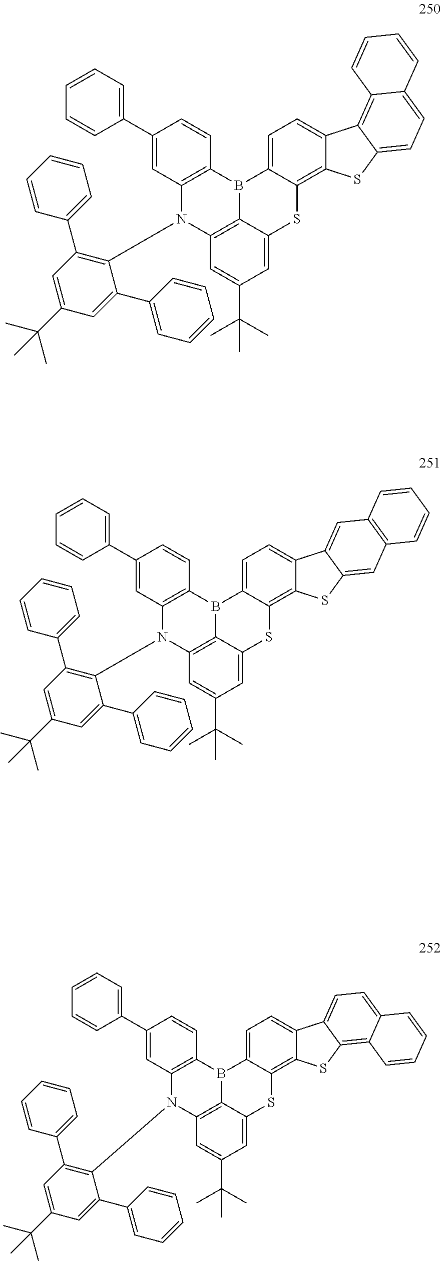

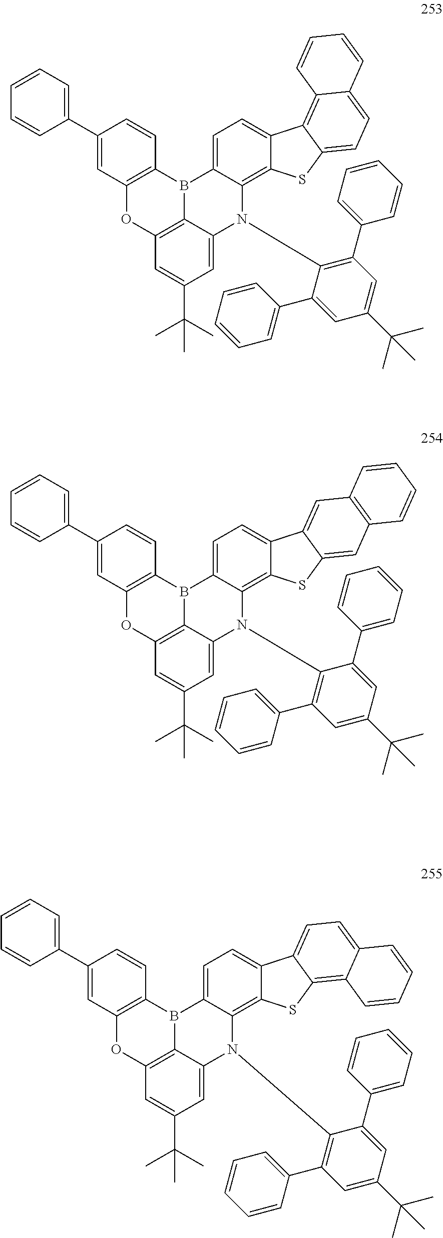

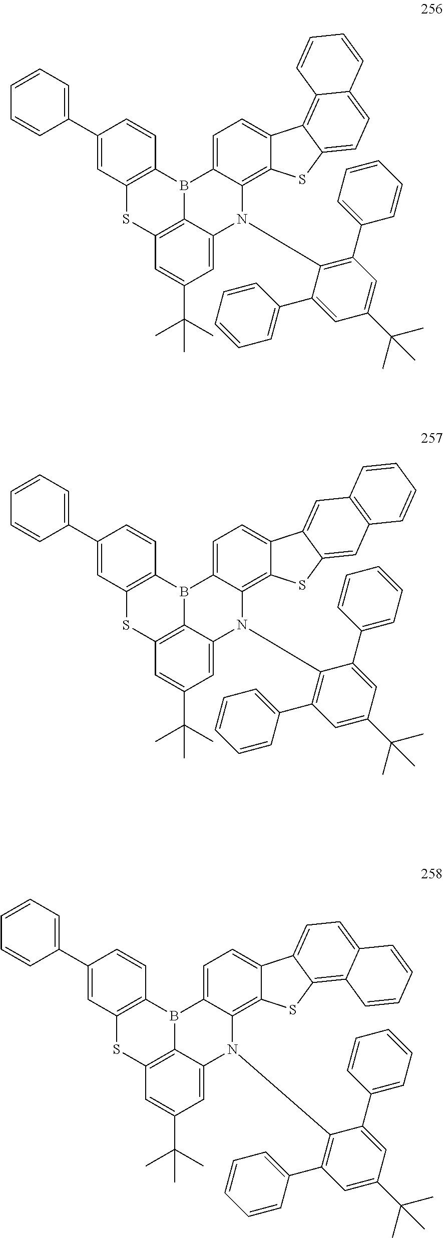

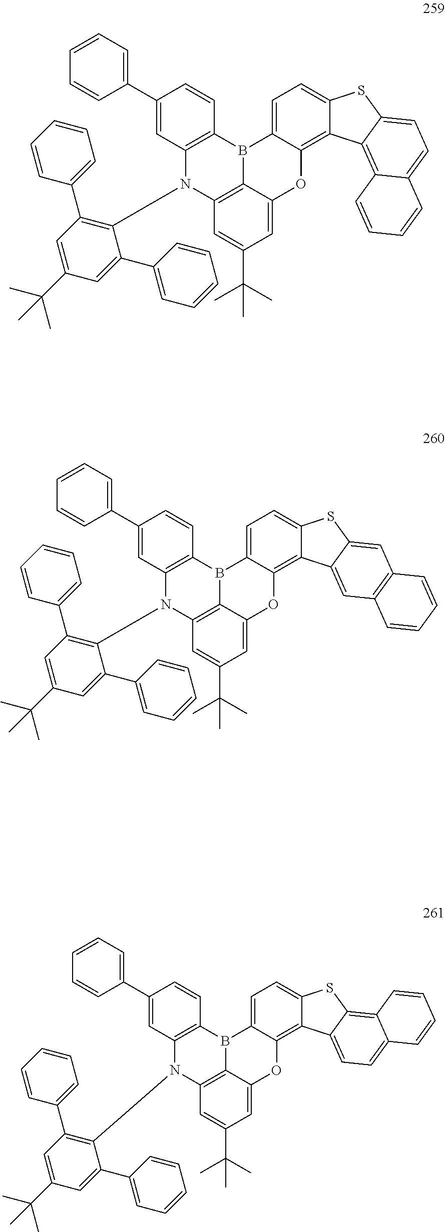

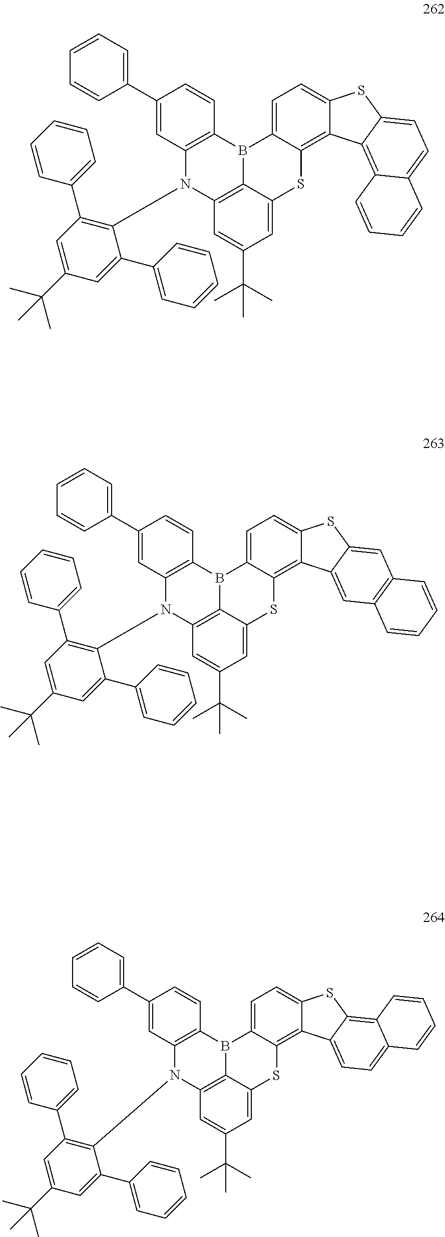

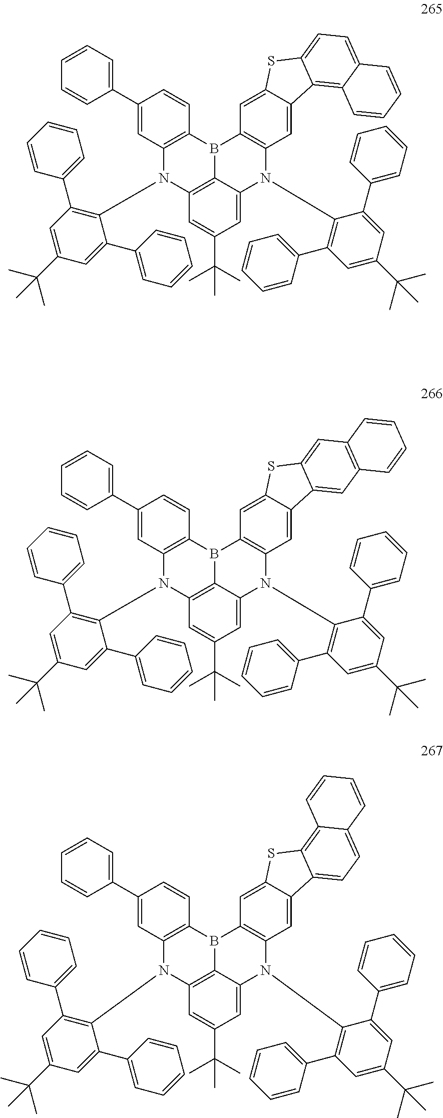

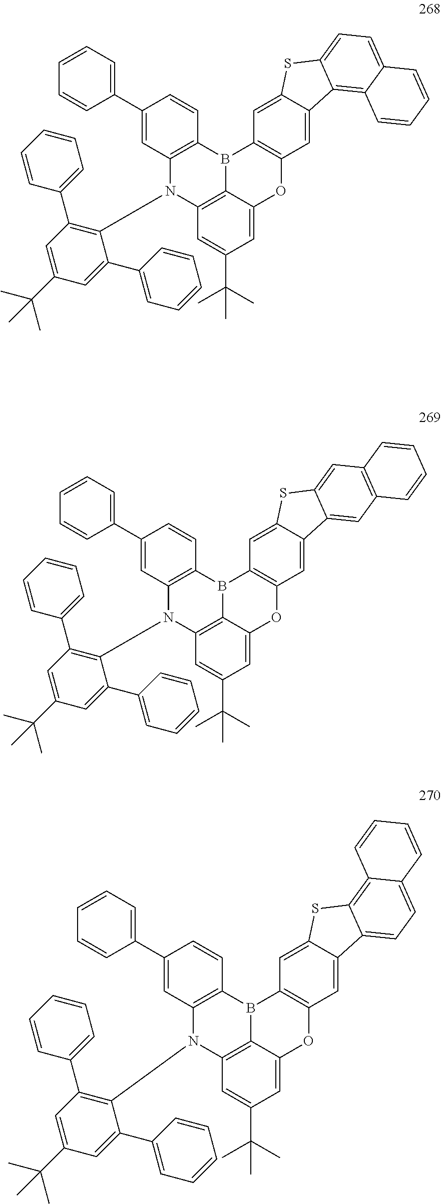

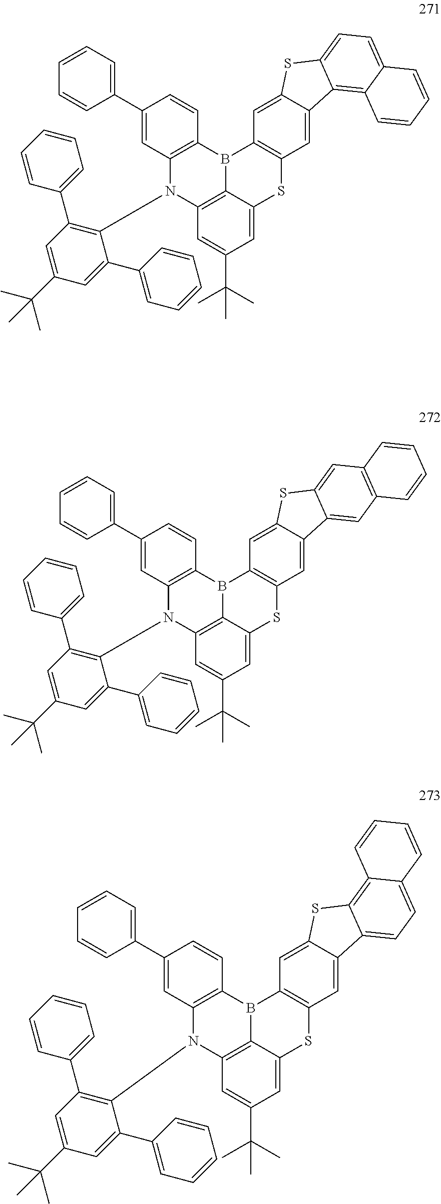

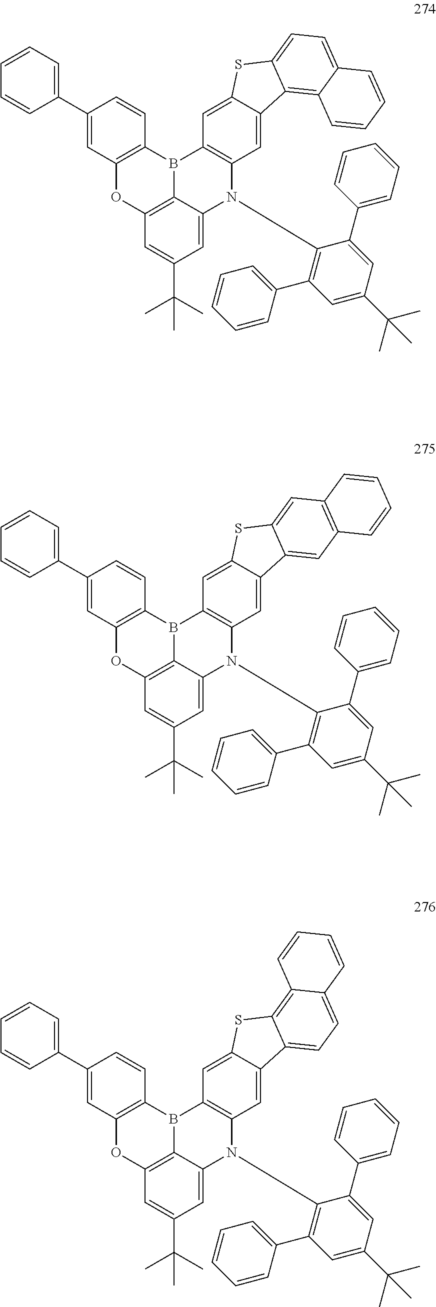 [SMILES: CC(C)(C)c1cc(-c2ccccc2)c(N2c3cc4c(cc3B3c5ccc(-c6ccccc6)cc5Oc5cc(C(C)(C)C)cc2c53)sc2ccc3ccccc3c24)c(-c2ccccc2)c1 ; CC(C)(C)c1cc(-c2ccccc2)c(N2c3cc4c(cc3B3c5ccc(-c6ccccc6)cc5Oc5cc(C(C)(C)C)cc2c53)sc2cc3ccccc3cc24)c(-c2ccccc2)c1 ; CC(C)(C)c1cc(-c2ccccc2)c(N2c3cc4c(cc3B3c5ccc(-c6ccccc6)cc5Oc5cc(C(C)(C)C)cc2c53)sc2c3ccccc3ccc42)c(-c2ccccc2)c1]

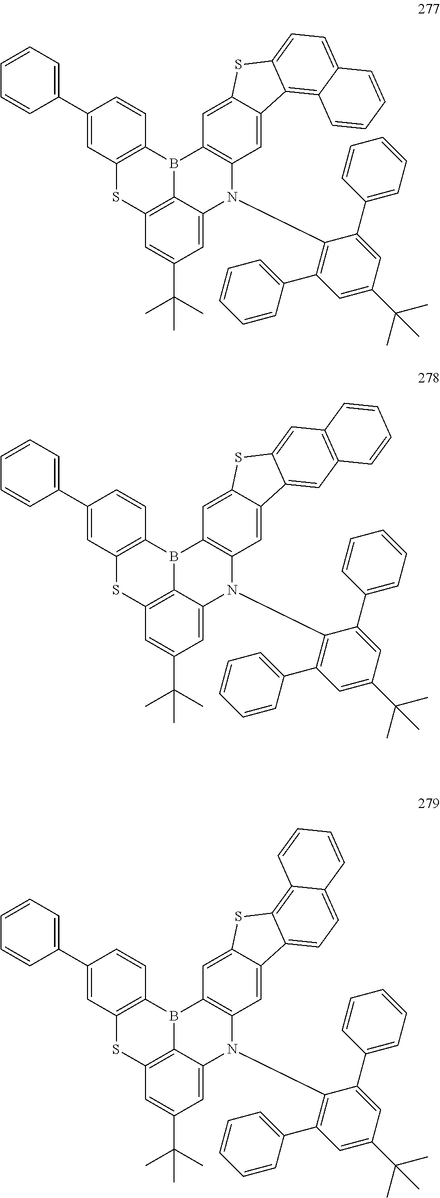 [SMILES: CC(C)(C)c1cc(-c2ccccc2)c(N2c3cc4c(cc3B3c5ccc(-c6ccccc6)cc5Sc5cc(C(C)(C)C)cc2c53)sc2ccc3ccccc3c24)c(-c2ccccc2)c1 ; CC(C)(C)c1cc(-c2ccccc2)c(N2c3cc4c(cc3B3c5ccc(-c6ccccc6)cc5Sc5cc(C(C)(C)C)cc2c53)sc2cc3ccccc3cc24)c(-c2ccccc2)c1 ; CC(C)(C)c1cc(-c2ccccc2)c(N2c3cc4c(cc3B3c5ccc(-c6ccccc6)cc5Sc5cc(C(C)(C)C)cc2c53)sc2c3ccccc3ccc42)c(-c2ccccc2)c1]

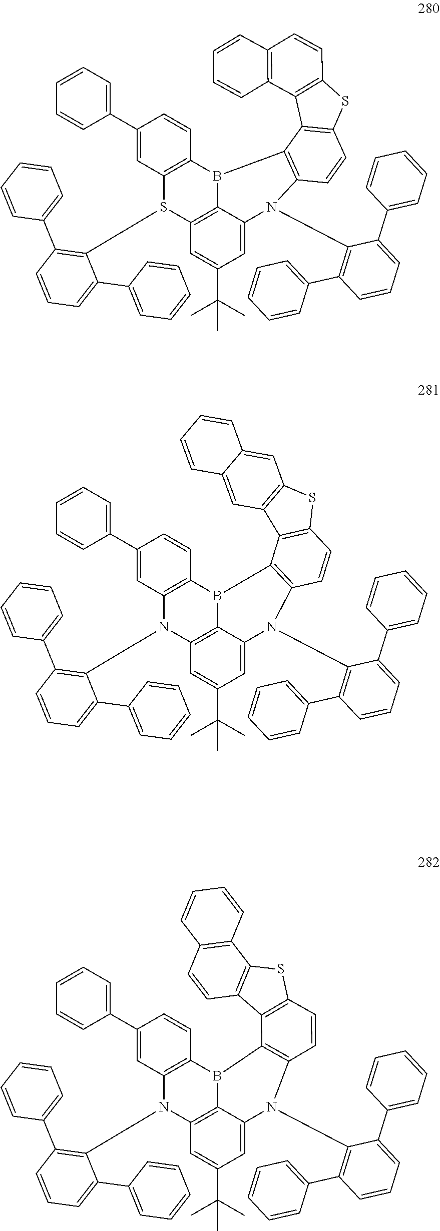

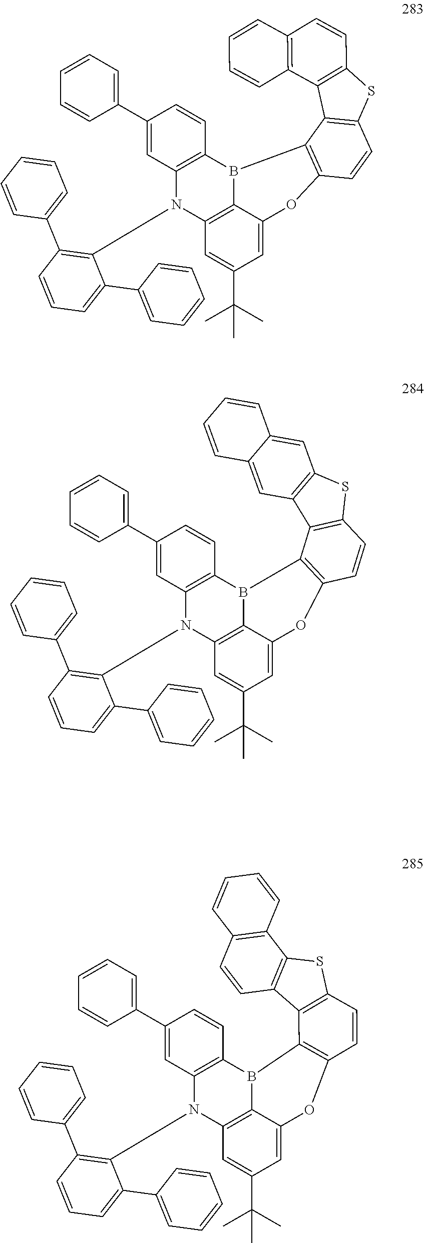 [SMILES: CC(C)(C)c1cc2c3c(c1)N(c1c(-c4ccccc4)cccc1-c1ccccc1)c1cc(-c4ccccc4)ccc1B3c1c(ccc3sc4ccc5ccccc5c4c13)O2 ; CC(C)(C)c1cc2c3c(c1)N(c1c(-c4ccccc4)cccc1-c1ccccc1)c1cc(-c4ccccc4)ccc1B3c1c(ccc3sc4cc5ccccc5cc4c13)O2 ; CC(C)(C)c1cc2c3c(c1)N(c1c(-c4ccccc4)cccc1-c1ccccc1)c1cc(-c4ccccc4)ccc1B3c1c(ccc3sc4c5ccccc5ccc4c13)O2]

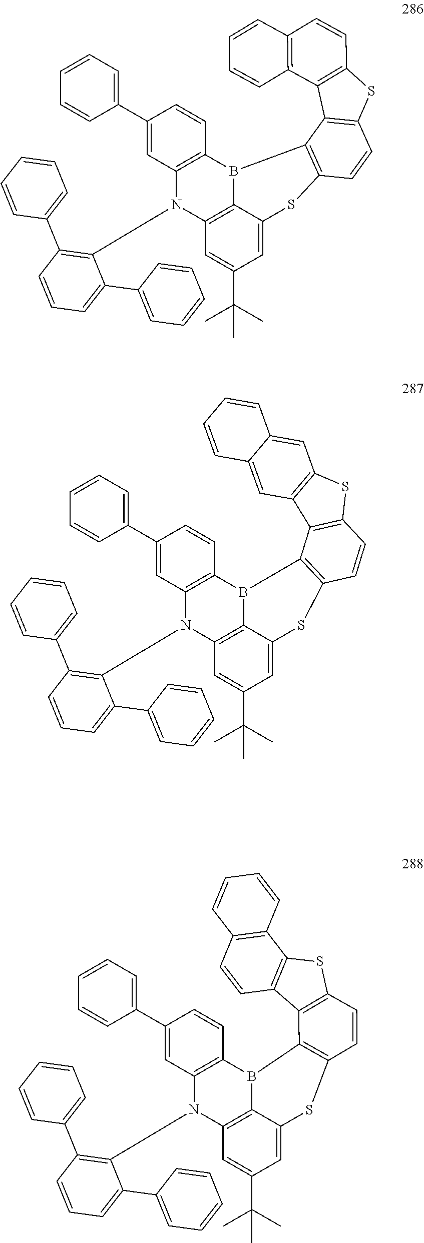 [SMILES: CC(C)(C)c1cc2c3c(c1)N(c1c(-c4ccccc4)cccc1-c1ccccc1)c1cc(-c4ccccc4)ccc1B3c1c(ccc3sc4ccc5ccccc5c4c13)S2 ; CC(C)(C)c1cc2c3c(c1)N(c1c(-c4ccccc4)cccc1-c1ccccc1)c1cc(-c4ccccc4)ccc1B3c1c(ccc3sc4cc5ccccc5cc4c13)S2 ; CC(C)(C)c1cc2c3c(c1)N(c1c(-c4ccccc4)cccc1-c1ccccc1)c1cc(-c4ccccc4)ccc1B3c1c(ccc3sc4c5ccccc5ccc4c13)S2]

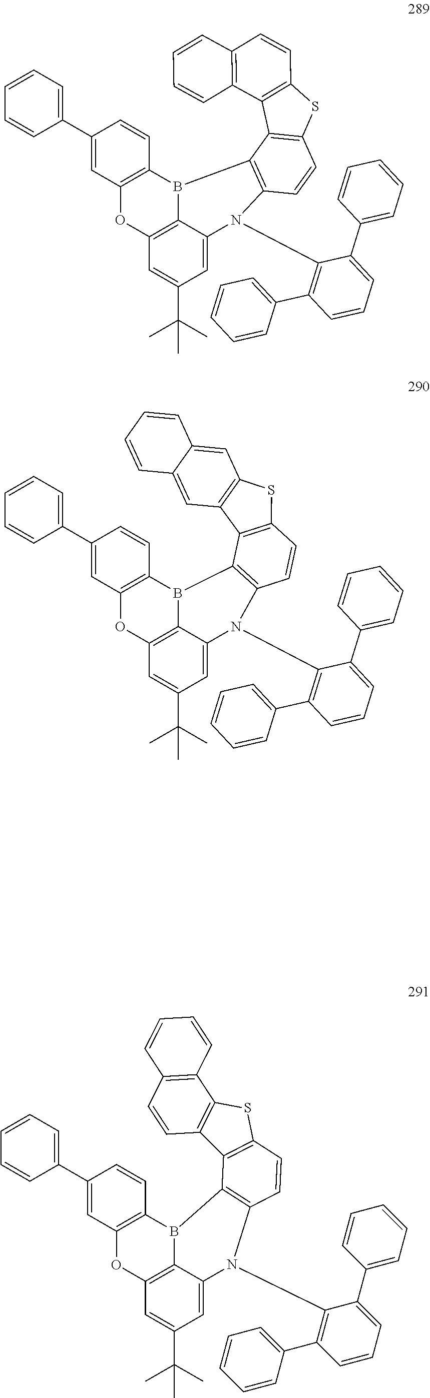 [SMILES: CC(C)(C)c1cc2c3c(c1)N(c1c(-c4ccccc4)cccc1-c1ccccc1)c1ccc4sc5ccc6ccccc6c5c4c1B3c1ccc(-c3ccccc3)cc1O2 ; CC(C)(C)c1cc2c3c(c1)N(c1c(-c4ccccc4)cccc1-c1ccccc1)c1ccc4sc5cc6ccccc6cc5c4c1B3c1ccc(-c3ccccc3)cc1O2 ; CC(C)(C)c1cc2c3c(c1)N(c1c(-c4ccccc4)cccc1-c1ccccc1)c1ccc4sc5c6ccccc6ccc5c4c1B3c1ccc(-c3ccccc3)cc1O2]

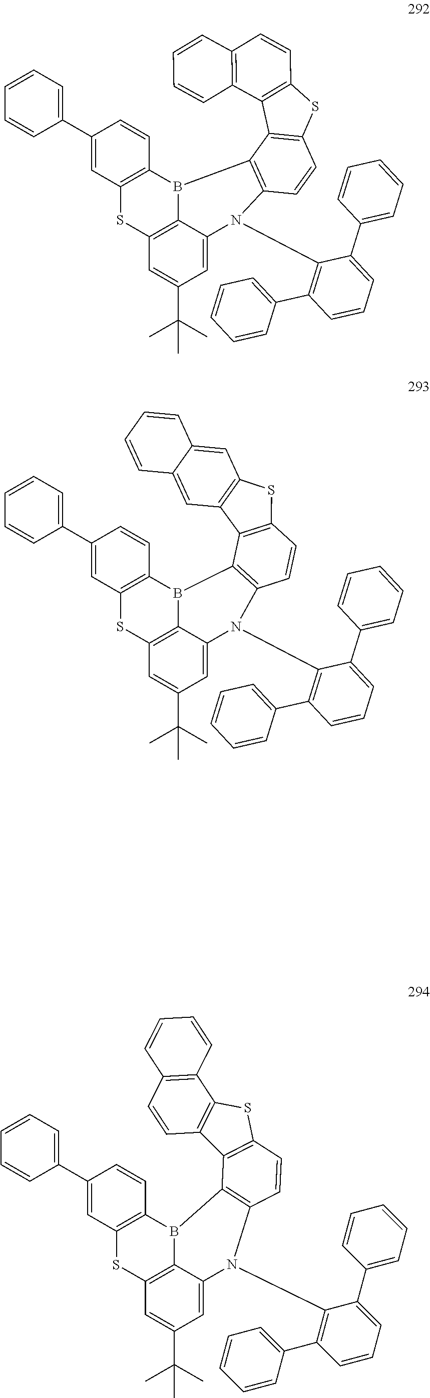 [SMILES: CC(C)(C)c1cc2c3c(c1)N(c1c(-c4ccccc4)cccc1-c1ccccc1)c1ccc4sc5ccc6ccccc6c5c4c1B3c1ccc(-c3ccccc3)cc1S2 ; CC(C)(C)c1cc2c3c(c1)N(c1c(-c4ccccc4)cccc1-c1ccccc1)c1ccc4sc5cc6ccccc6cc5c4c1B3c1ccc(-c3ccccc3)cc1S2 ; CC(C)(C)c1cc2c3c(c1)N(c1c(-c4ccccc4)cccc1-c1ccccc1)c1ccc4sc5c6ccccc6ccc5c4c1B3c1ccc(-c3ccccc3)cc1S2]

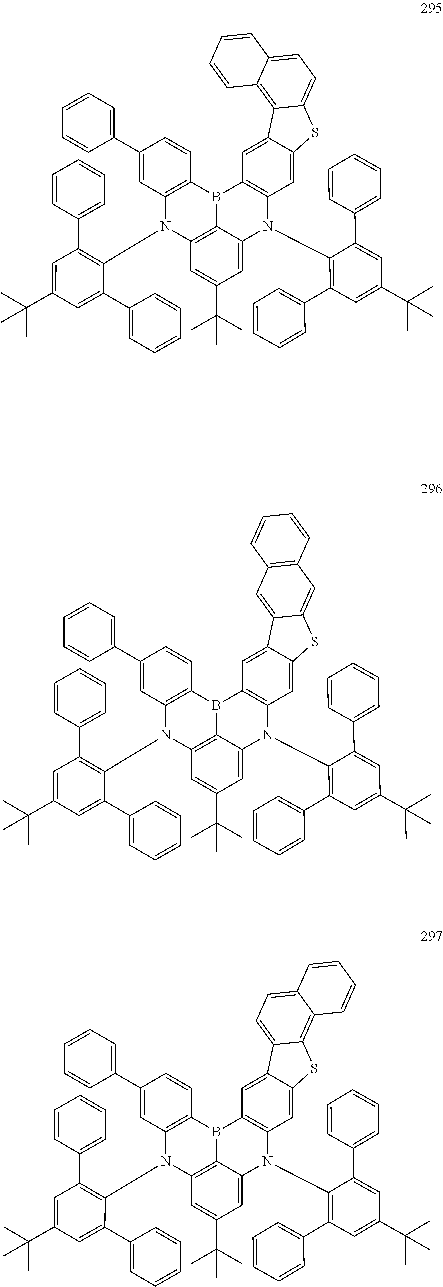

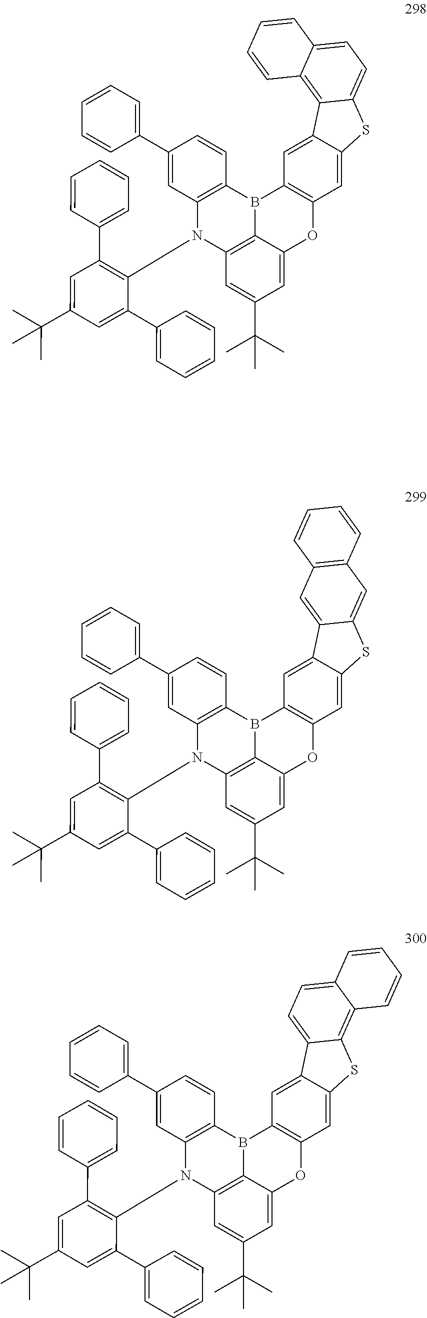 [SMILES: CC(C)(C)c1cc(-c2ccccc2)c(N2c3cc(-c4ccccc4)ccc3B3c4cc5c(cc4Oc4cc(C(C)(C)C)cc2c43)sc2ccc3ccccc3c25)c(-c2ccccc2)c1 ; CC(C)(C)c1cc(-c2ccccc2)c(N2c3cc(-c4ccccc4)ccc3B3c4cc5c(cc4Oc4cc(C(C)(C)C)cc2c43)sc2cc3ccccc3cc25)c(-c2ccccc2)c1 ; CC(C)(C)c1cc(-c2ccccc2)c(N2c3cc(-c4ccccc4)ccc3B3c4cc5c(cc4Oc4cc(C(C)(C)C)cc2c43)sc2c3ccccc3ccc52)c(-c2ccccc2)c1]

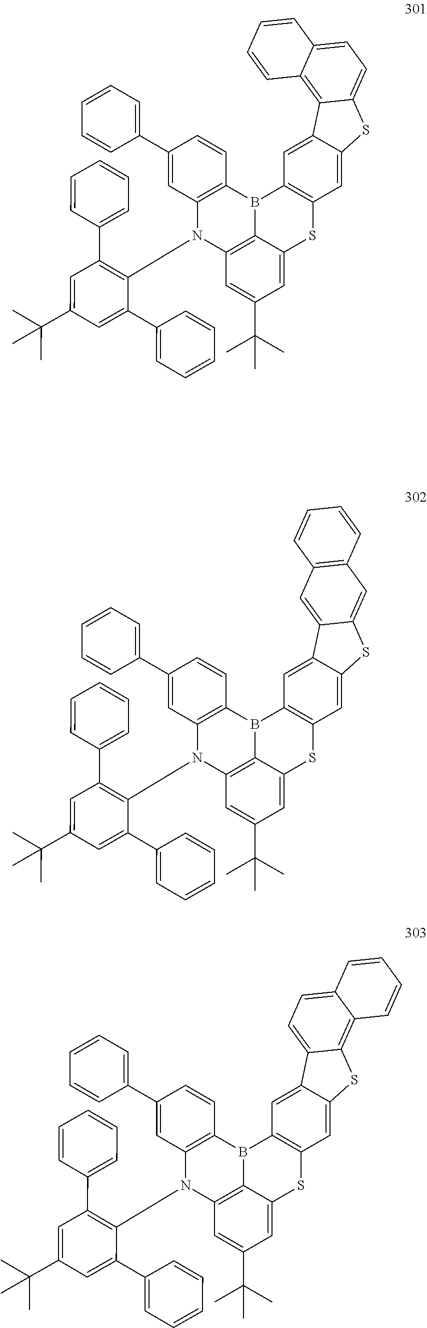 [SMILES: CC(C)(C)c1cc(-c2ccccc2)c(N2c3cc(-c4ccccc4)ccc3B3c4cc5c(cc4Sc4cc(C(C)(C)C)cc2c43)sc2ccc3ccccc3c25)c(-c2ccccc2)c1 ; CC(C)(C)c1cc(-c2ccccc2)c(N2c3cc(-c4ccccc4)ccc3B3c4cc5c(cc4Sc4cc(C(C)(C)C)cc2c43)sc2cc3ccccc3cc25)c(-c2ccccc2)c1 ; CC(C)(C)c1cc(-c2ccccc2)c(N2c3cc(-c4ccccc4)ccc3B3c4cc5c(cc4Sc4cc(C(C)(C)C)cc2c43)sc2c3ccccc3ccc52)c(-c2ccccc2)c1]

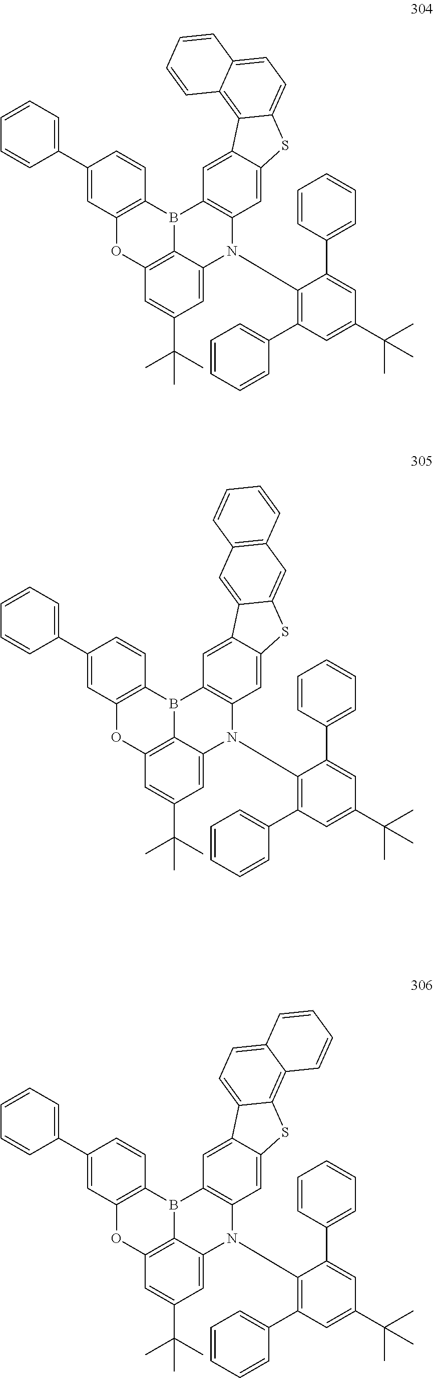 [SMILES: CC(C)(C)c1cc(-c2ccccc2)c(N2c3cc4sc5ccc6ccccc6c5c4cc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4ccc(-c5ccccc5)cc4Oc4cc(C(C)(C)C)cc2c43)c(-c2ccccc2)c1]

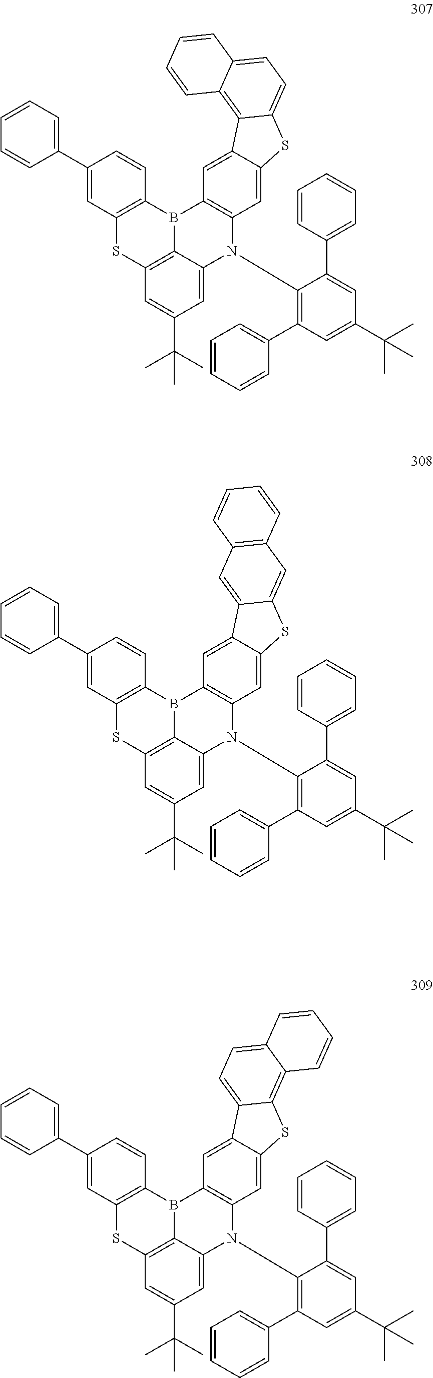 [SMILES: CC(C)(C)c1cc(-c2ccccc2)c(N2c3cc4sc5ccc6ccccc6c5c4cc3B3c4ccc(-c5ccccc5)cc4Sc4cc(C(C)(C)C)cc2c43)c(-c2ccccc2)c1 ; CC(C)(C)c1cc(-c2ccccc2)c(N2c3cc4sc5cc6ccccc6cc5c4cc3B3c4ccc(-c5ccccc5)cc4Sc4cc(C(C)(C)C)cc2c43)c(-c2ccccc2)c1 ; CC(C)(C)c1cc(-c2ccccc2)c(N2c3cc4sc5c6ccccc6ccc5c4cc3B3c4ccc(-c5ccccc5)cc4Sc4cc(C(C)(C)C)cc2c43)c(-c2ccccc2)c1]

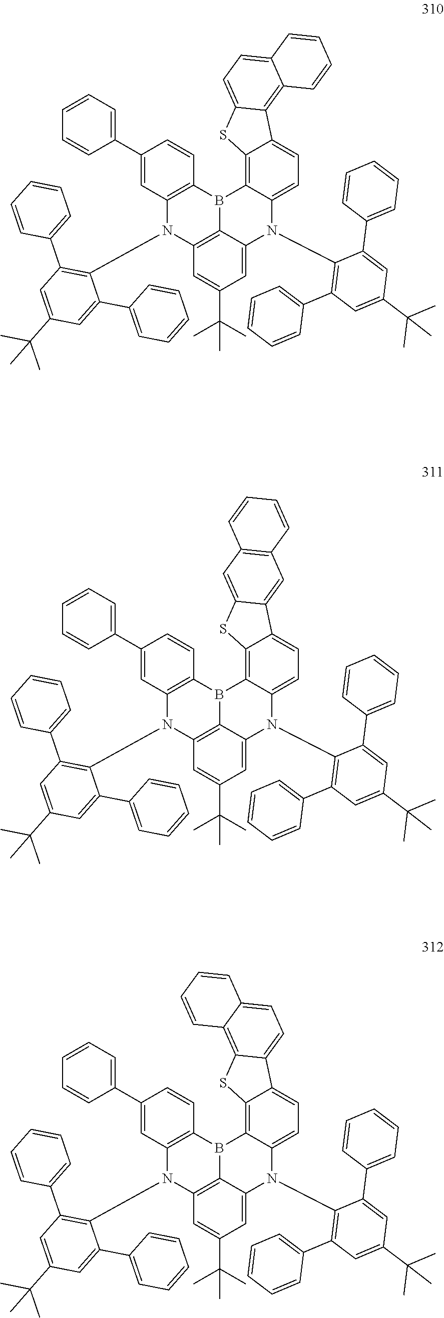

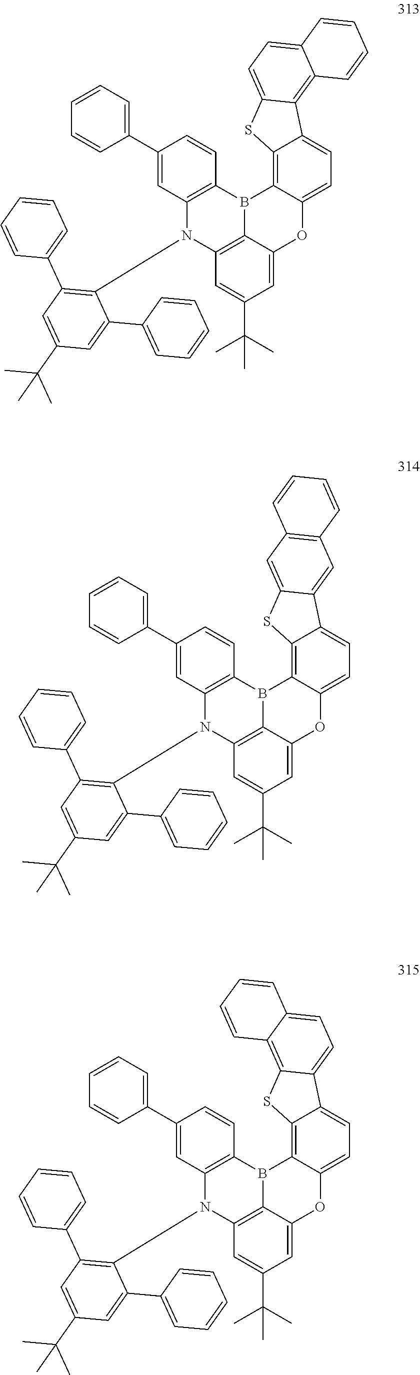 [SMILES: CC(C)(C)c1cc(-c2ccccc2)c(N2c3cc(-c4ccccc4)ccc3B3c4c(cc(C(C)(C)C)cc42)Oc2ccc4c(sc5ccc6ccccc6c54)c23)c(-c2ccccc2)c1 ; CC(C)(C)c1cc(-c2ccccc2)c(N2c3cc(-c4ccccc4)ccc3B3c4c(cc(C(C)(C)C)cc42)Oc2ccc4c(sc5cc6ccccc6cc54)c23)c(-c2ccccc2)c1 ; CC(C)(C)c1cc(-c2ccccc2)c(N2c3cc(-c4ccccc4)ccc3B3c4c(cc(C(C)(C)C)cc42)Oc2ccc4c(sc5c6ccccc6ccc45)c23)c(-c2ccccc2)c1]

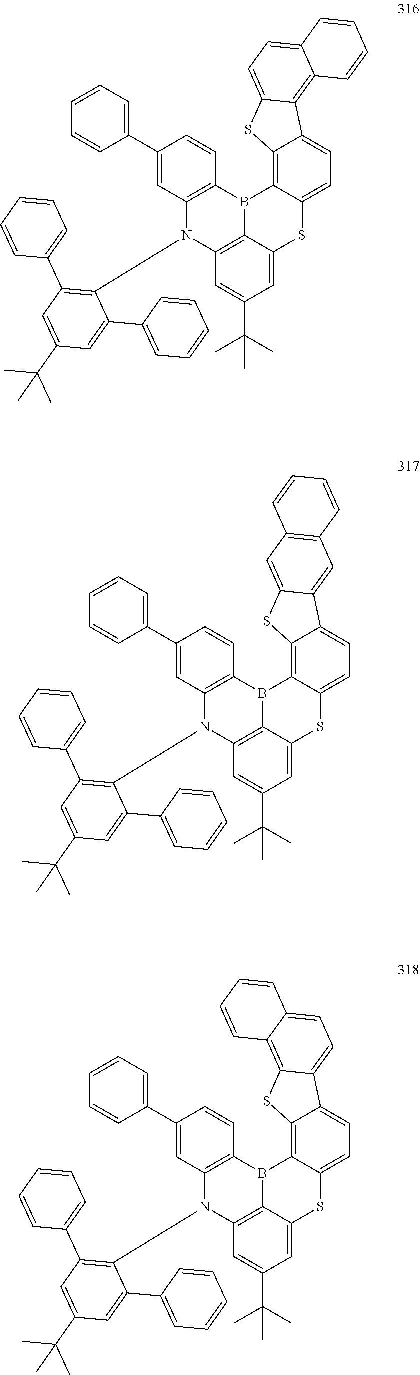 [SMILES: CC(C)(C)c1cc(-c2ccccc2)c(N2c3cc(-c4ccccc4)ccc3B3c4c(cc(C(C)(C)C)cc42)Sc2ccc4c(sc5ccc6ccccc6c54)c23)c(-c2ccccc2)c1 ; CC(C)(C)c1cc(-c2ccccc2)c(N2c3cc(-c4ccccc4)ccc3B3c4c(cc(C(C)(C)C)cc42)Sc2ccc4c(sc5cc6ccccc6cc54)c23)c(-c2ccccc2)c1 ; CC(C)(C)c1cc(-c2ccccc2)c(N2c3cc(-c4ccccc4)ccc3B3c4c(cc(C(C)(C)C)cc42)Sc2ccc4c(sc5c6ccccc6ccc45)c23)c(-c2ccccc2)c1]

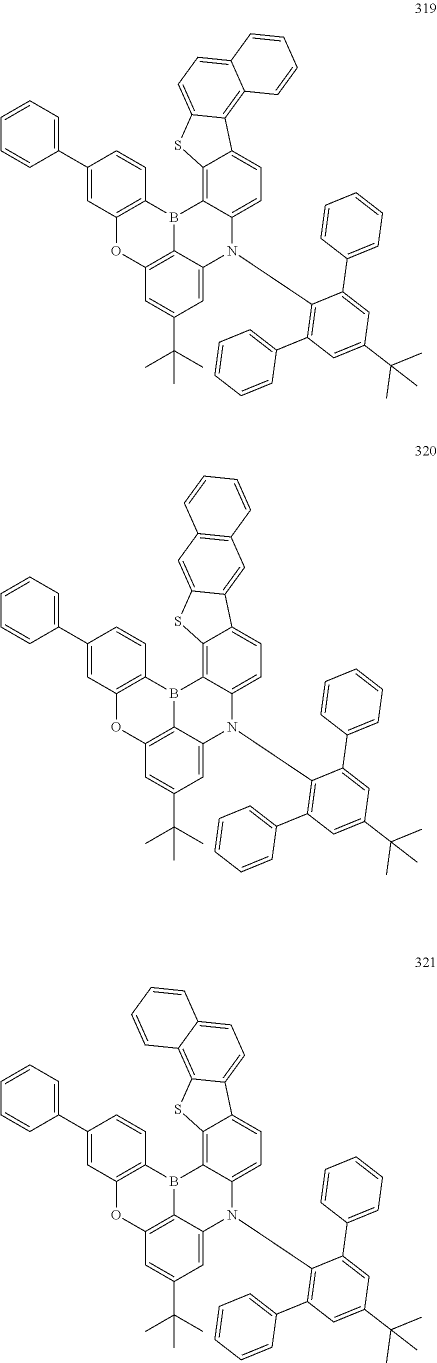 [SMILES: CC(C)(C)c1cc(-c2ccccc2)c(N2c3cc(C(C)(C)C)cc4c3B(c3ccc(-c5ccccc5)cc3O4)c3c2ccc2c3sc3ccc4ccccc4c32)c(-c2ccccc2)c1 ; CC(C)(C)c1cc(-c2ccccc2)c(N2c3cc(C(C)(C)C)cc4c3B(c3ccc(-c5ccccc5)cc3O4)c3c2ccc2c3sc3cc4ccccc4cc32)c(-c2ccccc2)c1 ; CC(C)(C)c1cc(-c2ccccc2)c(N2c3cc(C(C)(C)C)cc4c3B(c3ccc(-c5ccccc5)cc3O4)c3c2ccc2c3sc3c4ccccc4ccc23)c(-c2ccccc2)c1]

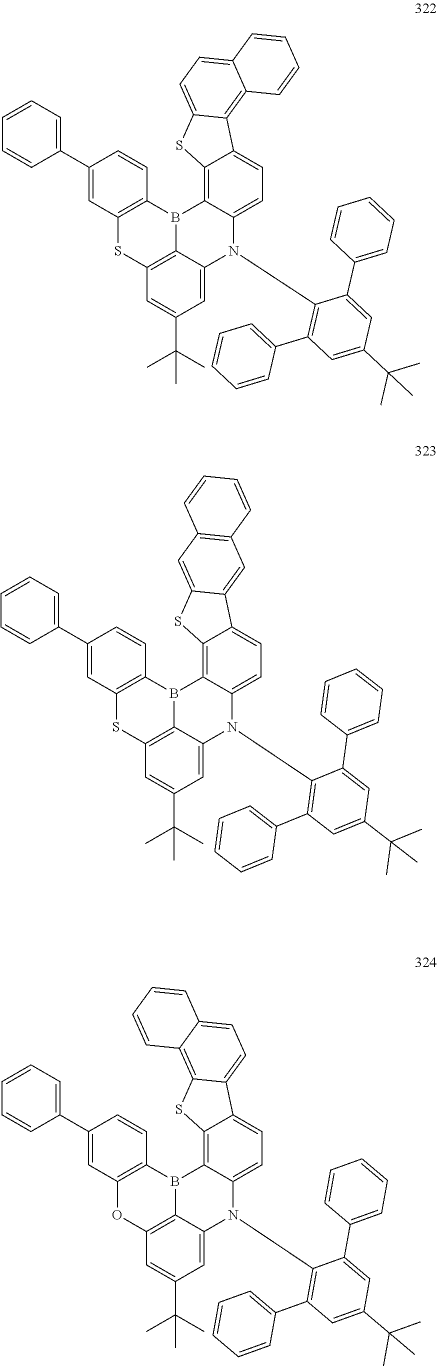 [SMILES: CC(C)(C)c1cc(-c2ccccc2)c(N2c3cc(C(C)(C)C)cc4c3B(c3ccc(-c5ccccc5)cc3S4)c3c2ccc2c3sc3ccc4ccccc4c32)c(-c2ccccc2)c1 ; CC(C)(C)c1cc(-c2ccccc2)c(N2c3cc(C(C)(C)C)cc4c3B(c3ccc(-c5ccccc5)cc3S4)c3c2ccc2c3sc3cc4ccccc4cc32)c(-c2ccccc2)c1 ; CC(C)(C)c1cc(-c2ccccc2)c(N2c3cc(C(C)(C)C)cc4c3B(c3ccc(-c5ccccc5)cc3O4)c3c2ccc2c3sc3c4ccccc4ccc23)c(-c2ccccc2)c1]

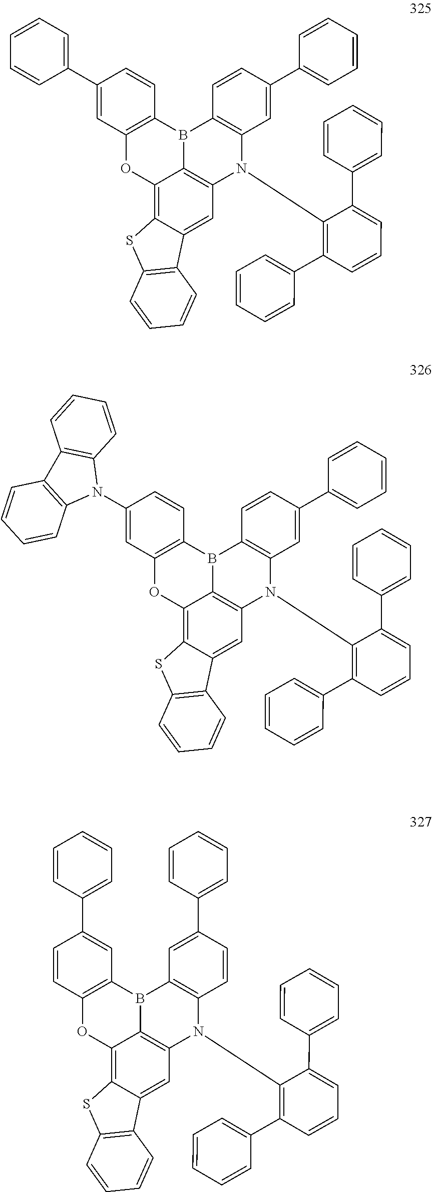 [SMILES: c1ccc(-c2ccc3c(c2)Oc2c4c(cc5c2sc2ccccc25)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4c(sc5ccccc54)c4c2B3c2ccc(-n3c5ccccc5c5ccccc53)cc2O4)cc1 ; c1ccc(-c2ccc3c(c2)B2c4cc(-c5ccccc5)ccc4N(c4c(-c5ccccc5)cccc4-c4ccccc4)c4cc5c(sc6ccccc65)c(c42)O3)cc1]

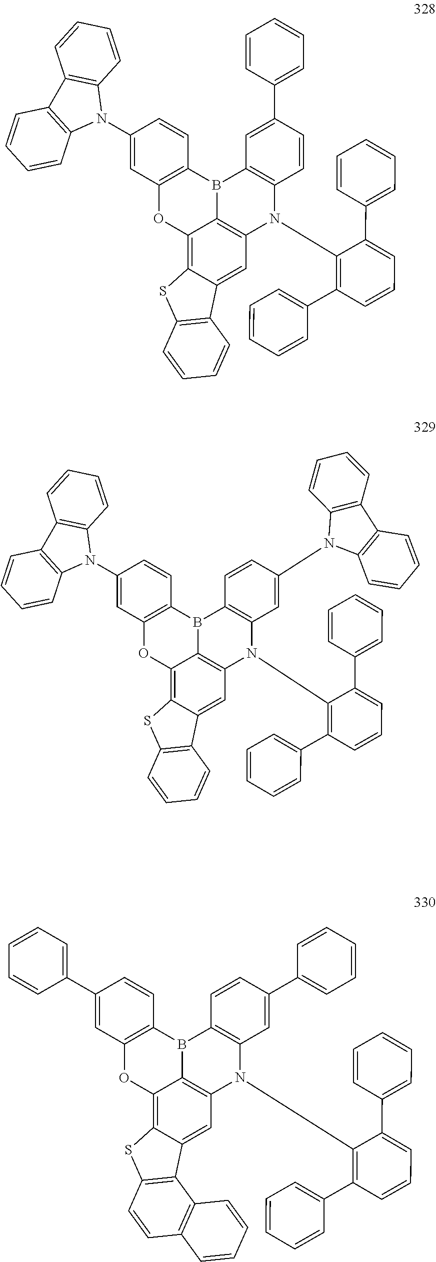 [SMILES: c1ccc(-c2ccc3c(c2)B2c4ccc(-n5c6ccccc6c6ccccc65)cc4Oc4c2c(cc2c4sc4ccccc42)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2c4sc3ccccc32)cc1 ; c1ccc(-c2ccc3c(c2)Oc2c4c(cc5c2sc2ccc6ccccc6c25)N(c2c(-c5ccccc5)cccc2-c2ccccc2)c2cc(-c5ccccc5)ccc2B34)cc1]

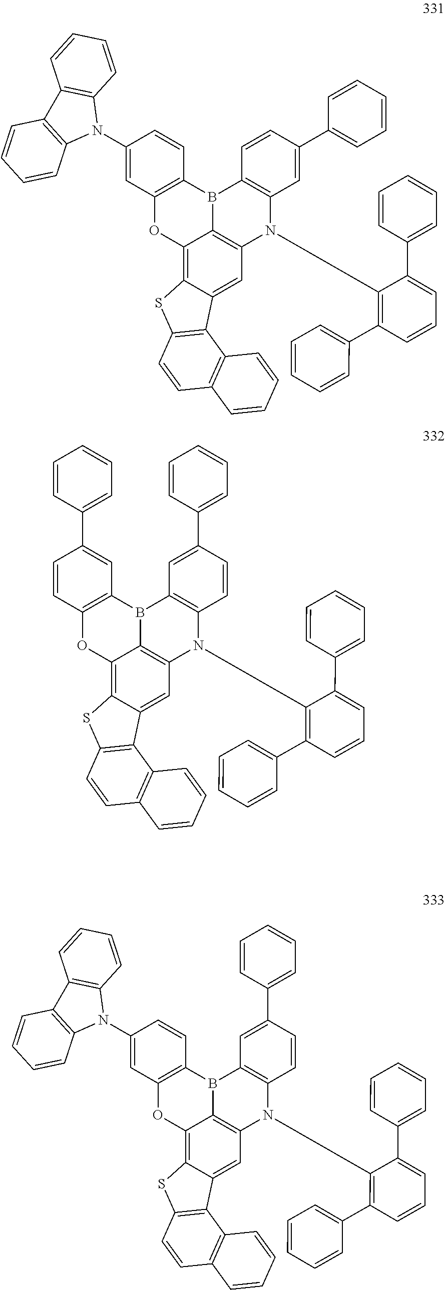

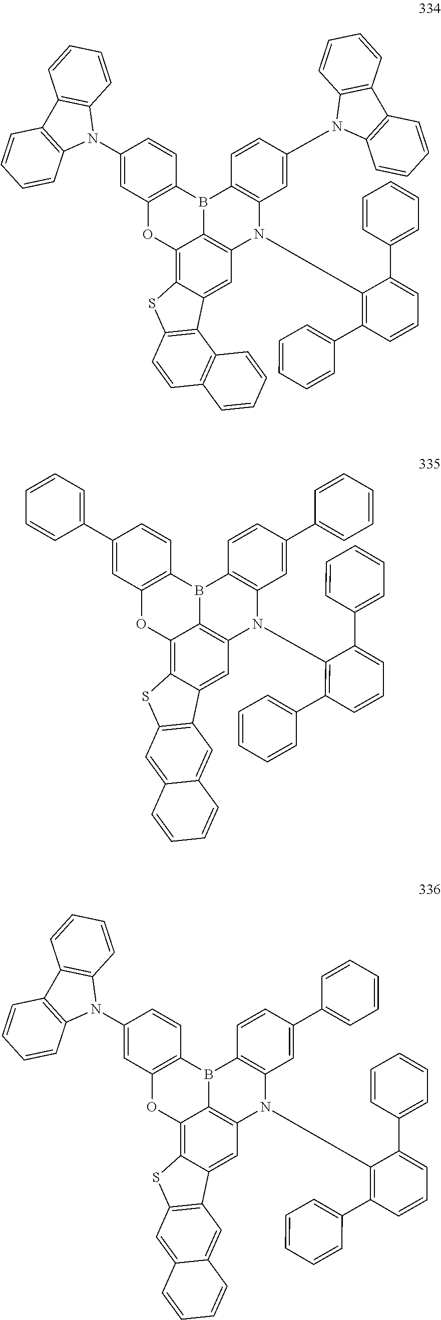 [SMILES: c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2c4sc3ccc4ccccc4c32)cc1 ; c1ccc(-c2ccc3c(c2)Oc2c4c(cc5c2sc2cc6ccccc6cc25)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4c(sc5cc6ccccc6cc54)c4c2B3c2ccc(-n3c5ccccc5c5ccccc53)cc2O4)cc1]

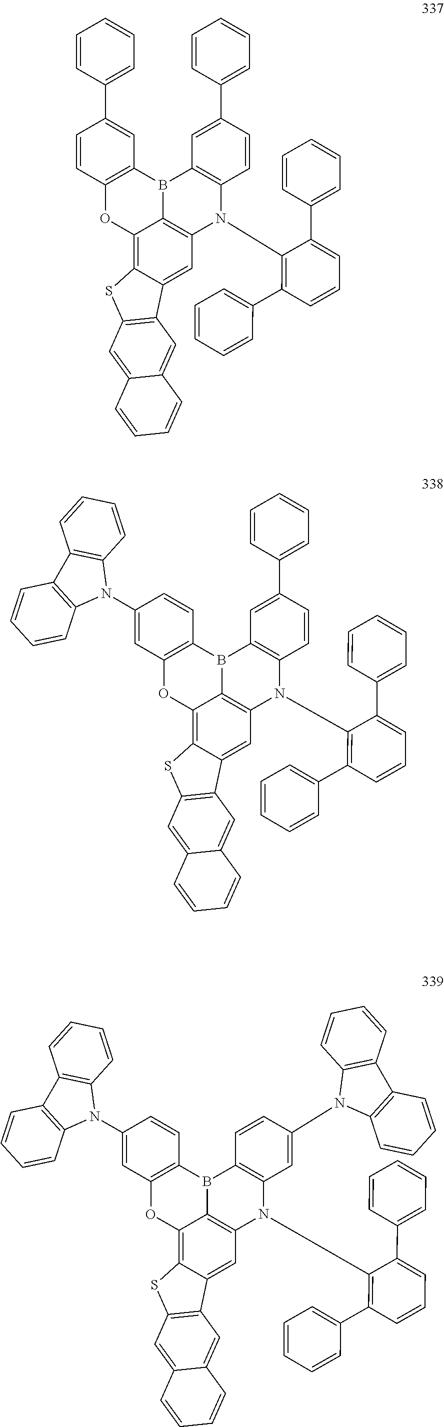 [SMILES: c1ccc(-c2ccc3c(c2)B2c4cc(-c5ccccc5)ccc4N(c4c(-c5ccccc5)cccc4-c4ccccc4)c4cc5c(sc6cc7ccccc7cc65)c(c42)O3)cc1 ; c1ccc(-c2ccc3c(c2)B2c4ccc(-n5c6ccccc6c6ccccc65)cc4Oc4c2c(cc2c4sc4cc5ccccc5cc42)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2c4sc3cc4ccccc4cc32)cc1]

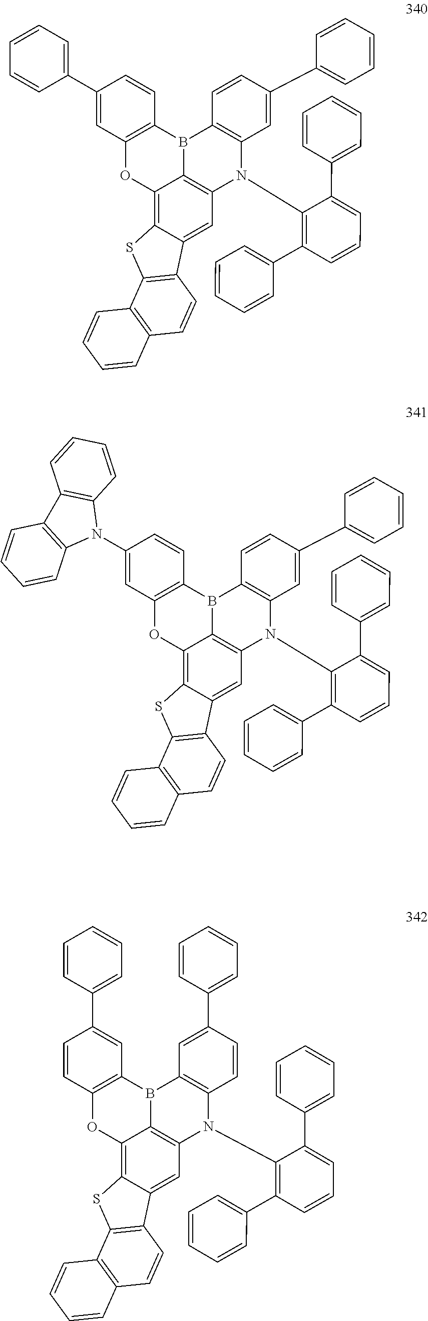 [SMILES: c1ccc(-c2ccc3c(c2)Oc2c4c(cc5c2sc2c6ccccc6ccc52)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4c(sc5c6ccccc6ccc45)c4c2B3c2ccc(-n3c5ccccc5c5ccccc53)cc2O4)cc1 ; c1ccc(-c2ccc3c(c2)B2c4cc(-c5ccccc5)ccc4N(c4c(-c5ccccc5)cccc4-c4ccccc4)c4cc5c(sc6c7ccccc7ccc56)c(c42)O3)cc1]

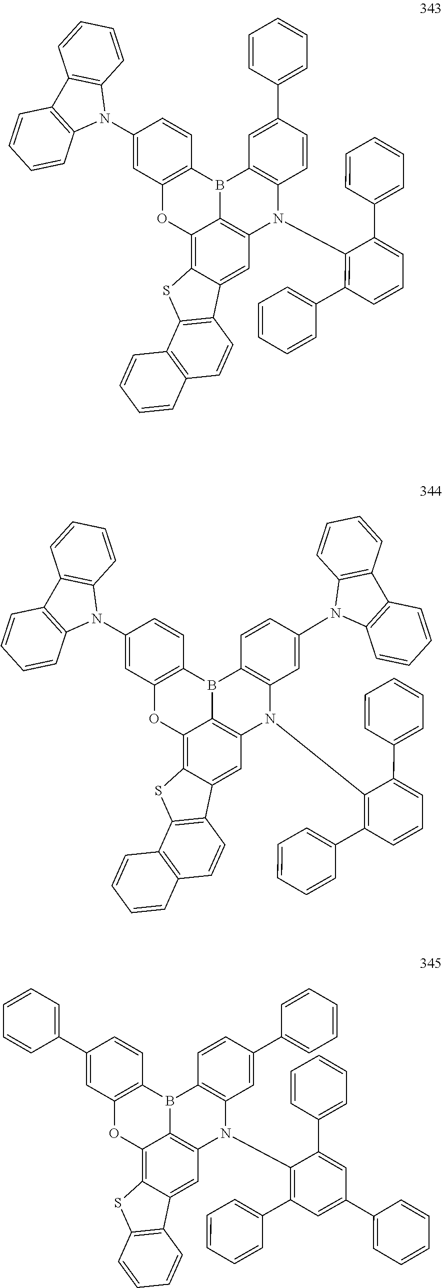 [SMILES: c1ccc(-c2ccc3c(c2)B2c4ccc(-n5c6ccccc6c6ccccc65)cc4Oc4c2c(cc2c4sc4c5ccccc5ccc24)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2c4sc3c4ccccc4ccc23)cc1 ; c1ccc(-c2ccc3c(c2)Oc2c4c(cc5c2sc2ccccc25)N(c2c(-c5ccccc5)cc(-c5ccccc5)cc2-c2ccccc2)c2cc(-c5ccccc5)ccc2B34)cc1]

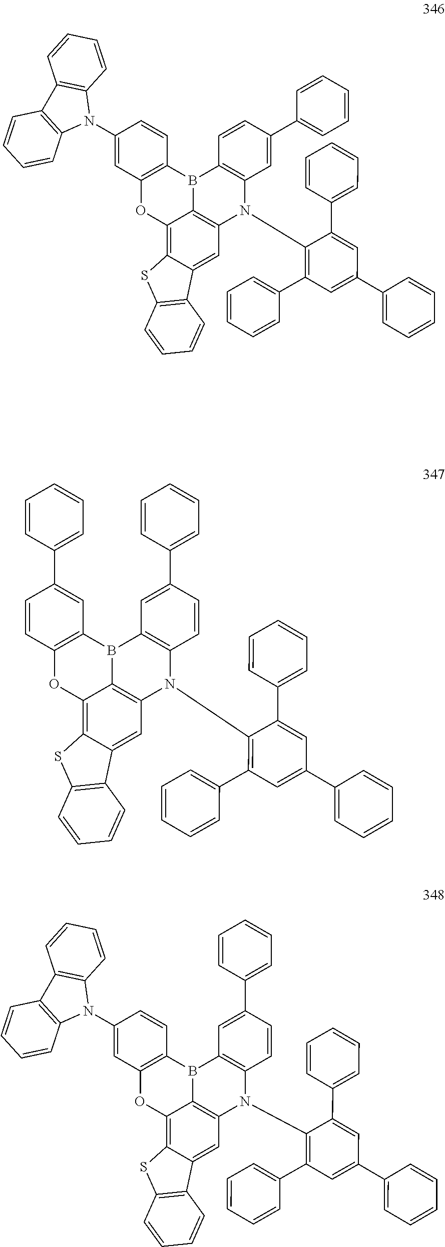 [SMILES: c1ccc(-c2cc(-c3ccccc3)c(N3c4cc(-c5ccccc5)ccc4B4c5ccc(-n6c7ccccc7c7ccccc76)cc5Oc5c4c3cc3c5sc4ccccc43)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5c(sc6ccccc65)c(c42)O3)cc1 ; c1ccc(-c2ccc3c(c2)B2c4ccc(-n5c6ccccc6c6ccccc65)cc4Oc4c2c(cc2c4sc4ccccc42)N3c2c(-c3ccccc3)cc(-c3ccccc3)cc2-c2ccccc2)cc1]

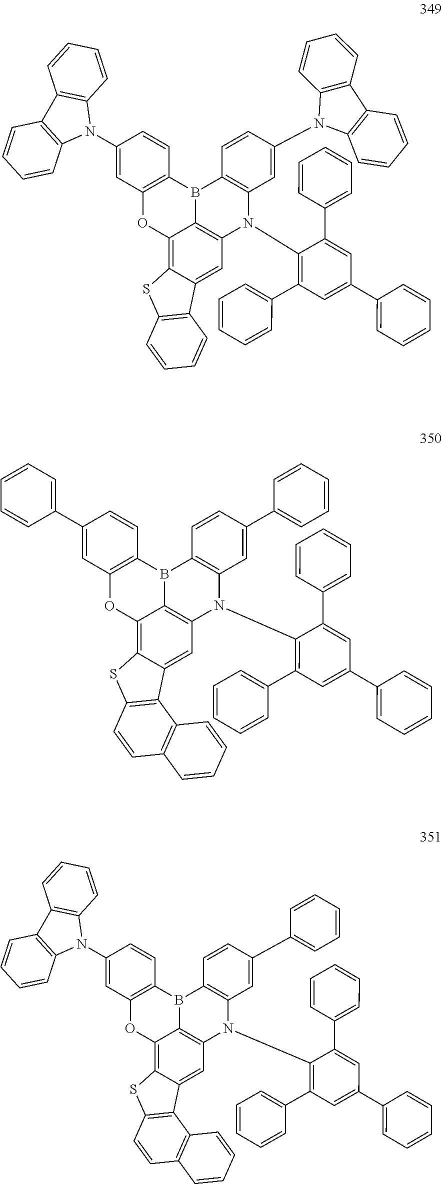 [SMILES: c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3c5sc4ccccc43)c(-c3ccccc3)c2)cc1 ; c1ccc(-c2ccc3c(c2)Oc2c4c(cc5c2sc2ccc6ccccc6c25)N(c2c(-c5ccccc5)cc(-c5ccccc5)cc2-c2ccccc2)c2cc(-c5ccccc5)ccc2B34)cc1 ; c1ccc(-c2cc(-c3ccccc3)c(N3c4cc(-c5ccccc5)ccc4B4c5ccc(-n6c7ccccc7c7ccccc76)cc5Oc5c4c3cc3c5sc4ccc5ccccc5c43)c(-c3ccccc3)c2)cc1]

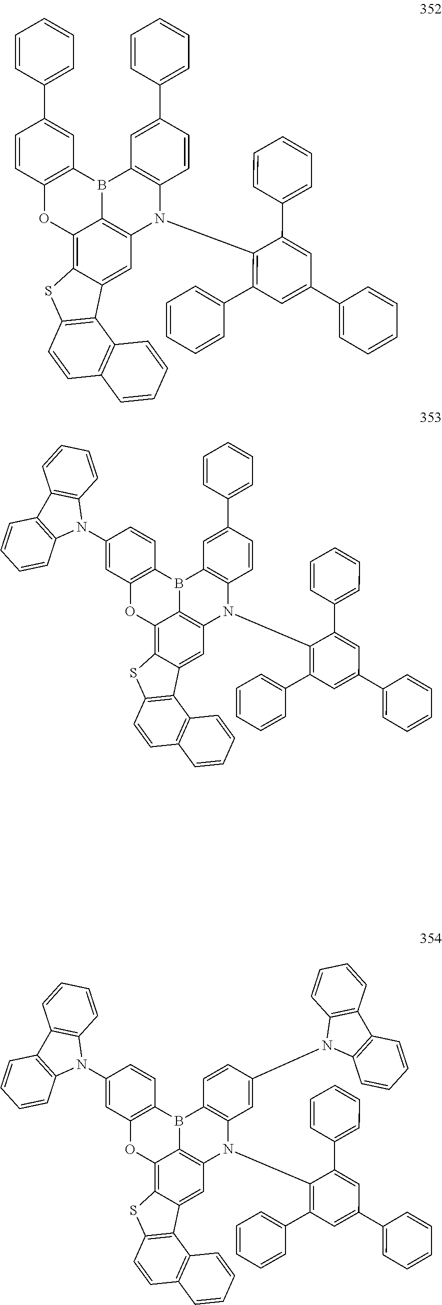 [SMILES: c1ccc(-c2ccc3c(c2)B2c4cc(-c5ccccc5)ccc4N(c4c(-c5ccccc5)cc(-c5ccccc5)cc4-c4ccccc4)c4cc5c(sc6ccc7ccccc7c65)c(c42)O3)cc1 ; c1ccc(-c2ccc3c(c2)B2c4ccc(-n5c6ccccc6c6ccccc65)cc4Oc4c2c(cc2c4sc4ccc5ccccc5c42)N3c2c(-c3ccccc3)cc(-c3ccccc3)cc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3c5sc4ccc5ccccc5c43)c(-c3ccccc3)c2)cc1]

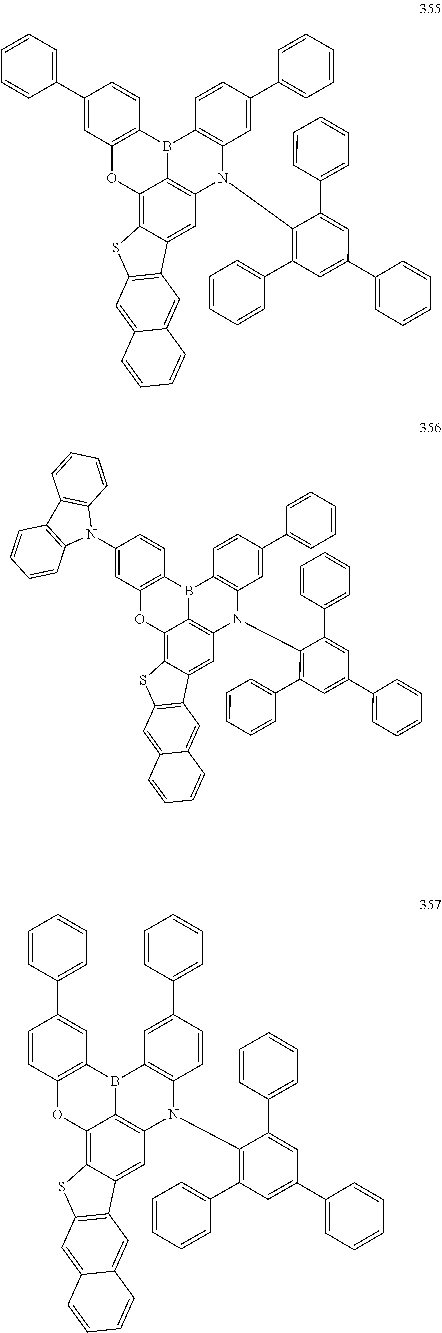 [SMILES: c1ccc(-c2ccc3c(c2)Oc2c4c(cc5c2sc2cc6ccccc6cc25)N(c2c(-c5ccccc5)cc(-c5ccccc5)cc2-c2ccccc2)c2cc(-c5ccccc5)ccc2B34)cc1 ; c1ccc(-c2cc(-c3ccccc3)c(N3c4cc(-c5ccccc5)ccc4B4c5ccc(-n6c7ccccc7c7ccccc76)cc5Oc5c4c3cc3c5sc4cc5ccccc5cc43)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5c(sc6cc7ccccc7cc65)c(c42)O3)cc1]

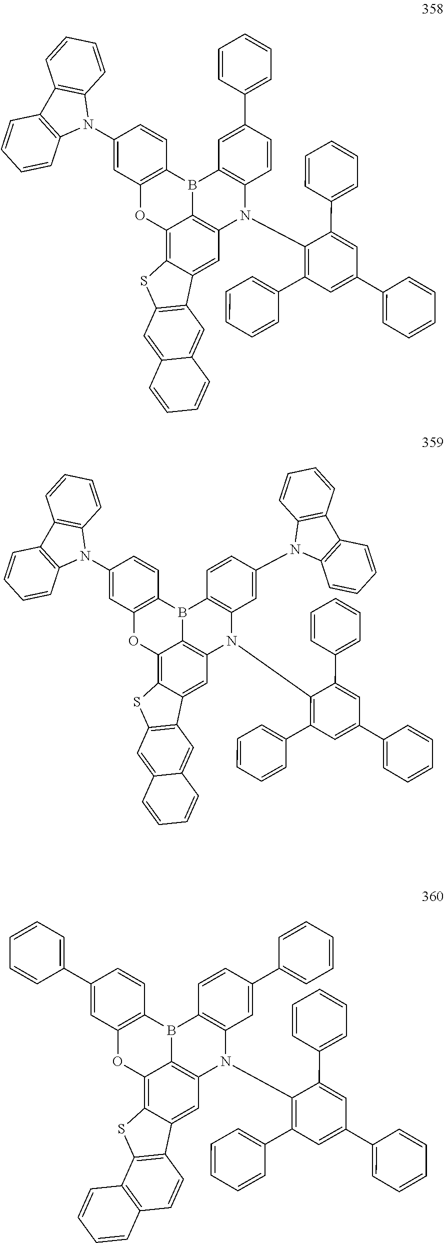 [SMILES: c1ccc(-c2ccc3c(c2)B2c4ccc(-n5c6ccccc6c6ccccc65)cc4Oc4c2c(cc2c4sc4cc5ccccc5cc42)N3c2c(-c3ccccc3)cc(-c3ccccc3)cc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3c5sc4cc5ccccc5cc43)c(-c3ccccc3)c2)cc1 ; c1ccc(-c2ccc3c(c2)Oc2c4c(cc5c2sc2c6ccccc6ccc52)N(c2c(-c5ccccc5)cc(-c5ccccc5)cc2-c2ccccc2)c2cc(-c5ccccc5)ccc2B34)cc1]

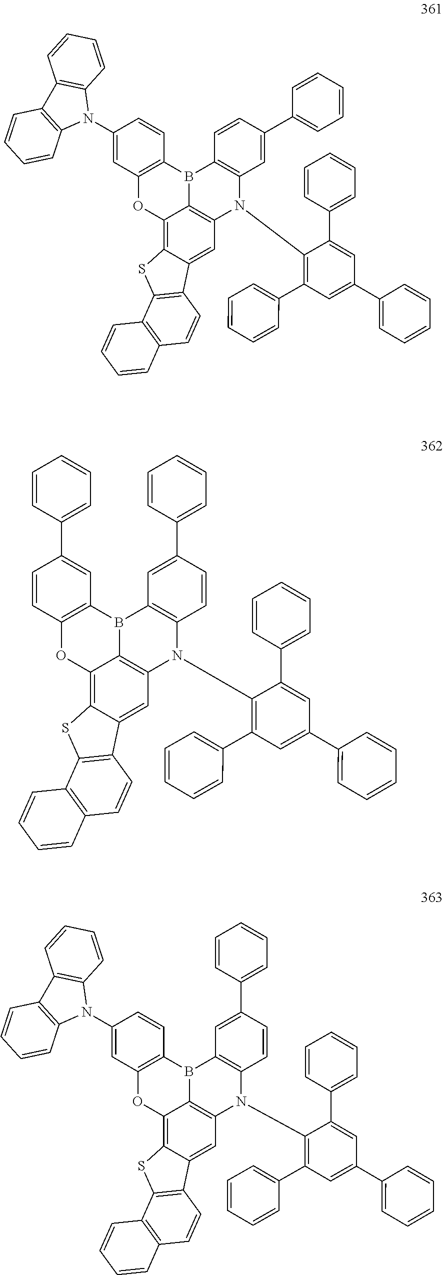 [SMILES: c1ccc(-c2cc(-c3ccccc3)c(N3c4cc(-c5ccccc5)ccc4B4c5ccc(-n6c7ccccc7c7ccccc76)cc5Oc5c4c3cc3c5sc4c5ccccc5ccc34)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5c(sc6c7ccccc7ccc56)c(c42)O3)cc1 ; c1ccc(-c2ccc3c(c2)B2c4ccc(-n5c6ccccc6c6ccccc65)cc4Oc4c2c(cc2c4sc4c5ccccc5ccc24)N3c2c(-c3ccccc3)cc(-c3ccccc3)cc2-c2ccccc2)cc1]

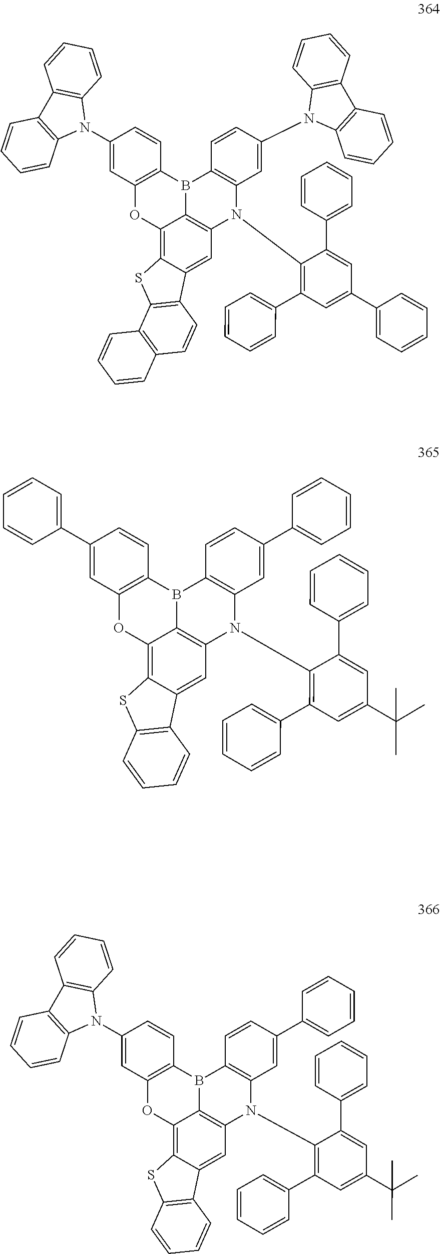 [SMILES: c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3c5sc4c5ccccc5ccc34)c(-c3ccccc3)c2)cc1 ; CC(C)(C)c1cc(-c2ccccc2)c(N2c3cc(-c4ccccc4)ccc3B3c4ccc(-c5ccccc5)cc4Oc4c3c2cc2c4sc3ccccc32)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Oc4c3c2cc2c4sc3ccccc32)c(-c2ccccc2)c1]

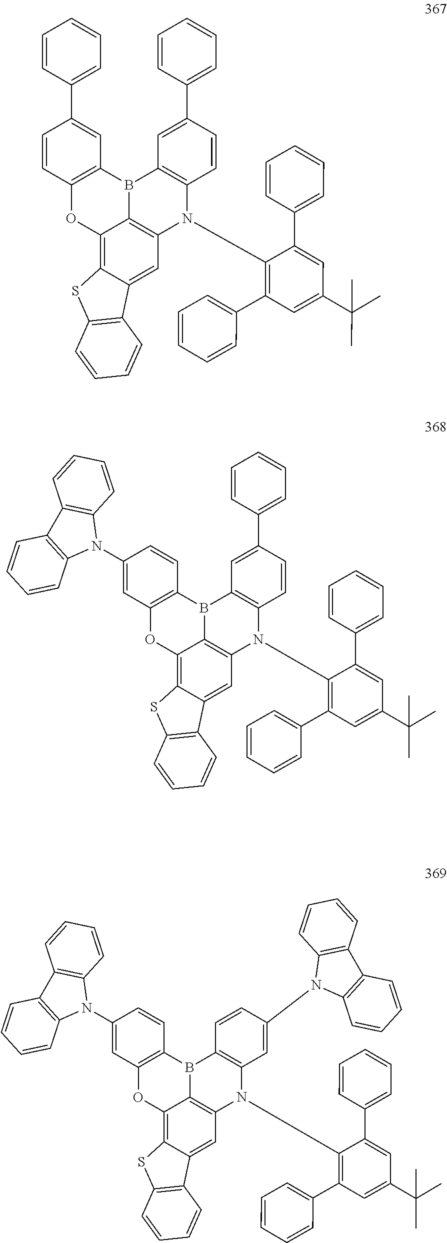 [SMILES: CC(C)(C)c1cc(-c2ccccc2)c(N2c3ccc(-c4ccccc4)cc3B3c4cc(-c5ccccc5)ccc4Oc4c3c2cc2c4sc3ccccc32)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4Oc4c3c2cc2c4sc3ccccc32)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2c4sc3ccccc32)c(-c2ccccc2)c1]

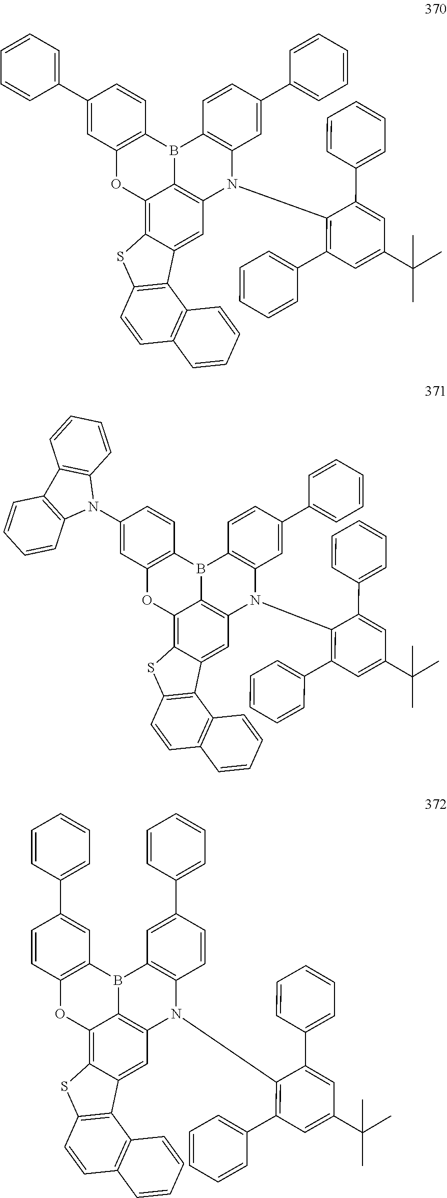 [SMILES: CC(C)(C)c1cc(-c2ccccc2)c(N2c3cc(-c4ccccc4)ccc3B3c4ccc(-c5ccccc5)cc4Oc4c3c2cc2c4sc3ccc4ccccc4c32)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Oc4c3c2cc2c4sc3ccc4ccccc4c32)c(-c2ccccc2)c1 ; CC(C)(C)c1cc(-c2ccccc2)c(N2c3ccc(-c4ccccc4)cc3B3c4cc(-c5ccccc5)ccc4Oc4c3c2cc2c4sc3ccc4ccccc4c32)c(-c2ccccc2)c1]

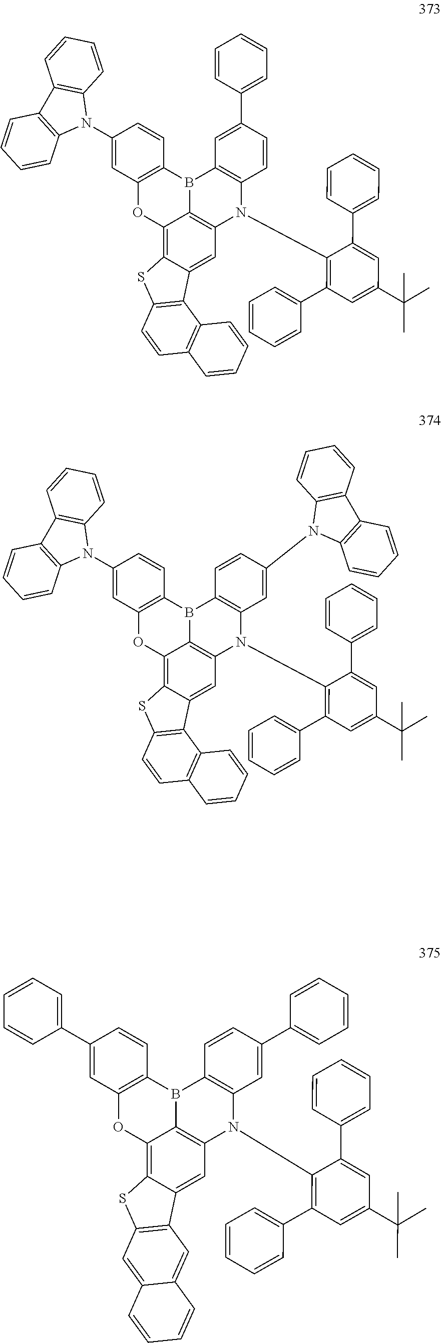 [SMILES: CC(C)(C)c1cc(-c2ccccc2)c(N2c3ccc(-c4ccccc4)cc3B3c4ccc(-n5c6ccccc6c6ccccc65)cc4Oc4c3c2cc2c4sc3ccc4ccccc4c32)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2c4sc3ccc4ccccc4c32)c(-c2ccccc2)c1 ; CC(C)(C)c1cc(-c2ccccc2)c(N2c3cc(-c4ccccc4)ccc3B3c4ccc(-c5ccccc5)cc4Oc4c3c2cc2c4sc3cc4ccccc4cc32)c(-c2ccccc2)c1]

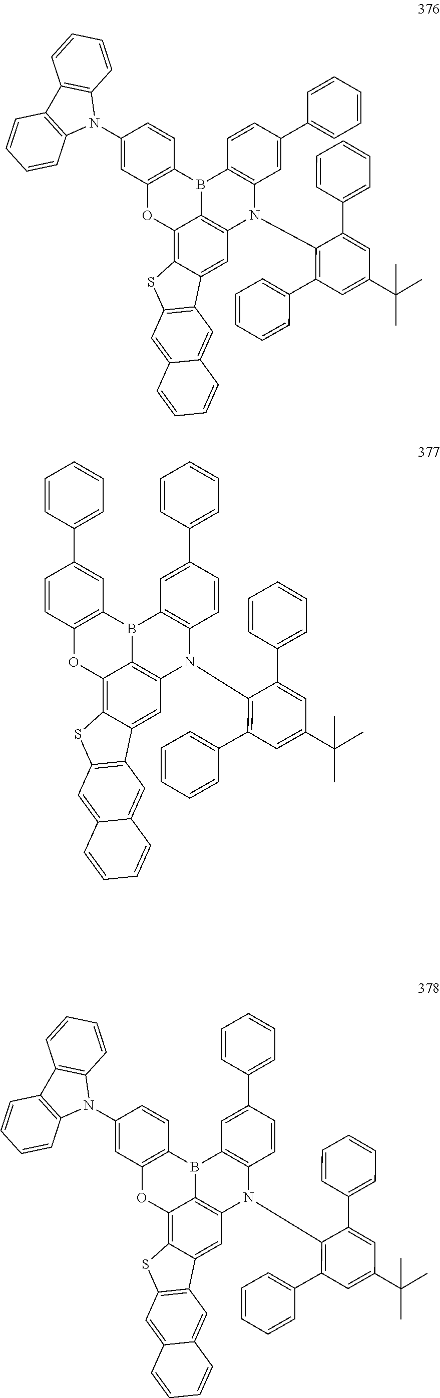 [SMILES: CC(C)(C)c1cc(-c2ccccc2)c(N2c3cc(-c4ccccc4)ccc3B3c4ccc(-n5c6ccccc6c6ccccc65)cc4Oc4c3c2cc2c4sc3cc4ccccc4cc32)c(-c2ccccc2)c1 ; CC(C)(C)c1cc(-c2ccccc2)c(N2c3ccc(-c4ccccc4)cc3B3c4cc(-c5ccccc5)ccc4Oc4c3c2cc2c4sc3cc4ccccc4cc32)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4Oc4c3c2cc2c4sc3cc4ccccc4cc32)c(-c2ccccc2)c1]

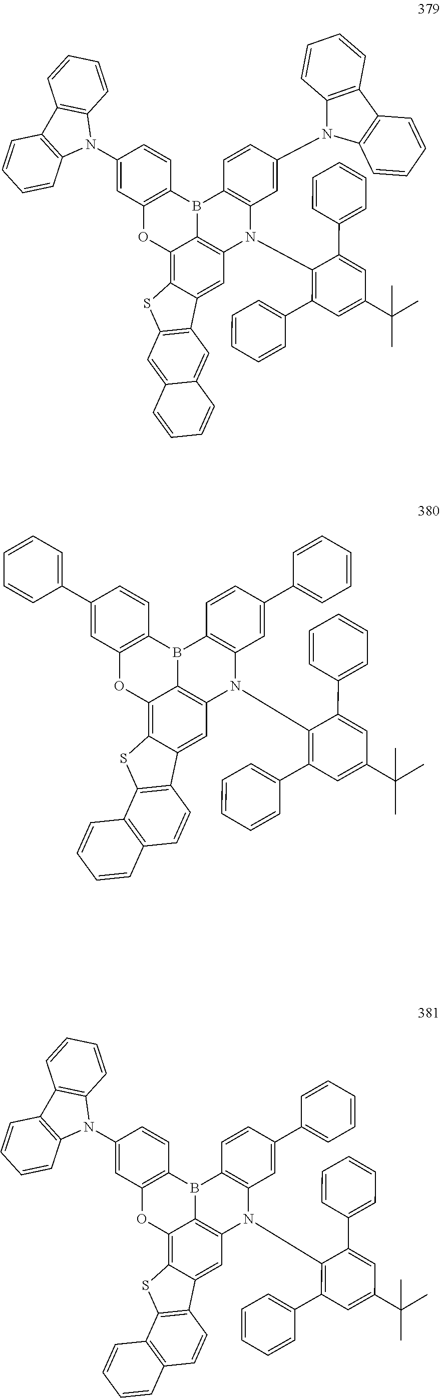 [SMILES: CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2c4sc3cc4ccccc4cc32)c(-c2ccccc2)c1 ; CC(C)(C)c1cc(-c2ccccc2)c(N2c3cc(-c4ccccc4)ccc3B3c4ccc(-c5ccccc5)cc4Oc4c3c2cc2c4sc3c4ccccc4ccc23)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Oc4c3c2cc2c4sc3c4ccccc4ccc23)c(-c2ccccc2)c1]

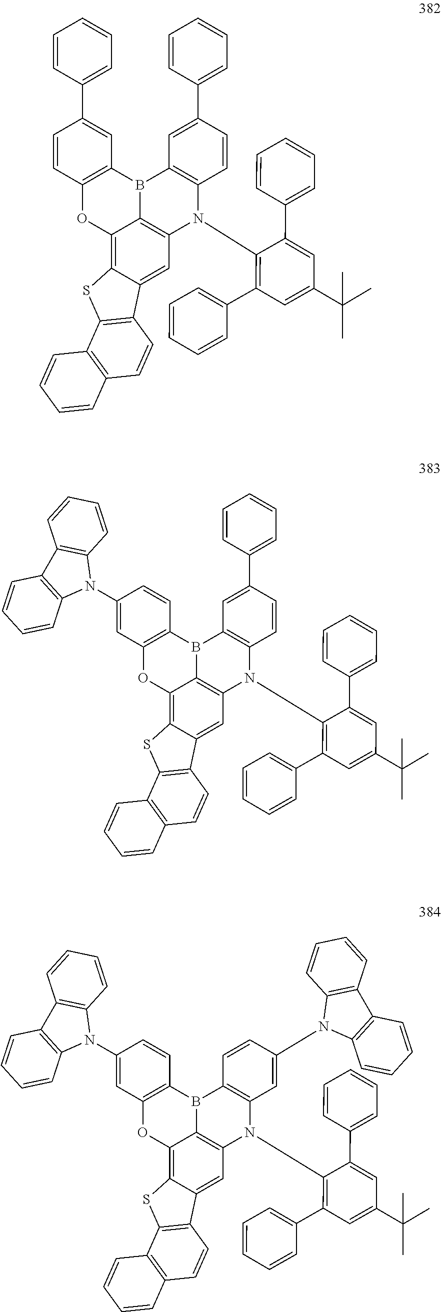 [SMILES: CC(C)(C)c1cc(-c2ccccc2)c(N2c3ccc(-c4ccccc4)cc3B3c4cc(-c5ccccc5)ccc4Oc4c3c2cc2c4sc3c4ccccc4ccc23)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4Oc4c3c2cc2c4sc3c4ccccc4ccc23)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2c4sc3c4ccccc4ccc23)c(-c2ccccc2)c1]

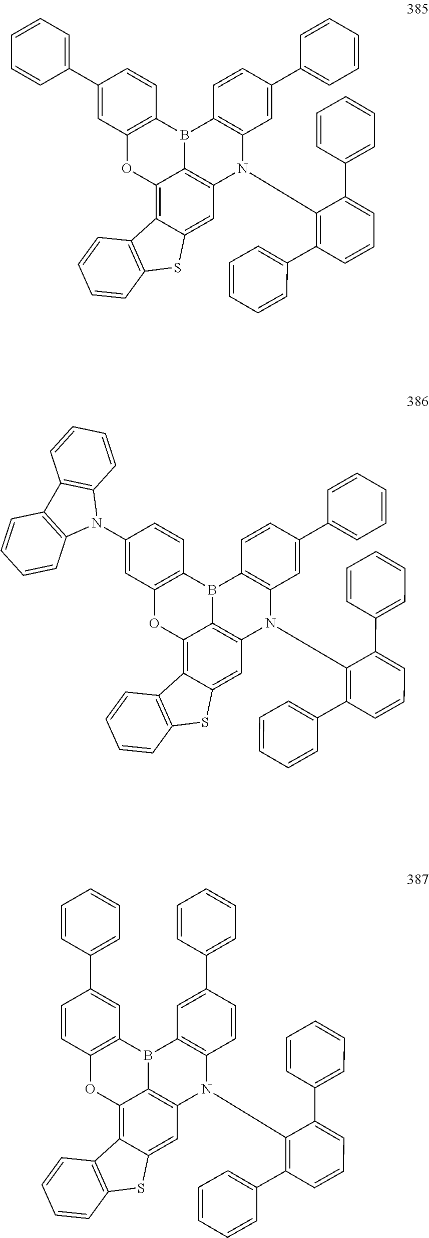 [SMILES: c1ccc(-c2ccc3c(c2)Oc2c4c(cc5sc6ccccc6c25)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4sc5ccccc5c4c4c2B3c2ccc(-n3c5ccccc5c5ccccc53)cc2O4)cc1 ; c1ccc(-c2ccc3c(c2)B2c4cc(-c5ccccc5)ccc4N(c4c(-c5ccccc5)cccc4-c4ccccc4)c4cc5sc6ccccc6c5c(c42)O3)cc1]

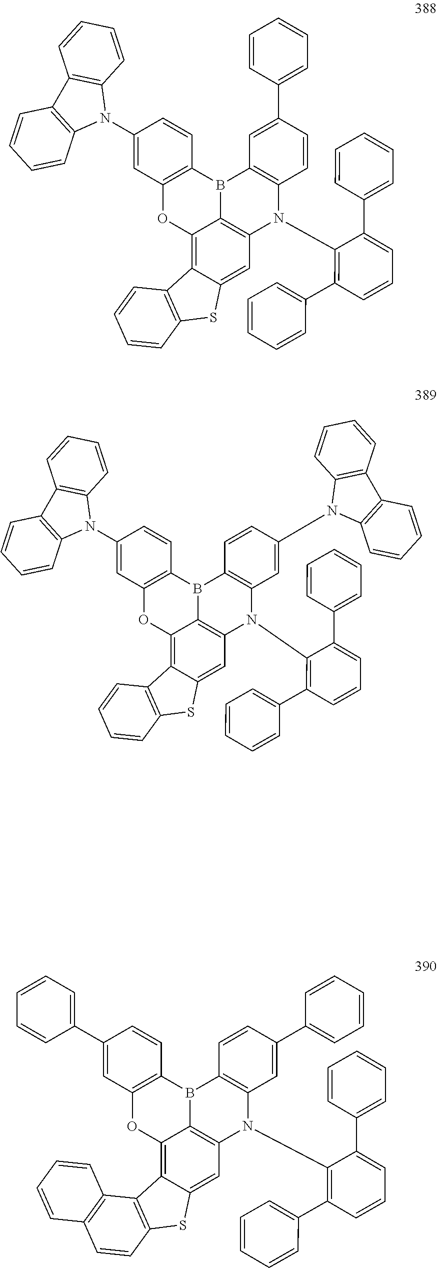 [SMILES: c1ccc(-c2ccc3c(c2)B2c4ccc(-n5c6ccccc6c6ccccc65)cc4Oc4c2c(cc2sc5ccccc5c42)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2sc3ccccc3c42)cc1 ; c1ccc(-c2ccc3c(c2)Oc2c4c(cc5sc6ccc7ccccc7c6c25)N(c2c(-c5ccccc5)cccc2-c2ccccc2)c2cc(-c5ccccc5)ccc2B34)cc1]

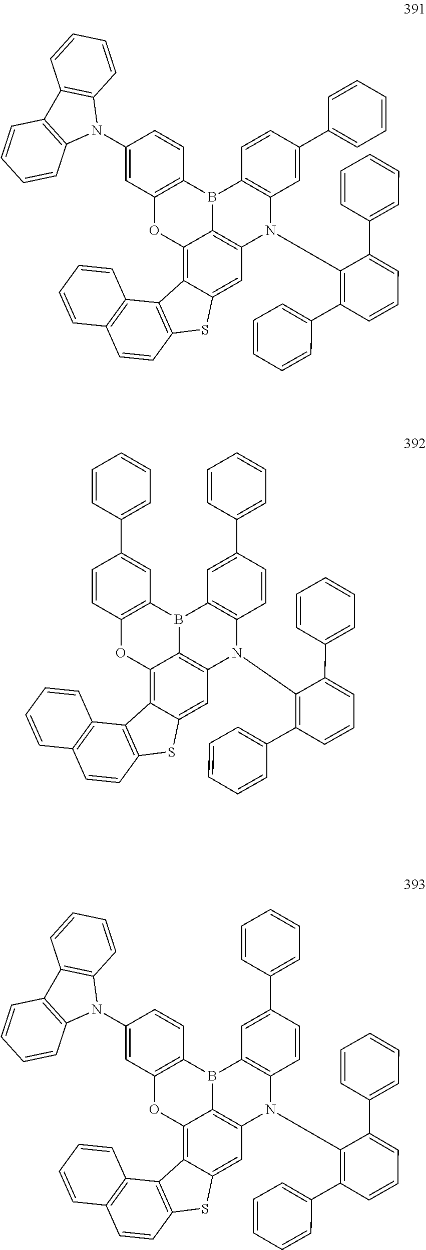 [SMILES: c1ccc(-c2ccc3c(c2)N(c2c(-c4ccccc4)cccc2-c2ccccc2)c2cc4sc5ccc6ccccc6c5c4c4c2B3c2ccc(-n3c5ccccc5c5ccccc53)cc2O4)cc1 ; c1ccc(-c2ccc3c(c2)B2c4cc(-c5ccccc5)ccc4N(c4c(-c5ccccc5)cccc4-c4ccccc4)c4cc5sc6ccc7ccccc7c6c5c(c42)O3)cc1 ; c1ccc(-c2ccc3c(c2)B2c4ccc(-n5c6ccccc6c6ccccc65)cc4Oc4c2c(cc2sc5ccc6ccccc6c5c42)N3c2c(-c3ccccc3)cccc2-c2ccccc2)cc1]

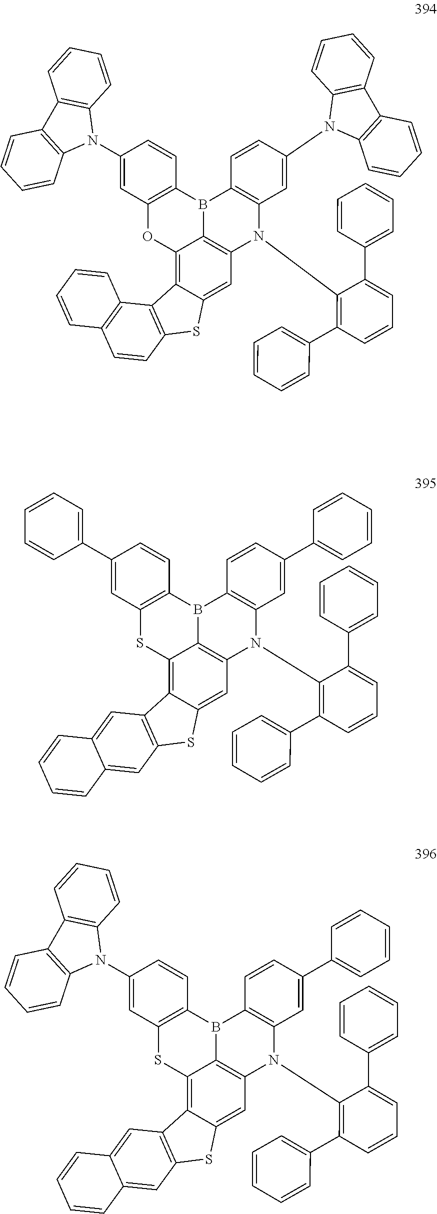 [SMILES: c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2sc3ccc5ccccc5c3c42)cc1 ; c1ccc(-c2ccc3c(c2)Sc2c4c(cc5sc6cc7ccccc7cc6c25)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4sc5cc6ccccc6cc5c4c4c2B3c2ccc(-n3c5ccccc5c5ccccc53)cc2S4)cc1]

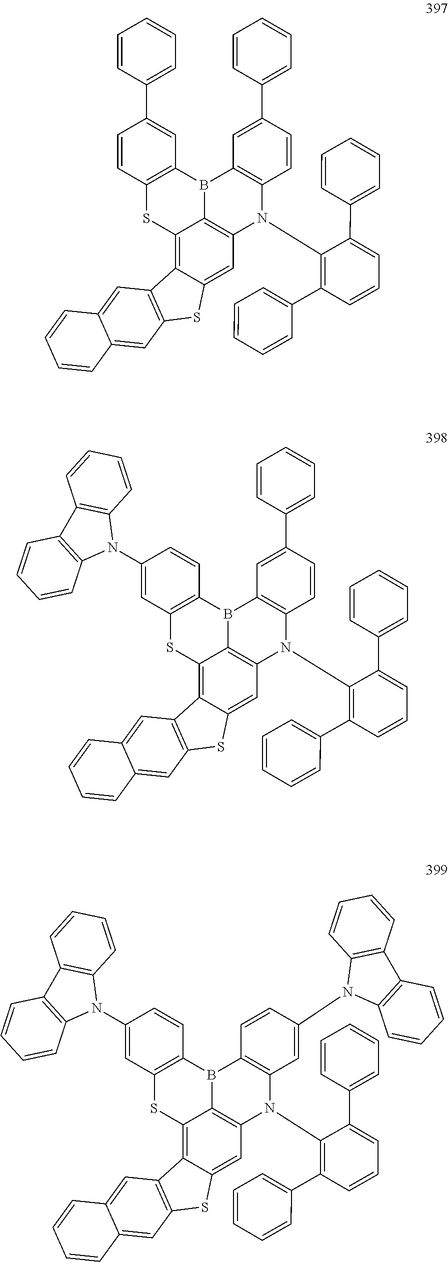 [SMILES: c1ccc(-c2ccc3c(c2)B2c4cc(-c5ccccc5)ccc4N(c4c(-c5ccccc5)cccc4-c4ccccc4)c4cc5sc6cc7ccccc7cc6c5c(c42)S3)cc1 ; c1ccc(-c2ccc3c(c2)B2c4ccc(-n5c6ccccc6c6ccccc65)cc4Sc4c2c(cc2sc5cc6ccccc6cc5c42)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Sc4c3c2cc2sc3cc5ccccc5cc3c42)cc1]

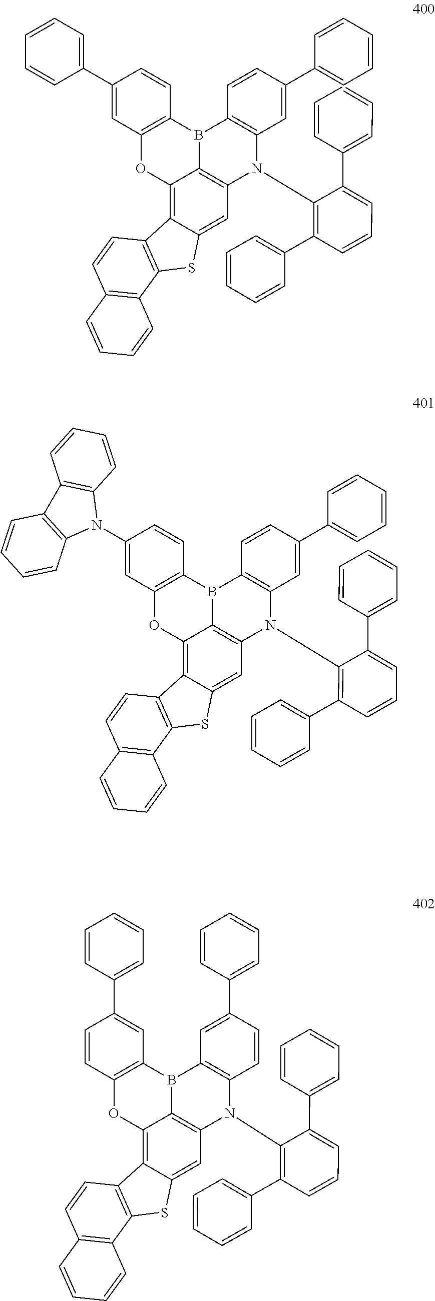 [SMILES: c1ccc(-c2ccc3c(c2)Oc2c4c(cc5sc6c7ccccc7ccc6c25)N(c2c(-c5ccccc5)cccc2-c2ccccc2)c2cc(-c5ccccc5)ccc2B34)cc1 ; c1ccc(-c2ccc3c(c2)N(c2c(-c4ccccc4)cccc2-c2ccccc2)c2cc4sc5c6ccccc6ccc5c4c4c2B3c2ccc(-n3c5ccccc5c5ccccc53)cc2O4)cc1 ; c1ccc(-c2ccc3c(c2)B2c4cc(-c5ccccc5)ccc4N(c4c(-c5ccccc5)cccc4-c4ccccc4)c4cc5sc6c7ccccc7ccc6c5c(c42)O3)cc1]

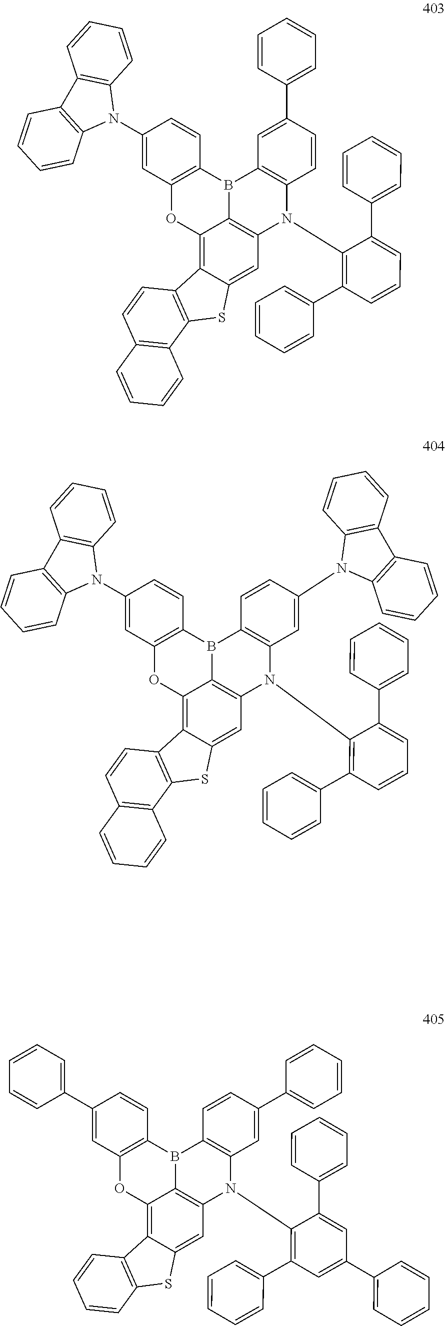 [SMILES: c1ccc(-c2ccc3c(c2)B2c4ccc(-n5c6ccccc6c6ccccc65)cc4Oc4c2c(cc2sc5c6ccccc6ccc5c42)N3c2c(-c3ccccc3)cccc2-c2ccccc2)cc1 ; c1ccc(-c2cccc(-c3ccccc3)c2N2c3cc(-n4c5ccccc5c5ccccc54)ccc3B3c4ccc(-n5c6ccccc6c6ccccc65)cc4Oc4c3c2cc2sc3c5ccccc5ccc3c42)cc1 ; c1ccc(-c2ccc3c(c2)Oc2c4c(cc5sc6ccccc6c25)N(c2c(-c5ccccc5)cc(-c5ccccc5)cc2-c2ccccc2)c2cc(-c5ccccc5)ccc2B34)cc1]

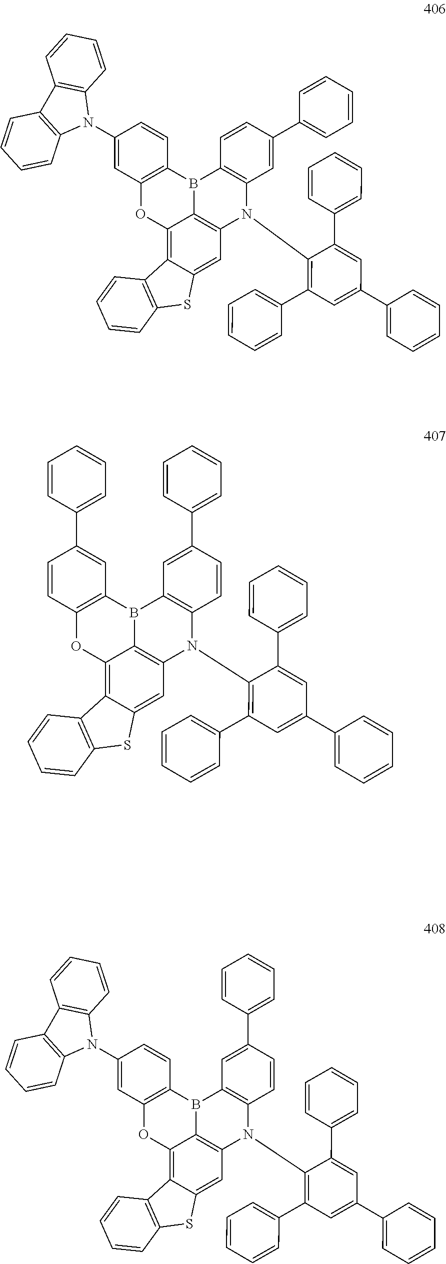 [SMILES: c1ccc(-c2cc(-c3ccccc3)c(N3c4cc(-c5ccccc5)ccc4B4c5ccc(-n6c7ccccc7c7ccccc76)cc5Oc5c4c3cc3sc4ccccc4c53)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5sc6ccccc6c5c(c42)O3)cc1 ; c1ccc(-c2ccc3c(c2)B2c4ccc(-n5c6ccccc6c6ccccc65)cc4Oc4c2c(cc2sc5ccccc5c42)N3c2c(-c3ccccc3)cc(-c3ccccc3)cc2-c2ccccc2)cc1]

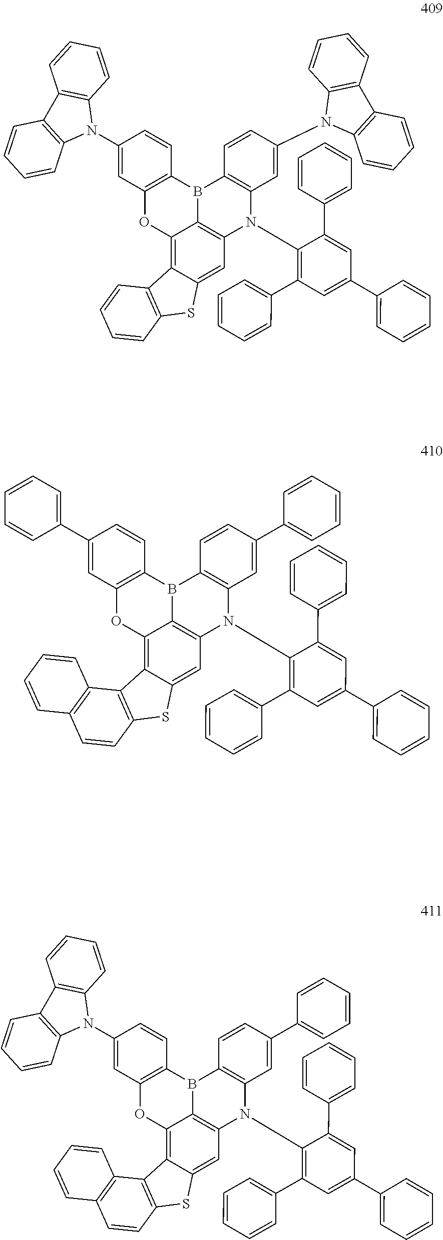 [SMILES: c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3sc4ccccc4c53)c(-c3ccccc3)c2)cc1 ; c1ccc(-c2ccc3c(c2)Oc2c4c(cc5sc6ccc7ccccc7c6c25)N(c2c(-c5ccccc5)cc(-c5ccccc5)cc2-c2ccccc2)c2cc(-c5ccccc5)ccc2B34)cc1 ; c1ccc(-c2cc(-c3ccccc3)c(N3c4cc(-c5ccccc5)ccc4B4c5ccc(-n6c7ccccc7c7ccccc76)cc5Oc5c4c3cc3sc4ccc6ccccc6c4c53)c(-c3ccccc3)c2)cc1]

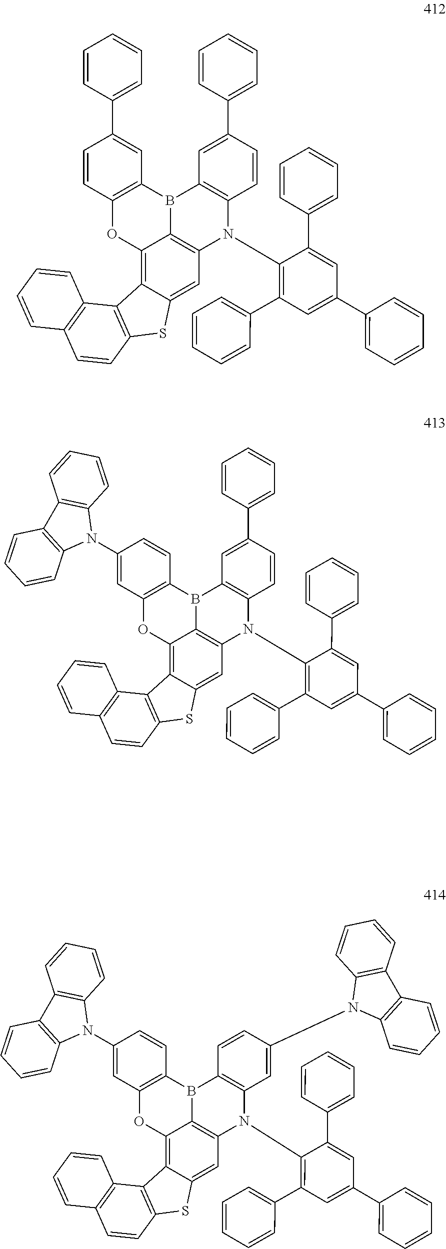 [SMILES: c1ccc(-c2ccc3c(c2)B2c4cc(-c5ccccc5)ccc4N(c4c(-c5ccccc5)cc(-c5ccccc5)cc4-c4ccccc4)c4cc5sc6ccc7ccccc7c6c5c(c42)O3)cc1 ; c1ccc(-c2ccc3c(c2)B2c4ccc(-n5c6ccccc6c6ccccc65)cc4Oc4c2c(cc2sc5ccc6ccccc6c5c42)N3c2c(-c3ccccc3)cc(-c3ccccc3)cc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3sc4ccc6ccccc6c4c53)c(-c3ccccc3)c2)cc1]

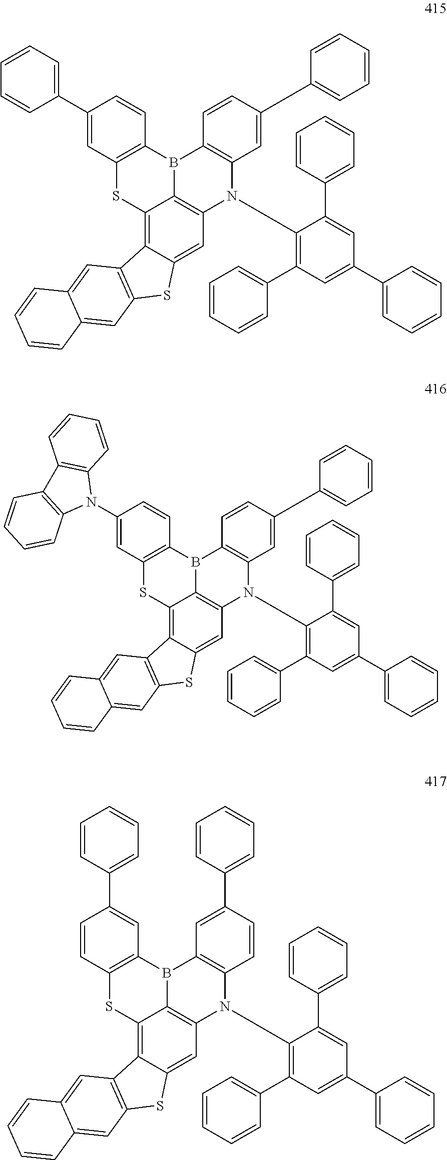 [SMILES: c1ccc(-c2ccc3c(c2)Sc2c4c(cc5sc6cc7ccccc7cc6c25)N(c2c(-c5ccccc5)cc(-c5ccccc5)cc2-c2ccccc2)c2cc(-c5ccccc5)ccc2B34)cc1 ; c1ccc(-c2cc(-c3ccccc3)c(N3c4cc(-c5ccccc5)ccc4B4c5ccc(-n6c7ccccc7c7ccccc76)cc5Sc5c4c3cc3sc4cc6ccccc6cc4c53)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5sc6cc7ccccc7cc6c5c(c42)S3)cc1]

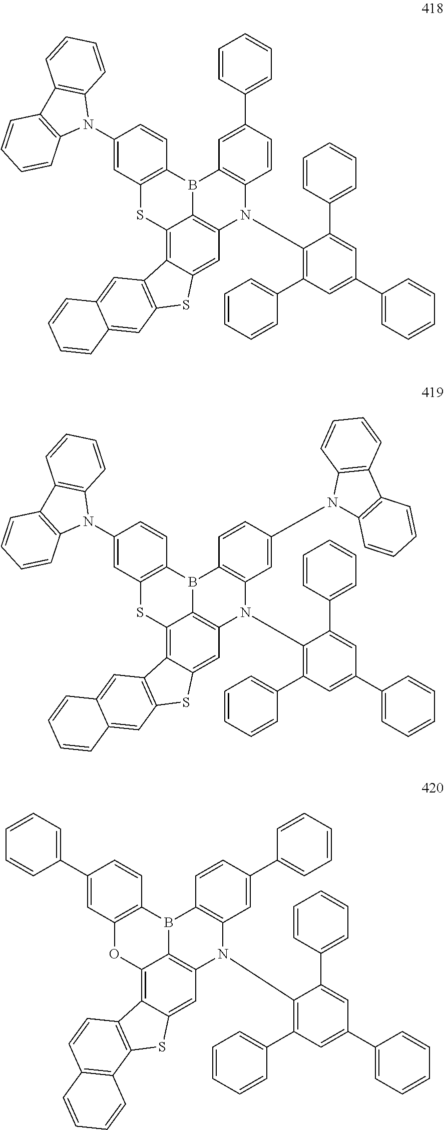 [SMILES: c1ccc(-c2ccc3c(c2)B2c4ccc(-n5c6ccccc6c6ccccc65)cc4Sc4c2c(cc2sc5cc6ccccc6cc5c42)N3c2c(-c3ccccc3)cc(-c3ccccc3)cc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5Sc5c4c3cc3sc4cc6ccccc6cc4c53)c(-c3ccccc3)c2)cc1 ; c1ccc(-c2ccc3c(c2)Oc2c4c(cc5sc6c7ccccc7ccc6c25)N(c2c(-c5ccccc5)cc(-c5ccccc5)cc2-c2ccccc2)c2cc(-c5ccccc5)ccc2B34)cc1]

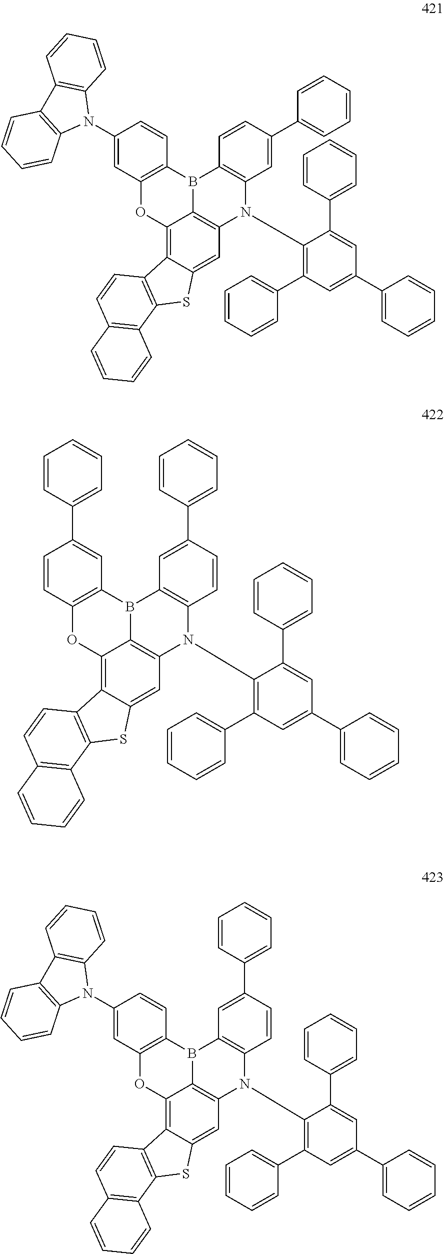 [SMILES: c1ccc(-c2cc(-c3ccccc3)c(N3c4cc(-c5ccccc5)ccc4B4c5ccc(-n6c7ccccc7c7ccccc76)cc5Oc5c4c3cc3sc4c6ccccc6ccc4c53)c(-c3ccccc3)c2)cc1 ; c1ccc(-c2ccc3c(c2)B2c4cc(-c5ccccc5)ccc4N(c4c(-c5ccccc5)cc(-c5ccccc5)cc4-c4ccccc4)c4cc5sc6c7ccccc7ccc6c5c(c42)O3)cc1 ; c1ccc(-c2ccc3c(c2)B2c4ccc(-n5c6ccccc6c6ccccc65)cc4Oc4c2c(cc2sc5c6ccccc6ccc5c42)N3c2c(-c3ccccc3)cc(-c3ccccc3)cc2-c2ccccc2)cc1]

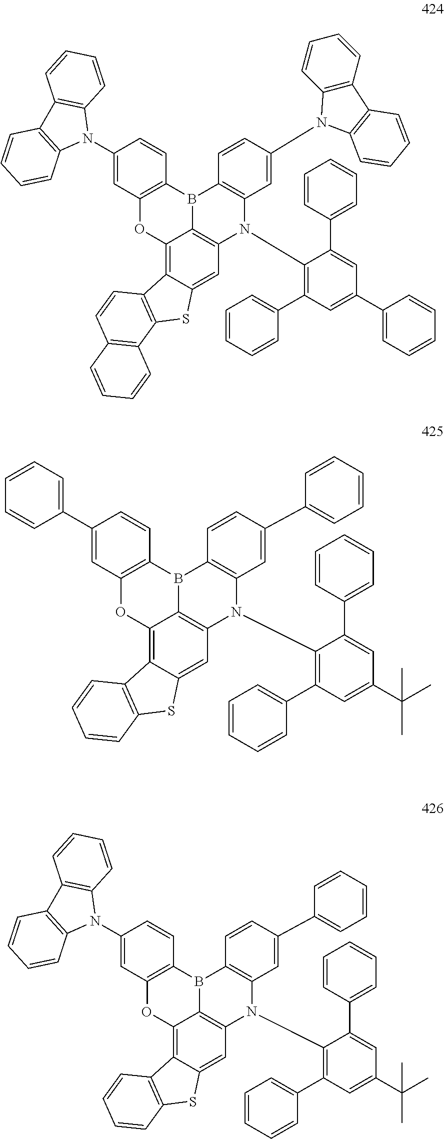 [SMILES: c1ccc(-c2cc(-c3ccccc3)c(N3c4cc(-n5c6ccccc6c6ccccc65)ccc4B4c5ccc(-n6c7ccccc7c7ccccc76)cc5Oc5c4c3cc3sc4c6ccccc6ccc4c53)c(-c3ccccc3)c2)cc1 ; CC(C)(C)c1cc(-c2ccccc2)c(N2c3cc(-c4ccccc4)ccc3B3c4ccc(-c5ccccc5)cc4Oc4c3c2cc2sc3ccccc3c42)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Oc4c3c2cc2sc3ccccc3c42)c(-c2ccccc2)c1]

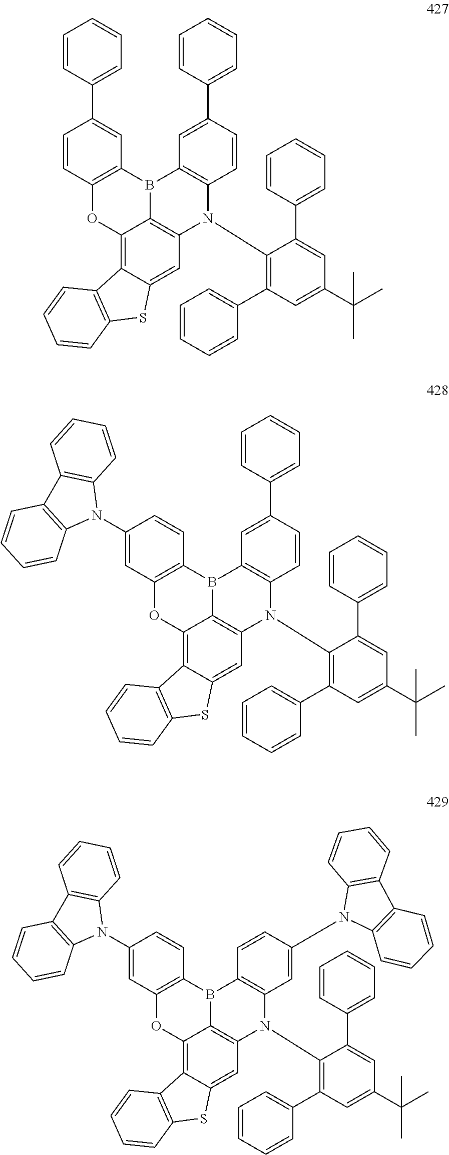 [SMILES: CC(C)(C)c1cc(-c2ccccc2)c(N2c3ccc(-c4ccccc4)cc3B3c4cc(-c5ccccc5)ccc4Oc4c3c2cc2sc3ccccc3c42)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4Oc4c3c2cc2sc3ccccc3c42)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2sc3ccccc3c42)c(-c2ccccc2)c1]

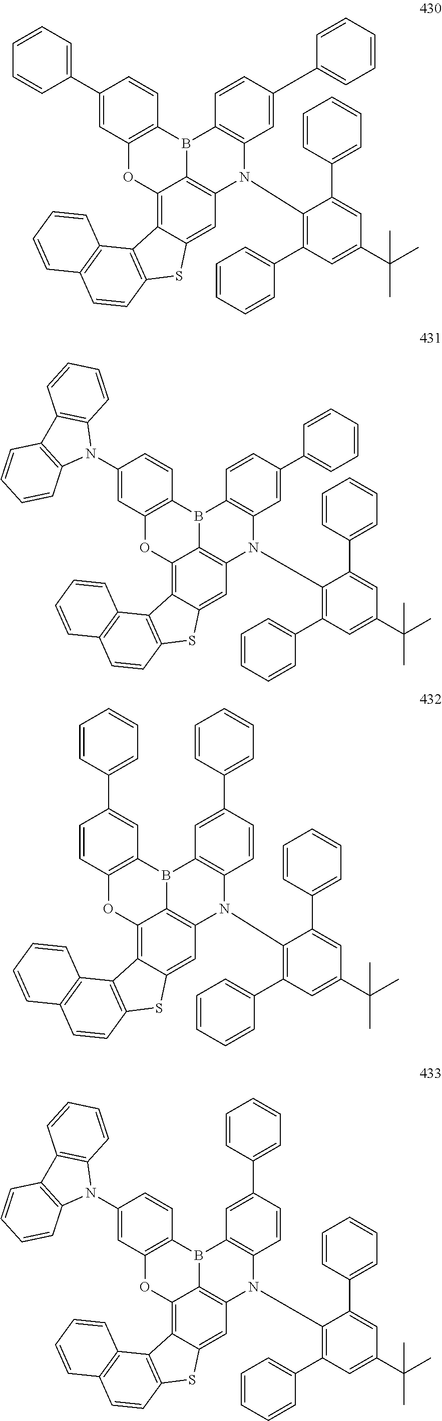

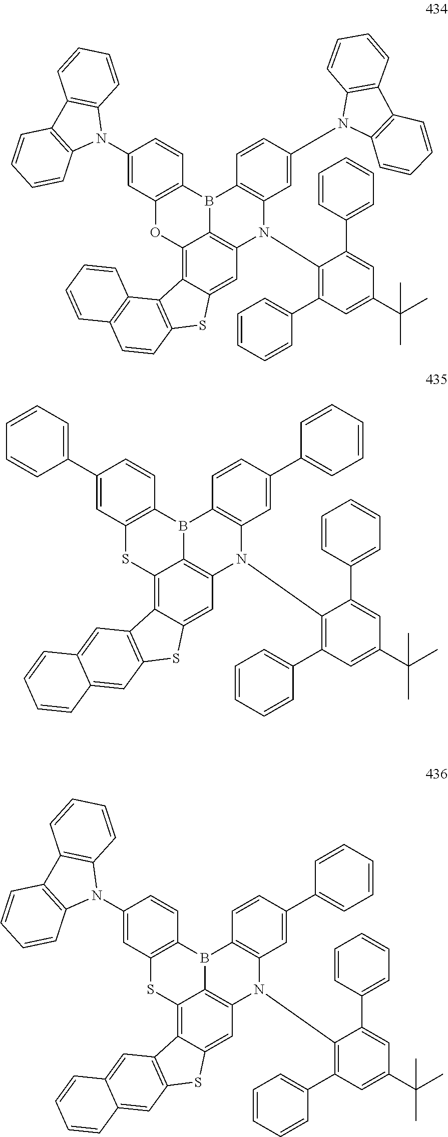 [SMILES: CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2sc3ccc5ccccc5c3c42)c(-c2ccccc2)c1 ; CC(C)(C)c1cc(-c2ccccc2)c(N2c3cc(-c4ccccc4)ccc3B3c4ccc(-c5ccccc5)cc4Sc4c3c2cc2sc3cc5ccccc5cc3c42)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Sc4c3c2cc2sc3cc5ccccc5cc3c42)c(-c2ccccc2)c1]

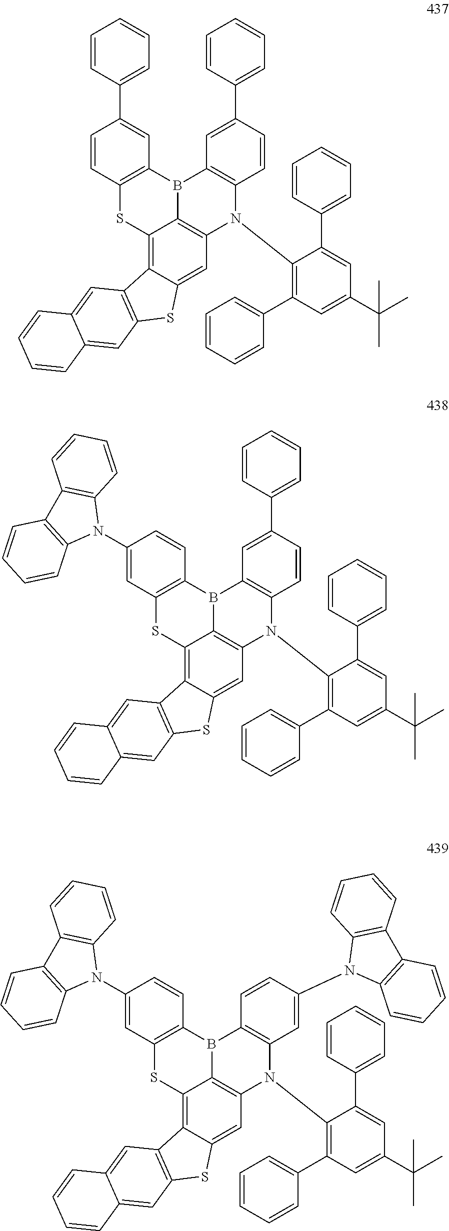 [SMILES: CC(C)(C)c1cc(-c2ccccc2)c(N2c3ccc(-c4ccccc4)cc3B3c4cc(-c5ccccc5)ccc4Sc4c3c2cc2sc3cc5ccccc5cc3c42)c(-c2ccccc2)c1 ; CC(C)(C)c1cc(-c2ccccc2)c(N2c3ccc(-c4ccccc4)cc3B3c4ccc(-n5c6ccccc6c6ccccc65)cc4Sc4c3c2cc2sc3cc5ccccc5cc3c42)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Sc4c3c2cc2sc3cc5ccccc5cc3c42)c(-c2ccccc2)c1]

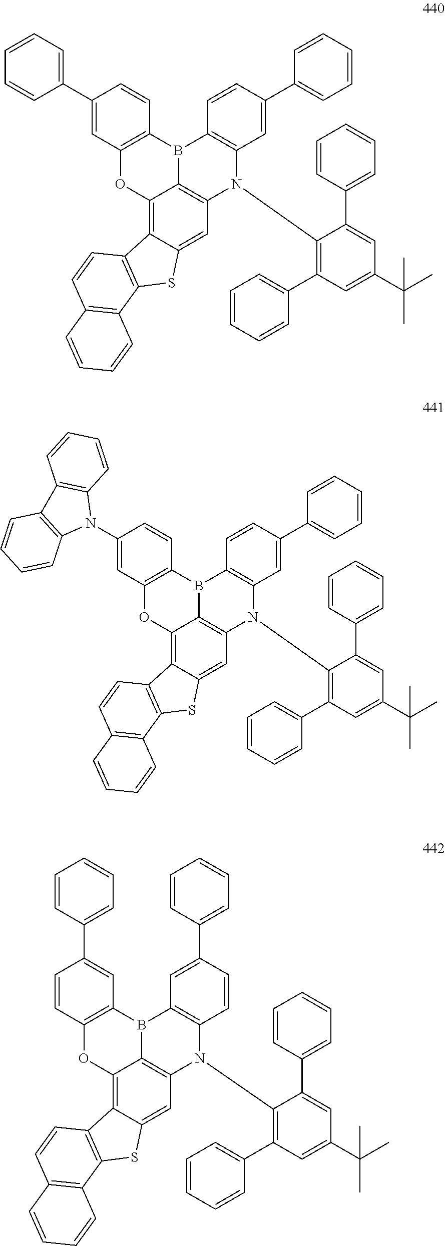 [SMILES: CC(C)(C)c1cc(-c2ccccc2)c(N2c3cc(-c4ccccc4)ccc3B3c4ccc(-c5ccccc5)cc4Oc4c3c2cc2sc3c5ccccc5ccc3c42)c(-c2ccccc2)c1 ; CC(C)(C)c1cc(-c2ccccc2)c(N2c3cc(-c4ccccc4)ccc3B3c4ccc(-n5c6ccccc6c6ccccc65)cc4Oc4c3c2cc2sc3c5ccccc5ccc3c42)c(-c2ccccc2)c1 ; CC(C)(C)c1cc(-c2ccccc2)c(N2c3ccc(-c4ccccc4)cc3B3c4cc(-c5ccccc5)ccc4Oc4c3c2cc2sc3c5ccccc5ccc3c42)c(-c2ccccc2)c1]

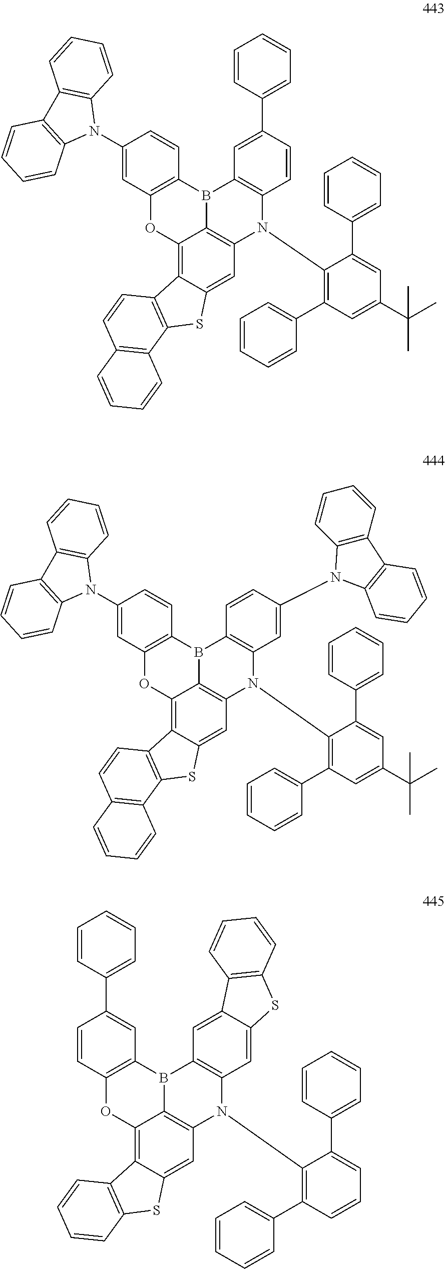 [SMILES: CC(C)(C)c1cc(-c2ccccc2)c(N2c3ccc(-c4ccccc4)cc3B3c4ccc(-n5c6ccccc6c6ccccc65)cc4Oc4c3c2cc2sc3c5ccccc5ccc3c42)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4Oc4c3c2cc2sc3c5ccccc5ccc3c42)c(-c2ccccc2)c1 ; c1ccc(-c2ccc3c(c2)B2c4cc5c(cc4N(c4c(-c6ccccc6)cccc4-c4ccccc4)c4cc6sc7ccccc7c6c(c42)O3)sc2ccccc25)cc1]

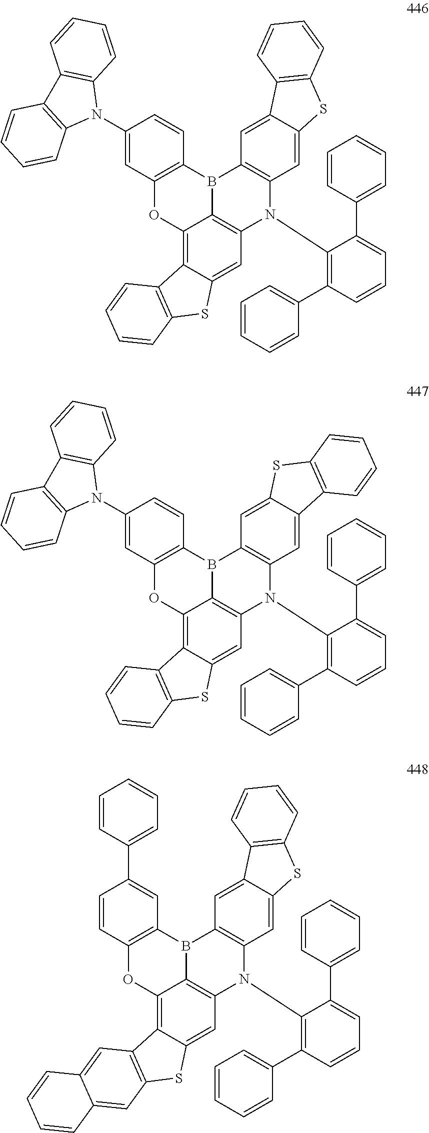 [SMILES: c1ccc(-c2cccc(-c3ccccc3)c2N2c3cc4sc5ccccc5c4cc3B3c4ccc(-n5c6ccccc6c6ccccc65)cc4Oc4c3c2cc2sc3ccccc3c42)cc1 ; c1ccc(-c2cccc(-c3ccccc3)c2N2c3cc4c(cc3B3c5ccc(-n6c7ccccc7c7ccccc76)cc5Oc5c3c2cc2sc3ccccc3c52)sc2ccccc24)cc1 ; c1ccc(-c2ccc3c(c2)B2c4cc5c(cc4N(c4c(-c6ccccc6)cccc4-c4ccccc4)c4cc6sc7cc8ccccc8cc7c6c(c42)O3)sc2ccccc25)cc1]

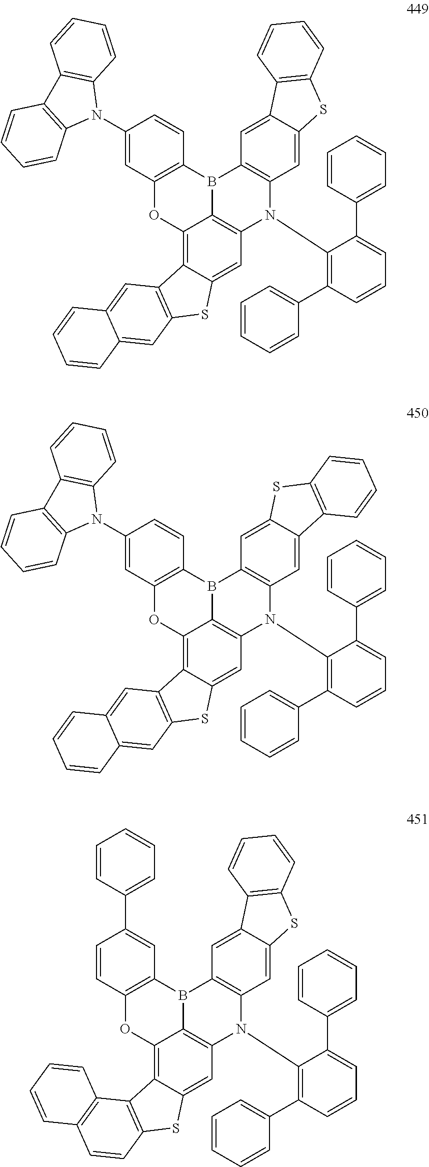 [SMILES: c1ccc(-c2cccc(-c3ccccc3)c2N2c3cc4sc5ccccc5c4cc3B3c4ccc(-n5c6ccccc6c6ccccc65)cc4Oc4c3c2cc2sc3cc5ccccc5cc3c42)cc1 ; c1ccc(-c2cccc(-c3ccccc3)c2N2c3cc4c(cc3B3c5ccc(-n6c7ccccc7c7ccccc76)cc5Oc5c3c2cc2sc3cc6ccccc6cc3c52)sc2ccccc24)cc1 ; c1ccc(-c2ccc3c(c2)B2c4cc5c(cc4N(c4c(-c6ccccc6)cccc4-c4ccccc4)c4cc6sc7ccc8ccccc8c7c6c(c42)O3)sc2ccccc25)cc1]

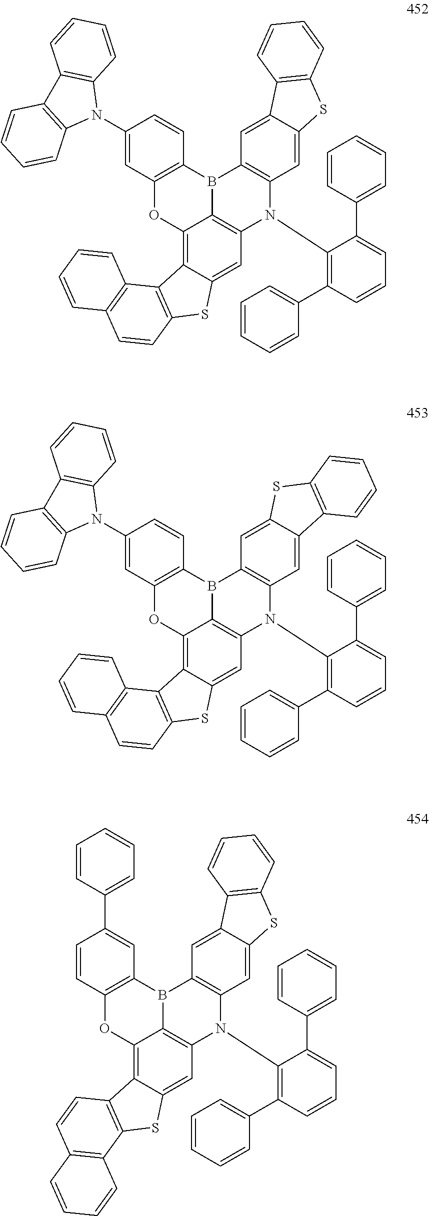 [SMILES: c1ccc(-c2cccc(-c3ccccc3)c2N2c3cc4sc5ccccc5c4cc3B3c4ccc(-n5c6ccccc6c6ccccc65)cc4Oc4c3c2cc2sc3ccc5ccccc5c3c42)cc1 ; c1ccc(-c2cccc(-c3ccccc3)c2N2c3cc4c(cc3B3c5ccc(-n6c7ccccc7c7ccccc76)cc5Oc5c3c2cc2sc3ccc6ccccc6c3c52)sc2ccccc24)cc1 ; c1ccc(-c2ccc3c(c2)B2c4cc5c(cc4N(c4c(-c6ccccc6)cccc4-c4ccccc4)c4cc6sc7c8ccccc8ccc7c6c(c42)O3)sc2ccccc25)cc1]

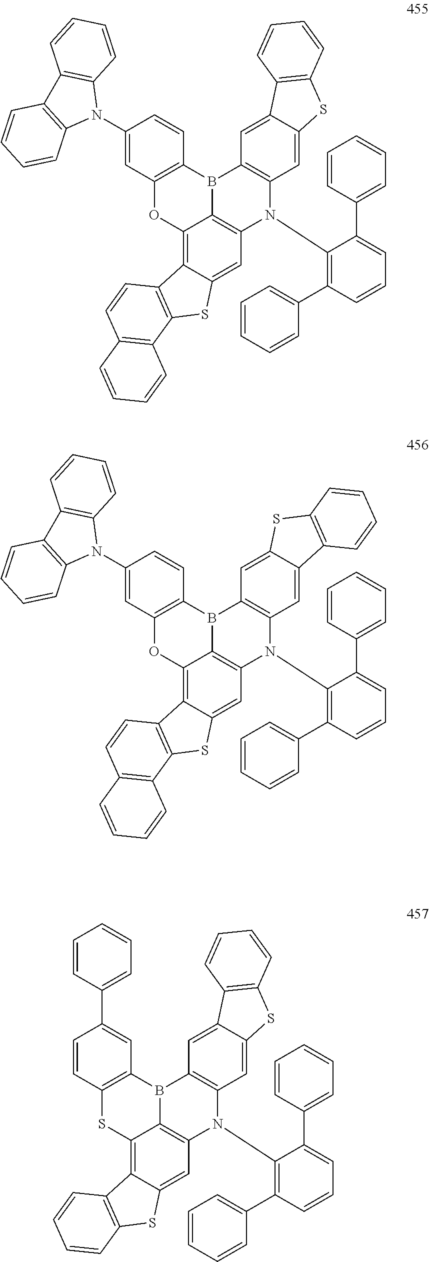 [SMILES: c1ccc(-c2cccc(-c3ccccc3)c2N2c3cc4sc5ccccc5c4cc3B3c4ccc(-n5c6ccccc6c6ccccc65)cc4Oc4c3c2cc2sc3c5ccccc5ccc3c42)cc1 ; c1ccc(-c2cccc(-c3ccccc3)c2N2c3cc4c(cc3B3c5ccc(-n6c7ccccc7c7ccccc76)cc5Oc5c3c2cc2sc3c6ccccc6ccc3c52)sc2ccccc24)cc1 ; c1ccc(-c2ccc3c(c2)B2c4cc5c(cc4N(c4c(-c6ccccc6)cccc4-c4ccccc4)c4cc6sc7ccccc7c6c(c42)S3)sc2ccccc25)cc1]

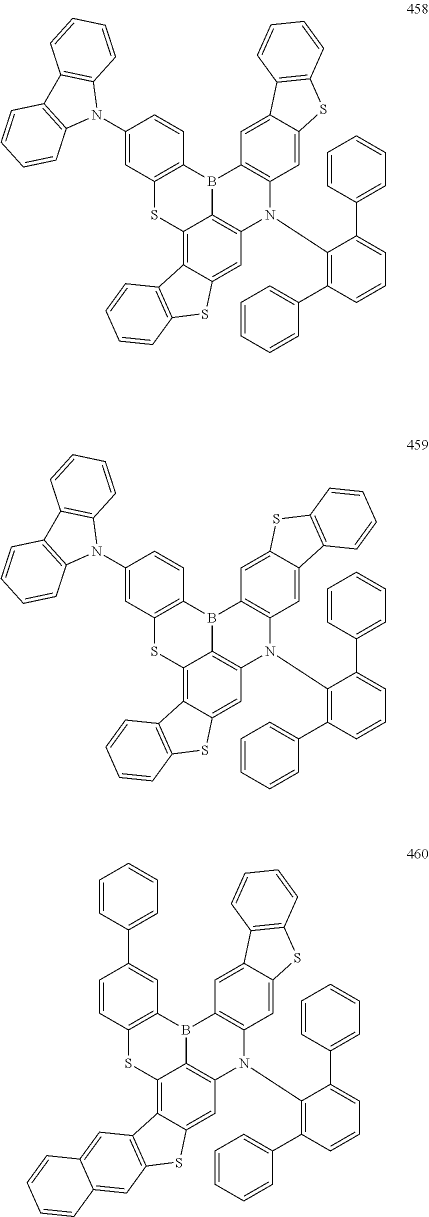 [SMILES: c1ccc(-c2cccc(-c3ccccc3)c2N2c3cc4sc5ccccc5c4cc3B3c4ccc(-n5c6ccccc6c6ccccc65)cc4Sc4c3c2cc2sc3ccccc3c42)cc1 ; c1ccc(-c2cccc(-c3ccccc3)c2N2c3cc4c(cc3B3c5ccc(-n6c7ccccc7c7ccccc76)cc5Sc5c3c2cc2sc3ccccc3c52)sc2ccccc24)cc1 ; c1ccc(-c2ccc3c(c2)B2c4cc5c(cc4N(c4c(-c6ccccc6)cccc4-c4ccccc4)c4cc6sc7cc8ccccc8cc7c6c(c42)S3)sc2ccccc25)cc1]

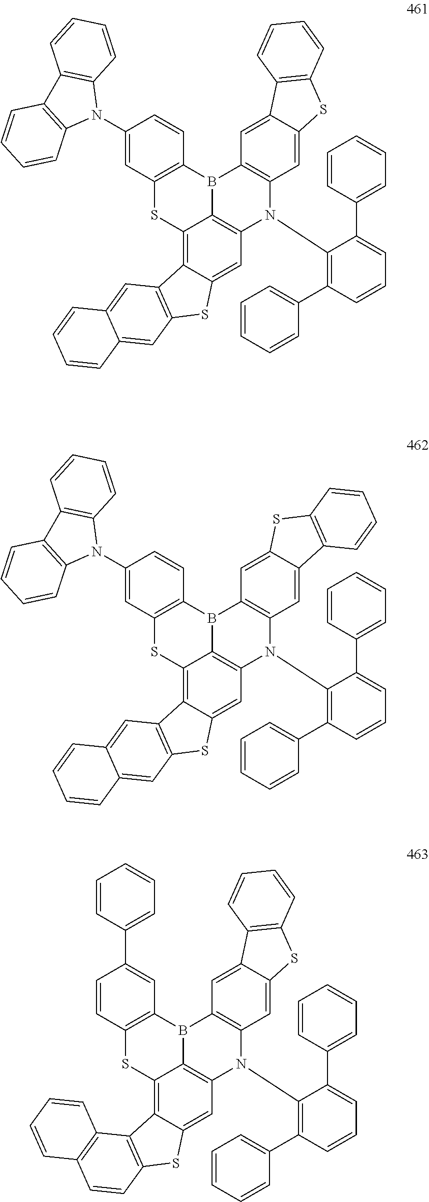 [SMILES: c1ccc(-c2cccc(-c3ccccc3)c2N2c3cc4sc5ccccc5c4cc3B3c4ccc(-n5c6ccccc6c6ccccc65)cc4Sc4c3c2cc2sc3cc5ccccc5cc3c42)cc1 ; c1ccc(-c2cccc(-c3ccccc3)c2N2c3cc4c(cc3B3c5ccc(-n6c7ccccc7c7ccccc76)cc5Sc5c3c2cc2sc3cc6ccccc6cc3c52)sc2ccccc24)cc1 ; c1ccc(-c2ccc3c(c2)B2c4cc5c(cc4N(c4c(-c6ccccc6)cccc4-c4ccccc4)c4cc6sc7ccc8ccccc8c7c6c(c42)S3)sc2ccccc25)cc1]

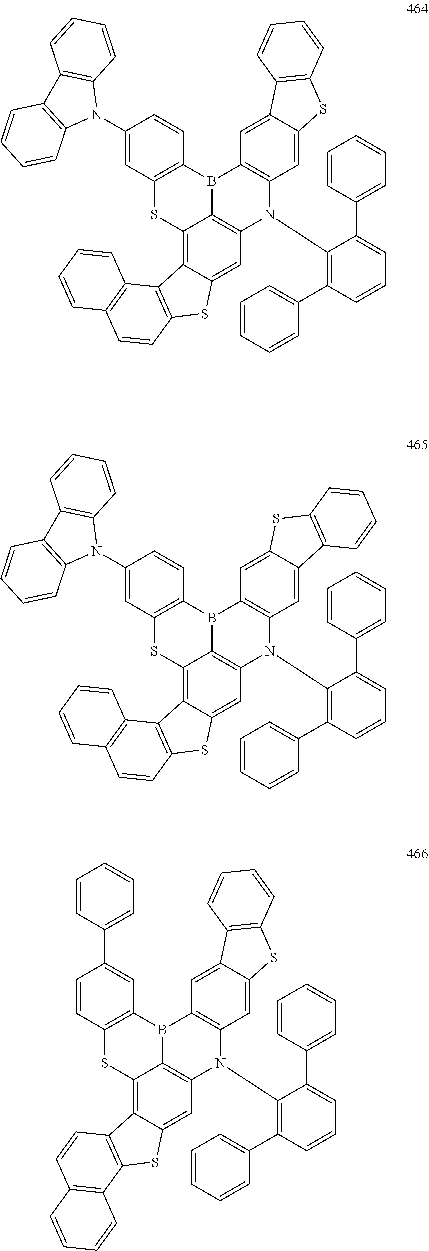 [SMILES: c1ccc(-c2cccc(-c3ccccc3)c2N2c3cc4sc5ccccc5c4cc3B3c4ccc(-n5c6ccccc6c6ccccc65)cc4Sc4c3c2cc2sc3ccc5ccccc5c3c42)cc1 ; c1ccc(-c2cccc(-c3ccccc3)c2N2c3cc4c(cc3B3c5ccc(-n6c7ccccc7c7ccccc76)cc5Sc5c3c2cc2sc3ccc6ccccc6c3c52)sc2ccccc24)cc1 ; c1ccc(-c2ccc3c(c2)B2c4cc5c(cc4N(c4c(-c6ccccc6)cccc4-c4ccccc4)c4cc6sc7c8ccccc8ccc7c6c(c42)S3)sc2ccccc25)cc1]

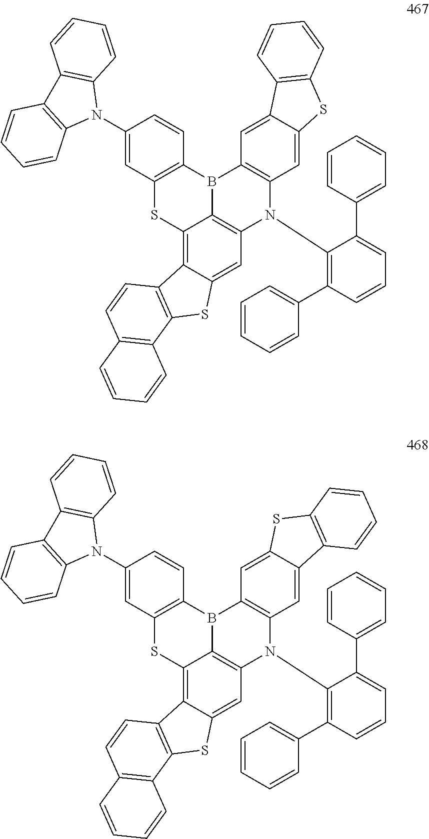 [SMILES: c1ccc(-c2cccc(-c3ccccc3)c2N2c3cc4sc5ccccc5c4cc3B3c4ccc(-n5c6ccccc6c6ccccc65)cc4Sc4c3c2cc2sc3c5ccccc5ccc3c42)cc1 ; c1ccc(-c2cccc(-c3ccccc3)c2N2c3cc4c(cc3B3c5ccc(-n6c7ccccc7c7ccccc76)cc5Sc5c3c2cc2sc3c6ccccc6ccc3c52)sc2ccccc24)cc1]

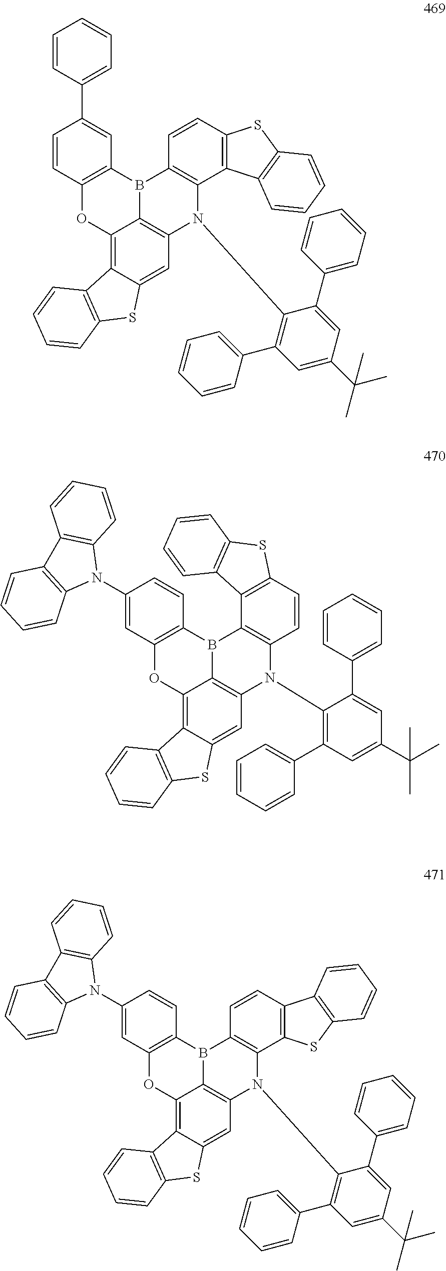 [SMILES: CC(C)(C)c1cc(-c2ccccc2)c(N2c3cc4sc5ccccc5c4c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4sc5ccccc5c4c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4sc5ccccc5c4c4c3B(c3ccc(-n5c6ccccc6c6ccccc65)cc3O4)c3ccc4c(sc5ccccc54)c32)c(-c2ccccc2)c1]

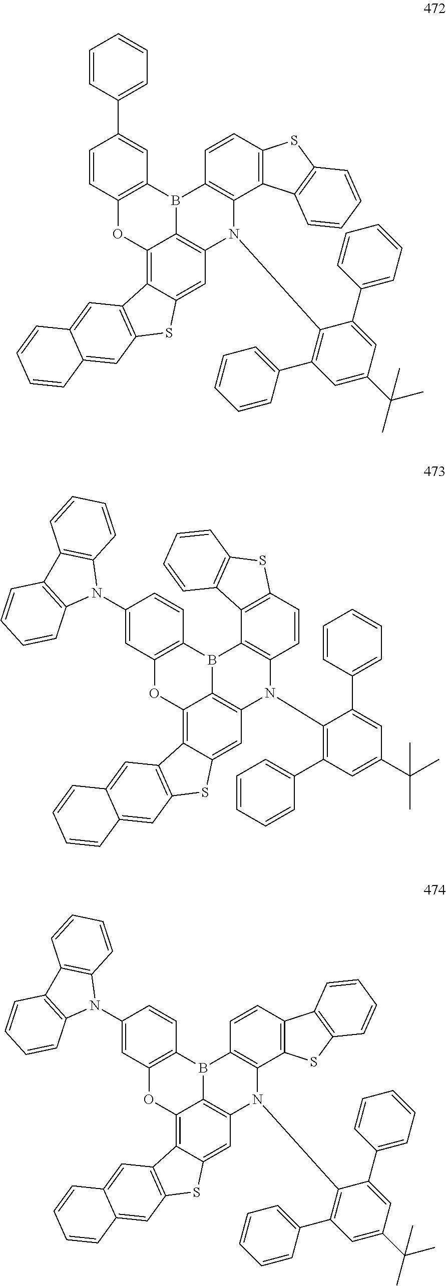 [SMILES: CC(C)(C)c1cc(-c2ccccc2)c(N2c3cc4sc5cc6ccccc6cc5c4c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4sc5cc6ccccc6cc5c4c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4sc5cc6ccccc6cc5c4c4c3B(c3ccc(-n5c6ccccc6c6ccccc65)cc3O4)c3ccc4c(sc5ccccc54)c32)c(-c2ccccc2)c1]

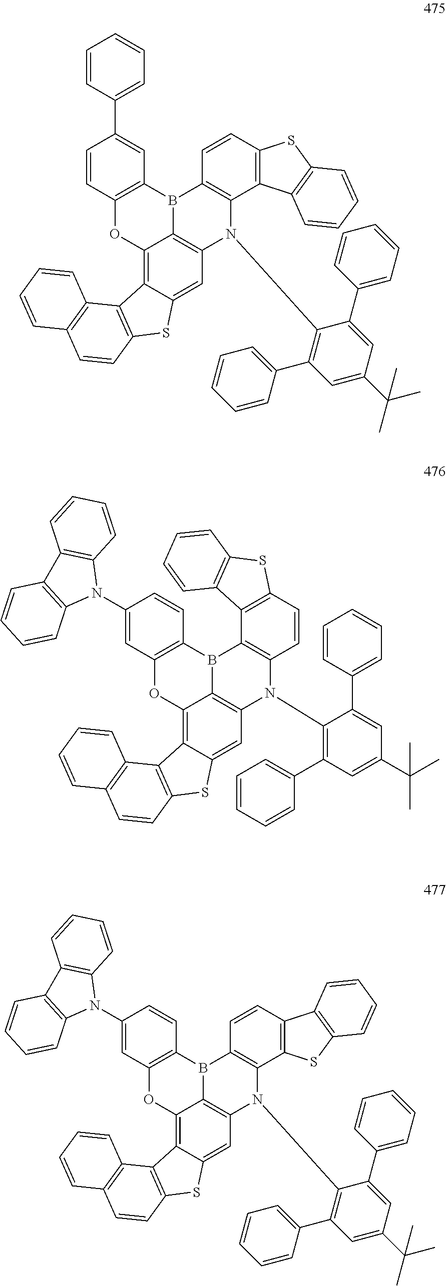 [SMILES: CC(C)(C)c1cc(-c2ccccc2)c(N2c3cc4sc5ccc6ccccc6c5c4c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4sc5ccc6ccccc6c5c4c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4sc5ccc6ccccc6c5c4c4c3B(c3ccc(-n5c6ccccc6c6ccccc65)cc3O4)c3ccc4c(sc5ccccc54)c32)c(-c2ccccc2)c1]

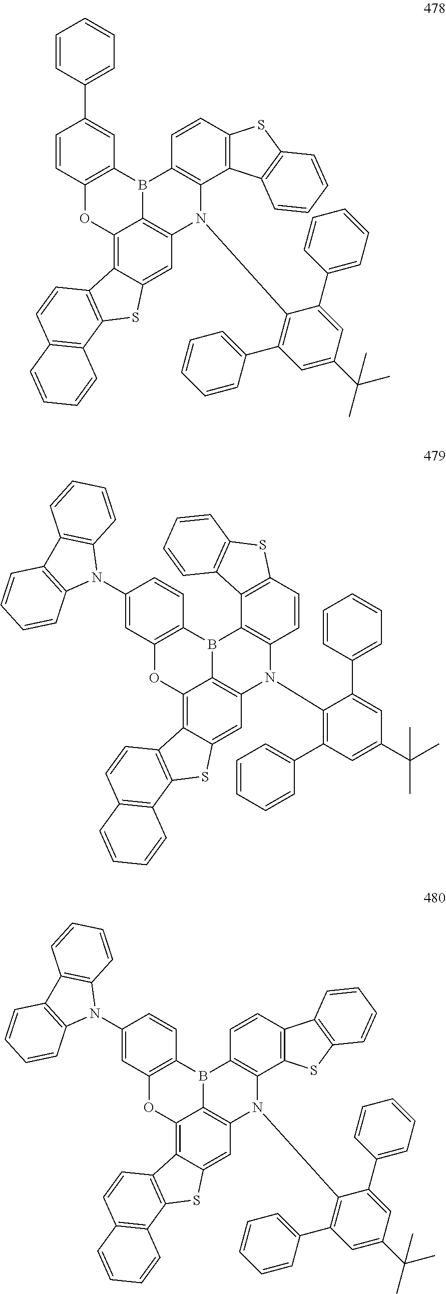 [SMILES: CC(C)(C)c1cc(-c2ccccc2)c(N2c3cc4sc5c6ccccc6ccc5c4c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4sc5c6ccccc6ccc5c4c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4sc5c6ccccc6ccc5c4c4c3B(c3ccc(-n5c6ccccc6c6ccccc65)cc3O4)c3ccc4c(sc5ccccc54)c32)c(-c2ccccc2)c1]

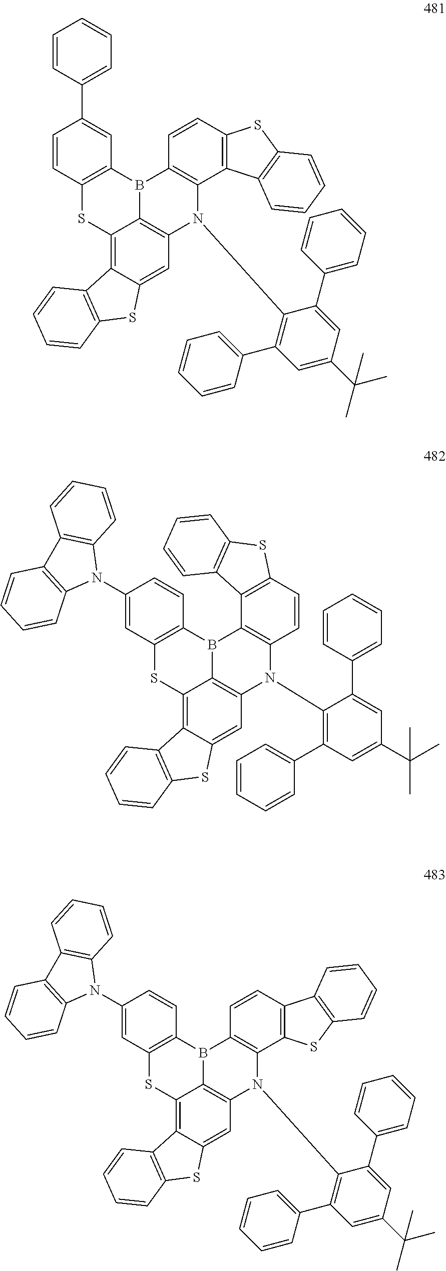 [SMILES: CC(C)(C)c1cc(-c2ccccc2)c(N2c3cc4sc5ccccc5c4c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4sc5ccccc5c4c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4sc5ccccc5c4c4c3B(c3ccc(-n5c6ccccc6c6ccccc65)cc3S4)c3ccc4c(sc5ccccc54)c32)c(-c2ccccc2)c1]

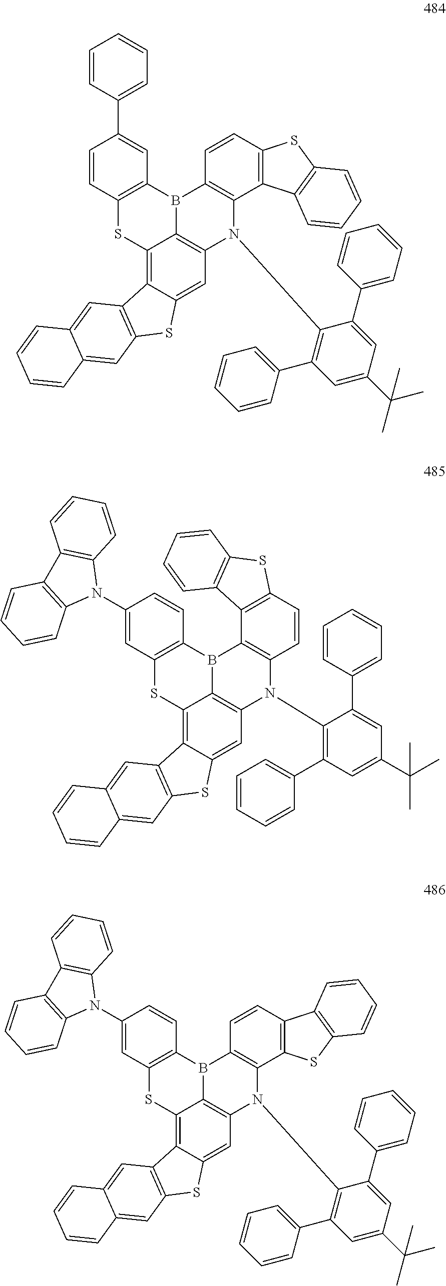 [SMILES: CC(C)(C)c1cc(-c2ccccc2)c(N2c3cc4sc5cc6ccccc6cc5c4c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4sc5cc6ccccc6cc5c4c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4sc5cc6ccccc6cc5c4c4c3B(c3ccc(-n5c6ccccc6c6ccccc65)cc3S4)c3ccc4c(sc5ccccc54)c32)c(-c2ccccc2)c1]

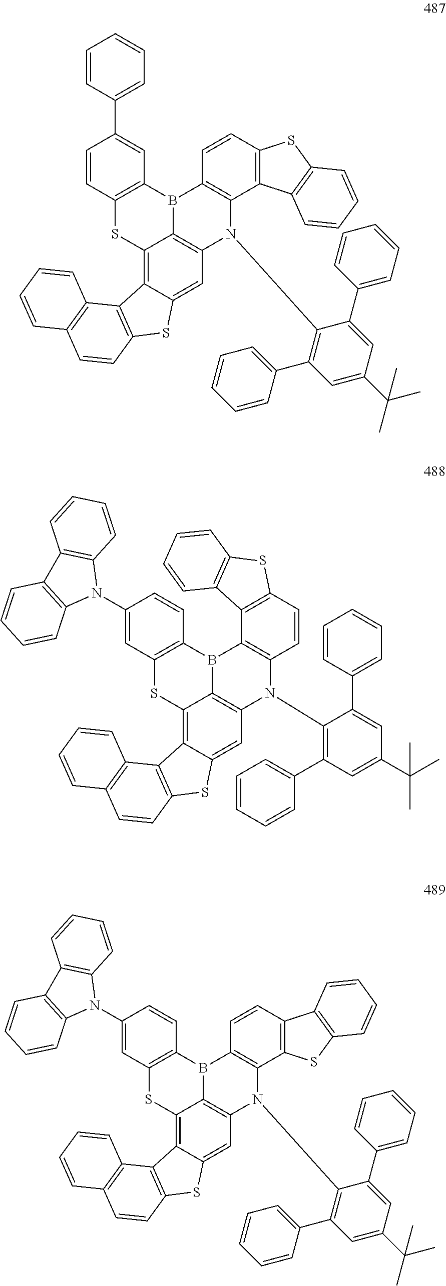 [SMILES: CC(C)(C)c1cc(-c2ccccc2)c(N2c3cc4sc5ccc6ccccc6c5c4c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4sc5ccc6ccccc6c5c4c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4sc5ccc6ccccc6c5c4c4c3B(c3ccc(-n5c6ccccc6c6ccccc65)cc3S4)c3ccc4c(sc5ccccc54)c32)c(-c2ccccc2)c1]

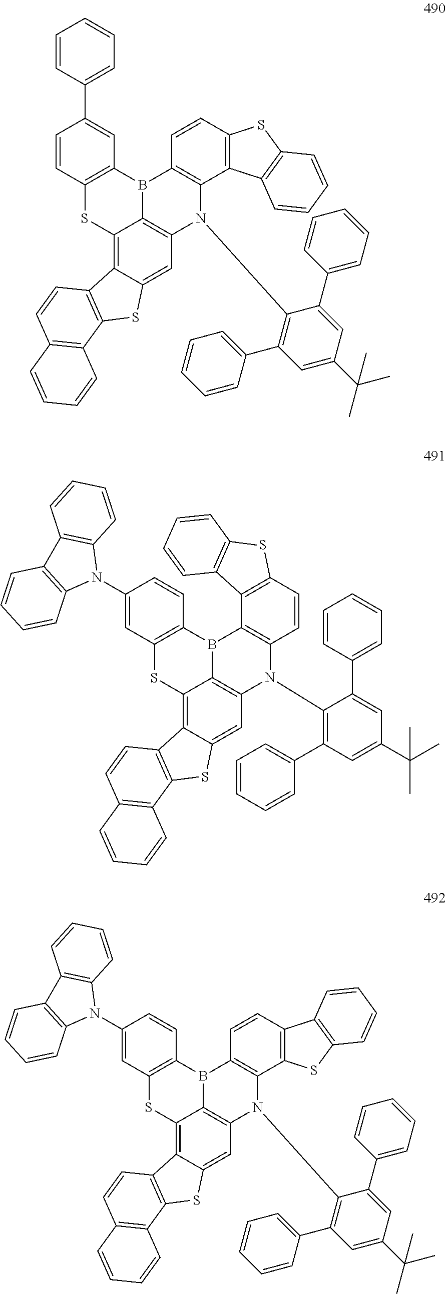 [SMILES: CC(C)(C)c1cc(-c2ccccc2)c(N2c3cc4sc5c6ccccc6ccc5c4c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4sc5c6ccccc6ccc5c4c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4sc5c6ccccc6ccc5c4c4c3B(c3ccc(-n5c6ccccc6c6ccccc65)cc3S4)c3ccc4c(sc5ccccc54)c32)c(-c2ccccc2)c1]

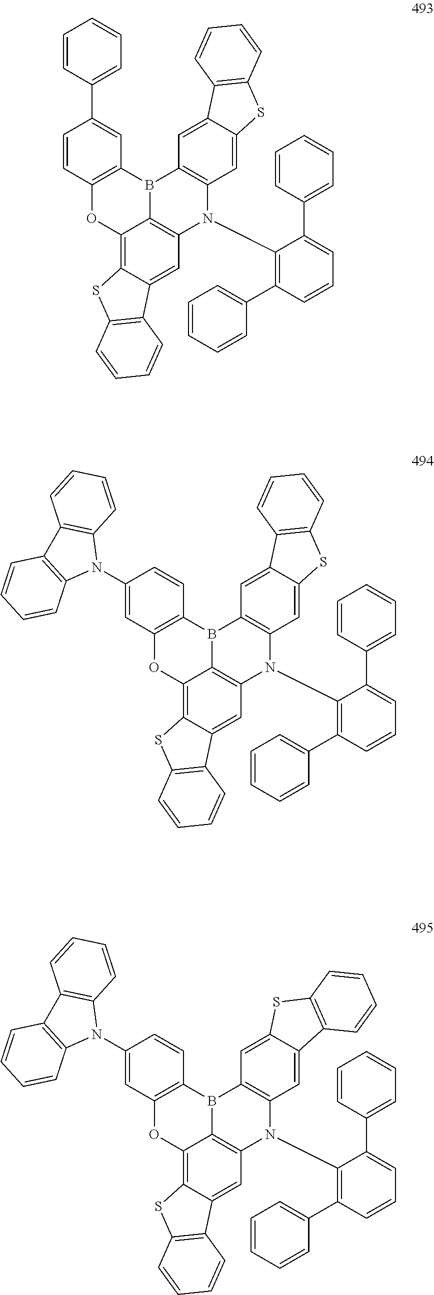 [SMILES: c1ccc(-c2ccc3c(c2)B2c4cc5c(cc4N(c4c(-c6ccccc6)cccc4-c4ccccc4)c4cc6c(sc7ccccc76)c(c42)O3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Oc4c3c2cc2c4sc3ccccc32)cc1 ; c1ccc(-c2cccc(-c3ccccc3)c2N2c3cc4c(cc3B3c5ccc(-n6c7ccccc7c7ccccc76)cc5Oc5c3c2cc2c5sc3ccccc32)sc2ccccc24)cc1]

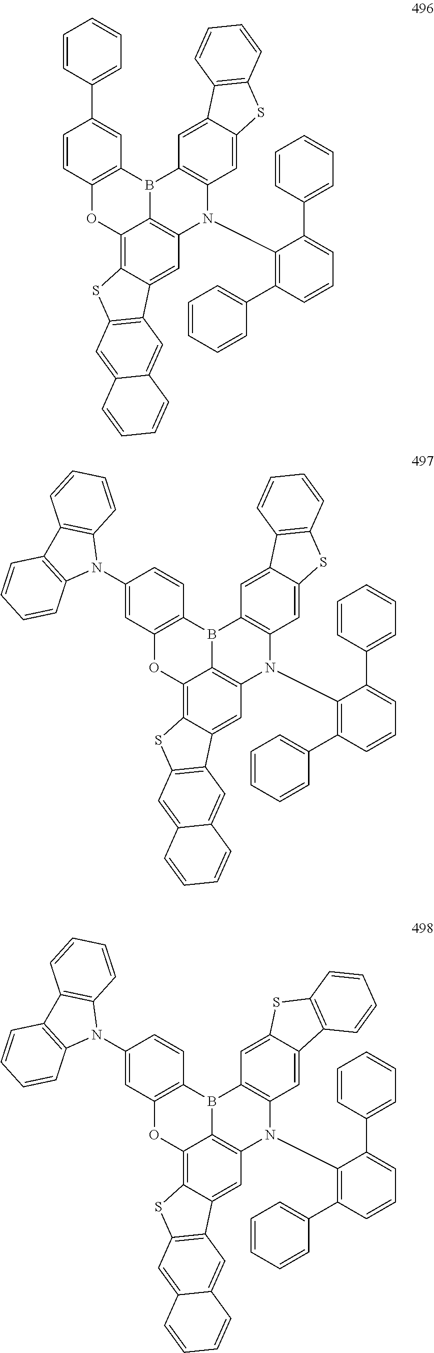

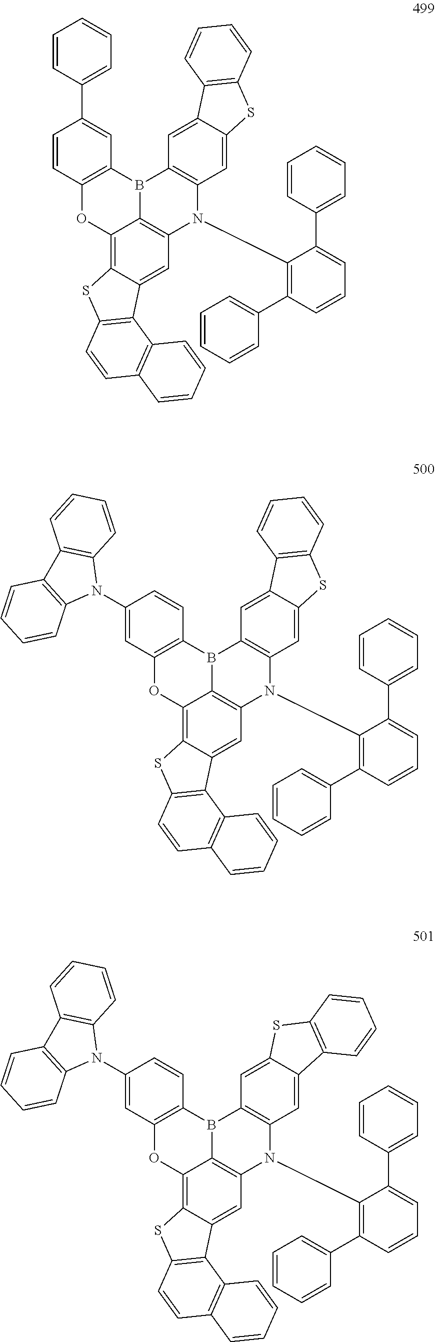 [SMILES: c1ccc(-c2ccc3c(c2)B2c4cc5c(cc4N(c4c(-c6ccccc6)cccc4-c4ccccc4)c4cc6c(sc7ccc8ccccc8c76)c(c42)O3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Oc4c3c2cc2c4sc3ccc4ccccc4c32)cc1 ; c1ccc(-c2cccc(-c3ccccc3)c2N2c3cc4c(cc3B3c5ccc(-n6c7ccccc7c7ccccc76)cc5Oc5c3c2cc2c5sc3ccc5ccccc5c32)sc2ccccc24)cc1]

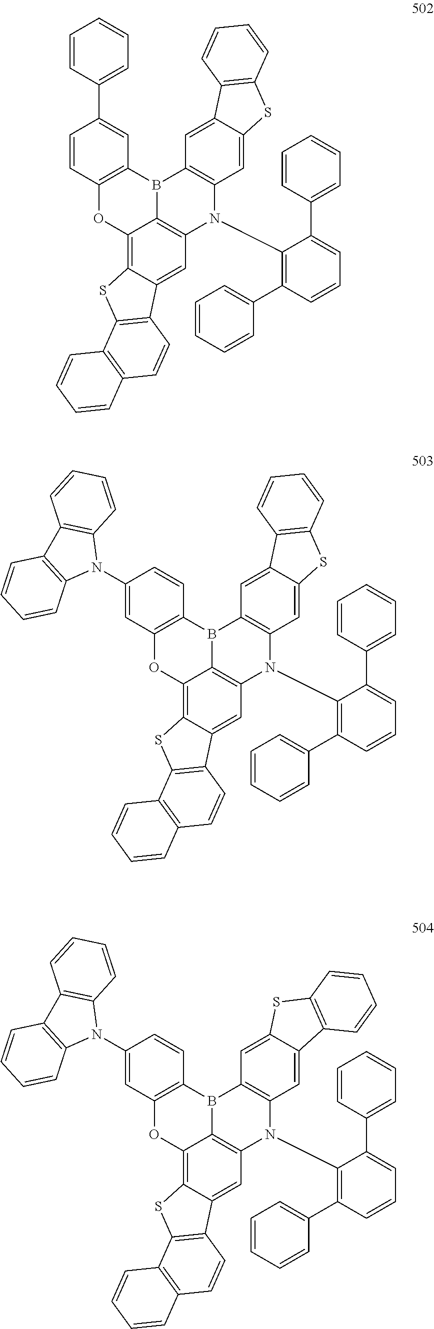 [SMILES: c1ccc(-c2ccc3c(c2)B2c4cc5c(cc4N(c4c(-c6ccccc6)cccc4-c4ccccc4)c4cc6c(sc7c8ccccc8ccc67)c(c42)O3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Oc4c3c2cc2c4sc3c4ccccc4ccc23)cc1 ; c1ccc(-c2cccc(-c3ccccc3)c2N2c3cc4c(cc3B3c5ccc(-n6c7ccccc7c7ccccc76)cc5Oc5c3c2cc2c5sc3c5ccccc5ccc23)sc2ccccc24)cc1]

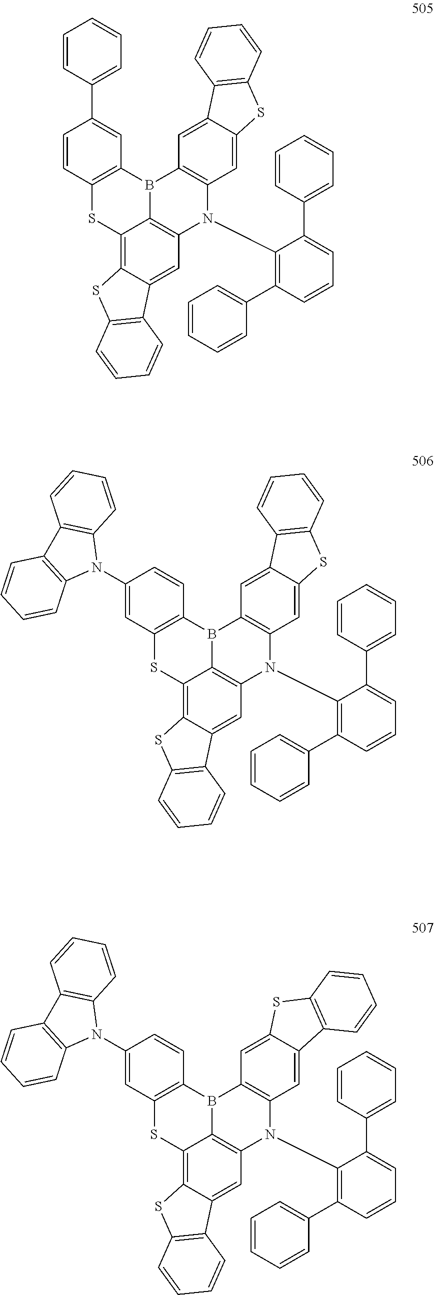 [SMILES: c1ccc(-c2ccc3c(c2)B2c4cc5c(cc4N(c4c(-c6ccccc6)cccc4-c4ccccc4)c4cc6c(sc7ccccc76)c(c42)S3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Sc4c3c2cc2c4sc3ccccc32)cc1 ; c1ccc(-c2cccc(-c3ccccc3)c2N2c3cc4c(cc3B3c5ccc(-n6c7ccccc7c7ccccc76)cc5Sc5c3c2cc2c5sc3ccccc32)sc2ccccc24)cc1]

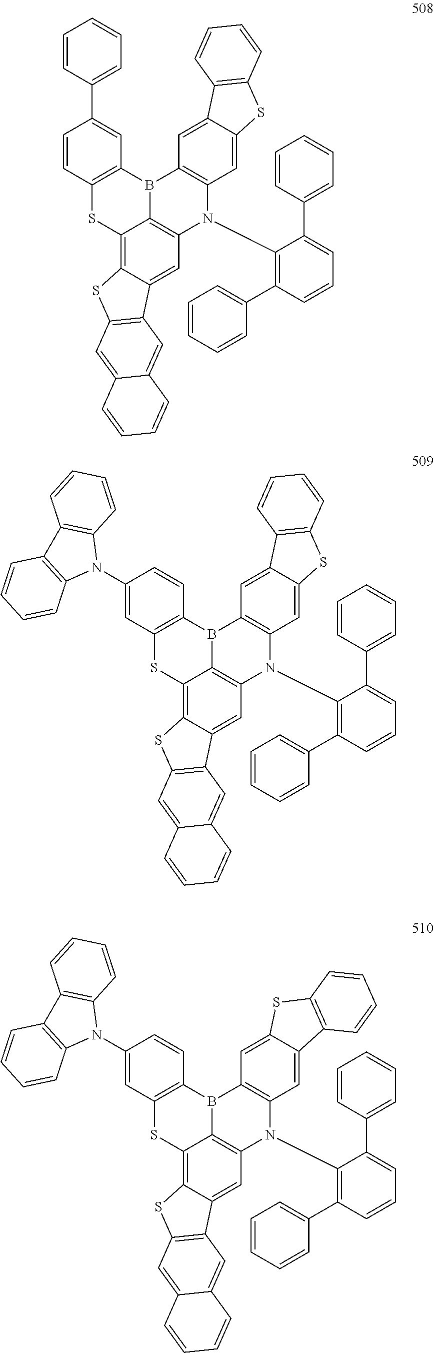

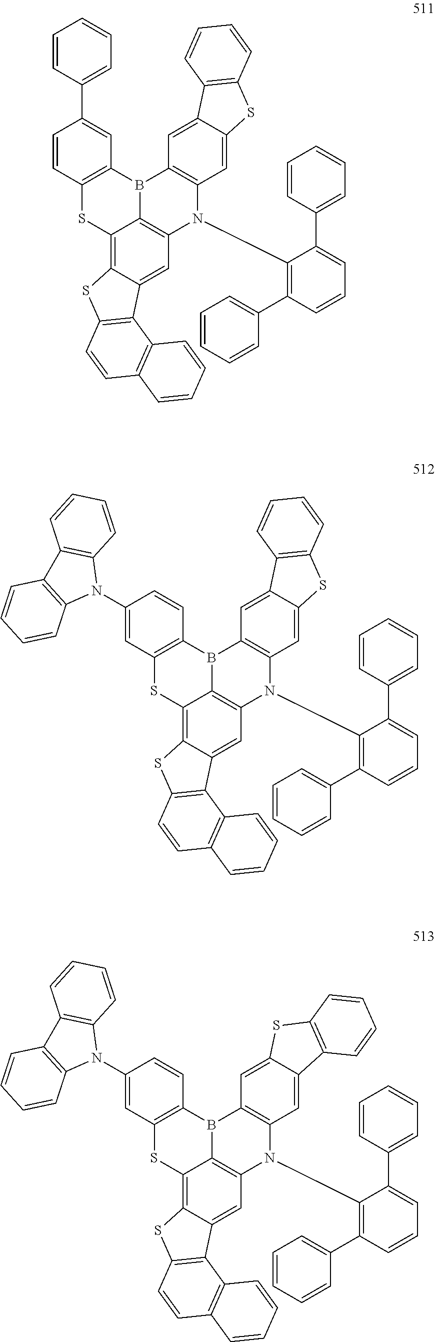 [SMILES: c1ccc(-c2ccc3c(c2)B2c4cc5c(cc4N(c4c(-c6ccccc6)cccc4-c4ccccc4)c4cc6c(sc7ccc8ccccc8c76)c(c42)S3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Sc4c3c2cc2c4sc3ccc4ccccc4c32)cc1 ; c1ccc(-c2cccc(-c3ccccc3)c2N2c3cc4c(cc3B3c5ccc(-n6c7ccccc7c7ccccc76)cc5Sc5c3c2cc2c5sc3ccc5ccccc5c32)sc2ccccc24)cc1]

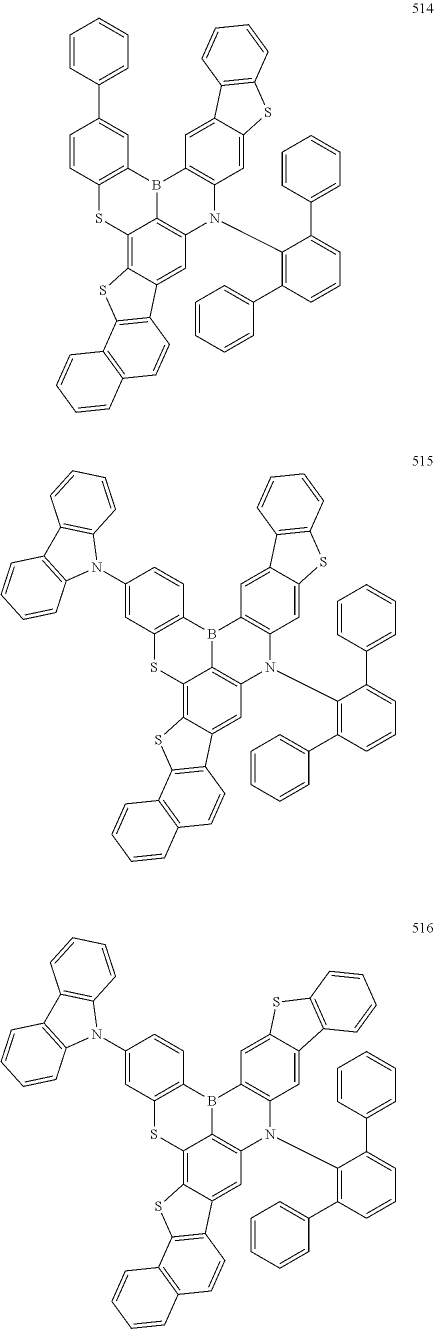 [SMILES: c1ccc(-c2ccc3c(c2)B2c4cc5c(cc4N(c4c(-c6ccccc6)cccc4-c4ccccc4)c4cc6c(sc7c8ccccc8ccc67)c(c42)S3)sc2ccccc25)cc1 ; c1ccc(-c2cccc(-c3ccccc3)c2N2c3cc4sc5ccccc5c4cc3B3c4ccc(-n5c6ccccc6c6ccccc65)cc4Sc4c3c2cc2c4sc3c4ccccc4ccc23)cc1 ; c1ccc(-c2cccc(-c3ccccc3)c2N2c3cc4c(cc3B3c5ccc(-n6c7ccccc7c7ccccc76)cc5Sc5c3c2cc2c5sc3c5ccccc5ccc23)sc2ccccc24)cc1]

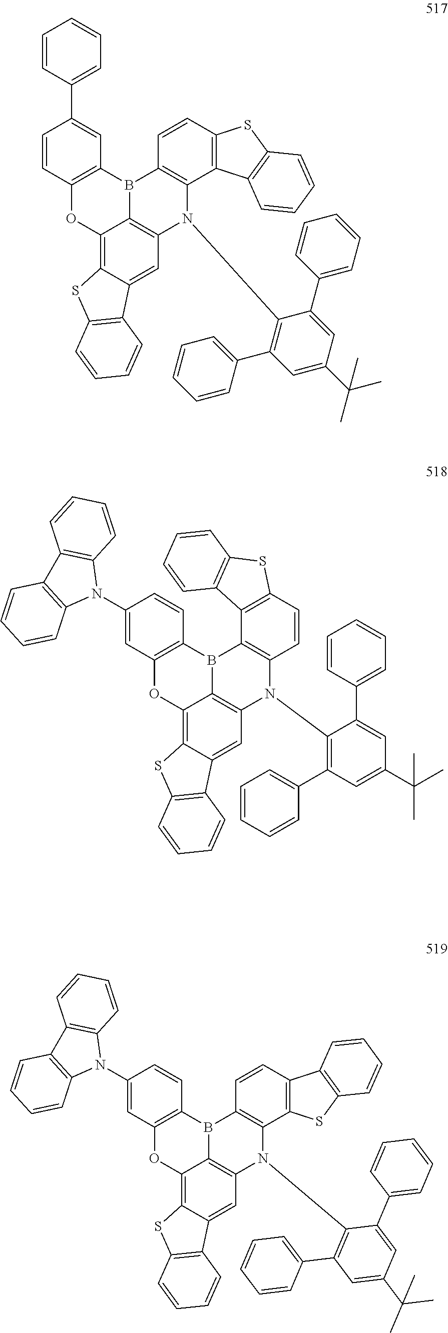 [SMILES: CC(C)(C)c1cc(-c2ccccc2)c(N2c3cc4c(sc5ccccc54)c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4c(sc5ccccc54)c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4c(sc5ccccc54)c4c3B(c3ccc(-n5c6ccccc6c6ccccc65)cc3O4)c3ccc4c(sc5ccccc54)c32)c(-c2ccccc2)c1]

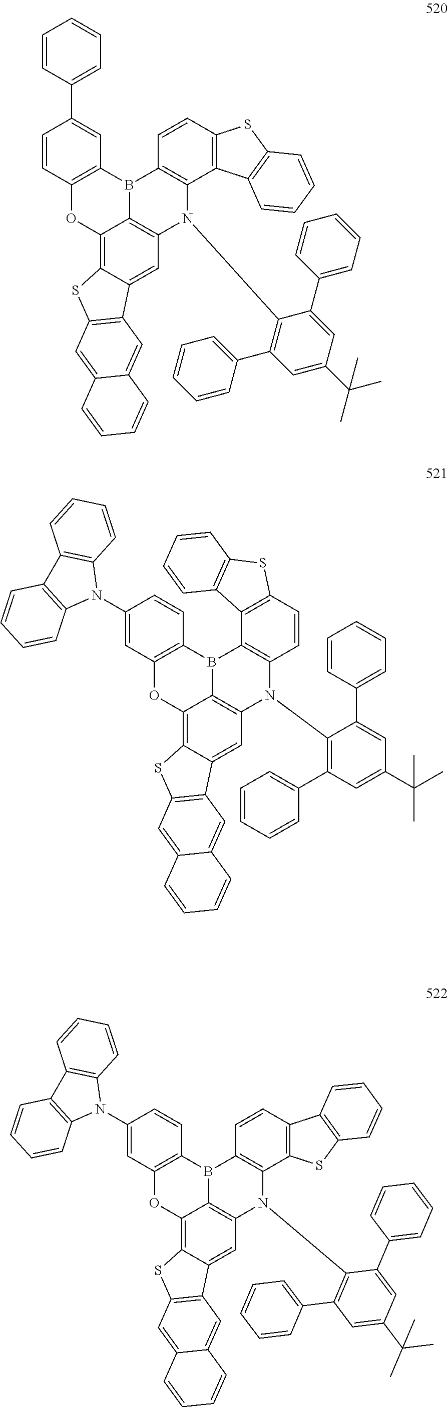 [SMILES: CC(C)(C)c1cc(-c2ccccc2)c(N2c3cc4c(sc5cc6ccccc6cc54)c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4c(sc5cc6ccccc6cc54)c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4c(sc5cc6ccccc6cc54)c4c3B(c3ccc(-n5c6ccccc6c6ccccc65)cc3O4)c3ccc4c(sc5ccccc54)c32)c(-c2ccccc2)c1]

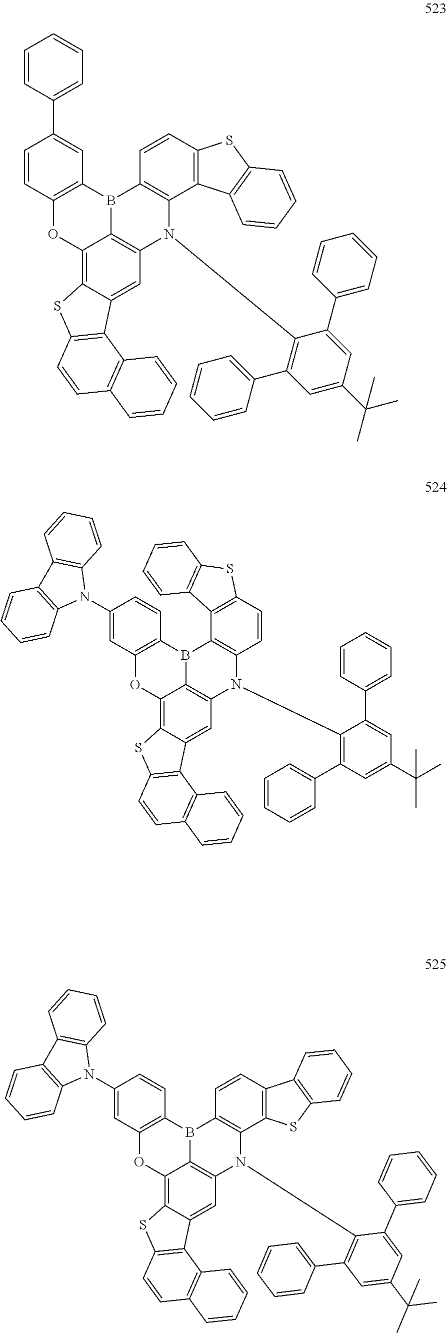 [SMILES: CC(C)(C)c1cc(-c2ccccc2)c(N2c3cc4c(sc5ccc6ccccc6c54)c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4c(sc5ccc6ccccc6c54)c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4c(sc5ccc6ccccc6c54)c4c3B(c3ccc(-n5c6ccccc6c6ccccc65)cc3O4)c3ccc4c(sc5ccccc54)c32)c(-c2ccccc2)c1]

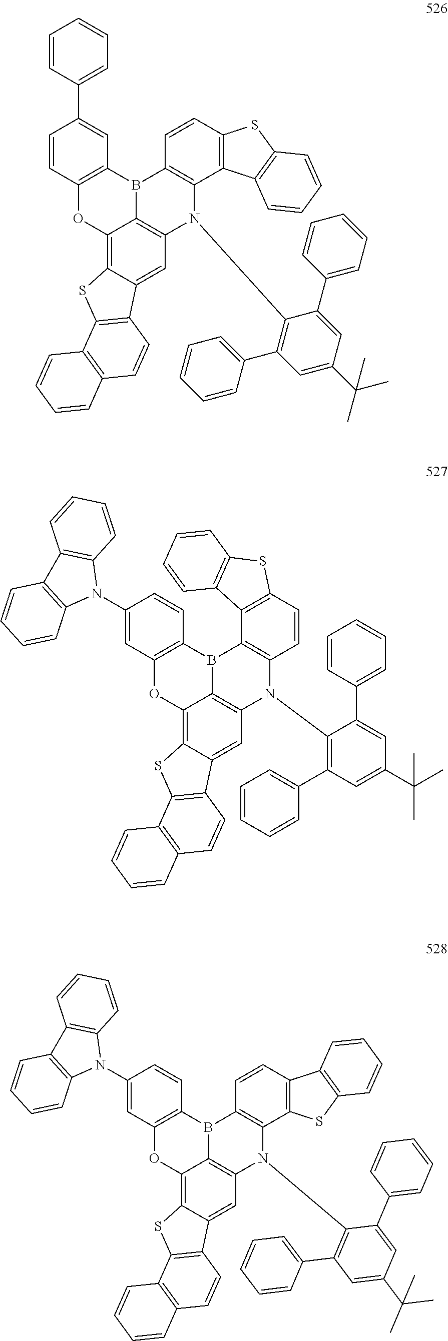 [SMILES: CC(C)(C)c1cc(-c2ccccc2)c(N2c3cc4c(sc5c6ccccc6ccc45)c4c3B(c3cc(-c5ccccc5)ccc3O4)c3ccc4sc5ccccc5c4c32)c(-c2ccccc2)c1 ; CC(C)(C)c1cc(-c2ccccc2)c(N2c3cc4c(sc5c6ccccc6ccc45)c4c3B(c3ccc(-n5c6ccccc6c6ccccc65)cc3O4)c3c2ccc2sc4ccccc4c32)c(-c2ccccc2)c1 ; CC(C)(C)c1cc(-c2ccccc2)c(N2c3cc4c(sc5c6ccccc6ccc45)c4c3B(c3ccc(-n5c6ccccc6c6ccccc65)cc3O4)c3ccc4c(sc5ccccc54)c32)c(-c2ccccc2)c1]

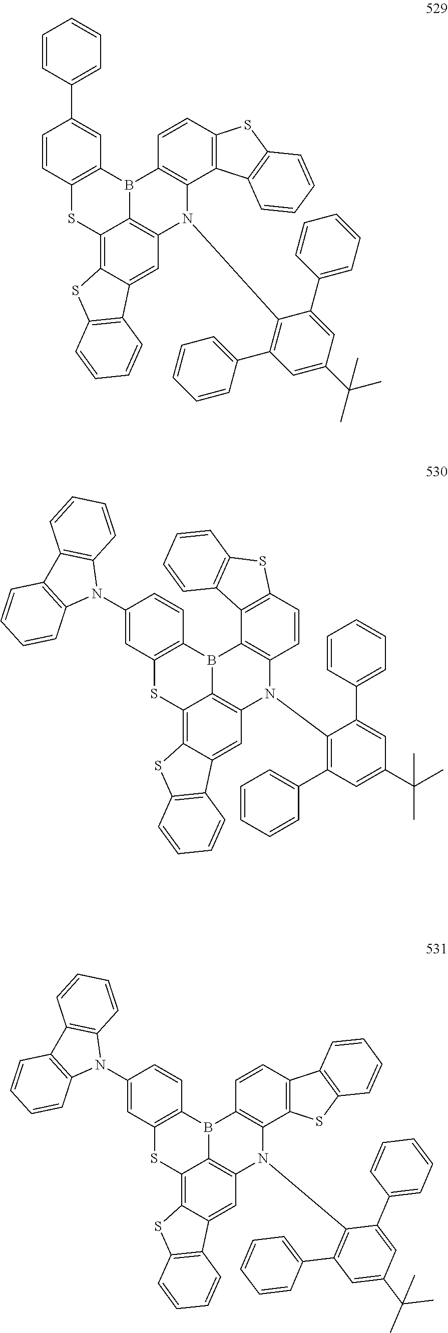 [SMILES: CC(C)(C)c1cc(-c2ccccc2)c(N2c3cc4c(sc5ccccc54)c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4c(sc5ccccc54)c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4c(sc5ccccc54)c4c3B(c3ccc(-n5c6ccccc6c6ccccc65)cc3S4)c3ccc4c(sc5ccccc54)c32)c(-c2ccccc2)c1]

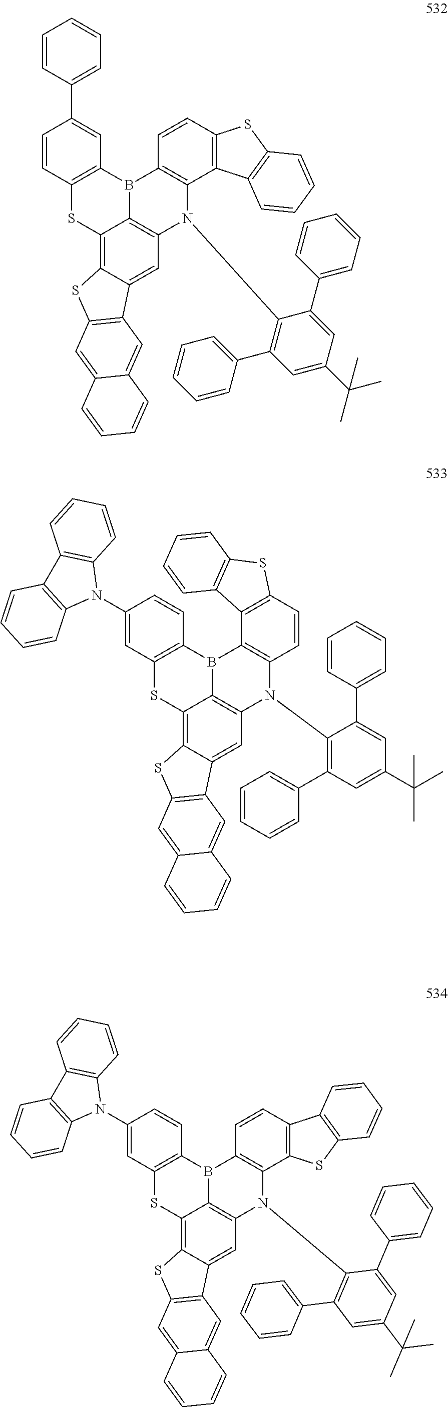 [SMILES: CC(C)(C)c1cc(-c2ccccc2)c(N2c3cc4c(sc5cc6ccccc6cc54)c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4c(sc5cc6ccccc6cc54)c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4c(sc5cc6ccccc6cc54)c4c3B(c3ccc(-n5c6ccccc6c6ccccc65)cc3S4)c3ccc4c(sc5ccccc54)c32)c(-c2ccccc2)c1]

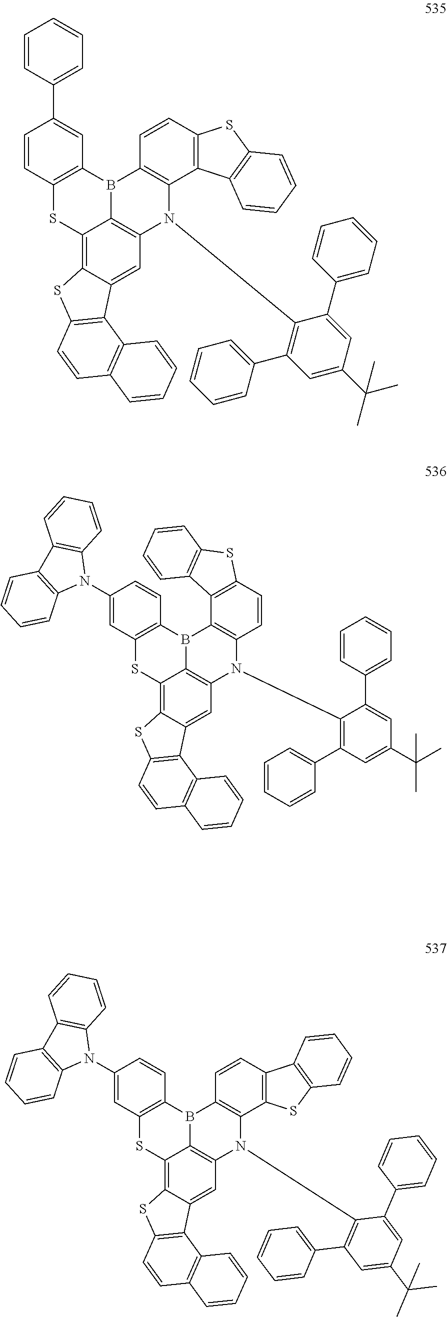 [SMILES: CC(C)(C)c1cc(-c2ccccc2)c(N2c3cc4c(sc5ccc6ccccc6c54)c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4c(sc5ccc6ccccc6c54)c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4c(sc5ccc6ccccc6c54)c4c3B(c3ccc(-n5c6ccccc6c6ccccc65)cc3S4)c3ccc4c(sc5ccccc54)c32)c(-c2ccccc2)c1]

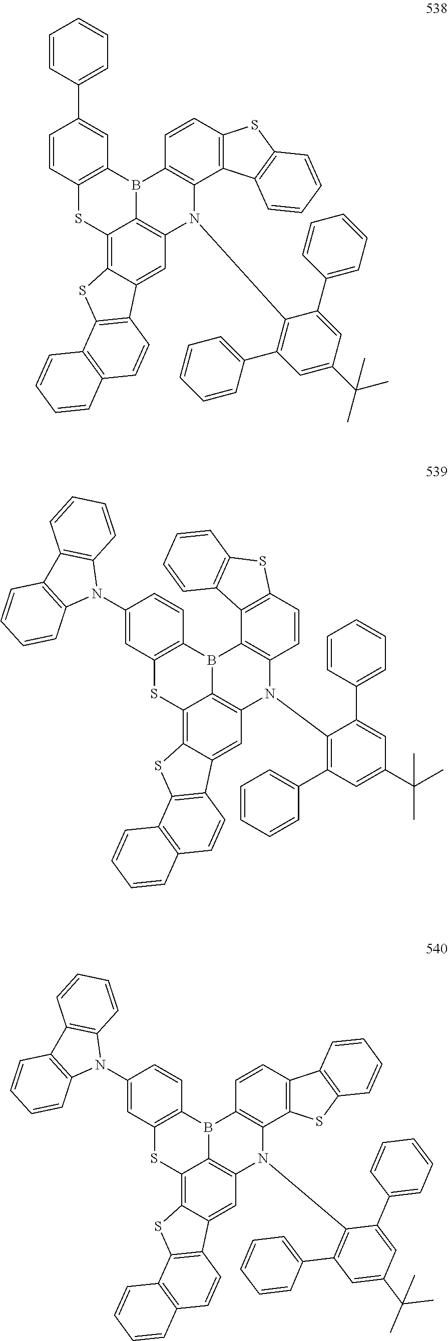 [SMILES: CC(C)(C)c1cc(-c2ccccc2)c(N2c3cc4c(sc5c6ccccc6ccc45)c4c3B(c3cc(-c5ccccc5)ccc3S4)c3ccc4sc5ccccc5c4c32)c(-c2ccccc2)c1 ; CC(C)(C)c1cc(-c2ccccc2)c(N2c3cc4c(sc5c6ccccc6ccc45)c4c3B(c3ccc(-n5c6ccccc6c6ccccc65)cc3S4)c3c2ccc2sc4ccccc4c32)c(-c2ccccc2)c1 ; CC(C)(C)c1cc(-c2ccccc2)c(N2c3cc4c(sc5c6ccccc6ccc45)c4c3B(c3ccc(-n5c6ccccc6c6ccccc65)cc3S4)c3ccc4c(sc5ccccc54)c32)c(-c2ccccc2)c1]

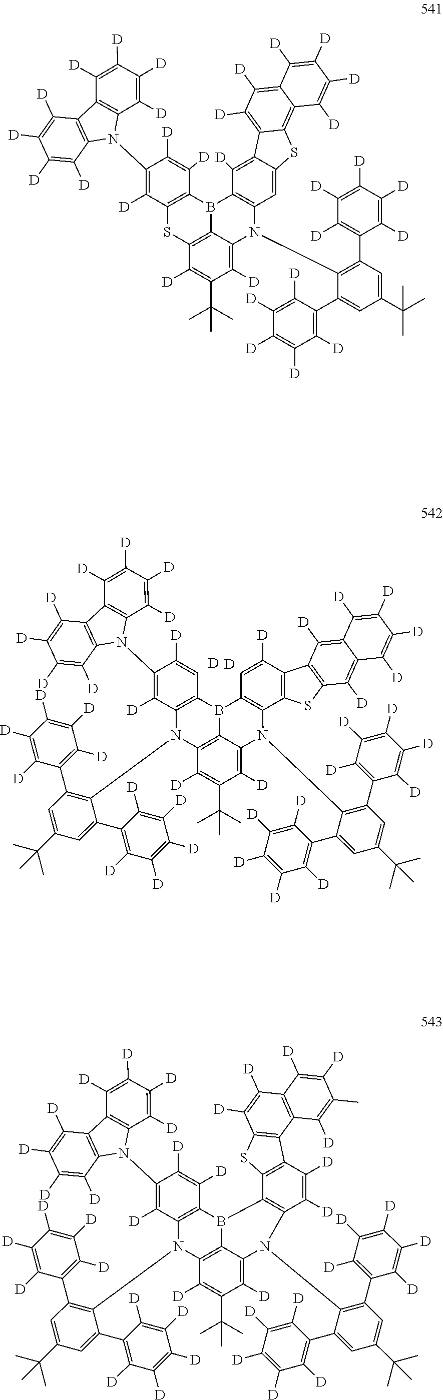

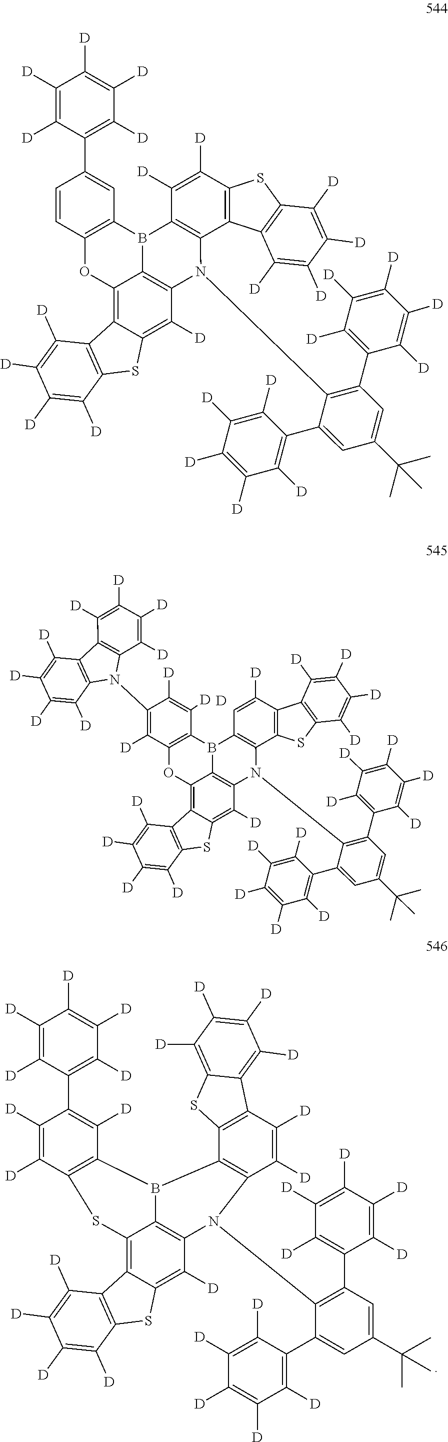

Since the condensed cyclic compound represented by Formula 1 includes a group represented by Formula 1A (e.g., a dibenzothiophene group) in the core thereof, a heavy-atom effect may be exerted, and thus, the efficiency and roll-off ratio characteristics of a light-emitting device including the condensed cyclic compound may be improved.

In an embodiment, since the condensed cyclic compound represented by Formula 1 includes a group represented by Formula 1B as a substituent of a ring-forming nitrogen (N) atom and includes a substituent such as T₁ (e.g., a phenyl group, a carbazolyl group, etc.), interaction with another compound may be suppressed, so that the stability of the condensed cyclic compound may be improved, and thus, the lifespan characteristics of a light-emitting device including the condensed cyclic compound may be improved.

Methods of synthesizing the condensed cyclic compound represented by Formula 1 may be readily understood by one of ordinary skill in the art by referring to the Synthesis Examples and the Examples described below.

In an embodiment, the first electrode of the light-emitting device may be an anode,
the second electrode of the light-emitting device may be a cathode,
the interlayer may further include a hole transport region between the first electrode and the emission layer, and an electron transport region between the emission layer and the second electrode,
the hole transport region may include a hole injection layer, a hole transport layer, an emission auxiliary layer, an electron-blocking layer, or any combination thereof, and
the electron transport region may include a buffer layer, a hole-blocking layer, an electron control layer, an electron transport layer, an electron injection layer, or any combination thereof.

In an embodiment, the condensed cyclic compound may be included between the first electrode and the second electrode of the light-emitting device. Accordingly, the interlayer of the light-emitting device may include the condensed cyclic compound. For example, in an embodiment, the emission layer of the interlayer may include the condensed cyclic compound.

In an embodiment, the condensed cyclic compound in the emission layer may be a thermally activated delayed fluorescence (TADF) emitter, and the emission layer may emit delayed fluorescence. The emission layer may emit red light, green light, blue light, and/or white light. For example, the emission layer may emit blue light. The blue light may have a maximum emission wavelength in a range of, for example, about 400 nm to about 490 nm. For example, the blue light may have a maximum emission wavelength in a range of about 420 nm to about 480 nm. For example, the blue light may have a maximum emission wavelength in a range of about 430 nm to 480 nm. The emission layer may further include a host, and an amount of the host may be greater than an amount of the condensed cyclic compound.

In an embodiment, the emission layer may include the condensed cyclic compound and a host, the condensed cyclic compound in the emission layer may be a dopant, and an amount of the host in the emission layer may be greater than an amount of the condensed cyclic compound in the emission layer.

In an embodiment, the light-emitting device may include a capping layer outside the first electrode or outside the second electrode.

In an embodiment, the light-emitting device may further include at least one of a first capping layer outside the first electrode and a second capping layer outside the second electrode, and at least one of the first capping layer and the second capping layer may include the condensed cyclic compound represented by Formula 1. The first capping layer and/or the second capping layer may be the same as described herein.

In the specification, the term “(interlayer and/or capping layer) includes a condensed cyclic compound” may be understood as “(interlayer and/or capping layer) may include a condensed cyclic compound represented by Formula 1 or two or more different condensed cyclic compounds, each independently represented by Formula 1.”

In an embodiment, the interlayer and/or the capping layer may include Compound 1 only as the condensed cyclic compound. For example, Compound 1 may be present in the emission layer of the light-emitting device. In an embodiment, the interlayer may include, as the condensed cyclic compound, Compound 1 and Compound 2. For example, Compound 1 and Compound 2 may be present in the same layer (e.g., both Compound 1 and Compound 2 may be present in the emission layer), or may be present in different layers (e.g., Compound 1 may be present in the emission layer, and Compound 2 may be present in the electron transport region).

In the specification, the term “interlayer” may be a single layer and/or multiple layers between the first electrode and the second electrode of the light-emitting device.

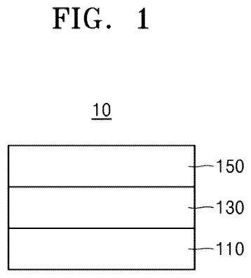

### [Description of FIG. 1]

FIG. 1 is a schematic cross-sectional view of a light-emitting device 10 according to an embodiment. The light-emitting device 10 may include a first electrode 110, an interlayer 130, and a second electrode 150.

Hereinafter, the structure of the light-emitting device 10 according to an embodiment and a method of manufacturing the light-emitting device 10 will be described with reference to FIG. 1.

### [First Electrode 110]

In FIG. 1, a substrate may be further included under the first electrode 110 or on the second electrode 150. In an embodiment, the substrate may be a glass substrate or a plastic substrate. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In an embodiment, when the first electrode 110 is a transflective electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. For example, the first electrode 110 may have a three-layer structure of ITO/Ag/ITO.

### [Interlayer 130]

The interlayer 130 may be arranged on the first electrode 110. The interlayer 130 may include an emission layer.

The interlayer 130 may further include a hole transport region between the first electrode 110 and the emission layer and an electron transport region between the emission layer and the second electrode 150.

The interlayer 130 may further include, in addition to various organic materials, a metal-containing compound such as an organometallic compound, an inorganic material such as a quantum dot, and the like.

In an embodiment, the interlayer 130 may include two or more emitting units stacked between the first electrode 110 and the second electrode 150, and at least one charge generation layer between adjacent units among the two or more emitting units. When the interlayer 130 includes the two or more emitting units and the at least one charge generation layer as described above, the light-emitting device 10 may be a tandem light-emitting device.

### [Hole Transport Region in Interlayer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron-blocking layer, or any combination thereof.

In an embodiment, the hole transport region may have a multi-layer structure, such as a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein the layers of each structure may be stacked from the first electrode 110 in its respective stated order, but the structure of the hole transport region is not limited thereto.

In embodiments, the hole transport region may include a compound represented by Formula 201, a compound represented by Formula 202, or any combination thereof:

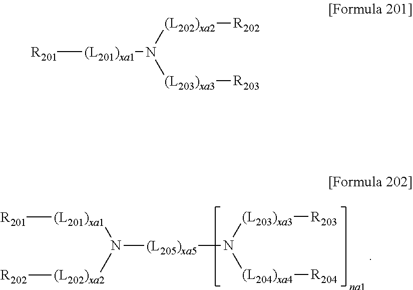

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217:

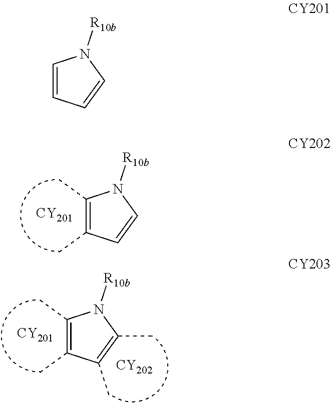

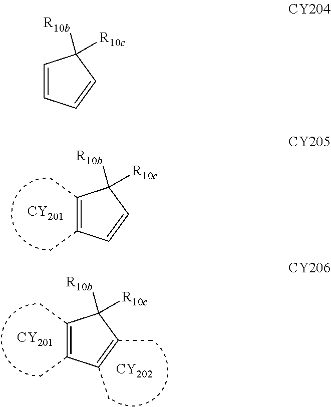

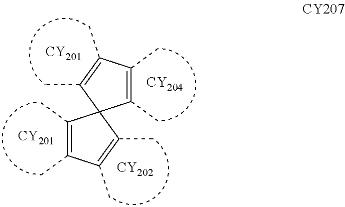

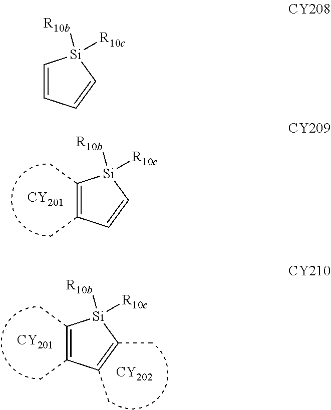

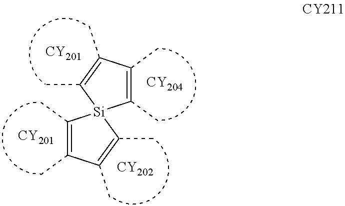

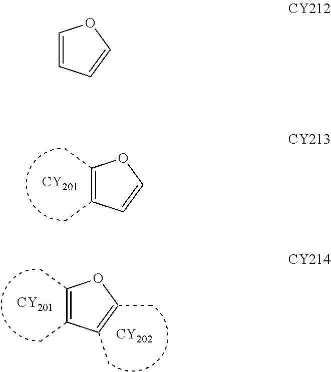

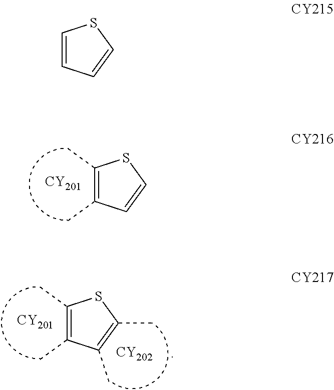

In Formulae CY201 to CY217, R_{10b} and R_{10c} may each be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY₂₀₁ to ring CY₂₀₄ may each independently be a benzene group, a naphthalene group, a phenanthrene group, or an anthracene group.

In an embodiment, the compound represented by Formula 201 and the compound represented by Formula 202 may each include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203 and may each independently include at least one of groups represented by Formulae CY204 to CY217.

In an embodiment, the compound represented by Formula 201 and the compound represented by Formula 202 may each not include groups represented by Formulae CY201 to CY217.

In an embodiment, the hole transport region may include one of Compounds HT1 to HT46, m-MTDATA, TDATA, 2-TNATA, NPB (NPD), β-NPB, TPD, spiro-TPD, spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA); polyaniline/poly(4-styrenesulfonate) (PANI/PSS), or any combination thereof:

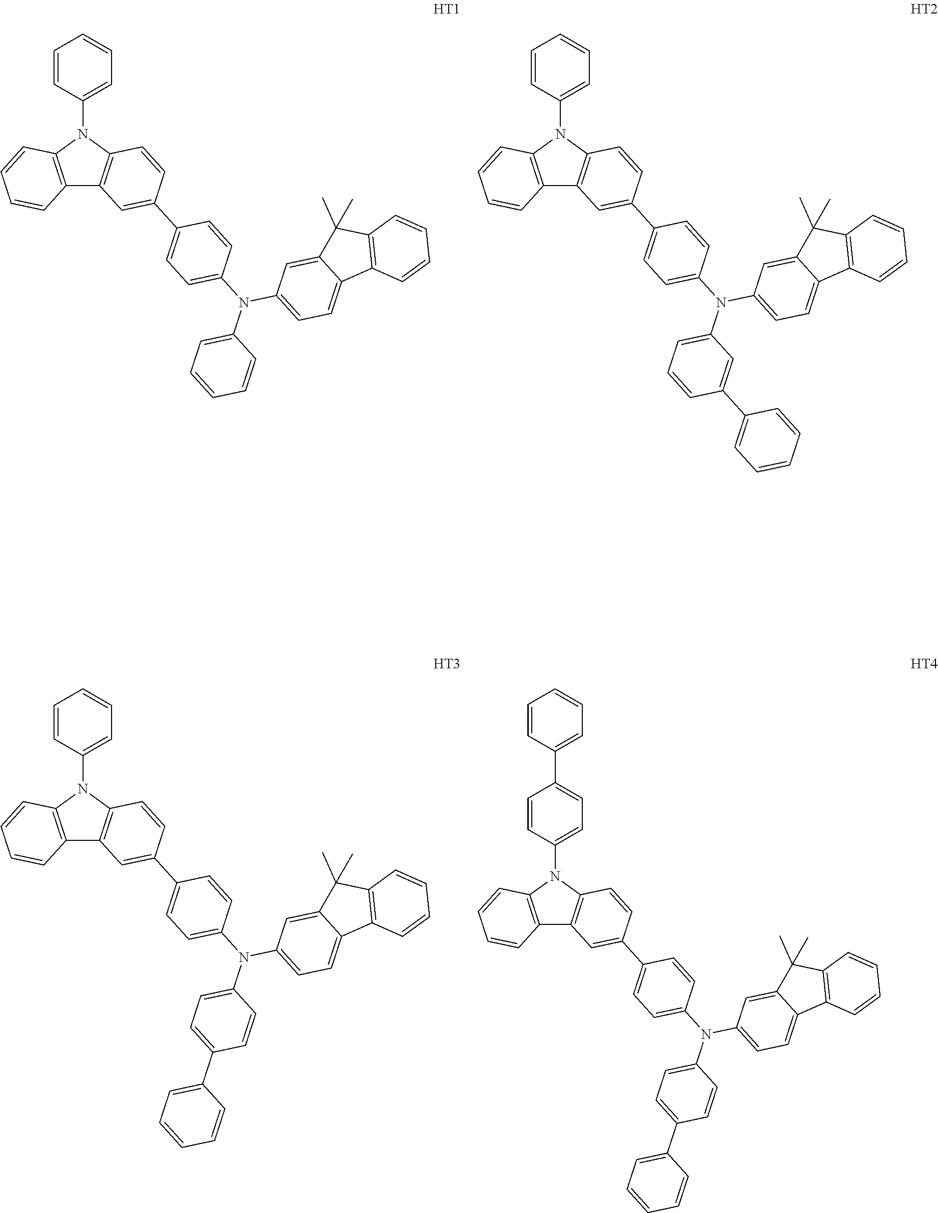 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc5c(c4)c4ccccc4n5-c4ccc(-c5ccccc5)cc4)cc3)cc21]

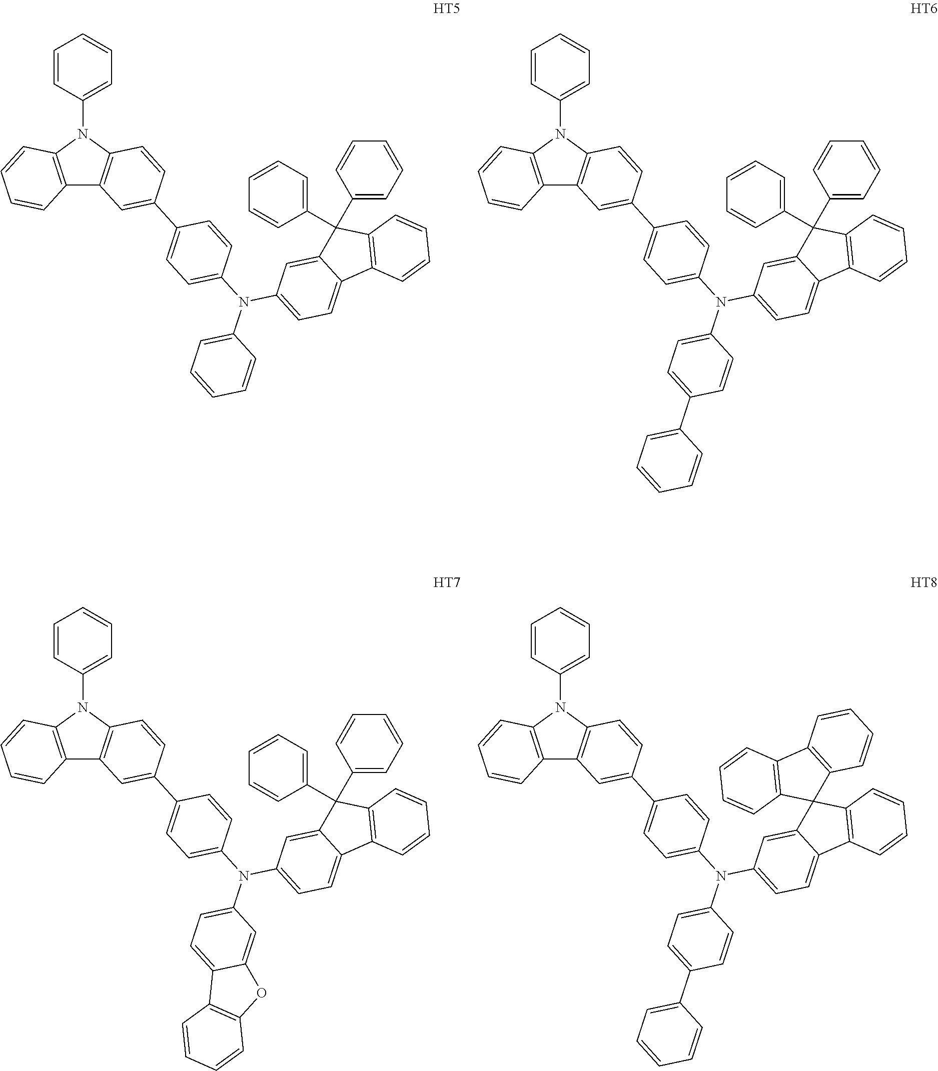 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

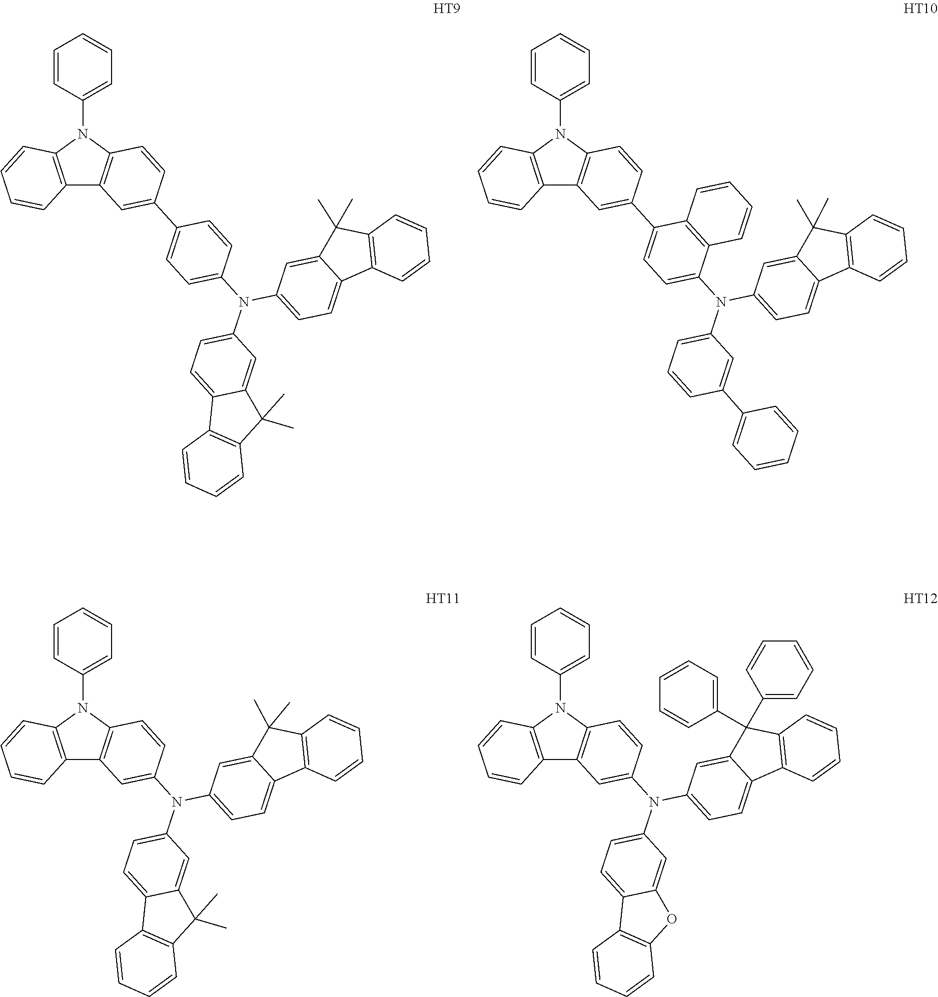 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

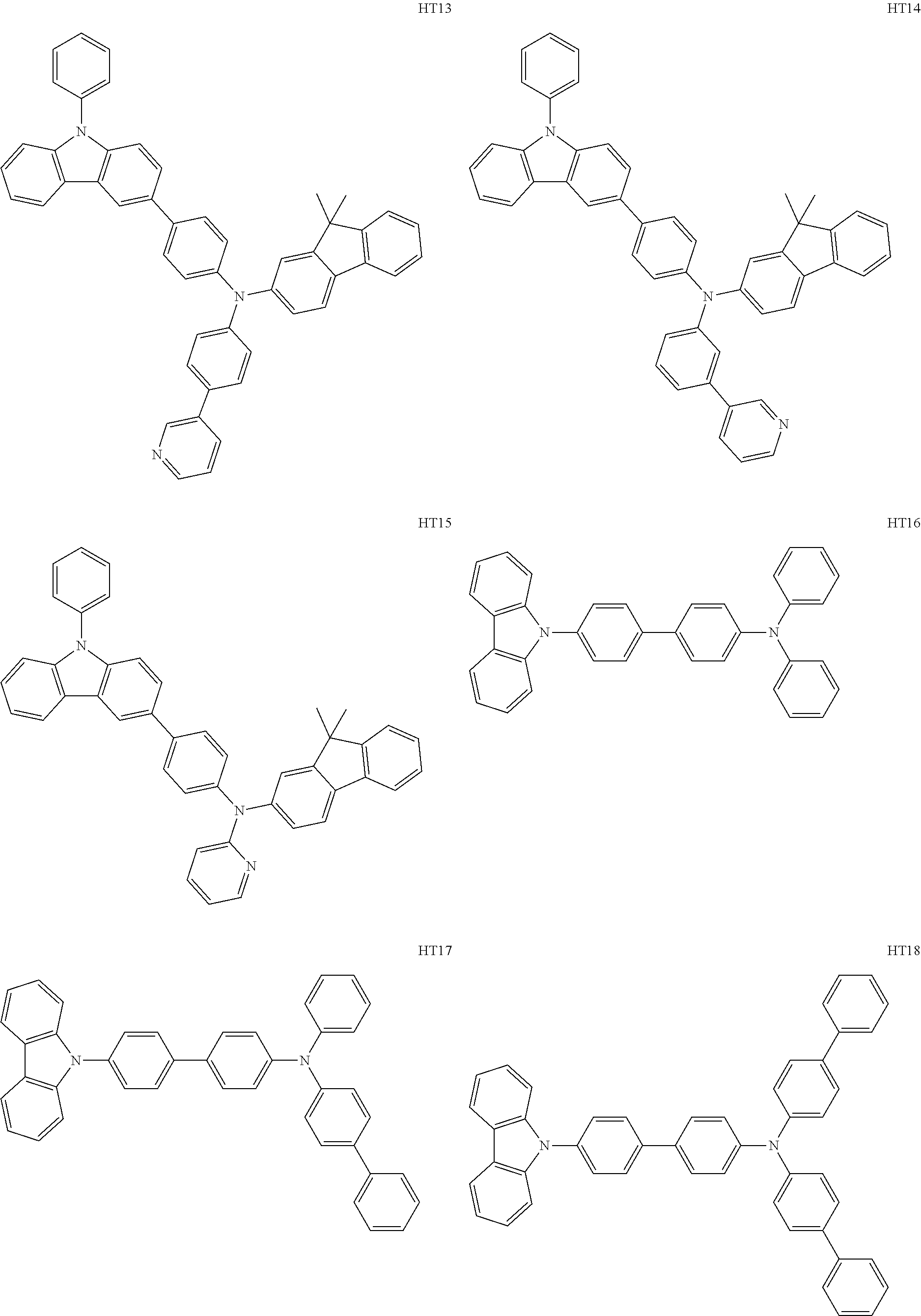 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

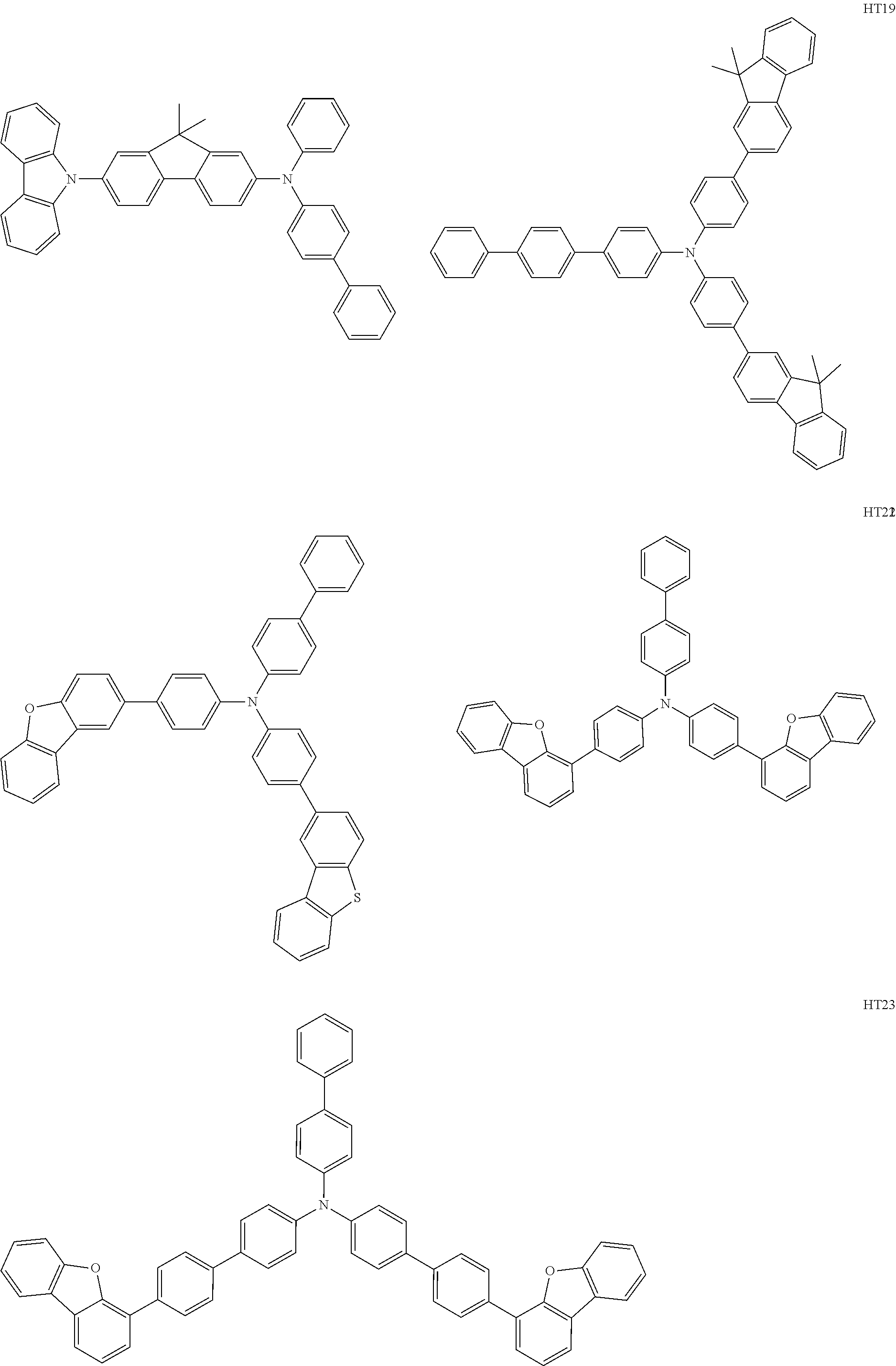 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

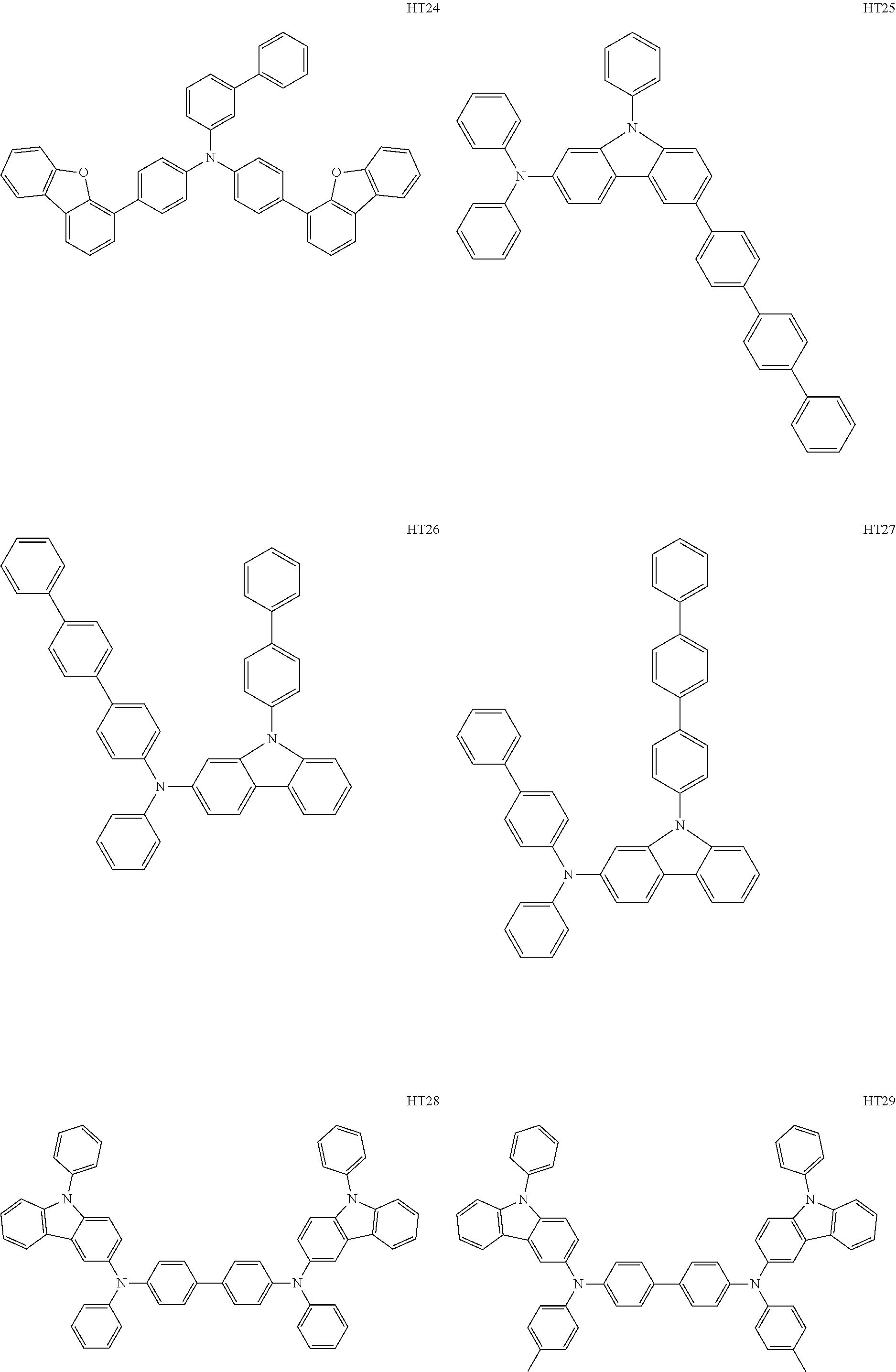

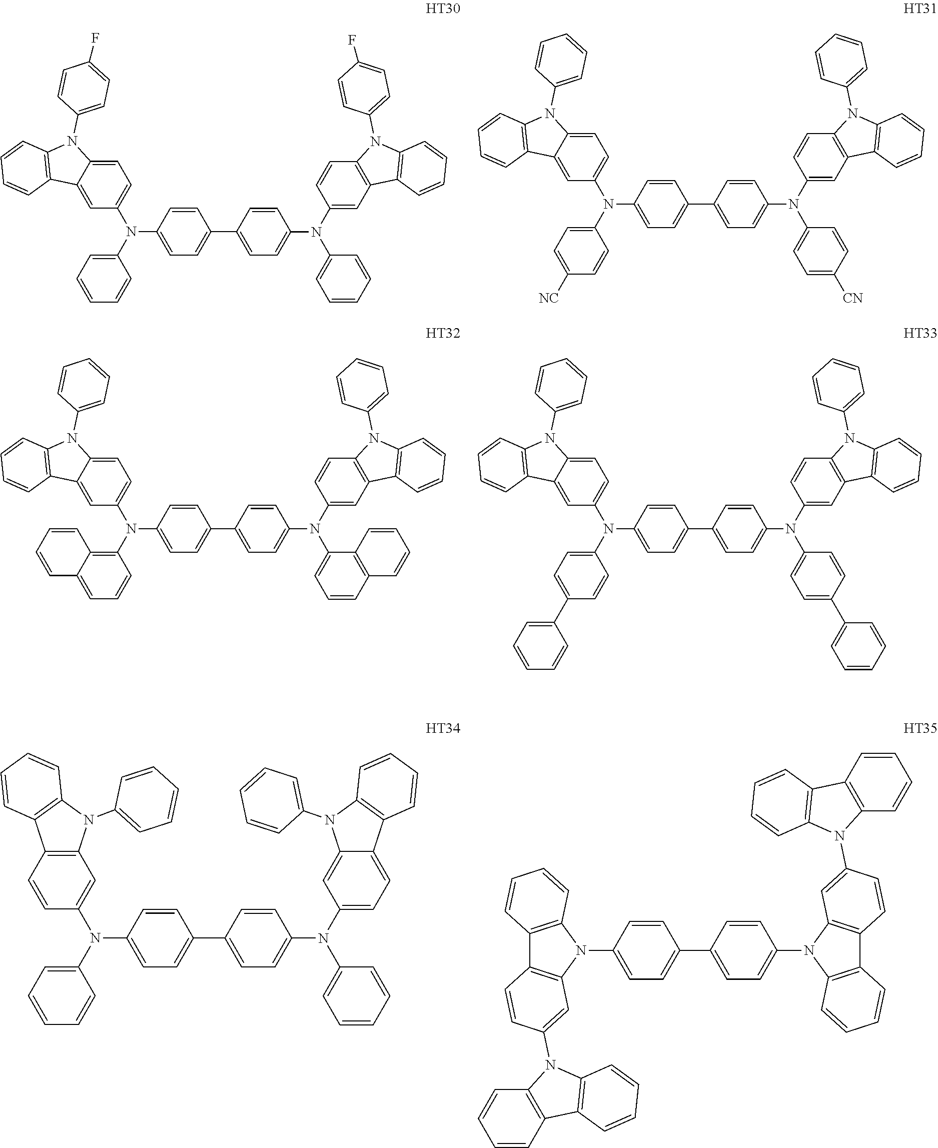

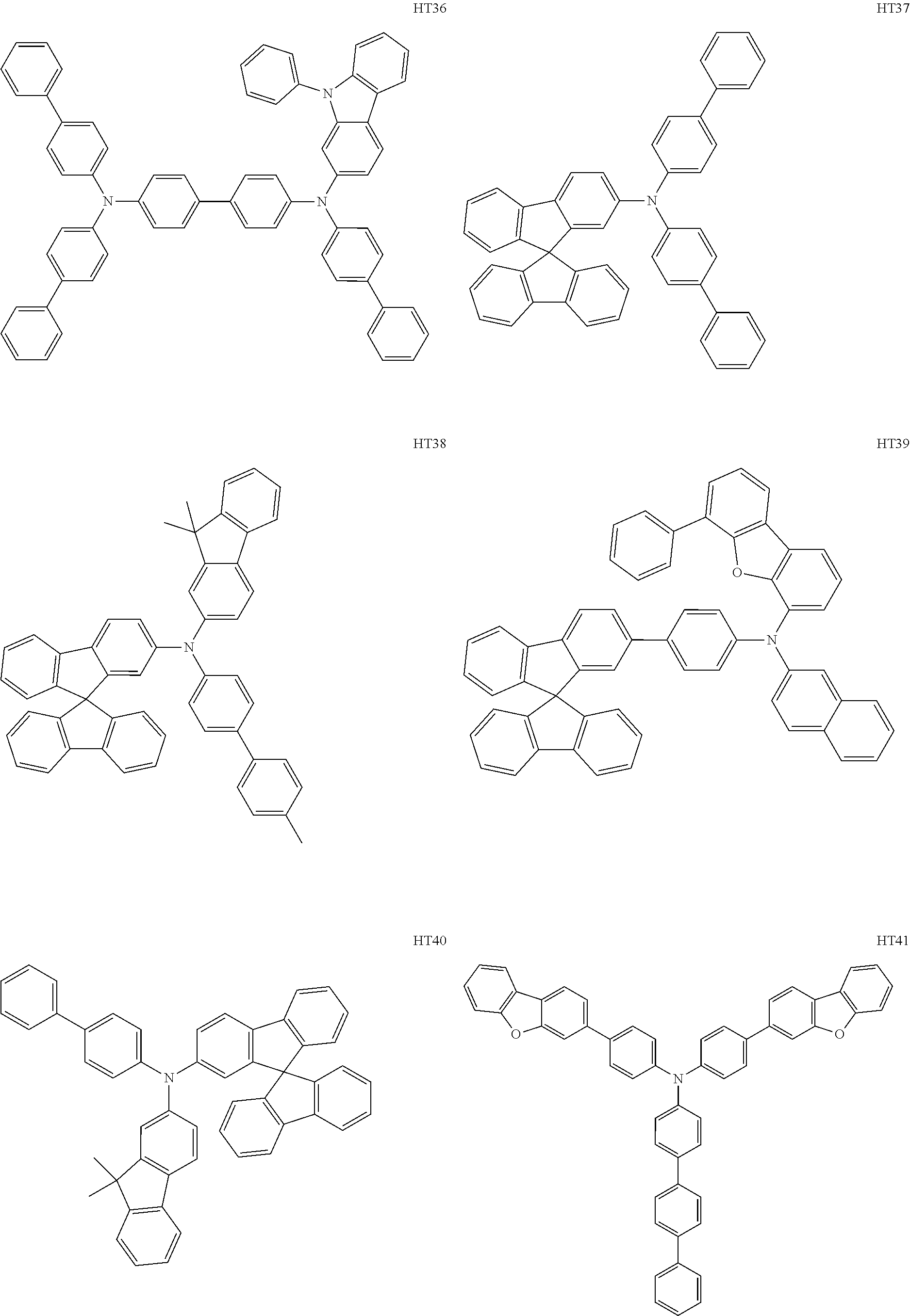

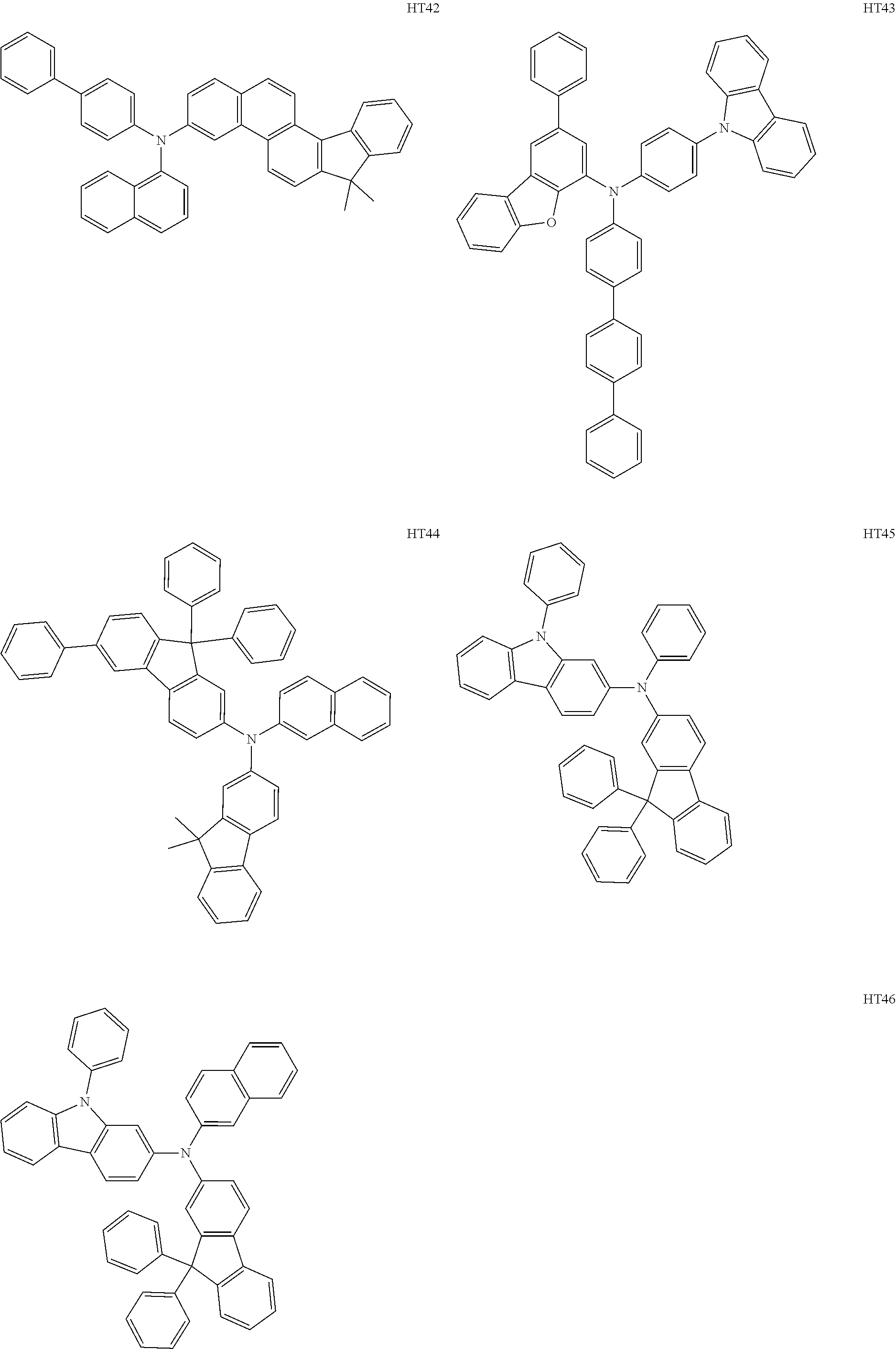 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

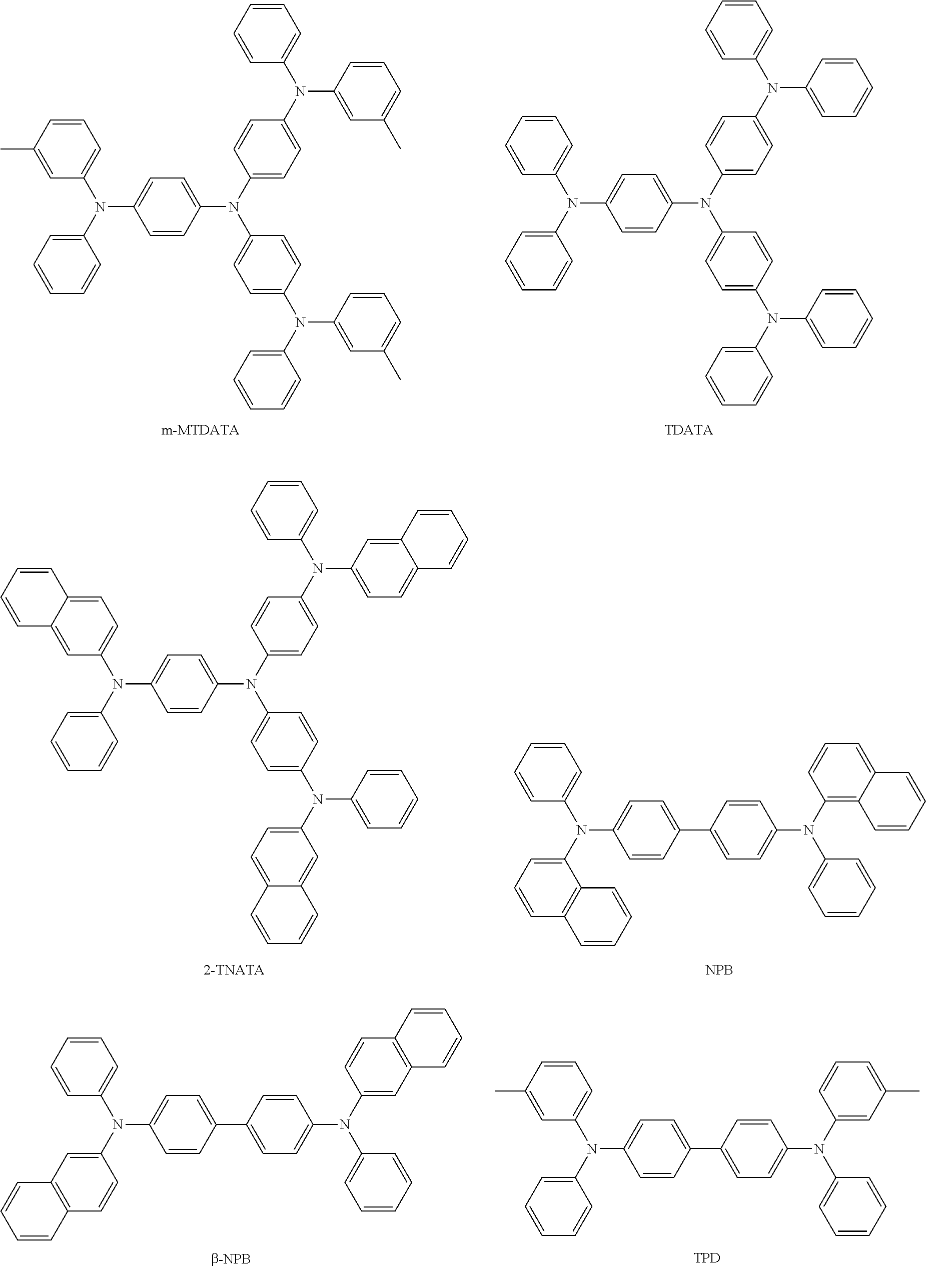

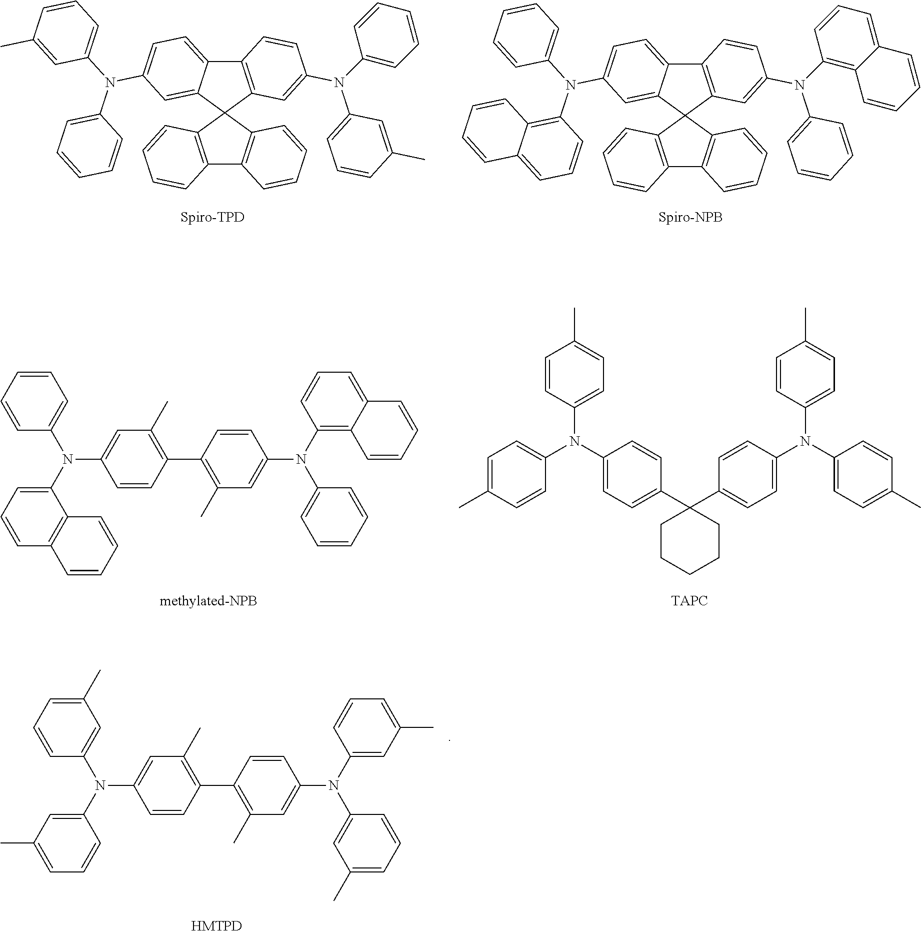

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within the ranges described above, satisfactory hole-transporting characteristics may be obtained without a substantial increase in driving voltage.

The emission auxiliary layer may increase light-emission efficiency by compensating for an optical resonance distance according to a wavelength of light emitted by the emission layer, and the electron-blocking layer may block the leakage of electrons from the emission layer to the hole transport region. Materials that may be included in the hole transport region may be included in the emission auxiliary layer and the electron-blocking layer.

[p-Dopant]

The hole transport region may further include, in addition to the materials described above, a charge-generation material for the improvement of conductive properties. The charge-generation material may be uniformly or non-uniformly dispersed in the hole transport region (e.g., in the form of a single layer consisting of a charge-generation material).

The charge-generation material may be, for example, a p-dopant.

In an embodiment, the p-dopant may have a lowest unoccupied molecular orbital (LUMO) energy level less than or equal to about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

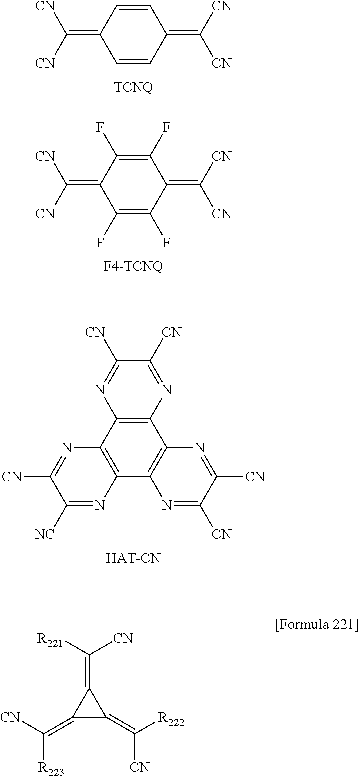

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (e.g., lithium (Li), sodium (Na), potassium (K), rubidium (Rb), cesium (Cs), etc.); an alkaline earth metal (e.g., beryllium (Be), magnesium (Mg), calcium (Ca), strontium (Sr), barium (Ba), etc.); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (e.g., zinc (Zn), indium (In), tin (Sn), etc.); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), a halogen (e.g., F, Cl, Br, I, etc.), and the like.

Examples of a compound including element EL1 and element EL2 may include a metal oxide, a metal halide (e.g., a metal fluoride, a metal chloride, a metal bromide, a metal iodide, etc.), a metalloid halide (e.g., a metalloid fluoride, a metalloid chloride, a metalloid bromide, a metalloid iodide, etc.), a metal telluride, or any combination thereof.

Examples of a metal oxide may include a tungsten oxide (e.g., WO, W₂O₃, WO₂, WO₃, W₂O₅, etc.), a vanadium oxide (e.g., VO, V₂O₃, VO₂, V₂O₅, etc.), a molybdenum oxide (e.g., MoO, Mo₂O₃, MoO₂, MoO₃, Mo₂O₅, etc.), a rhenium oxide (e.g., ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiC, NaCl, KCl, RbCI, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, Mg₁₂, CaI₂, SrI₂, BaI₂, and the like.

Examples of a transition metal halide may include a titanium halide (e.g., TiF₄, TiCl₄, TiBr₄, TiI₄, etc.), a zirconium halide (e.g., ZrF₄, ZrCl₄, ZrBr₄, ZrI₄, etc.), a hafnium halide (e.g., HfF₄, HfCl₄, HfBr₄, HfI₄, etc.), a vanadium halide (e.g., VF₃, VCI₃, VBr₃, VI₃, etc.), a niobium halide (e.g., NbF₃, NbCI₃, NbBr₃, NbI₃, etc.), a tantalum halide (e.g., TaF₃, TaCl₃, TaBr₃, TaI₃, etc.), a chromium halide (e.g., CrF₃, CrO₃, CrBr₃, CrI₃, etc.), a molybdenum halide (e.g., MoF₃, MoCl₃, MoBr₃, MoI₃, etc.), a tungsten halide (e.g., WF₃, WCl₃, WBr₃, WI₃, etc.), a manganese halide (e.g., MnF₂, MnCl₂, MnBr₂, MnI₂, etc.), a technetium halide (e.g., TcF₂, TcCl₂, TcBr₂, TcI₂, etc.), a rhenium halide (e.g., ReF₂, ReCl₂, ReBr₂, ReI₂, etc.), an iron halide (e.g., FeF₂, FeCl₂, FeBr₂, FeI₂, etc.), a ruthenium halide (e.g., RuF₂, RuCl₂, RuBr₂, RuI₂, etc.), an osmium halide (e.g., OsF₂, OsCl₂, OsBr₂, OsI₂, etc.), a cobalt halide (e.g., CoF₂, COCl₂, CoBr₂, CoI₂, etc.), a rhodium halide (e.g., RhF₂, RhCl₂, RhBr₂, RhI₂, etc.), an iridium halide (e.g., IrF₂, IrCl₂, IrBr₂, IrI₂, etc.), a nickel halide (e.g., NiF₂, NiCl₂, NiBr₂, NiI₂, etc.), a palladium halide (e.g., PdF₂, PdCl₂, PdBr₂, PdI₂, etc.), a platinum halide (e.g., PtF₂, PtCl₂, PtBr₂, PtI₂, etc.), a copper halide (e.g., CuF, CuCl, CuBr, CuI, etc.), a silver halide (e.g., AgF, AgCl, AgBr, AgI, etc.), a gold halide (e.g., AuF, AuCI, AuBr, AuI, etc.), and the like.

Examples of a post-transition metal halide may include a zinc halide (e.g., ZnF₂, ZnCl₂, ZnBr₂, ZnI₂, etc.), an indium halide (e.g., InI₃, etc.), a tin halide (e.g., SnI₂, etc.), and the like.

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and the like.

Examples of a metalloid halide may include an antimony halide (e.g., SbCl₅, etc.) and the like.

Examples of a metal telluride may include an alkali metal telluride (e.g., Li₂Te, Na₂Te, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

### [Emission Layer in Interlayer 130]

When the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other, to emit white light. In an embodiment, the emission layer may include two or more materials of a red light-emitting material, a green light-emitting material, and a blue light-emitting material, in which the two or more materials may be mixed with each other in a single layer, to emit white light. For example, the emission layer may emit blue light.

In an embodiment, the emission layer may include the condensed cyclic compound represented by Formula 1 as described herein.

The emission layer may include a host and a dopant.

In an embodiment, the dopant may include the condensed cyclic compound represented by Formula 1 as described herein. For example, the dopant may include, in addition to the condensed cyclic compound represented by Formula 1, a phosphorescent dopant, a fluorescent dopant, or any combination thereof. In an embodiment, in addition to the condensed cyclic compound represented by Formula 1, the phosphorescent dopant, the fluorescent dopant, and the like that may be further included in the emission layer may each be the same as described herein.

An amount of the dopant in the emission layer may be in a range of about 0.01 parts by weight to about 15 parts by weight, based on 100 parts by weight of the host.

In an embodiment, the emission layer may include a quantum dot.

In the specification, a quantum dot may be a crystal of a semiconductor compound, and may include any material capable of emitting light of various emission wavelengths according to the size of the crystal.

In an embodiment, the emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within any of the ranges described above, excellent luminescence characteristics may be obtained without a substantial increase in driving voltage.

### [Host]

The host may include a compound represented by Formula 301:

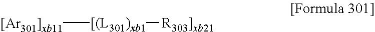

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to 0303 may each independently be the same as described in connection with Q₁.

In an embodiment, in Formula 301, when xb11 is 2 or more, two or more of Ar₃₀₁ may be linked to each other via a single bond.

In an embodiment, the host may include a compound represented by Formula 301-1, a compound represented by Formula 301-2, or any combination thereof:

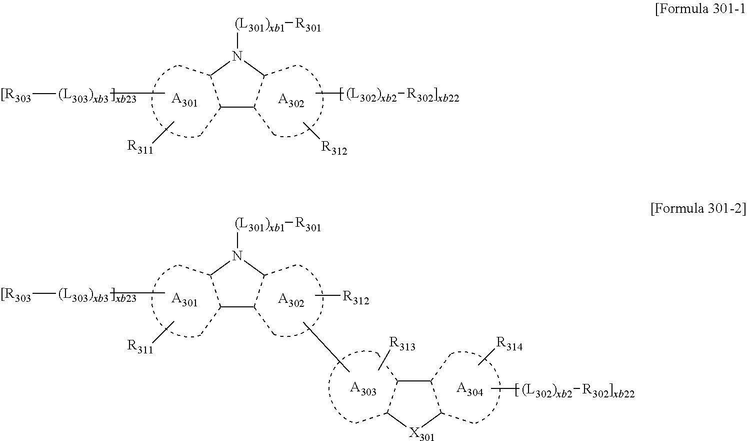

In Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkali earth metal complex, a post-transition metal complex, or any combination thereof. For example, the host may include a Be complex (e.g., Compound H55), a Mg complex, a Zn complex, or any combination thereof.

In an embodiment, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

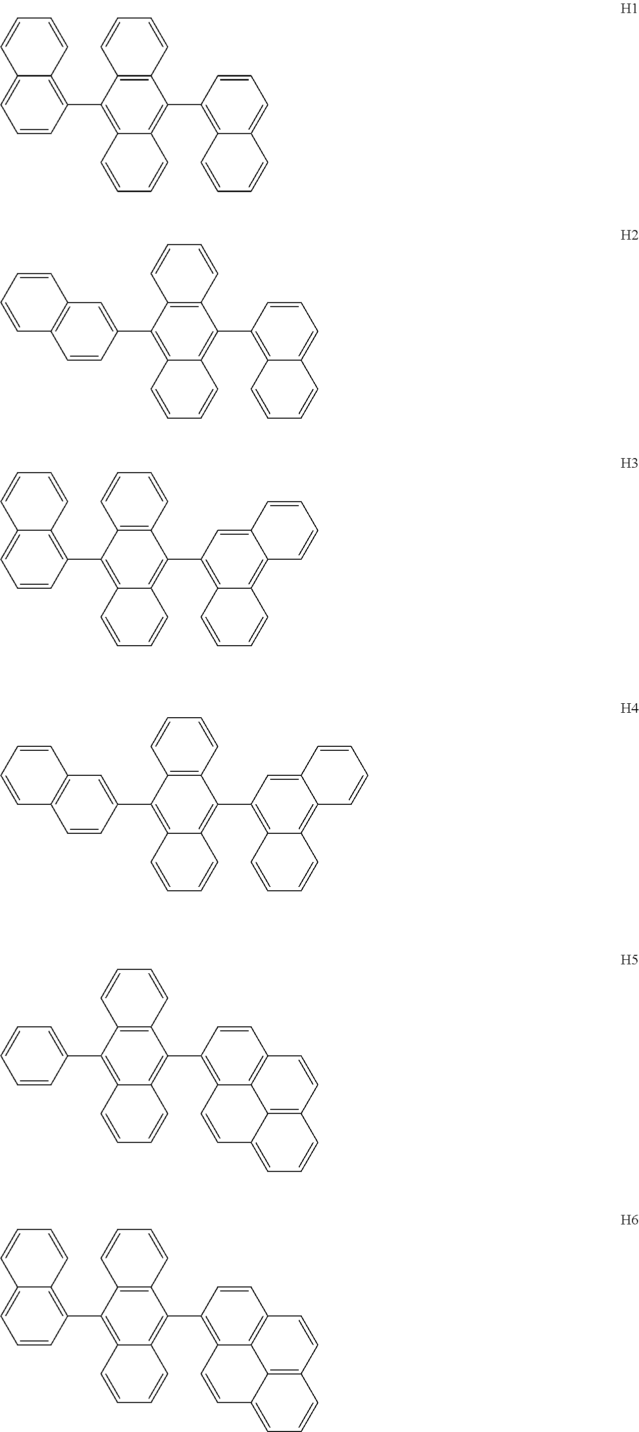

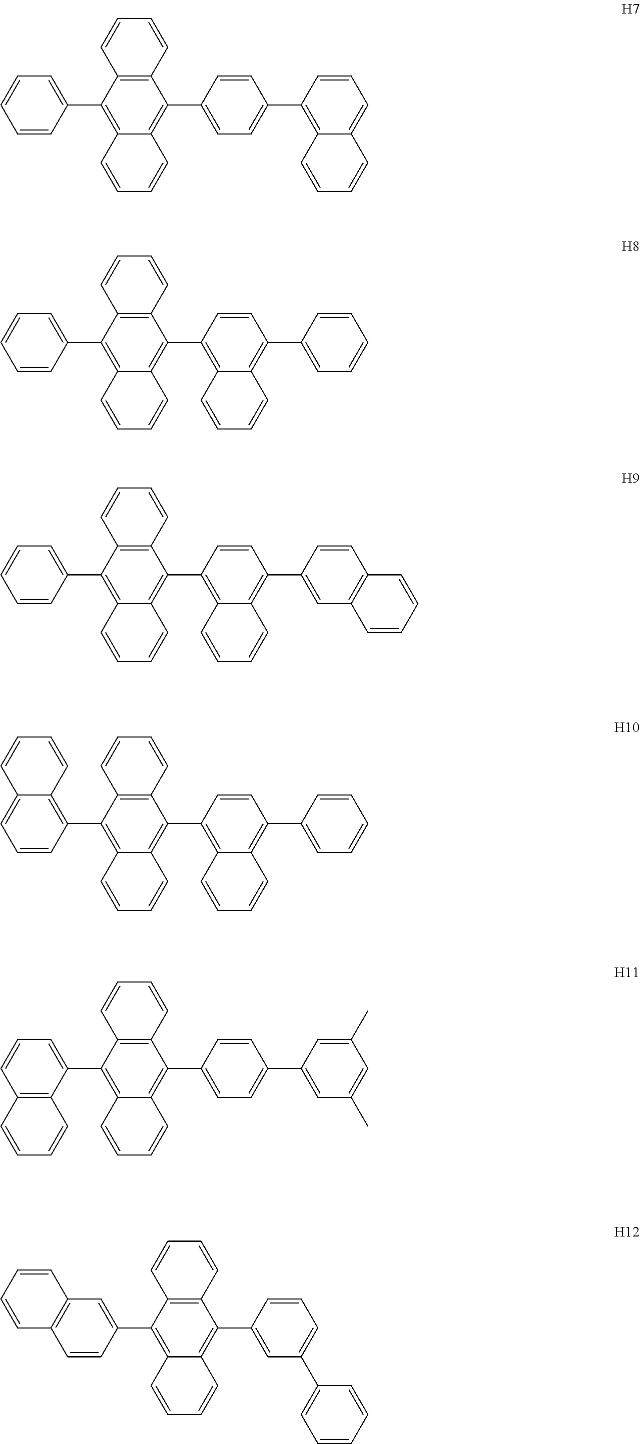

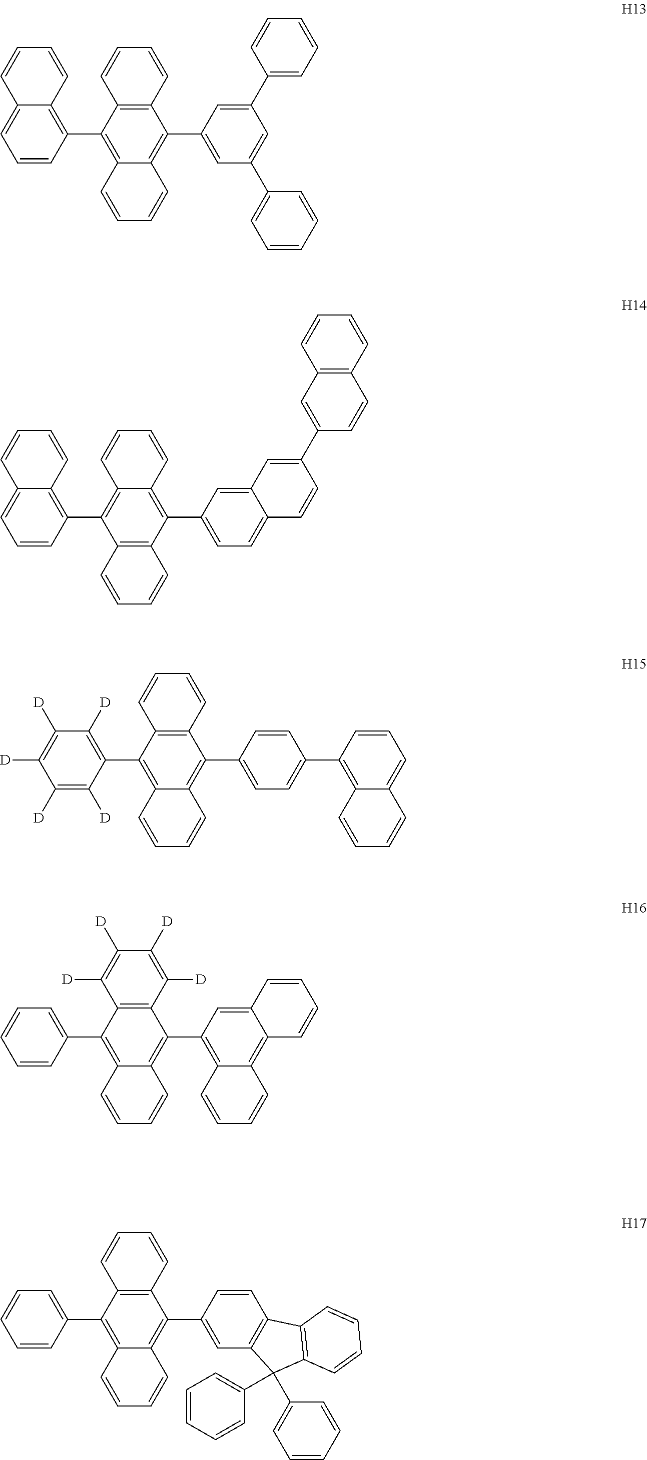

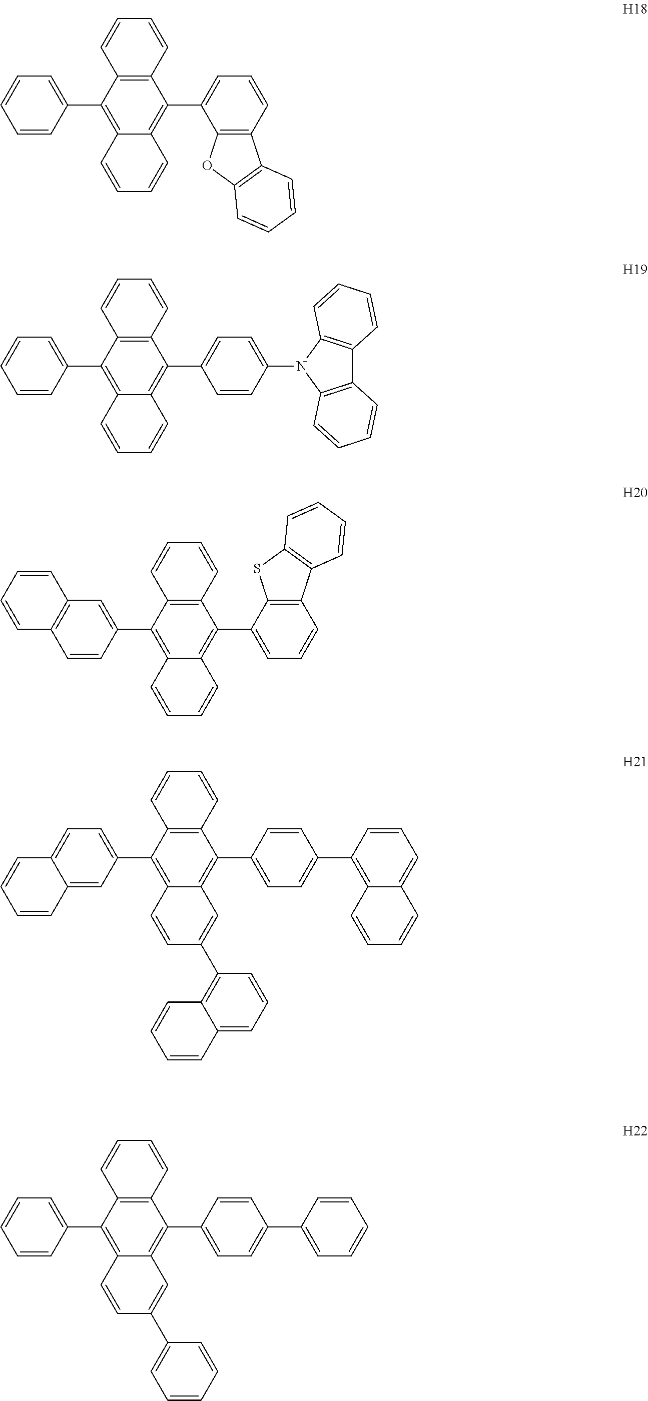

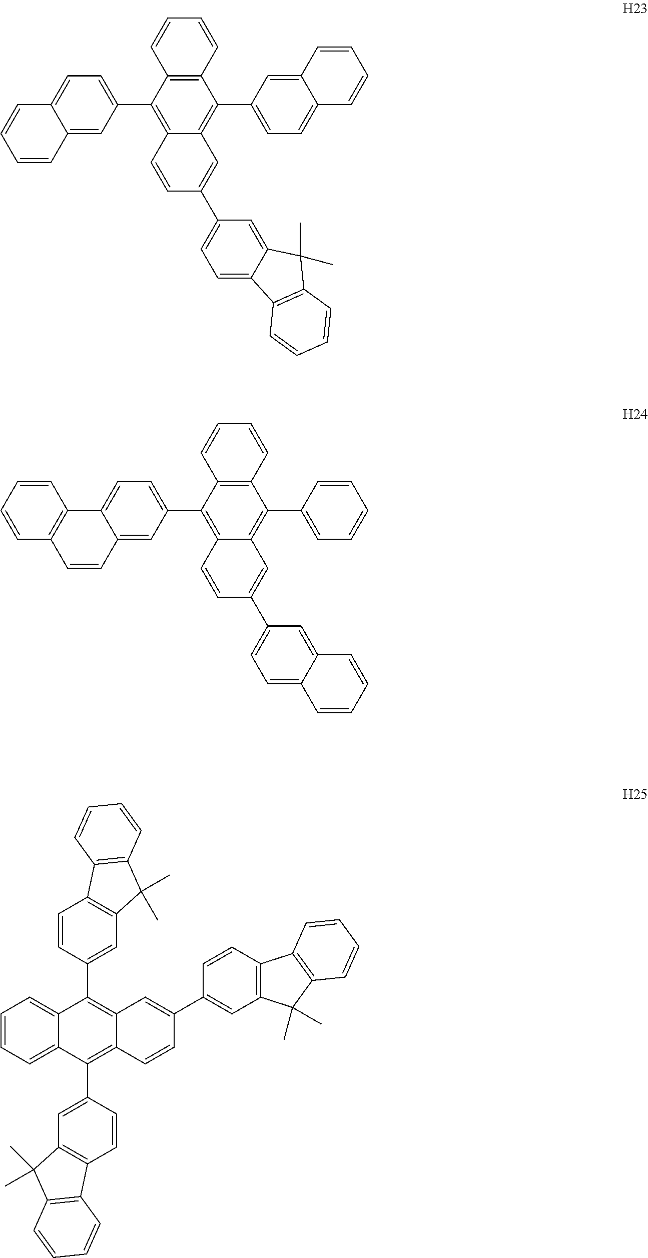

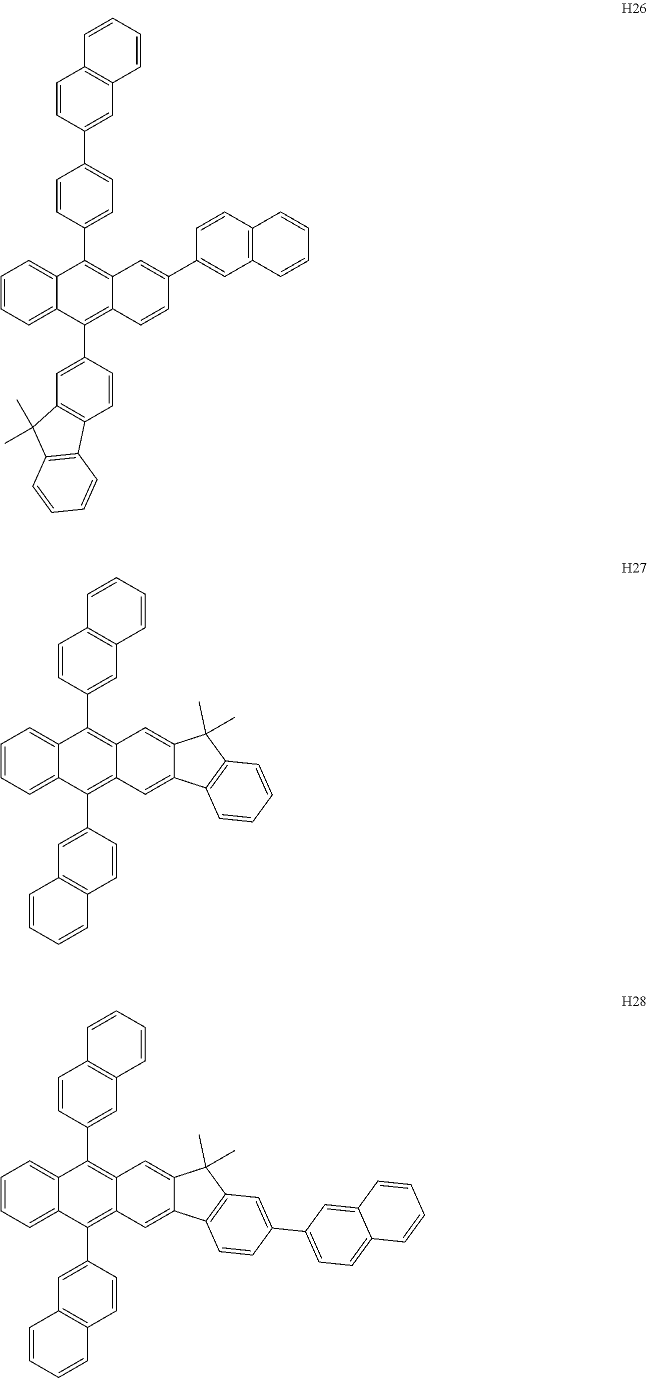

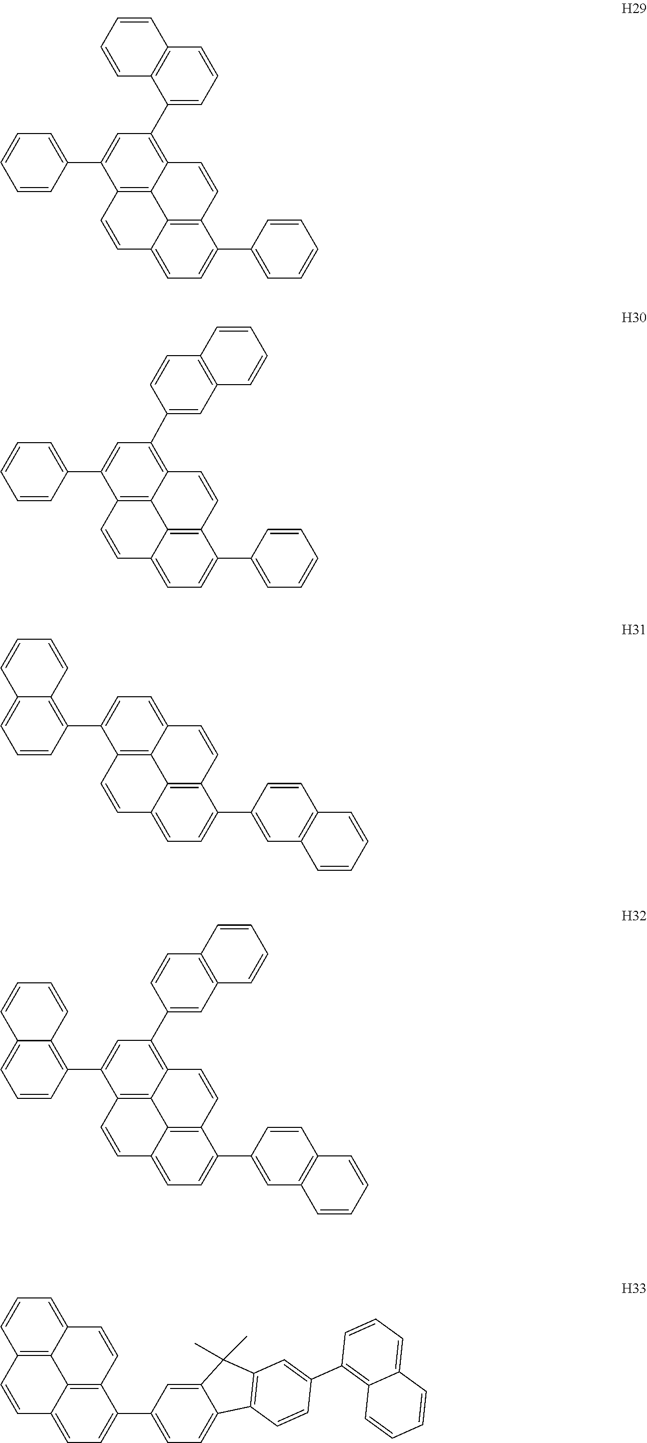

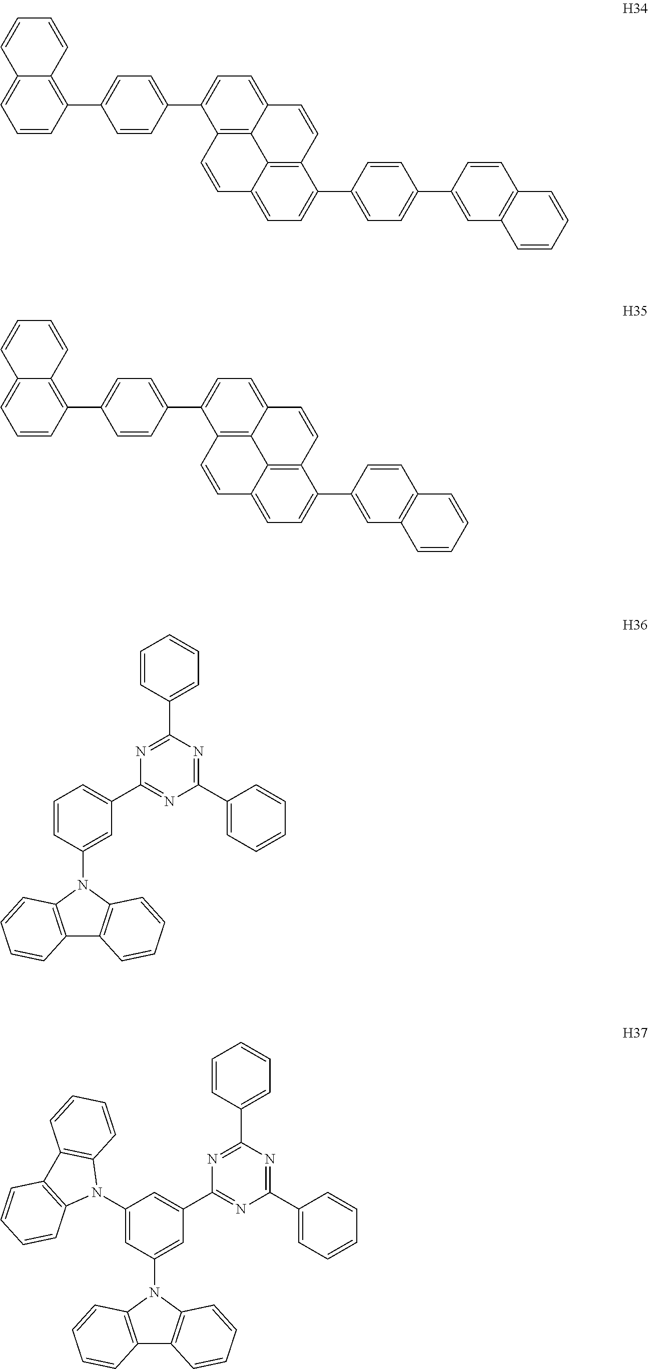

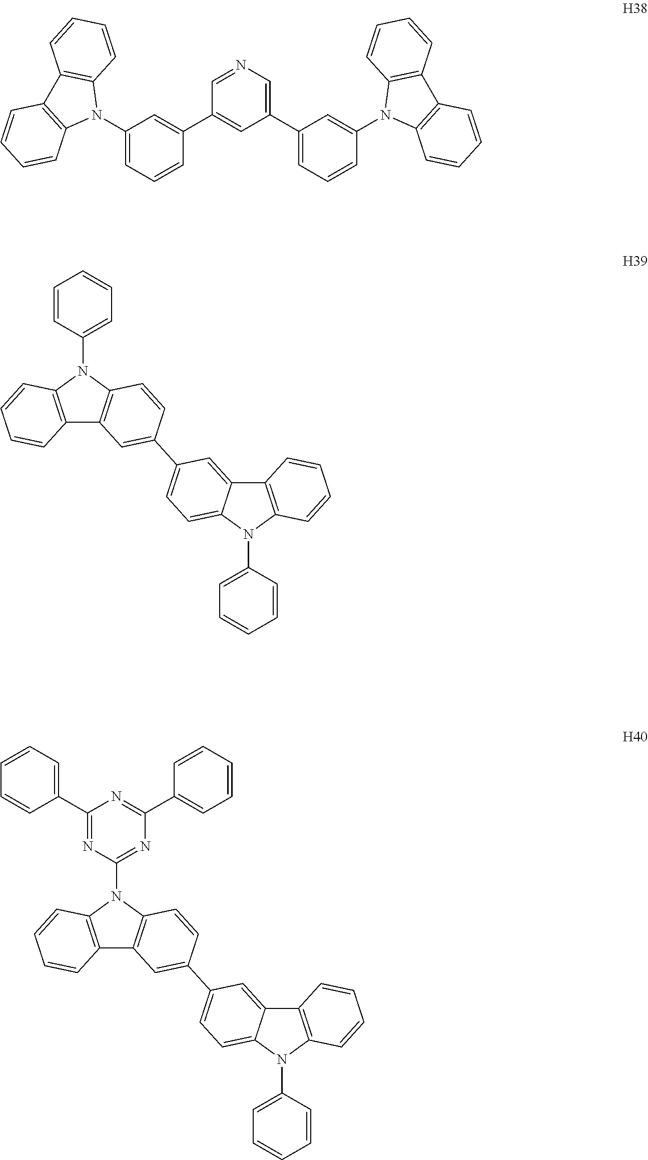 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

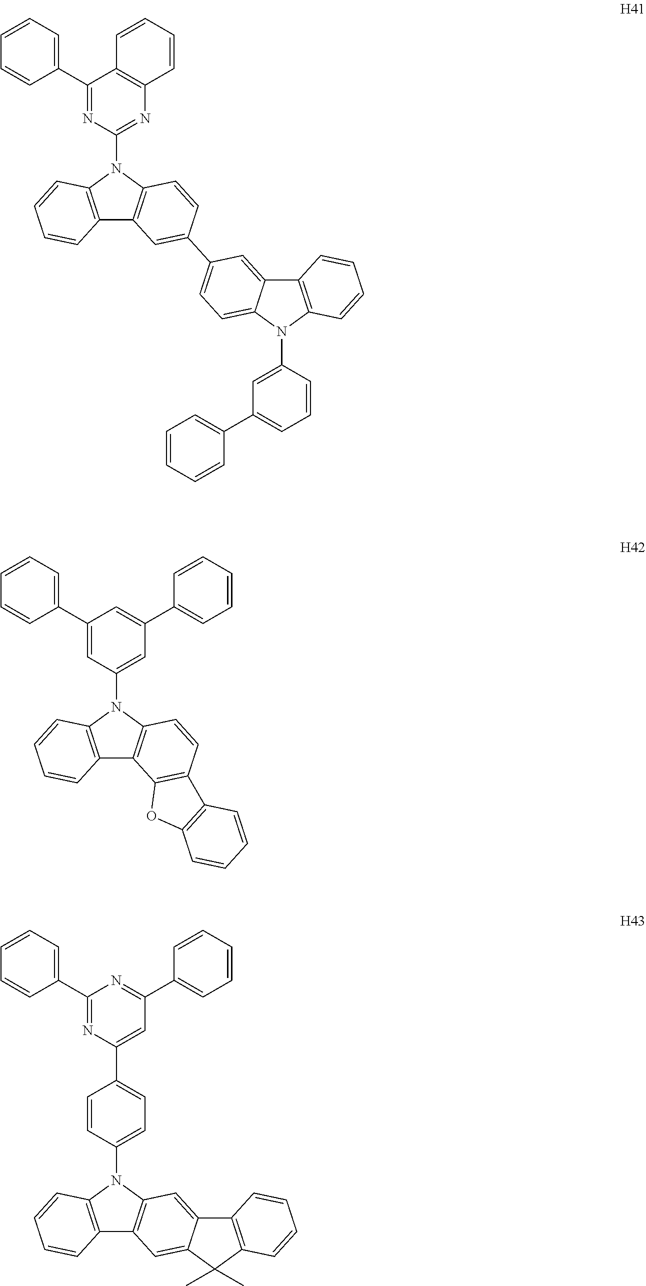 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

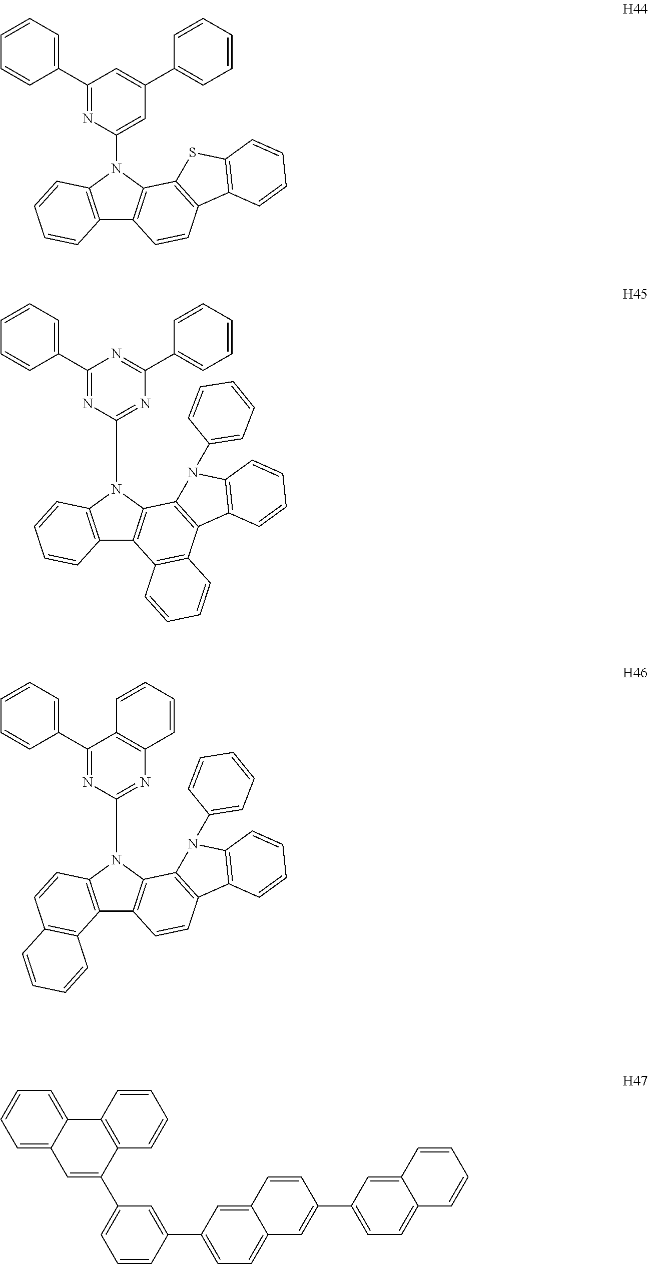

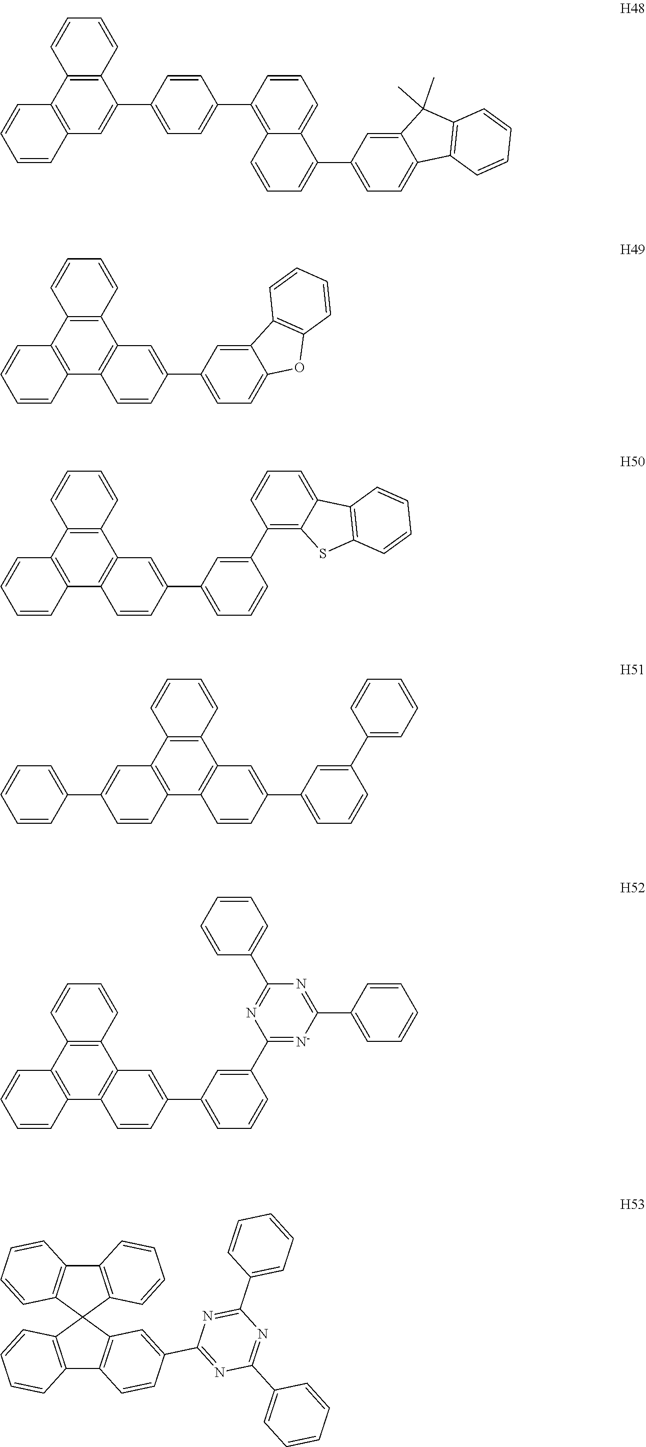

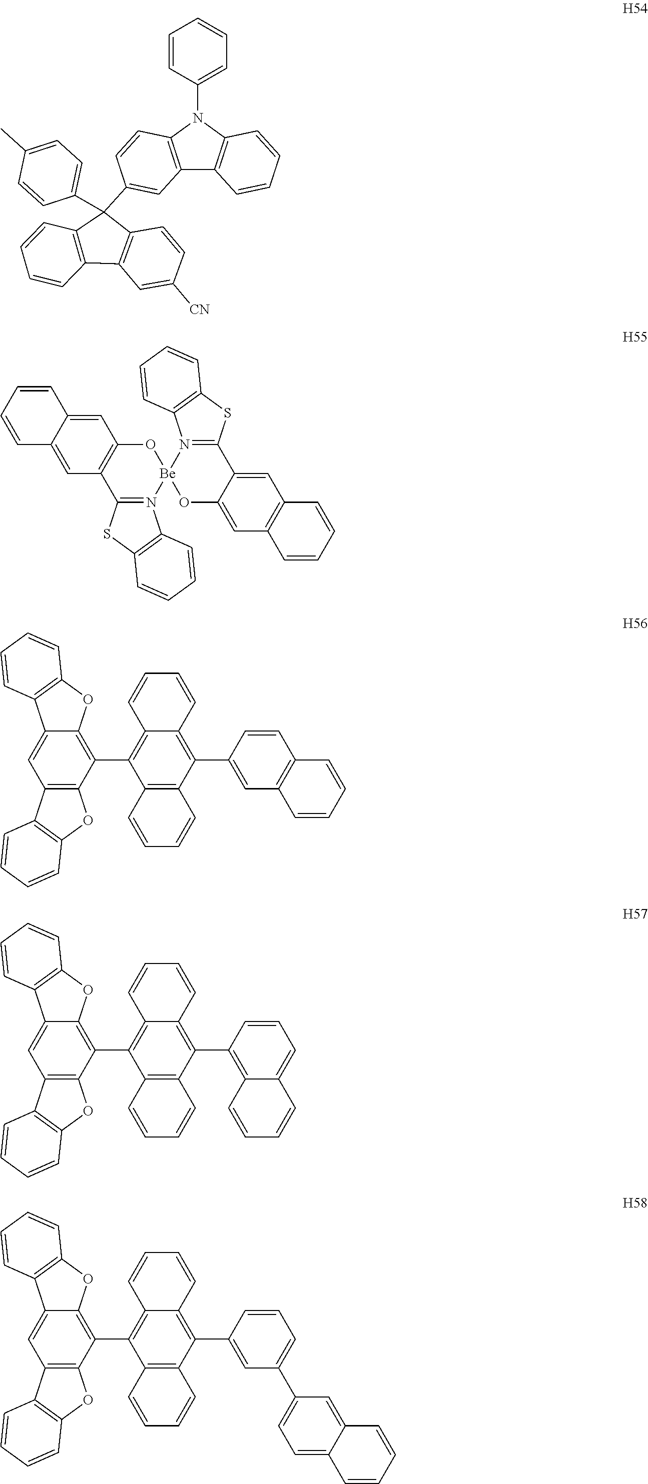

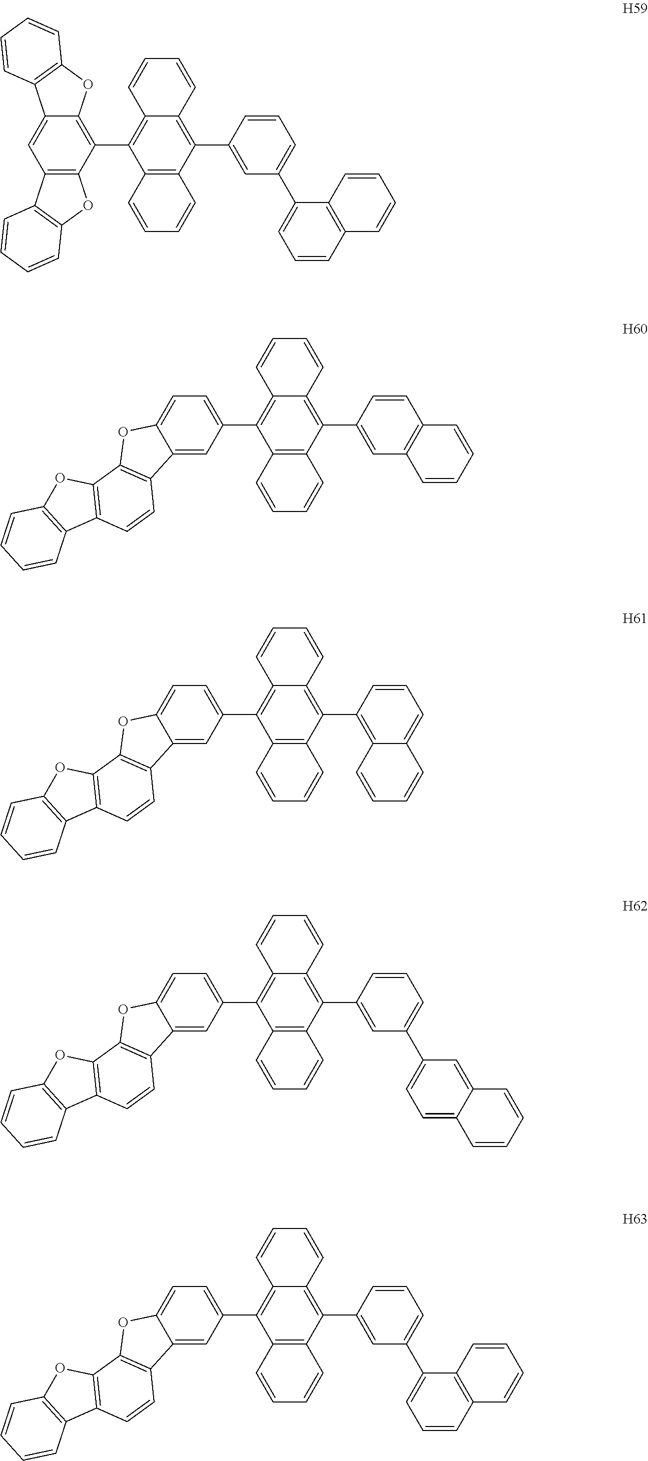 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1]

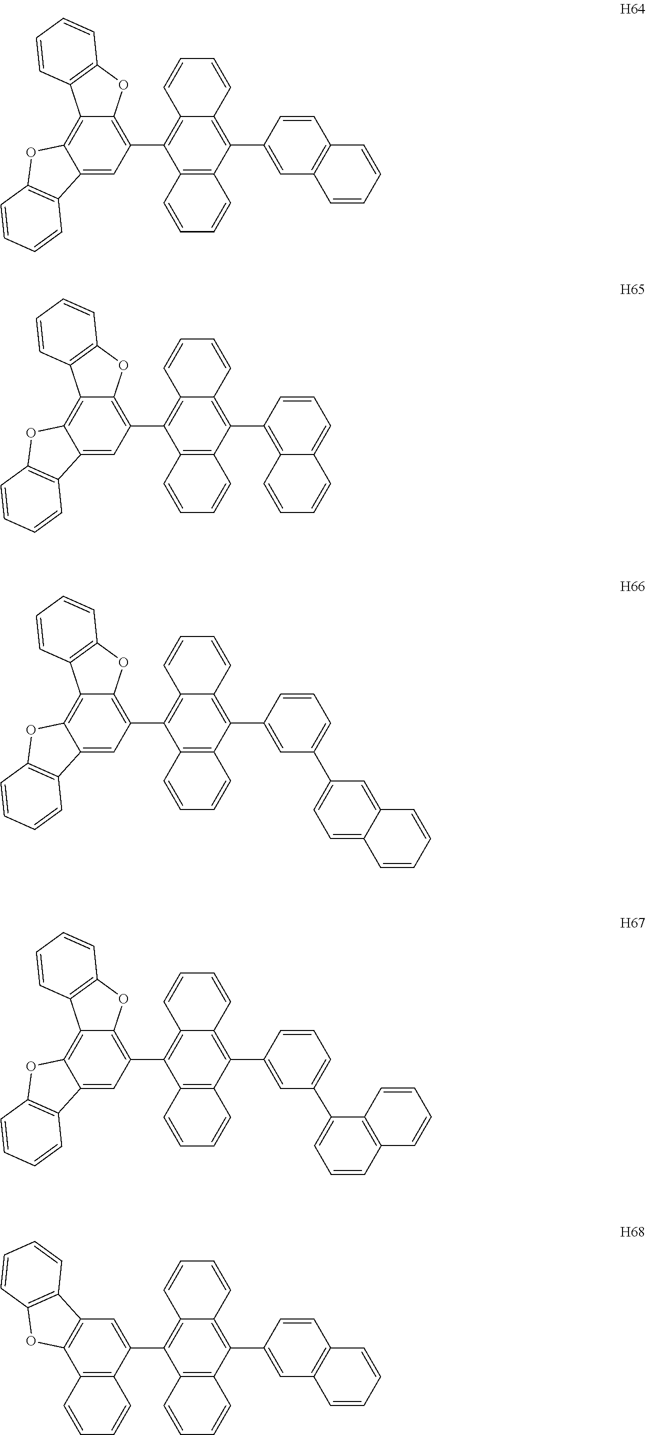 [SMILES: c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1]

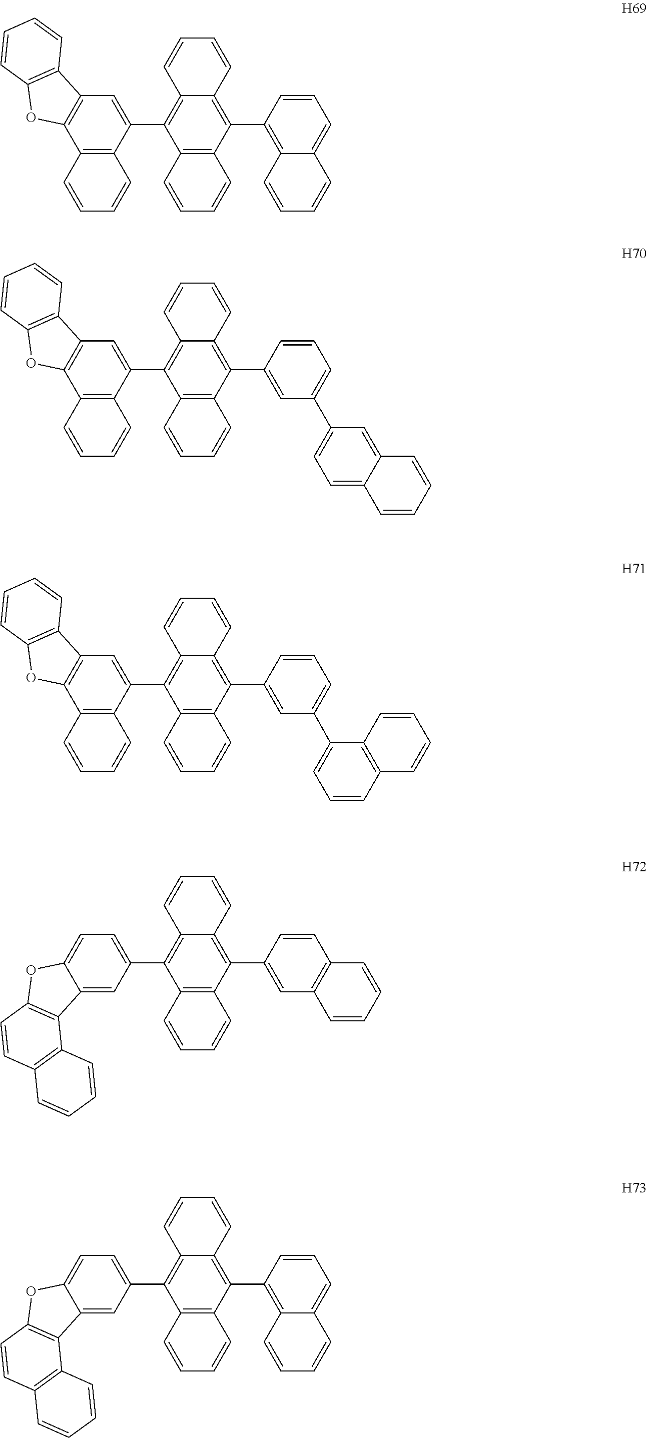 [SMILES: c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1]

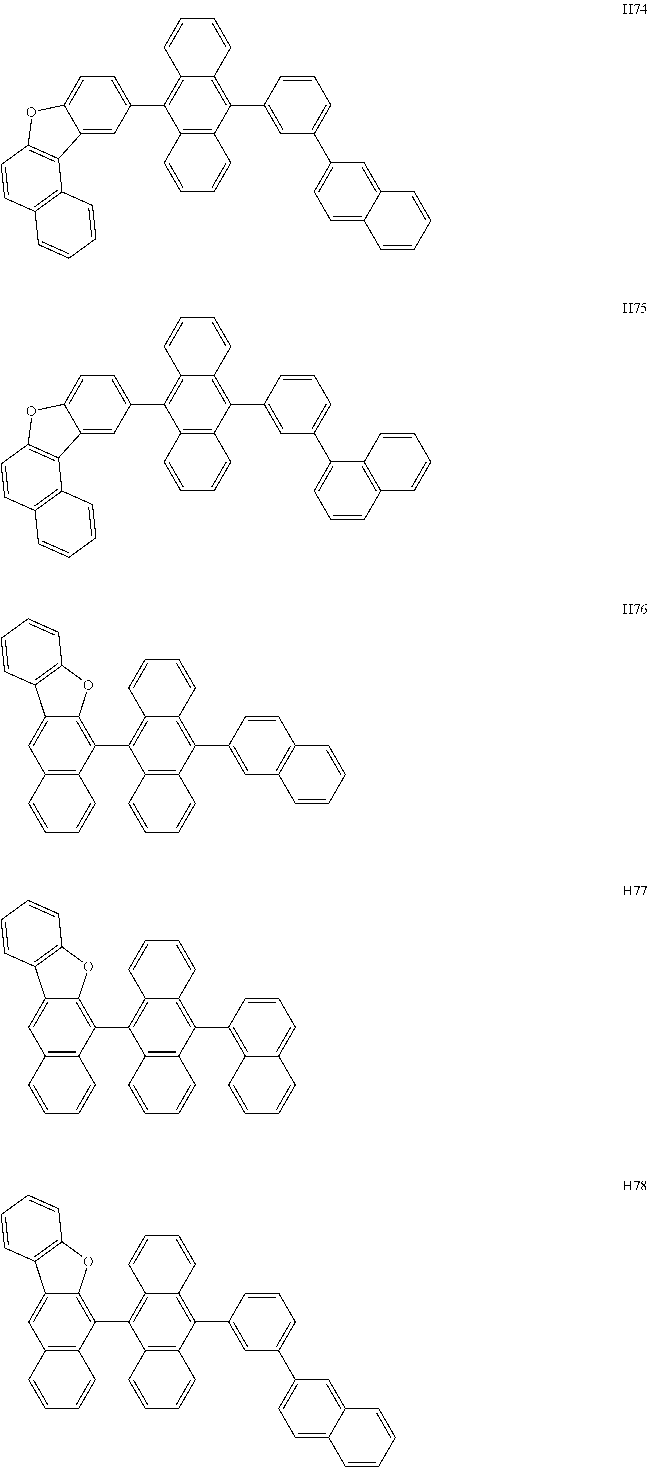 [SMILES: c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1]

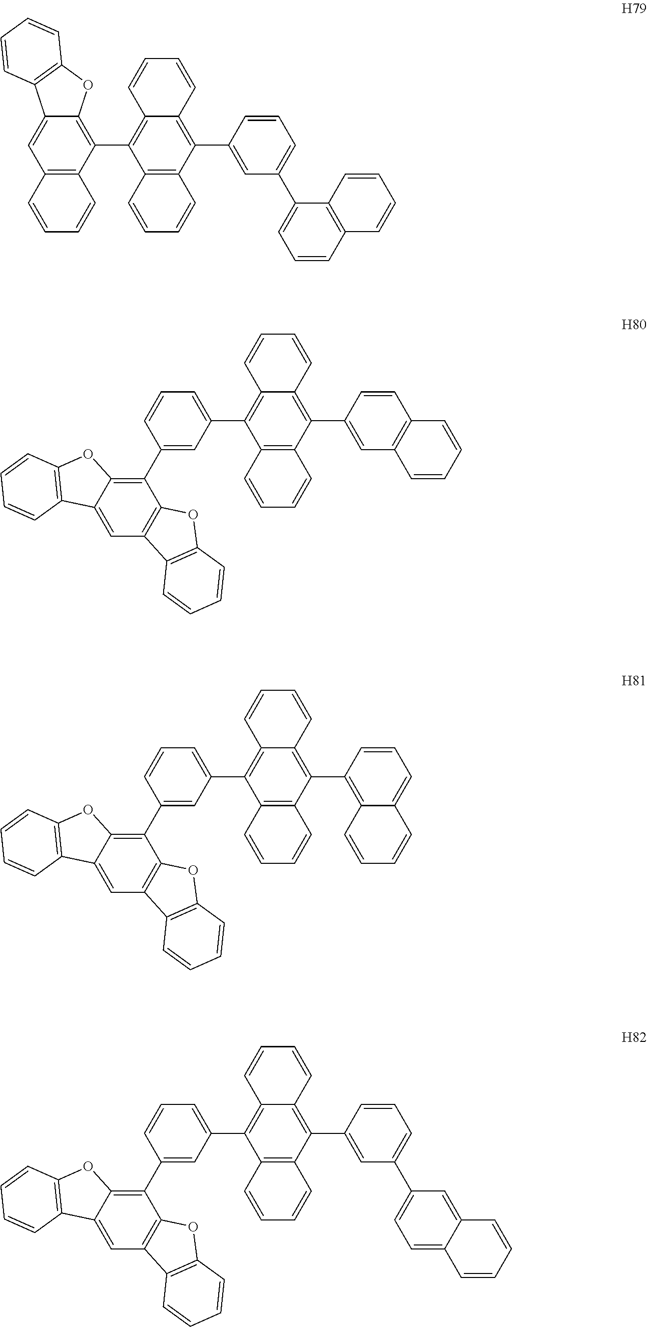 [SMILES: c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

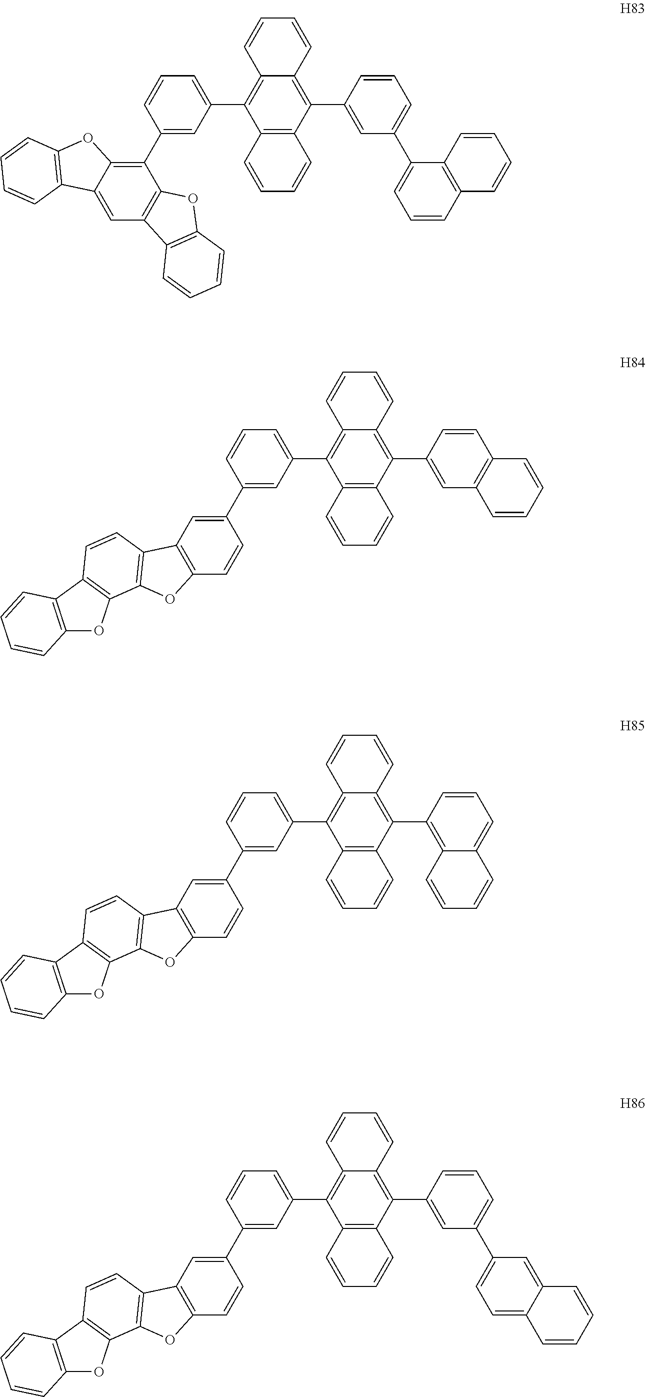 [SMILES: c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

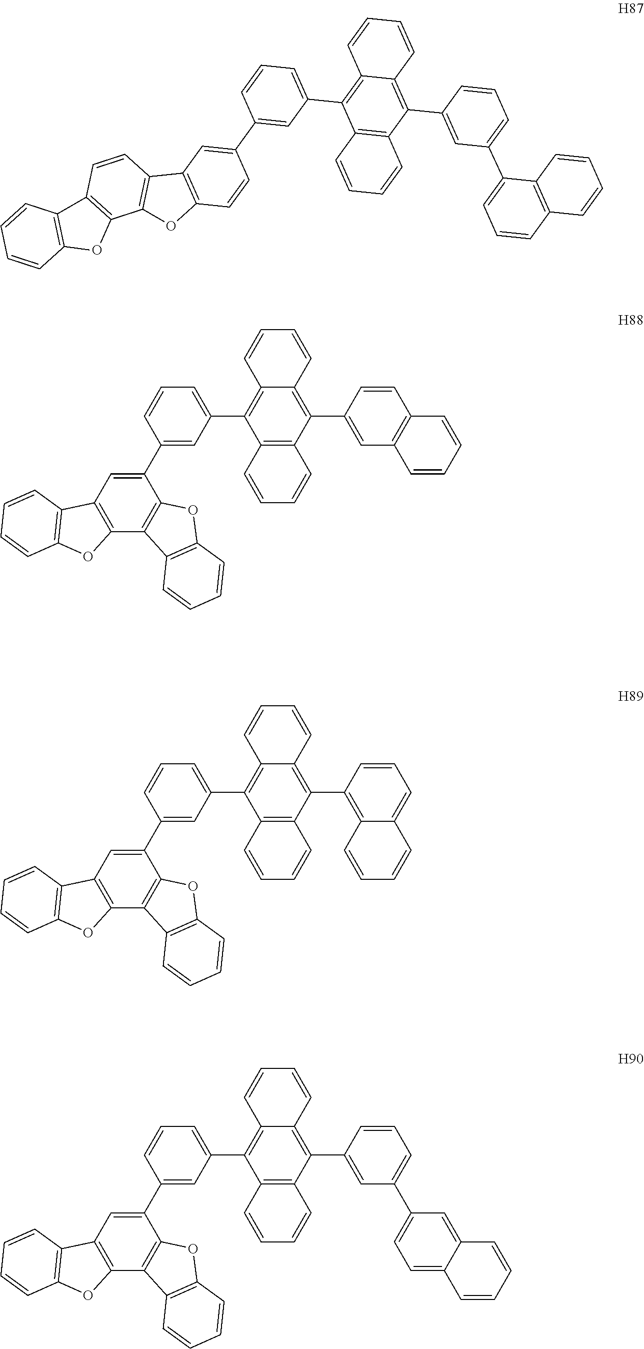 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1]

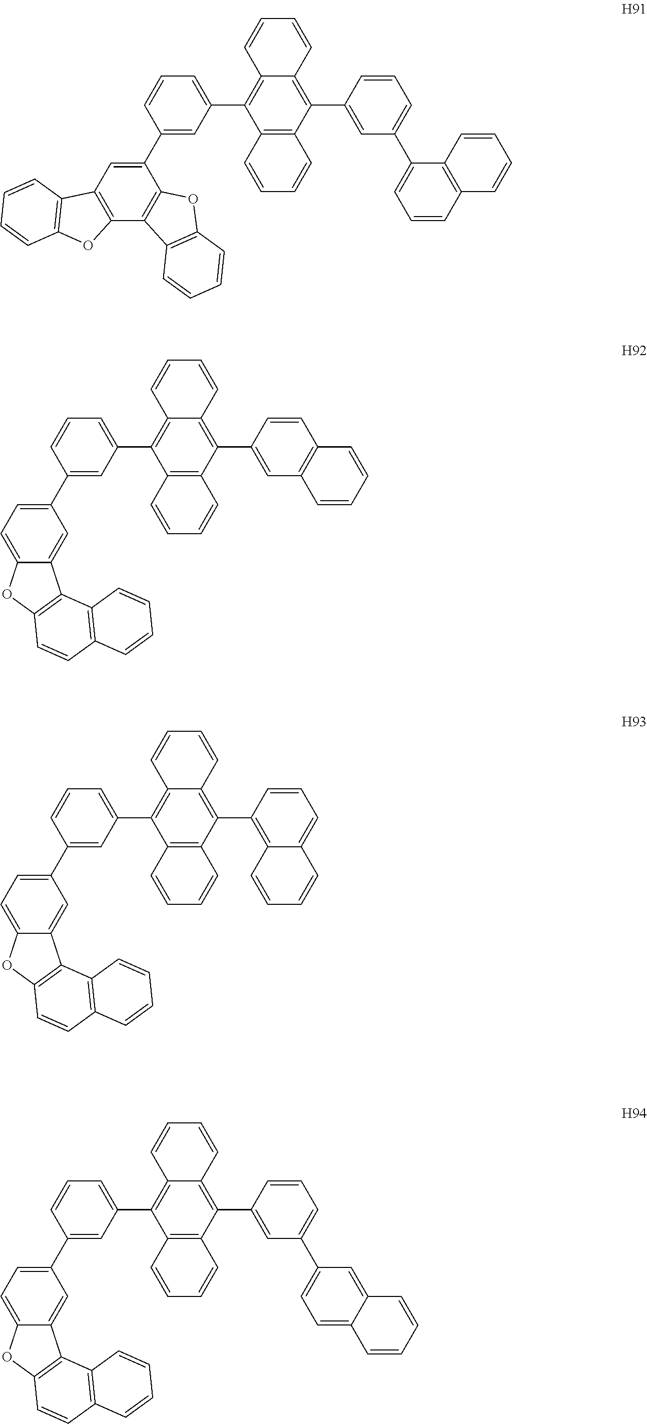 [SMILES: c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1]

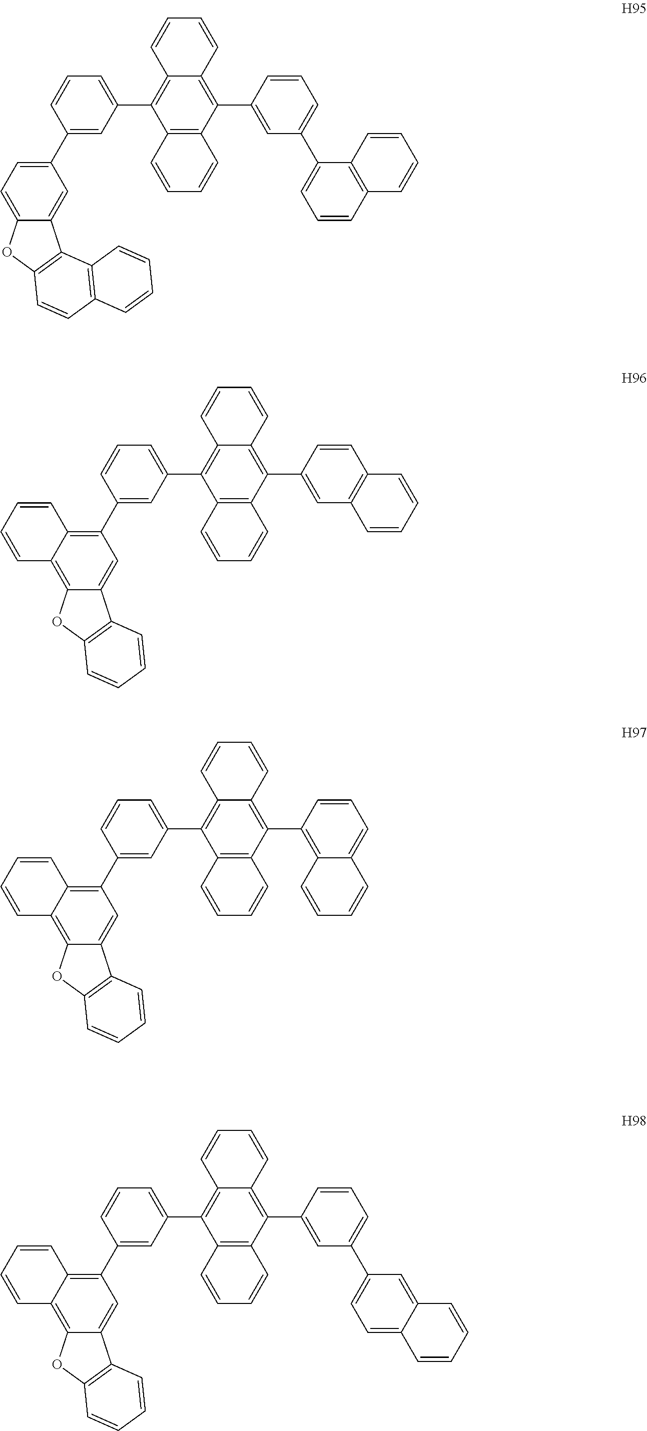 [SMILES: c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1]

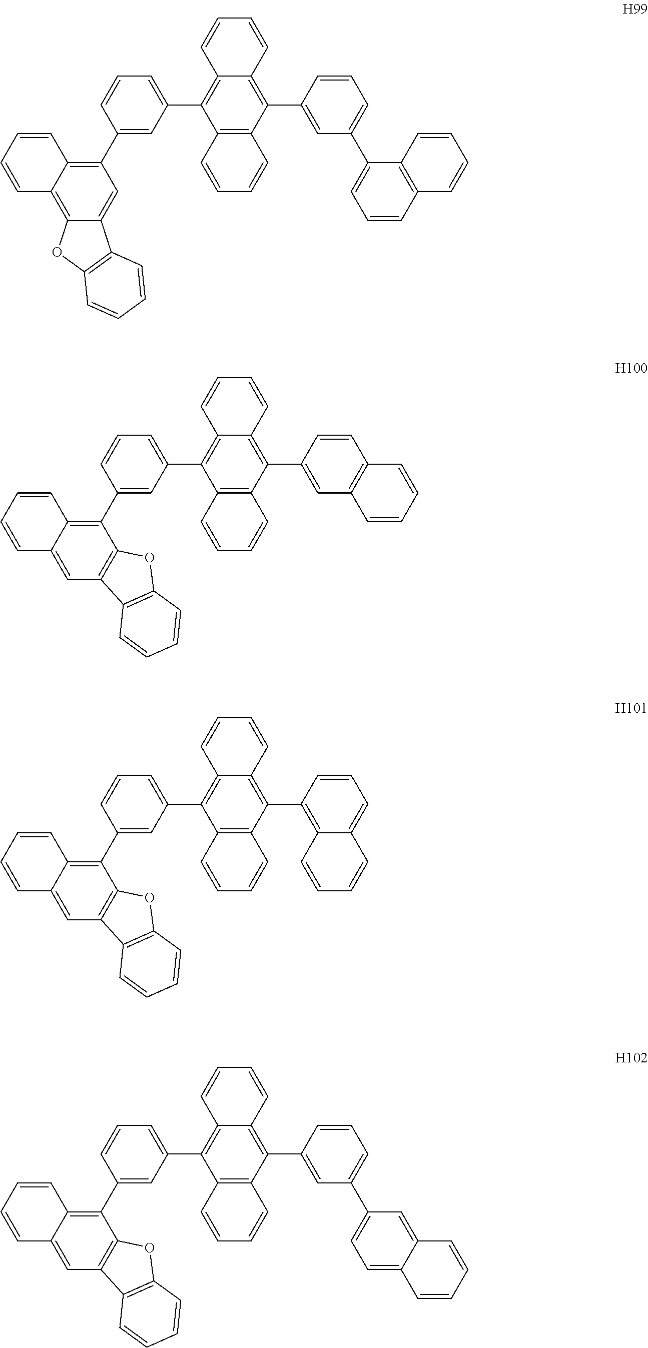 [SMILES: c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1]

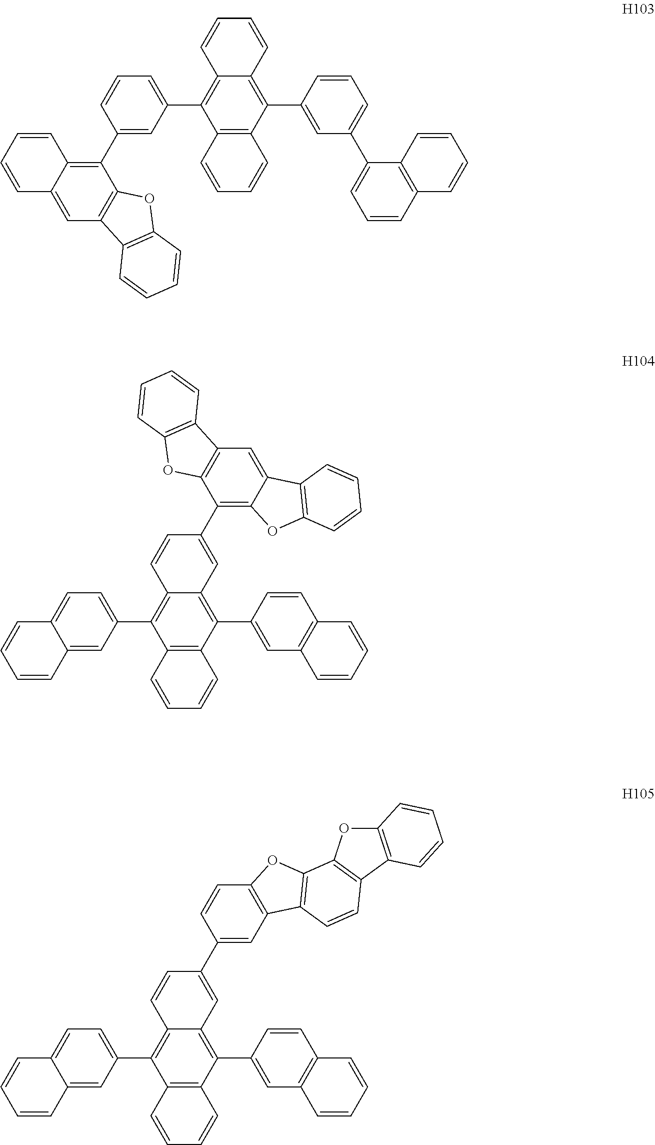 [SMILES: c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1]

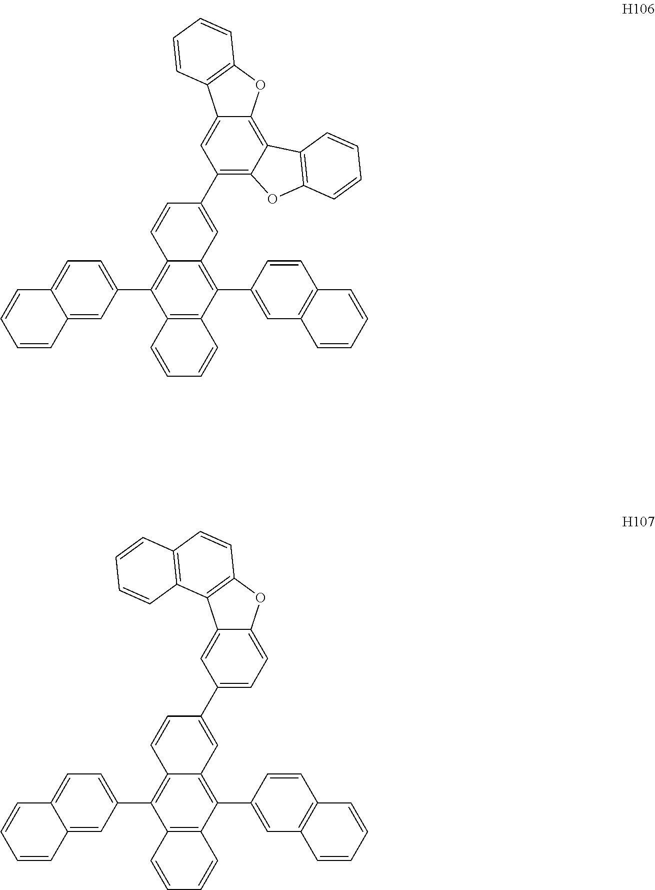 [SMILES: c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1]

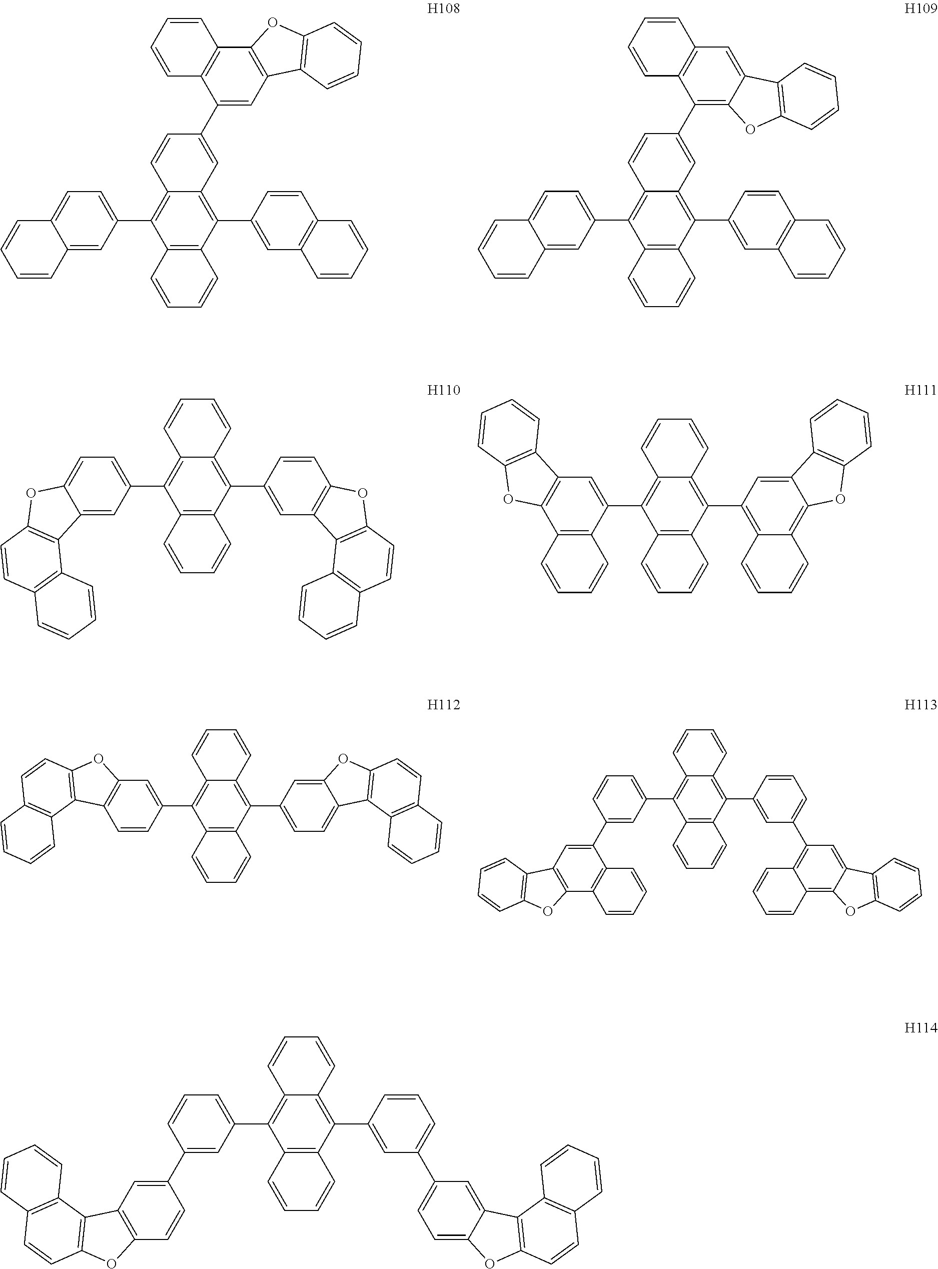

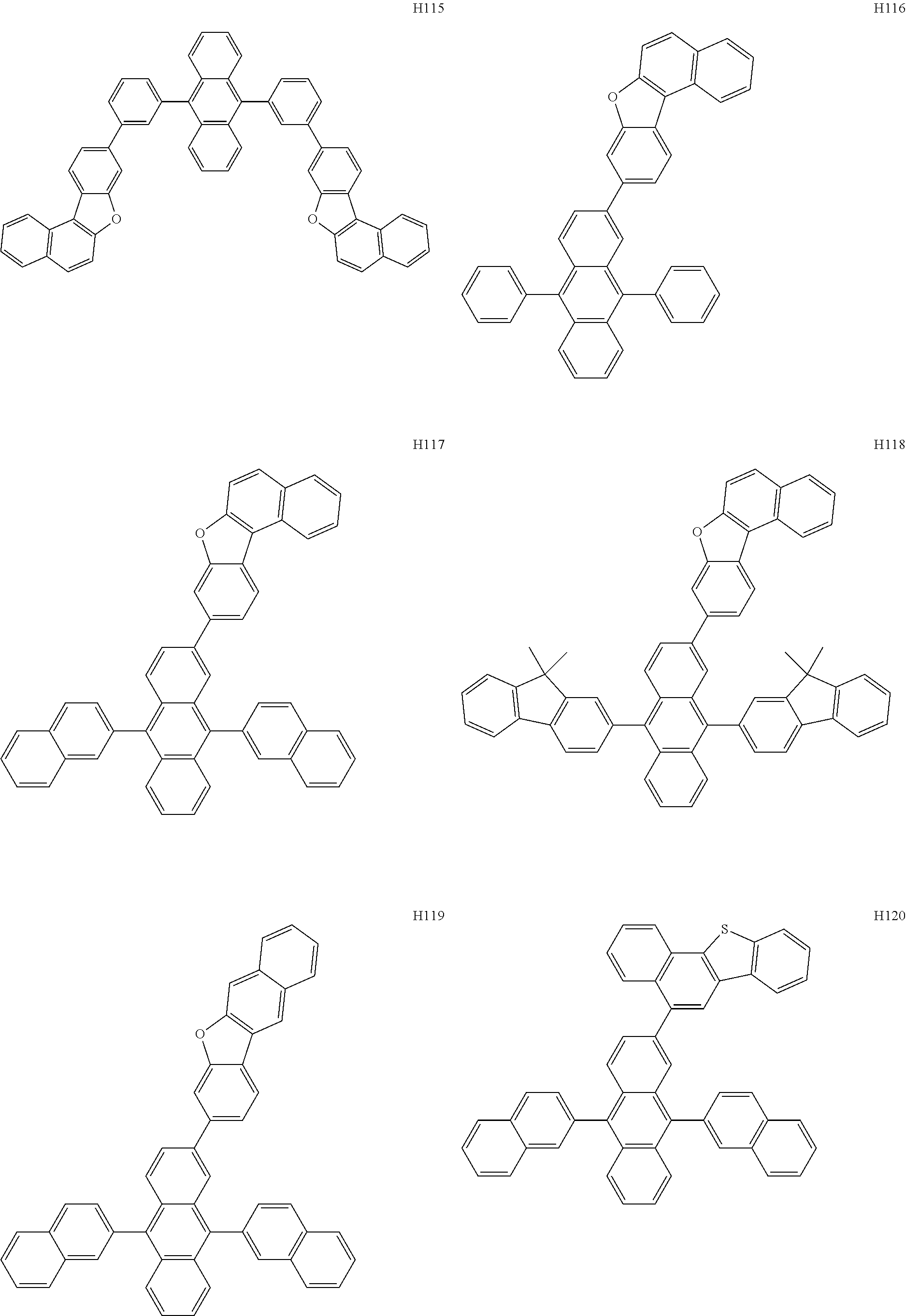

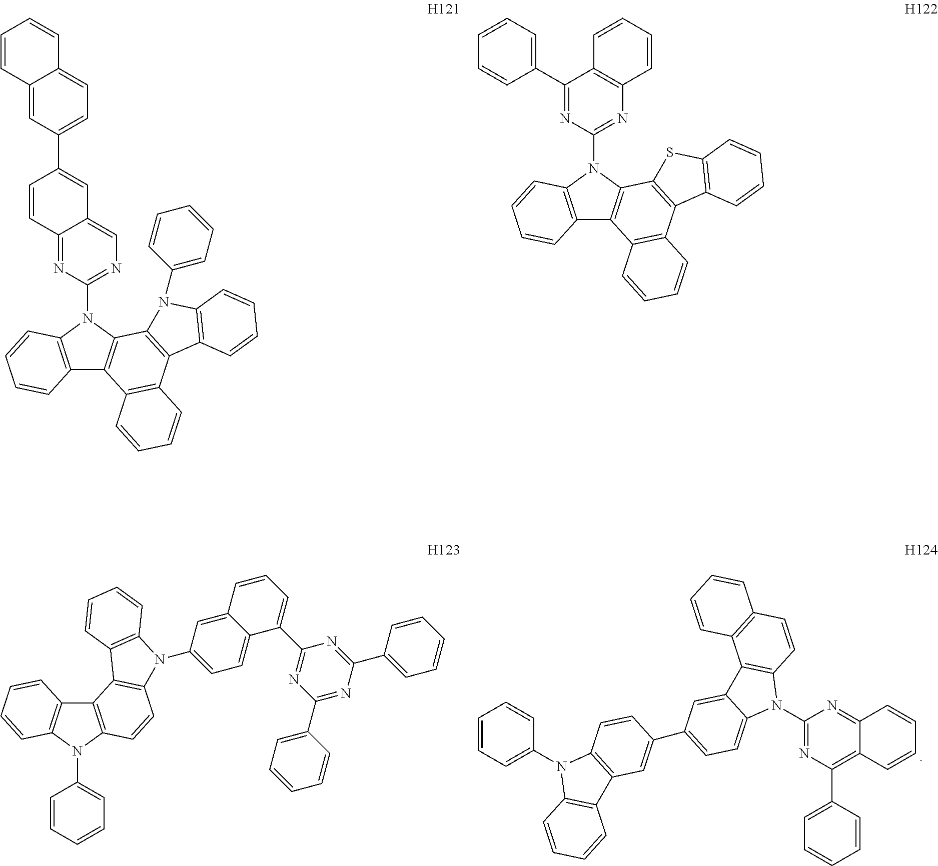 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

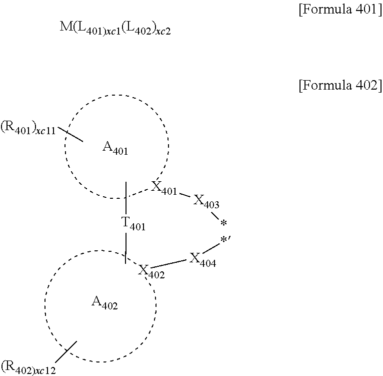

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is two or more, two or more of L₄₀₁(s) may be identical to or different from each other,
L₄₀₂ may be an organic ligand, and xc2 may be 0, 1, 2, 3, or 4, wherein when xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *=C═*′,
X₄₀₃ and X₄₀₄ may each independently be a chemical bond, O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 may each independently be an integer from 0 to 10,
Q₄₁₁ to Q₄₁₄ and Q₄₀₁ to Q₄₀₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof,
* and *′ in Formula 402 each indicate a binding site to M in Formula 401, and
R₁₀ₐ may be the same as described herein.

In embodiments, in Formula 402, X₄₀₁ may be nitrogen and X₄₀₂ may be carbon, or X₄₀₁ and X₄₀₂ may each be nitrogen.

In embodiments, when xc1 in Formula 401 is 2 or greater, two ring A₄₀₁(s) of at least two L₄₀₁(s) may optionally be bound via T₄₀₂ as a linking group, or two ring A₄₀₂(s) may optionally be bound via T₄₀₃ as a linking group (see Compounds PD1 to PD4 and PD7). T₄₀₂ and T₄₀₃ may each independently be the same as defined in connection with T₄₀₁.

In Formula 401, L₄₀₂ may be any suitable organic ligand. For example, L₄₀₂ may be a halogen group, a diketone group (e.g., an acetylacetonate group), a carboxylic acid group (e.g., a picolinate group), —C(═O), an isonitrile group, —CN, or a phosphorus group (e.g., a phosphine group or a phosphite group).

The phosphorescent dopant may include, for example, one of Compounds PD1 to PD41, or any combination thereof:

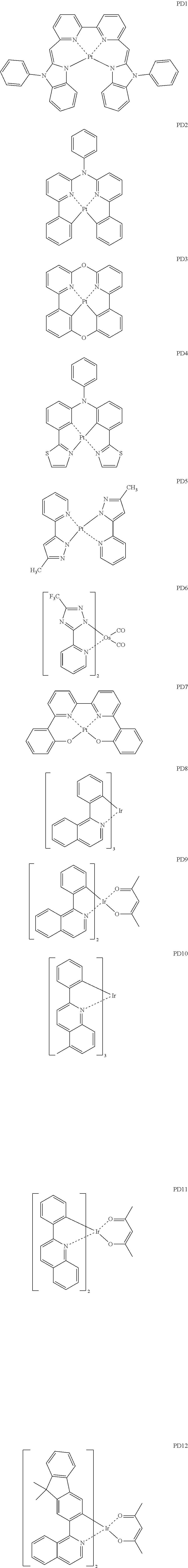

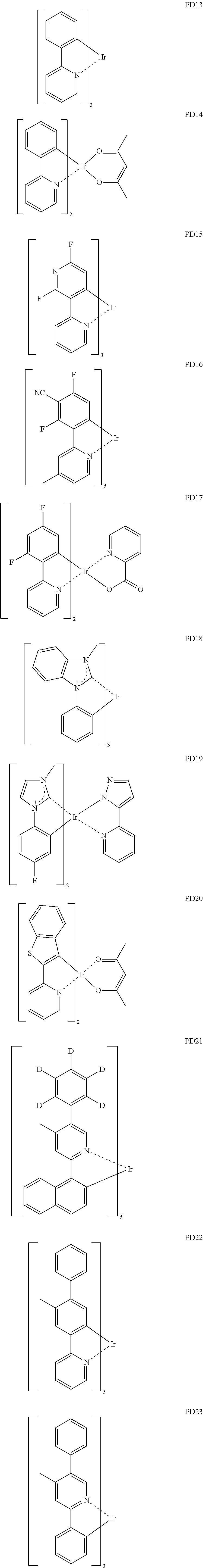

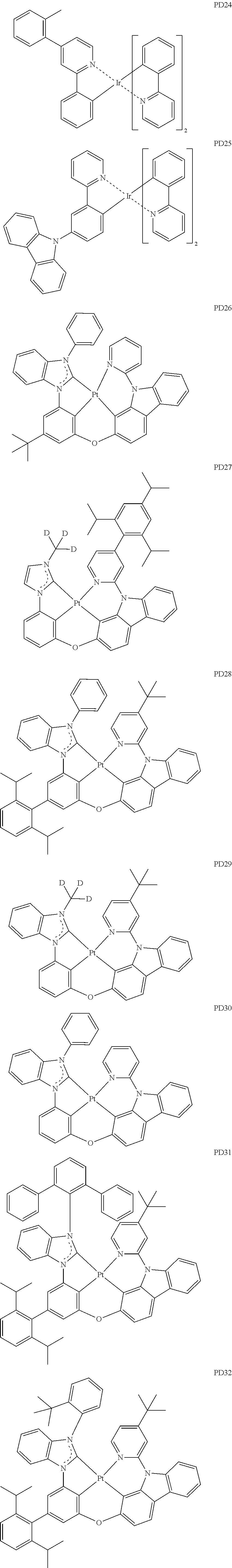

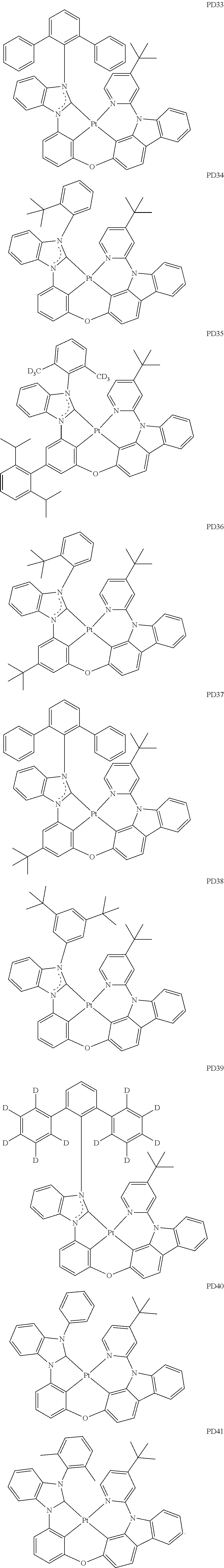

### [Fluorescent Dopant]

The fluorescent dopant may include an amine group-containing compound, a styryl group-containing compound, or any combination thereof.

In an embodiment, the fluorescent dopant may include a compound represented by Formula 501:

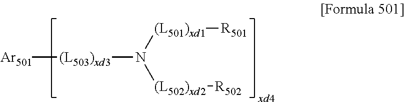

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (e.g., an anthracene group, a chrysene group, a pyrene group, etc.) in which three or more monocyclic groups are condensed with each other.

In an embodiment, in Formula 501, xd4 may be 2.

In an embodiment, the fluorescent dopant may include one of Compounds FD1 to FD36, DPVBi, DPAVBi, or any combination thereof:

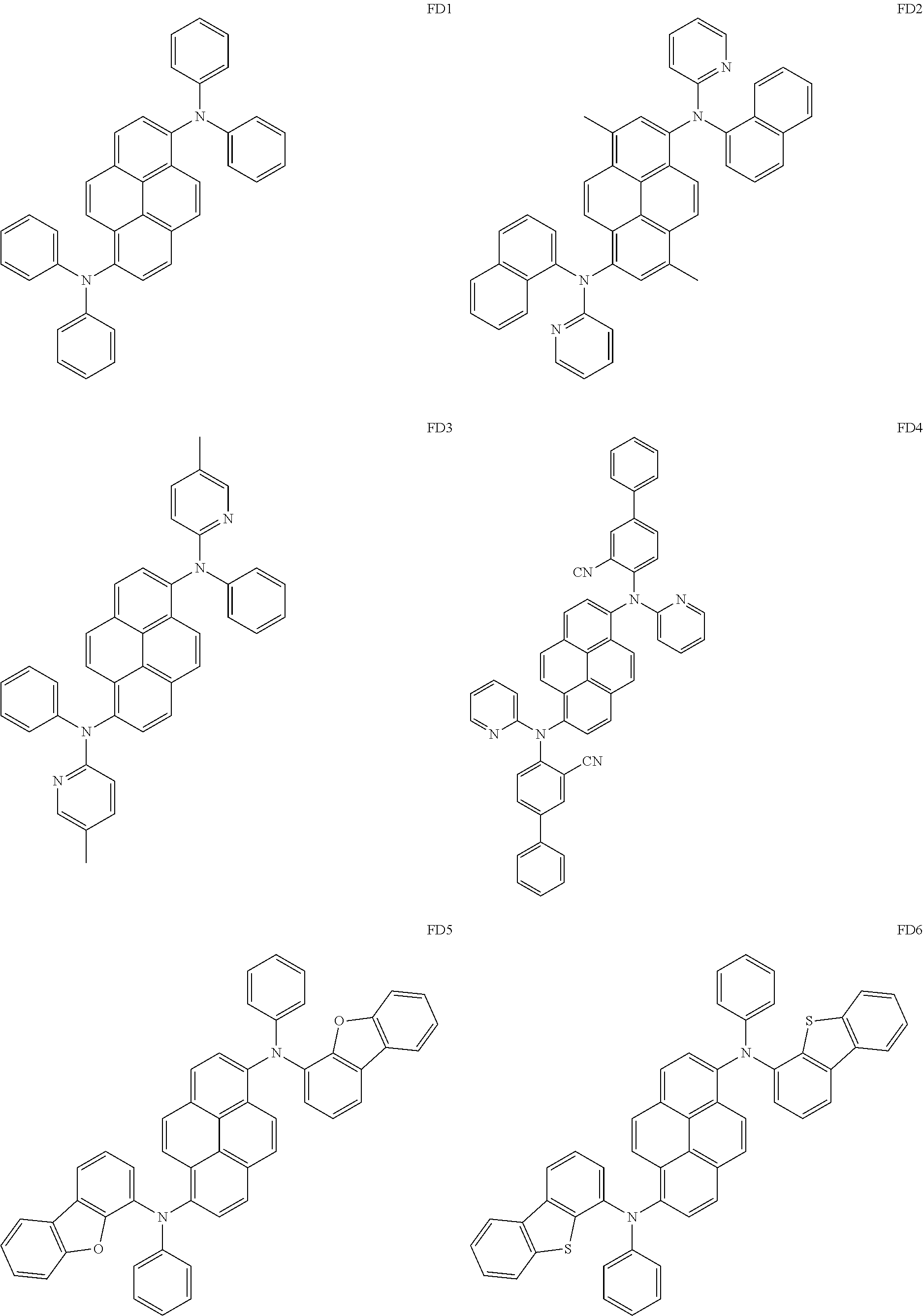

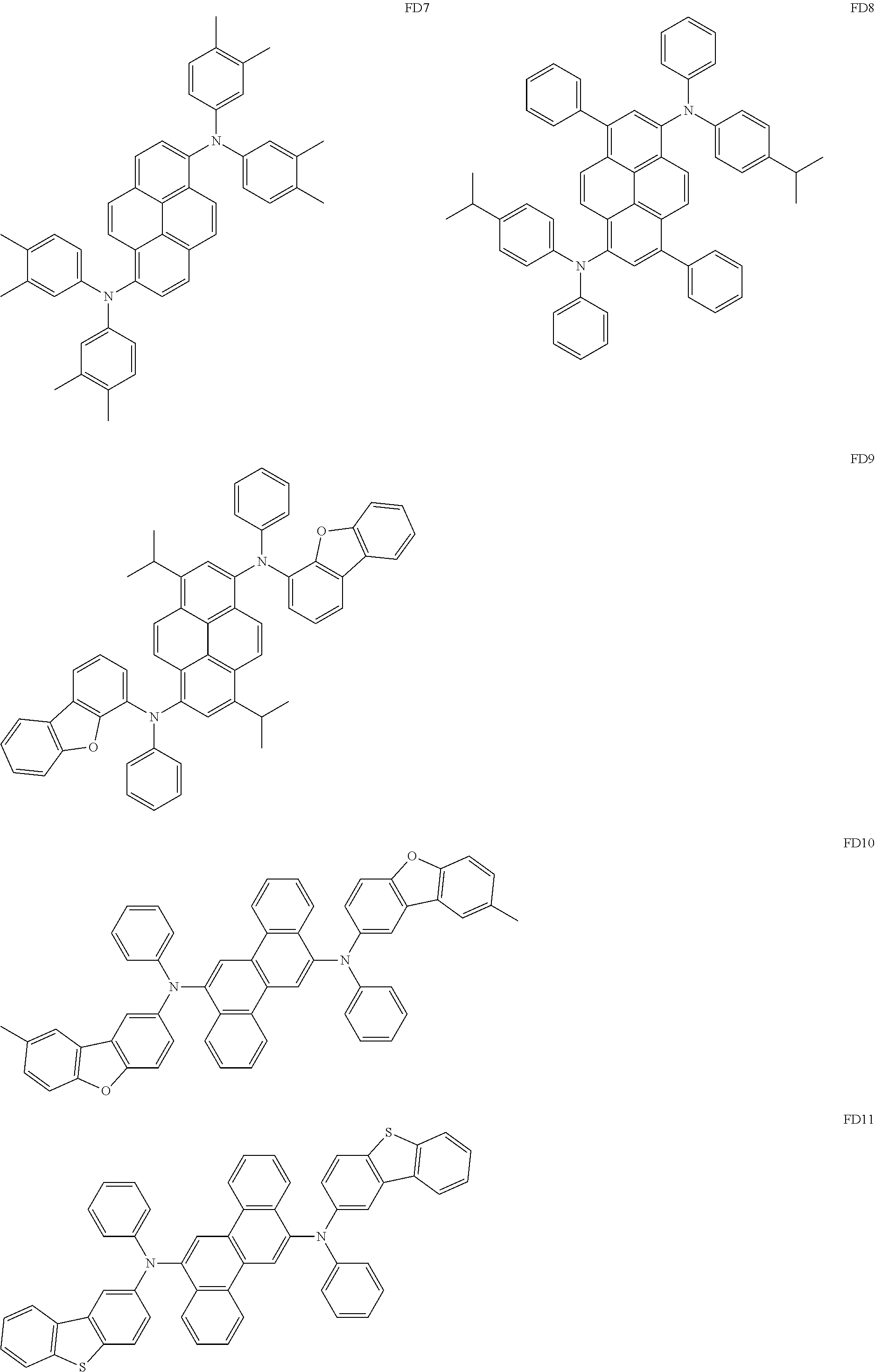

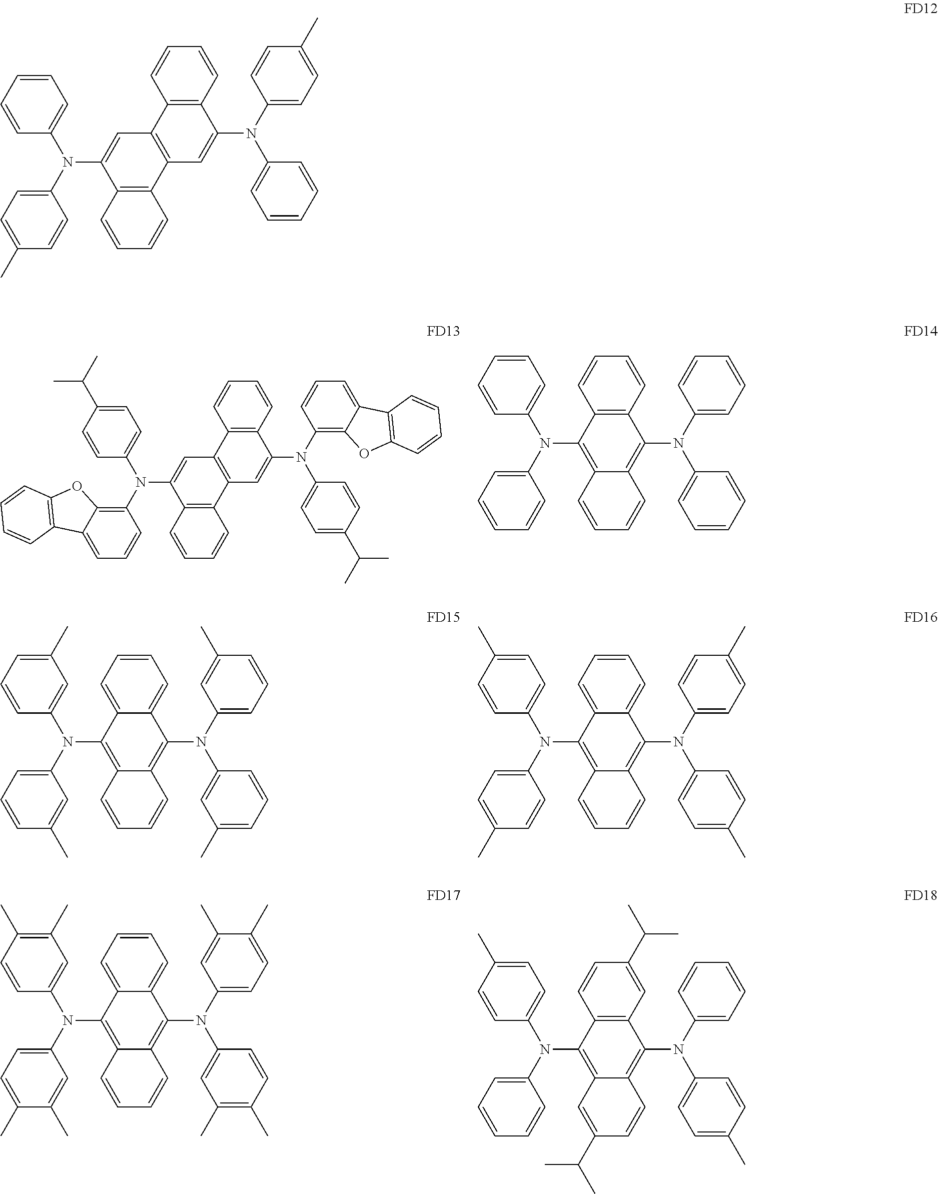

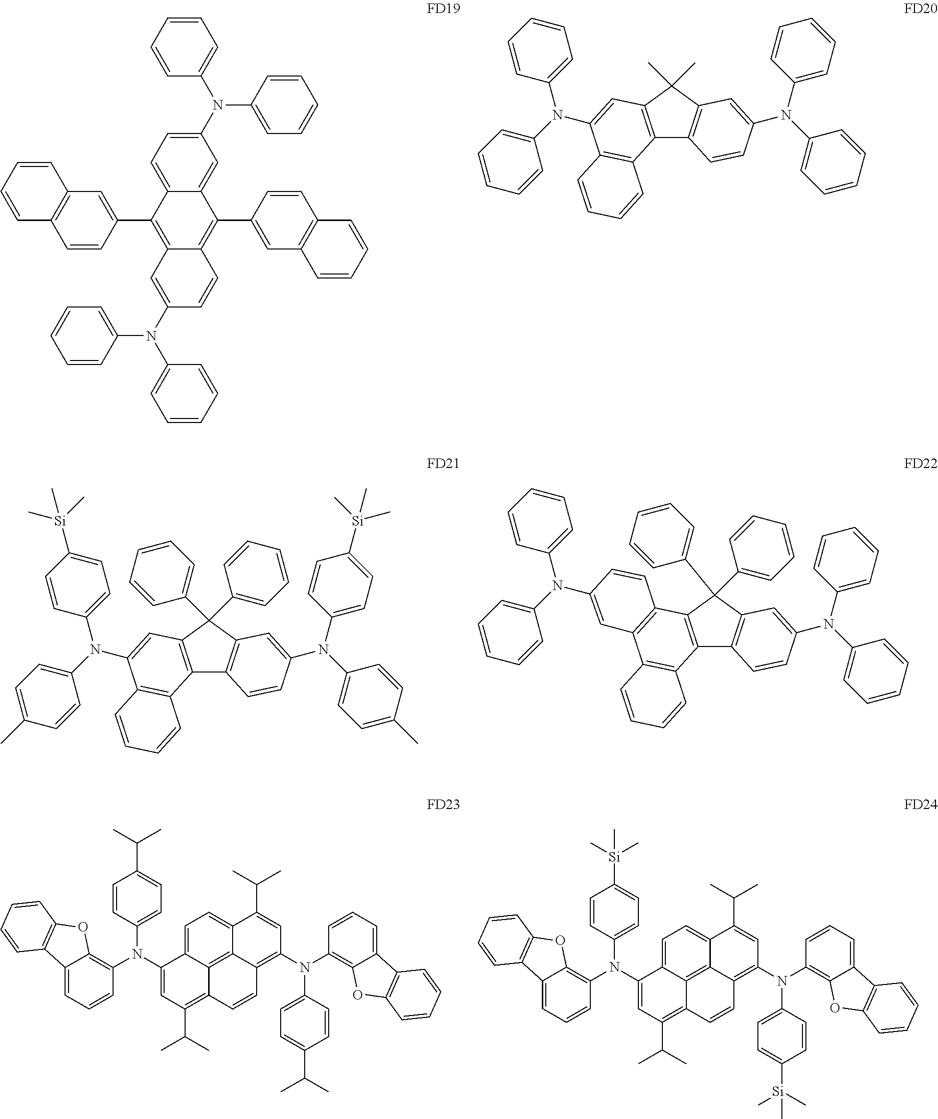

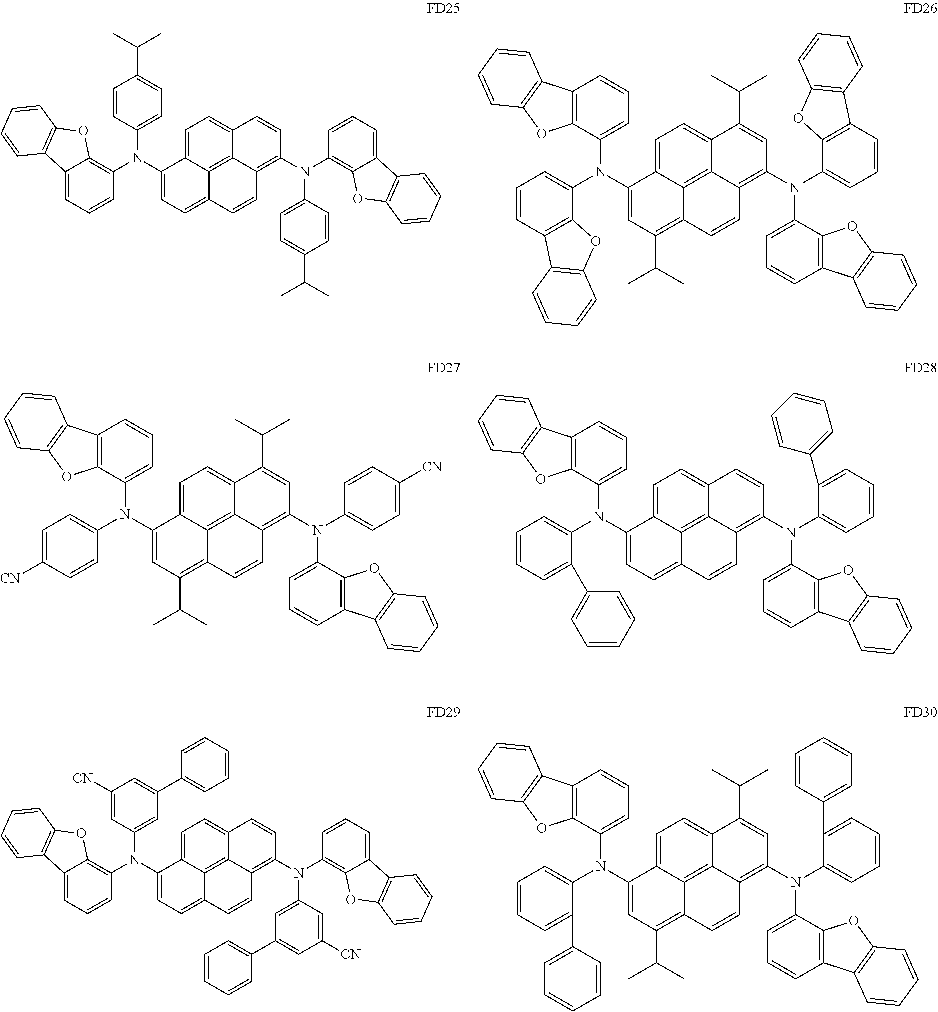

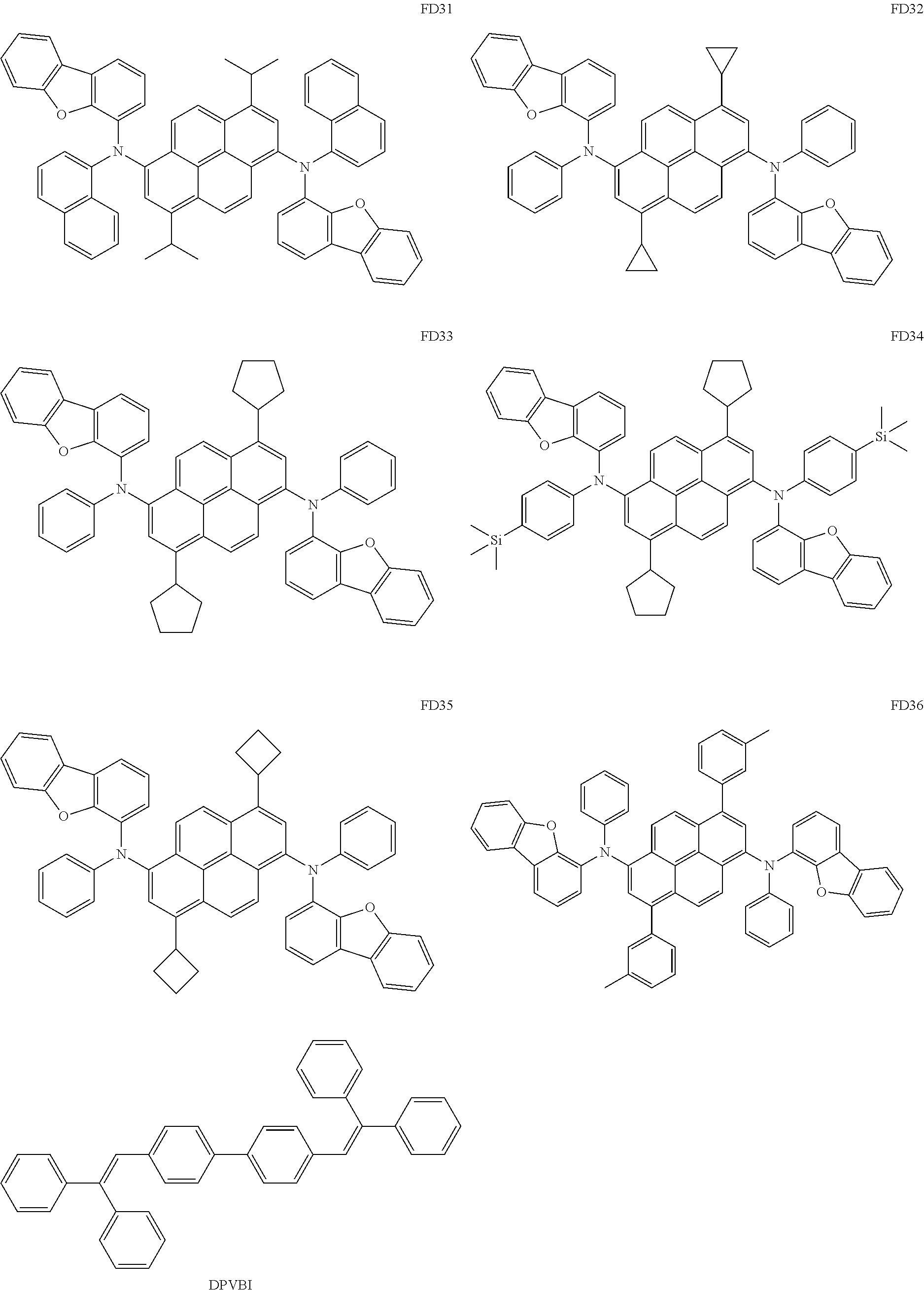

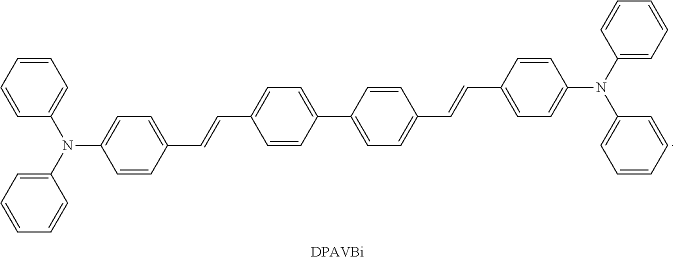 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1 ; "."]

### [Electron Transport Region in Interlayer 130]

The electron transport region may have a structure consisting of a layer consisting of a single material, a structure consisting of a layer including different materials, or a structure including multiple layers including different materials.

The electron transport region may include a buffer layer, a hole-blocking layer, an electron control layer, an electron transport layer, an electron injection layer, or any combination thereof.

In an embodiment, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein the layers of each structure may be stacked from the emission layer in its respective stated order, but the structure of the electron transport region is not limited thereto.

The electron transport region (e.g., the buffer layer, the hole-blocking layer, the electron control layer, or the electron transport layer in the electron transport region) may include a metal-free compound including at least one rr electron-deficient nitrogen-containing C₁-C₆₀ cyclic group.

In an embodiment, the electron transport region may include a compound represented by Formula 601:

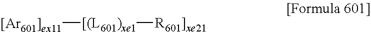

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, when xe11 is 2 or more, two or more of Ar₆₀₁ may be linked to each other via a single bond.

In an embodiment, in Formula 601, Ar₆₀₁ may be a substituted or unsubstituted anthracene group.

In an embodiment, the electron transport region may include a compound represented by Formula 601-1:

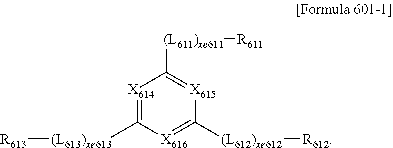

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formula 601 and 601-1, xe1 and xe611 to xe613 may each independently be 0, 1, or 2.

In an embodiment, the electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAIq, TAZ, NTAZ, or any combination thereof:

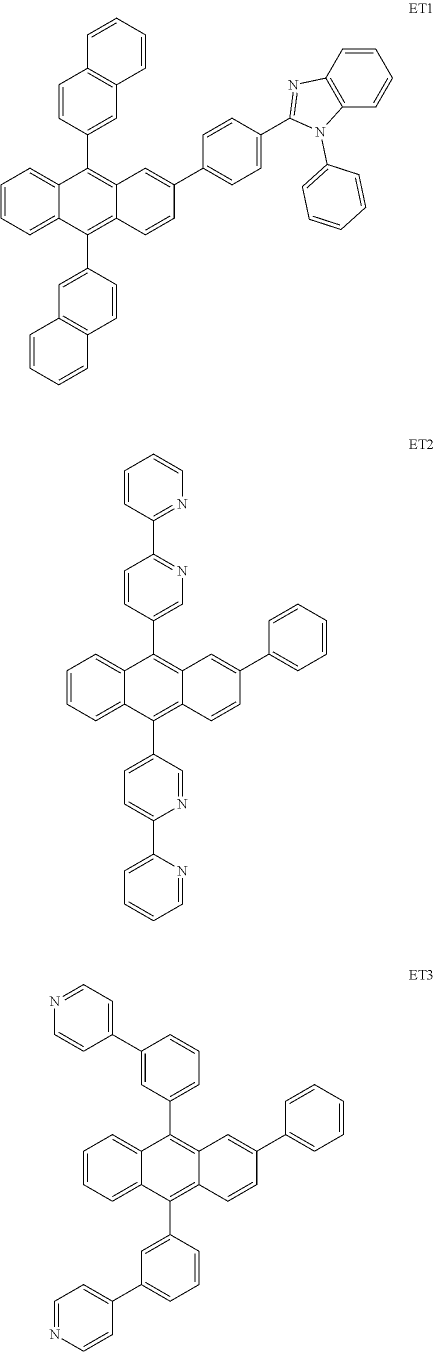 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

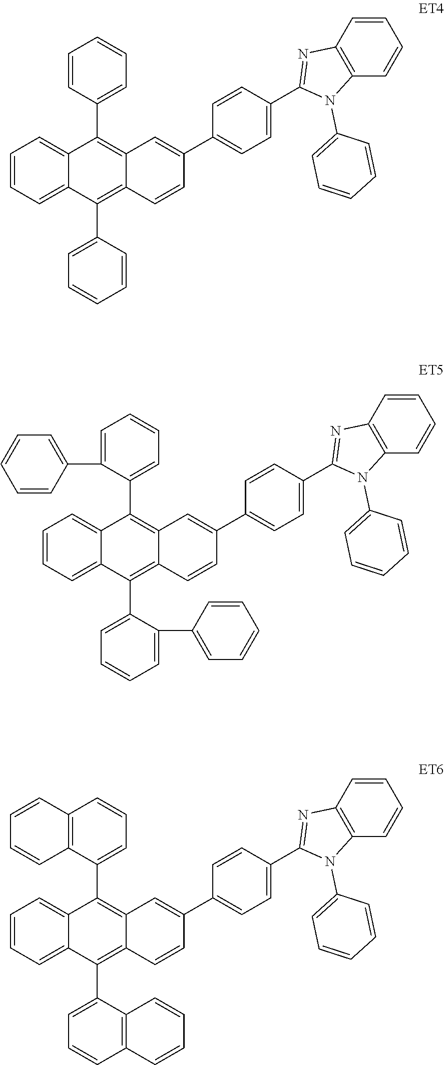 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

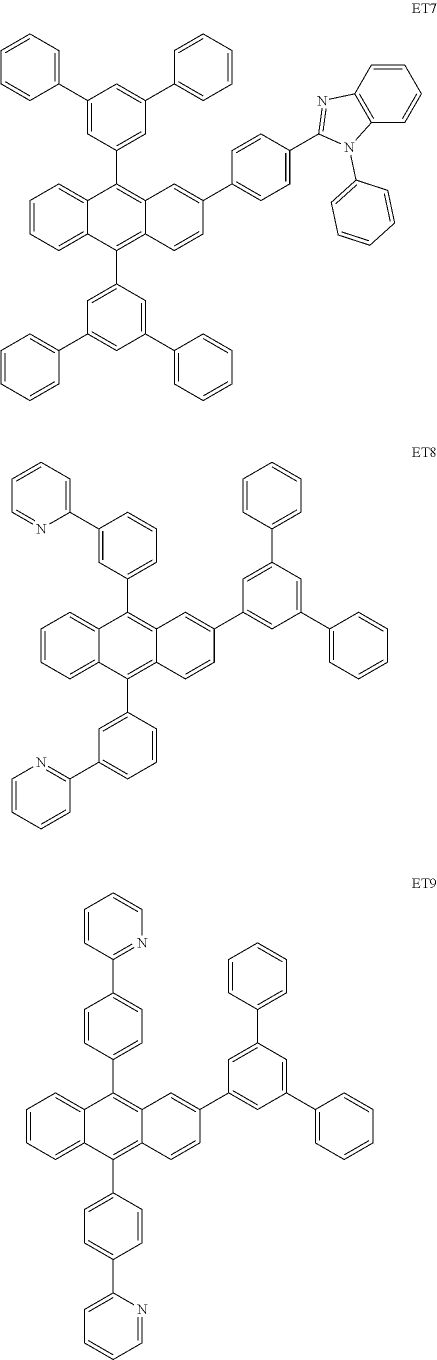 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

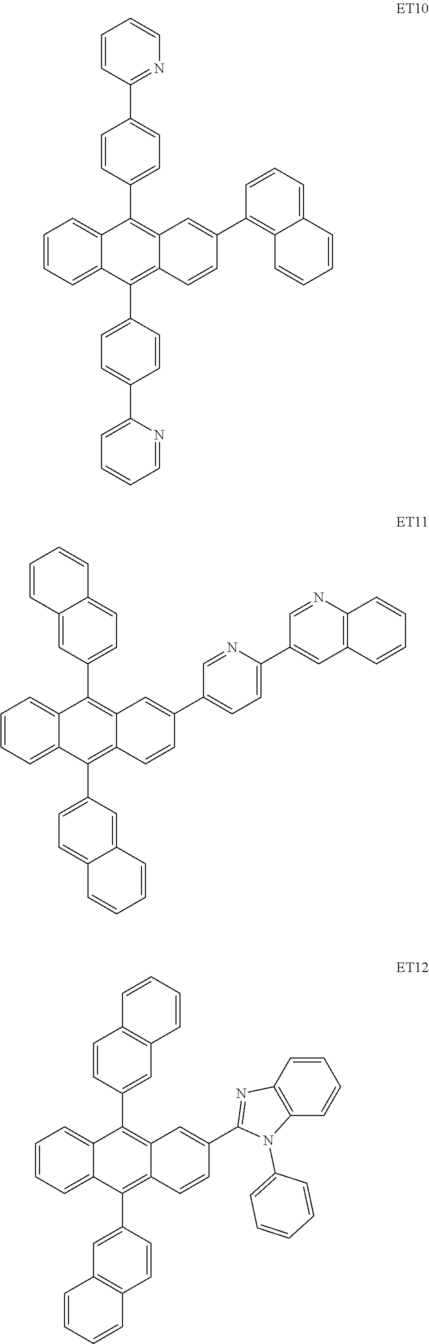 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

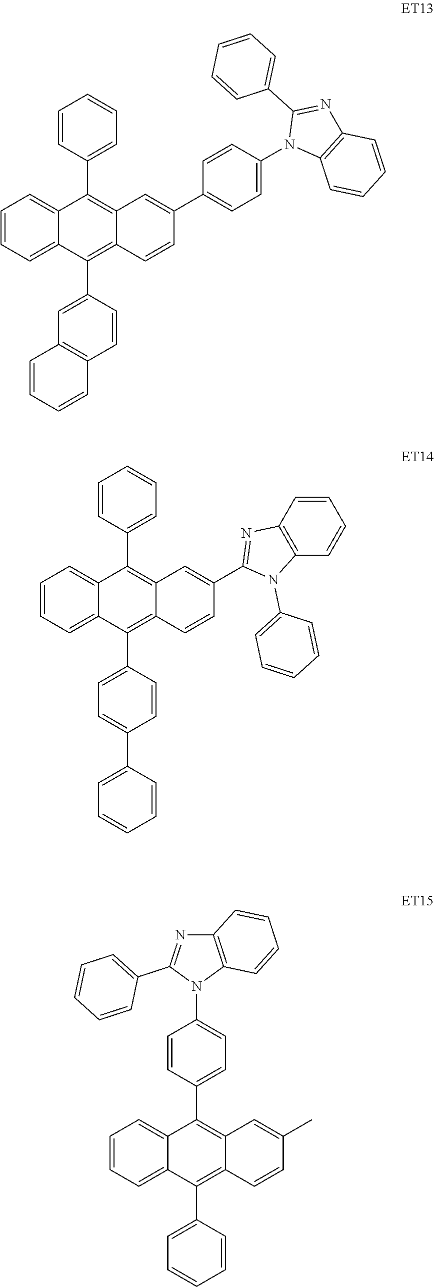 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

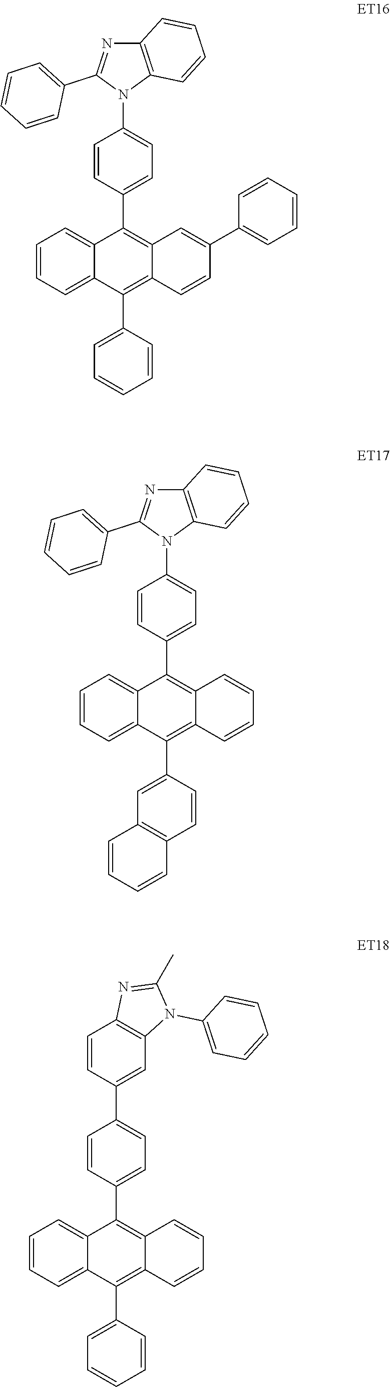 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

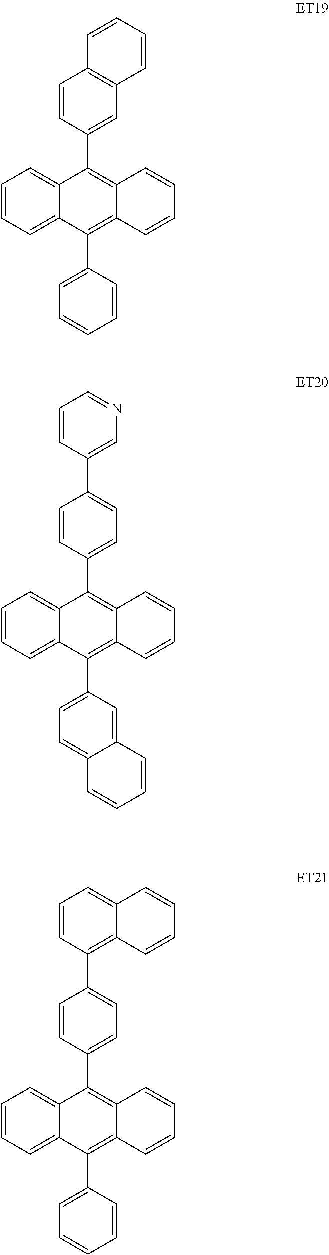

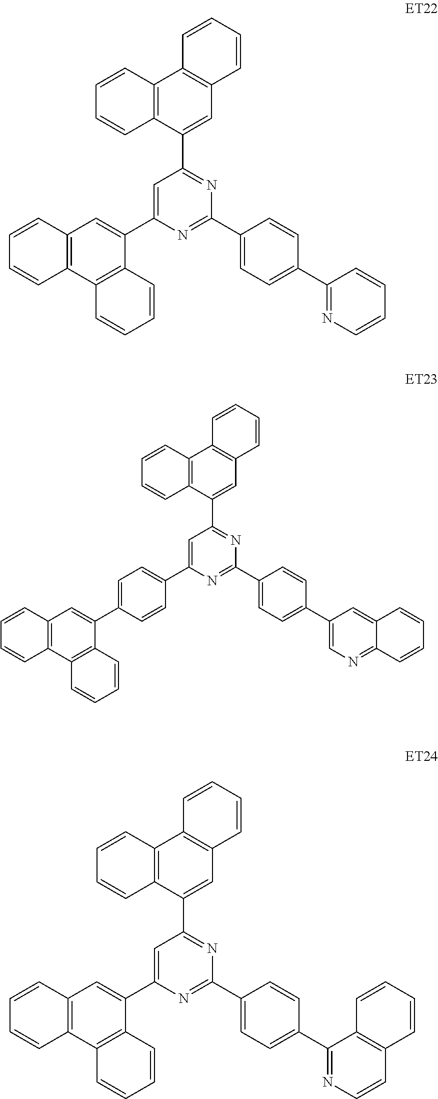 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

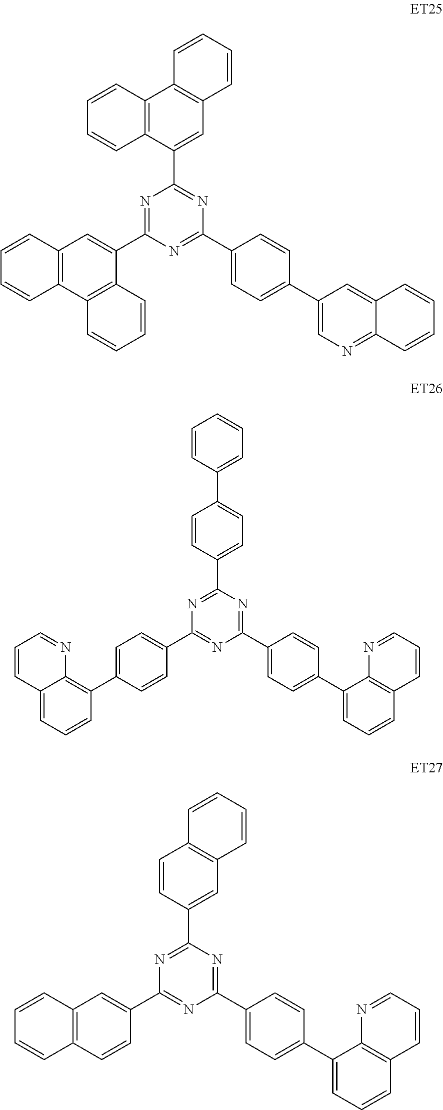 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

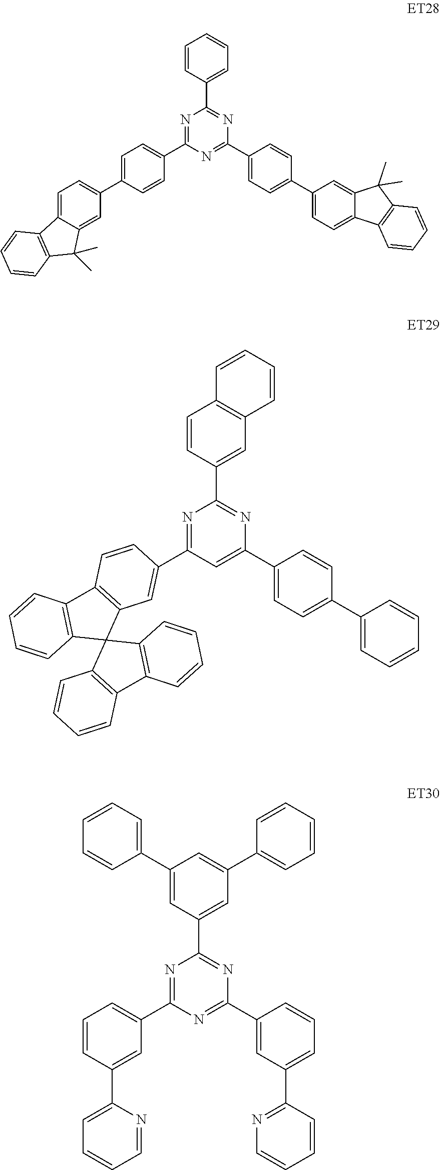 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

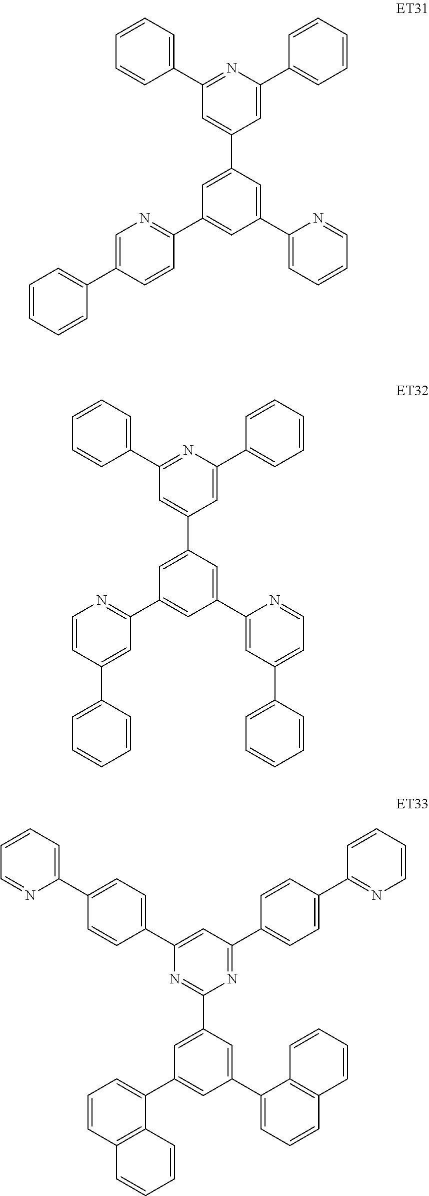 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

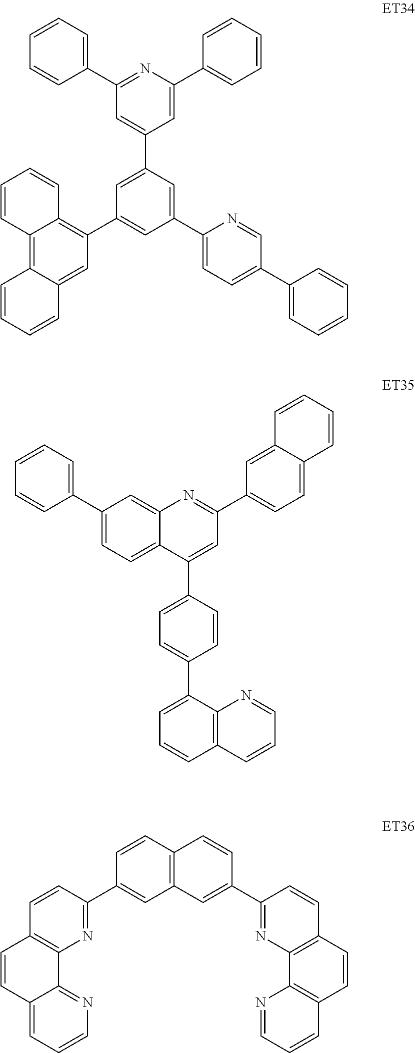 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

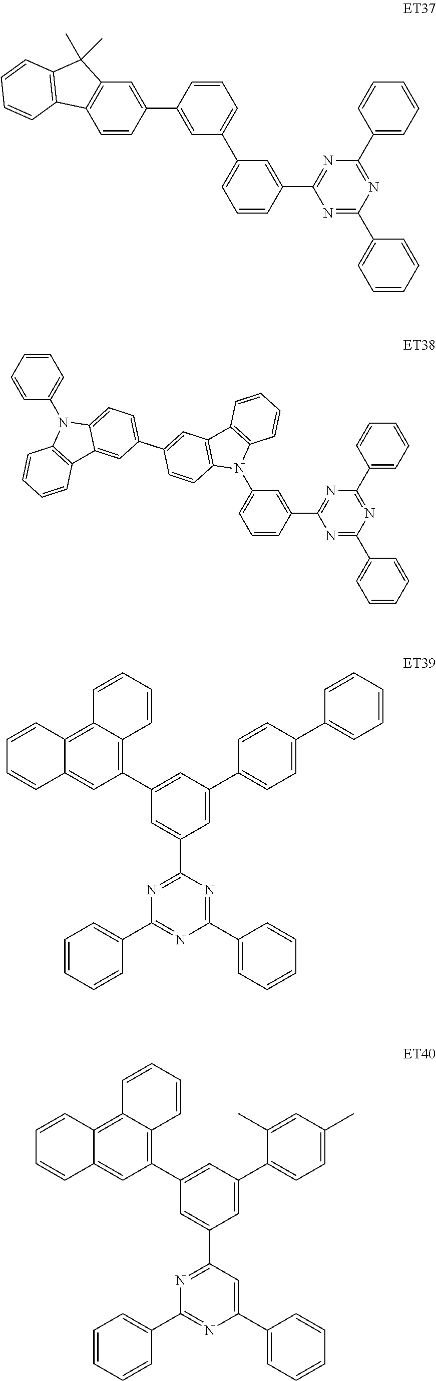 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

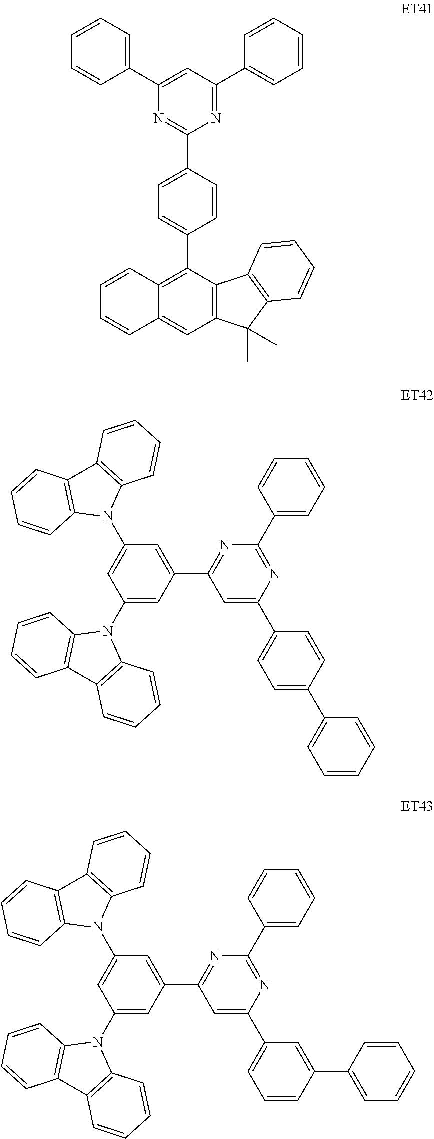 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

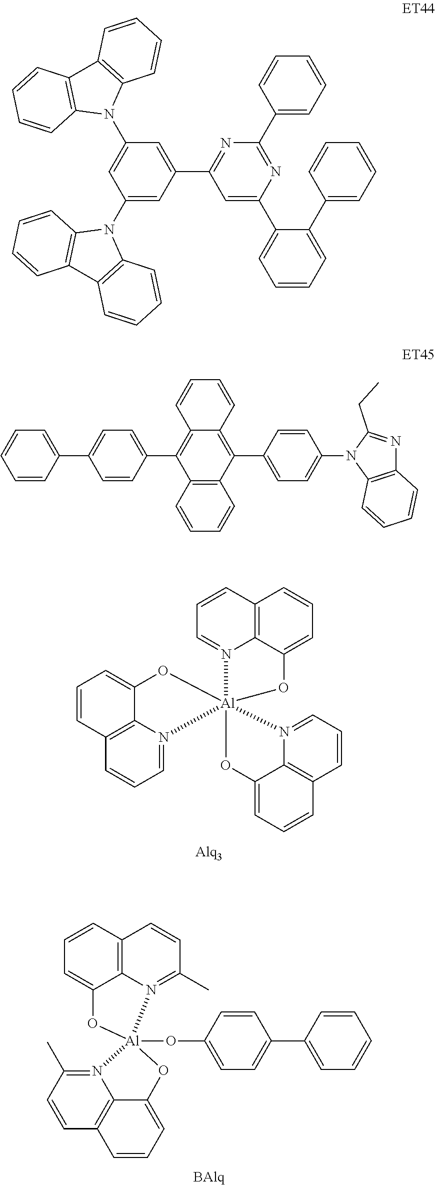

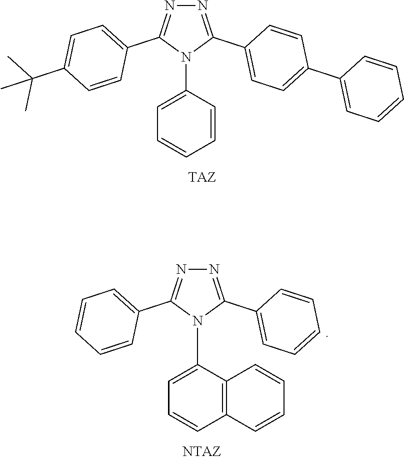 [SMILES: CC(C)(C)c1ccc(-c2nnc(-c3ccc(-c4ccccc4)cc3)n2-c2ccccc2)cc1 ; c1ccc(-c2nnc(-c3ccccc3)n2-c2cccc3ccccc23)cc1]

A thickness of the electron transport region may be in a range of about 160 Å to about 5,000 Å. For example, the thickness of the electron transport region may be in a range of about 100 Å to about 4,000 Å. When the electron transport region includes a buffer layer, a hole-blocking layer, an electron control layer, an electron transport layer, or any combination thereof, a thickness of the buffer layer, the hole-blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole-blocking layer, or the electron control layer may each independently be in a range of about 30 Å to about 300 Å. For example, the thickness of the electron transport layer may be in a range of about 150 Å to about 500 Å. When the thicknesses of the buffer layer, the hole-blocking layer, the electron control layer, the electron transport layer, and/or the electron transport region are within the ranges described above, satisfactory electron-transporting characteristics may be obtained without a substantial increase in driving voltage.

The electron transport region (e.g., the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of an alkali metal complex or an alkaline earth metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

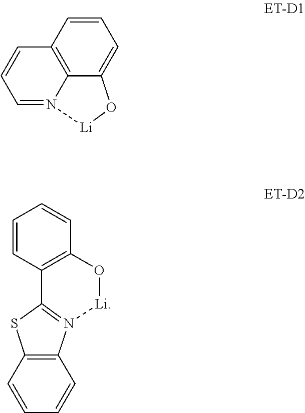

The electron transport region may include an electron injection layer that facilitates the injection of electrons from the second electrode 150. The electron injection layer may contact (e.g., directly contact) the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, K₂O, or the like; an alkali metal halide, such as LiF, NaF, CsF, KF, LiI, NaI, CsI, KI, or the like; or any combination thereof. The alkaline earth metal-containing compound may include an alkaline earth metal oxide, such as BaO, SrO, CaO, BaxSri-xO (wherein x is a real number satisfying the condition of 0<x<1), BaₓCa₁₋ₓO (wherein x is a real number satisfying the condition of 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth metal complex, and the rare earth metal complex may include an alkali metal ion, an alkaline earth metal ion, or a rare earth metal ion; and) a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (e.g., the compound represented by Formula 601).

In an embodiment, the electron injection layer may consist of an alkali metal-containing compound (e.g., an alkali metal halide); or the electron injection layer may consist of an alkali metal-containing compound (e.g., an alkali metal halide), and an alkali metal, an alkaline earth metal, a rare earth metal, or any combination thereof. For example, the electron injection layer may be a Kl:Yb co-deposited layer, an RbI:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within any of the ranges described above, satisfactory electron injection characteristics may be obtained without a substantial increase in driving voltage.

### [Second Electrode 150]

The second electrode 150 may be arranged on the interlayer 130 having a structure as described above. The second electrode 150 may be a cathode, which is an electron injection electrode. When the second electrode 150 is a cathode, a material for forming the second electrode 150 may include a material having a low-work function, such as a metal, an alloy, an electrically conductive compound, or any combination thereof.

The second electrode 150 may include lithium (Li), silver (Ag), magnesium (Mg), aluminum (Al), aluminum-lithium (A₁-Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layered structure or a multi-layered structure.

### [Capping Layer]

The light-emitting device 10 may include a first capping layer outside the first electrode 110, and/or a second capping layer outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in the emission layer of the interlayer 130 of the light-emitting device 10 may pass through the first electrode 110, which may be a transflective electrode or a transmissive electrode, and through the first capping layer to the outside. Light generated in the emission layer of the interlayer 130 of the light-emitting device 10 may pass through the second electrode 150, which may be a transflective electrode or a transmissive electrode, and through the second capping layer to the outside.

The first capping layer and the second capping layer may each increase external emission efficiency according to the principle of constructive interference. Accordingly, the light-extraction efficiency of the light-emitting device 10 may be increased, and thus, the luminescence efficiency of the light-emitting device 10 may be increased.

The first capping layer and the second capping layer may each include a material having a refractive index of greater than or equal to about 1.6 (with respect to a wavelength of about 589 nm)

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, β-NPB, or any combination thereof:

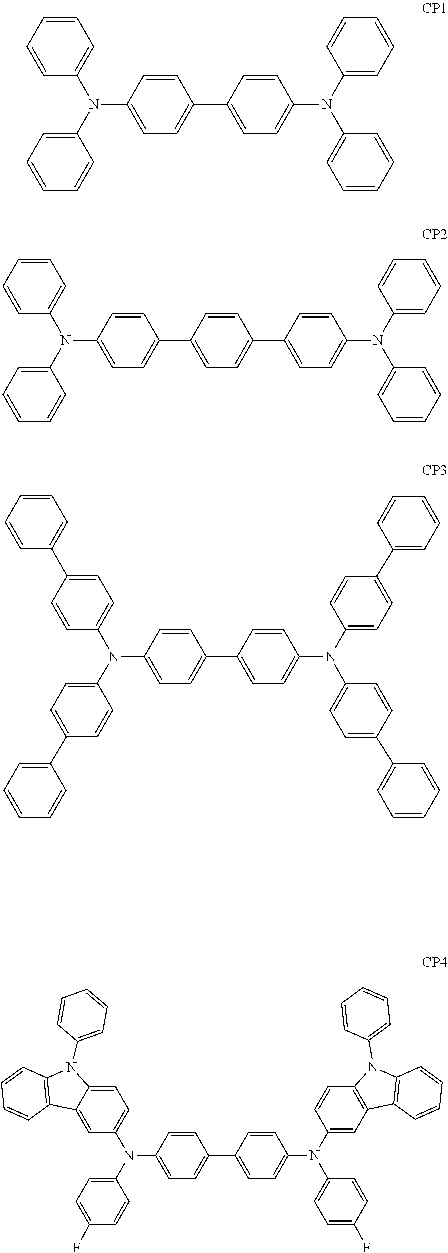 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

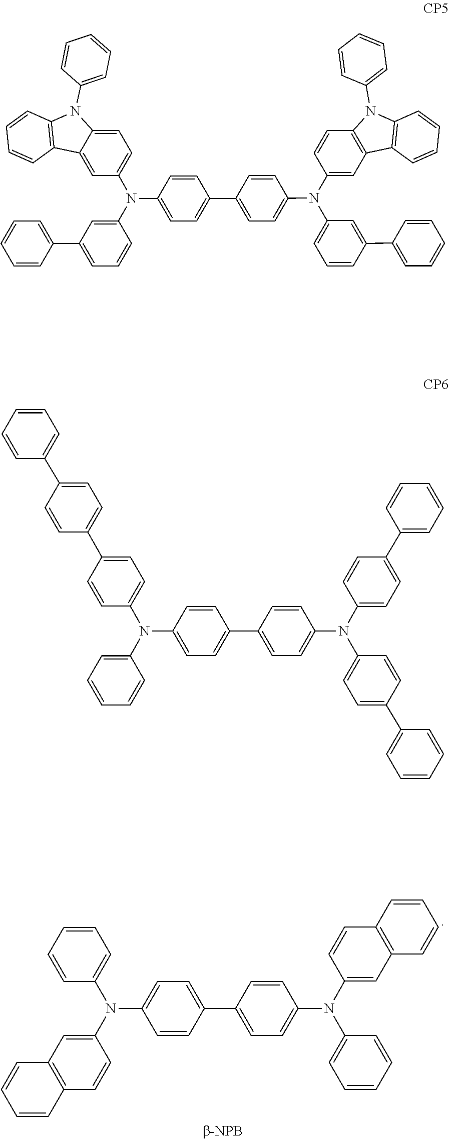 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Film]

The condensed cyclic compound represented by Formula 1 may be included in various films. Embodiments provide a film including the condensed cyclic compound represented by Formula 1. The film may be, for example, an optical member (or a light control means) (e.g., a color filter, a color conversion member, a capping layer, a light-extraction efficiency enhancement layer, a selective light-absorbing layer, a polarizing layer, a quantum dot-containing layer, etc.), a light-blocking member (e.g., a light-reflecting layer, a light-absorbing layer, etc.), a protective member (e.g., an insulating layer, a dielectric layer, etc.), or the like.

### [Electronic Apparatus]

The light-emitting device may be included in various electronic apparatuses. For example, an electronic apparatus including the light-emitting device may be a light-emitting apparatus, an authentication apparatus, or the like.

The electronic apparatus (e.g., a light-emitting apparatus) may further include, in addition to the light-emitting device, a color filter, a color conversion layer, or a color filter and a color conversion layer. The color filter and/or the color conversion layer may be arranged in at least one direction in which light emitted from the light-emitting device travels. For example, the light emitted from the light-emitting device may be blue light or white light. The light-emitting device may be the same as described herein. In an embodiment, the color conversion layer may include a quantum dot. The quantum dot may be, for example, a quantum dot as described herein.

The electronic apparatus may include a substrate. The substrate may include subpixels, the color filter may include color filter areas that respectively correspond to the subpixels, and the color conversion layer may include color conversion areas that respectively correspond to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. In an embodiment, the first area may include a red quantum dot, the second area may include a green quantum dot, and the third area may not include a quantum dot. The quantum dot may be the same as described herein. The first area, the second area, and/or the third area may each further include a scatterer.

In an embodiment, the light-emitting device may emit first light, the first area may absorb the first light to emit first-first color light, the second area may absorb the first light to emit second-first color light, and the third area may absorb the first light to emit third-first color light. In an embodiment, the first-first color light, the second-first color light, and the third-first color light may have different maximum emission wavelengths. For example, the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, and the like.

The active layer may include crystalline silicon, amorphous silicon, an organic semiconductor, an oxide semiconductor, and the like.

The electronic apparatus may further include a sealing portion for sealing the light-emitting device. The sealing portion may be arranged between the color filter and/or the color conversion layer and the light-emitting device. The sealing portion may allow light from the light-emitting device to be extracted to the outside, and may prevent ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (e.g., fingertips, pupils, etc.).

The authentication apparatus may further include, in addition to the light-emitting device as described above, a biometric information collector.

The electronic apparatus may be applied to various displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

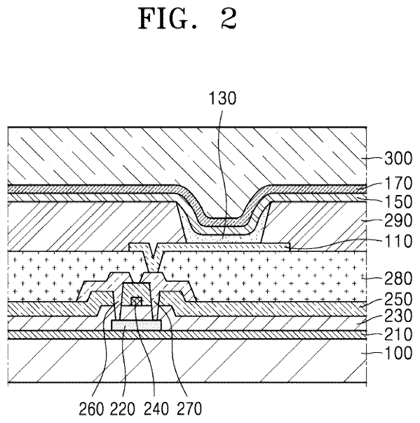

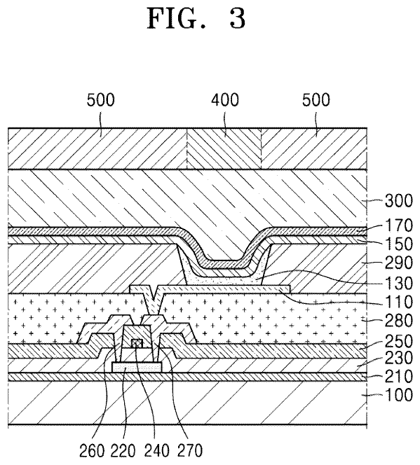

### [Descriptions of FIGS. 2 and 3]

FIG. 2 is a schematic cross-sectional view of an electronic apparatus according to an embodiment.

The electronic apparatus of FIG. 2 may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100, and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be arranged on the passivation layer 280. The passivation layer 280 may not completely cover the drain electrode 270 and may expose a portion of the drain electrode 270. The first electrode 110 may be connected (for example, electrically connected) to the exposed portion of the drain electrode 270.

A pixel-defining film 290 including an insulating material may be arranged on the first electrode 110. The pixel-defining film 290 may expose a certain region of the first electrode 110, and an interlayer 130 may be formed in the exposed region of the first electrode 110. The pixel-defining film 290 may be a polyimide-based organic film or a polyacrylic organic film. Although not shown in FIG. 2, at least some layers of the interlayer 130 may extend beyond the upper portion of the pixel-defining film 290 to be provided in the form of a common layer.

The second electrode 150 may be arranged on the interlayer 130, and a capping layer 170 may be further included on the second electrode 150. The capping layer 170 may be formed to cover the second electrode 150.

The encapsulation portion 300 may be arranged on the capping layer 170. The encapsulation portion 300 may be arranged on a light-emitting device to protect the light-emitting device from moisture or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or any combination of the inorganic film and the organic film.

FIG. 3 is a cross-sectional view of an electronic apparatus according to another embodiment.

The electronic apparatus of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, the electronic device included in the light-emitting apparatus of FIG. 3 may be a tandem light-emitting device.

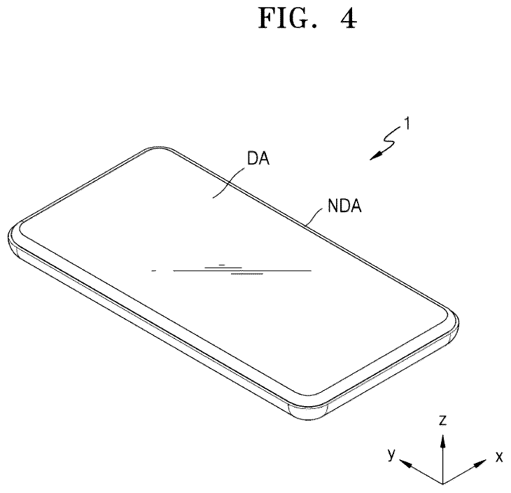

### [Description of FIG. 4]

FIG. 4 is a schematic perspective view of an electronic equipment 1 including a light-emitting device according to an embodiment.

The electronic equipment 1, which may be an apparatus that displays a moving image or a still image, may not only be a portable electronic device, such as a mobile phone, a smart phone, a tablet computer, a mobile communication terminal, an electronic notebook, an electronic book, a portable multimedia player (PMP), a navigation device, or an ultra-mobile PC (UMPC), but may also be various products, such as a television, a laptop, a monitor, a billboard, or an Internet of things (IoT) device, or a part of such various products.

In an embodiment, the electronic equipment 1 may be a wearable device, such as a smart watch, a watch phone, a glasses-type display, or a head mounted display (HMD), or a part of such a wearable device. However, embodiments are not limited thereto.

In an embodiment, examples of the electronic equipment 1 may include a dashboard of a vehicle, a center fascia of a vehicle, a center information display (CID) arranged on a dashboard of a vehicle, a room mirror display replacing a side mirror of a vehicle, an entertainment display for a rear seat of a vehicle, a display arranged on the back of a front seat, a head up display (HUD) installed in the front of a vehicle or projected on a front window glass, or a computer-generated hologram augmented-reality head up display (CGH AR HUD). FIG. 4 illustrates an embodiment in which the electronic equipment 1 is a smartphone for convenience of explanation.

The electronic equipment 1 may include a display area DA and a non-display area NDA outside the display area DA. A display apparatus may implement an image through a two-dimensional array of pixels that are arranged in the display area DA.

The non-display area NDA may be an area that does not display an image, and may surround (e.g., entirely surround) the display area DA. A driver for providing electrical signals or power to display devices arranged on the display area DA may be arranged in the non-display area NDA. A pad, which is an area to which an electronic element or a printed circuit board may be electrically connected, may be arranged in the non-display area NDA.

In the electronic equipment 1, a length in an x-axis direction and a length in a y-axis direction may be different from each other. In an embodiment, as shown in FIG. 4, a length in the x-axis direction may be less than a length in the y-axis direction. In an embodiment, a length in the x-axis direction may be the same as a length in the y-axis direction. In an embodiment, a length in the x-axis direction may be greater than a length in the y-axis direction.

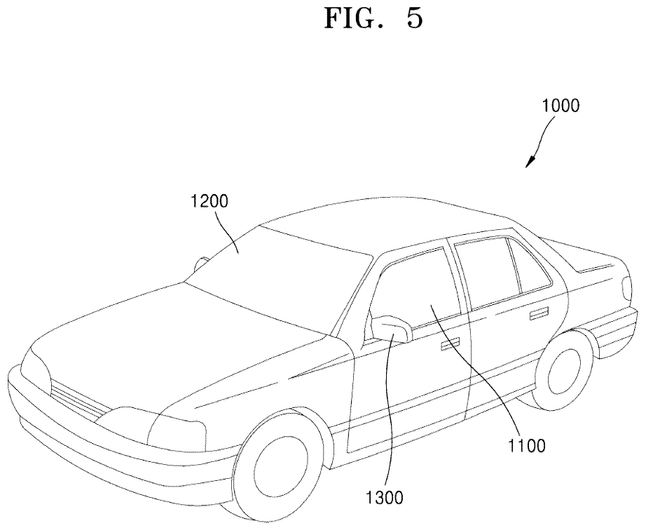

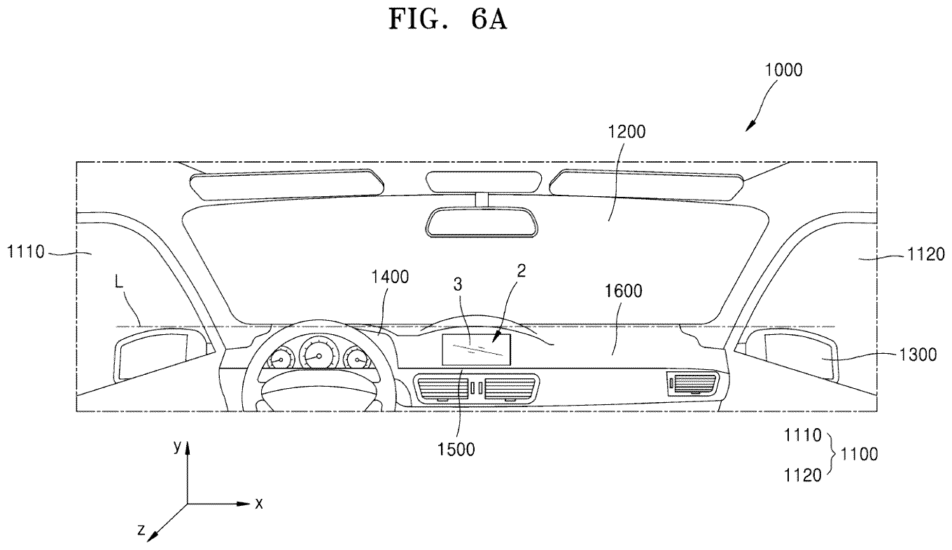

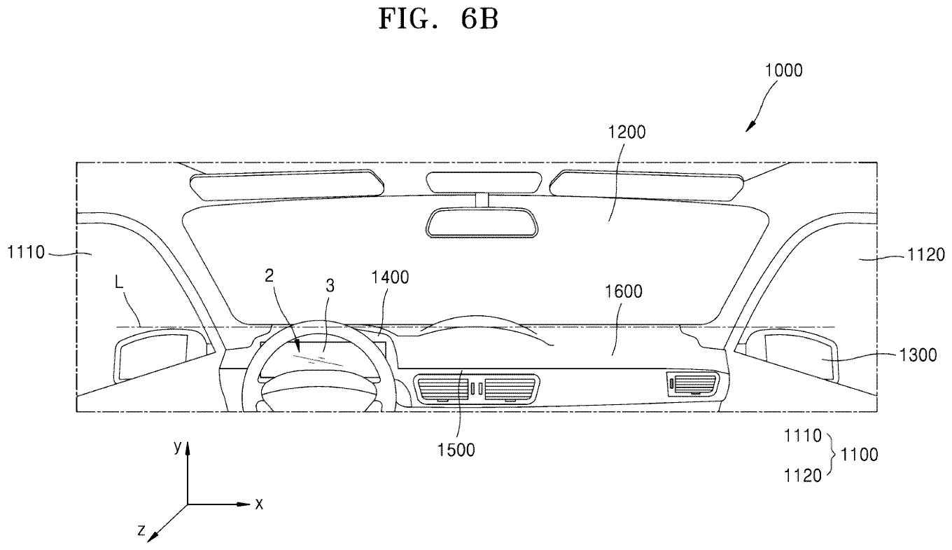

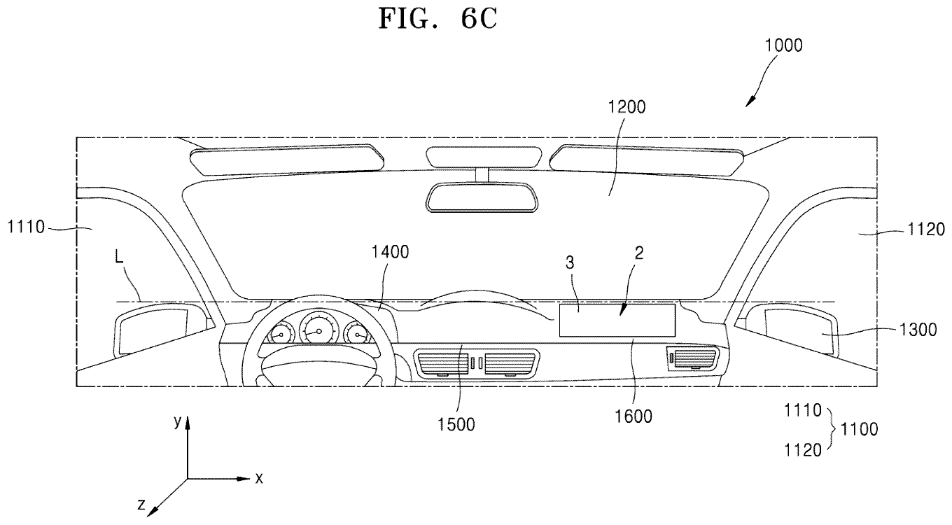

### [Descriptions of FIGS. 5 and 6A to 6C]

FIG. 5 is a schematic perspective view of an exterior of a vehicle 1000 as an electronic equipment including the light-emitting device according to an embodiment. FIGS. 6A to 6C are each a schematic diagram of an interior of the vehicle 1000 according to embodiments.

Referring to FIGS. 5, 6A, 6B, and 6C, the vehicle 1000 may include various apparatuses for moving a subject to be transported, such as a person, an object, or an animal, from a departure point to a destination point. The vehicle 1000 may include a vehicle traveling on a road or a track, a vessel moving over the sea or river, an airplane flying in the sky using the action of air, and the like.

The vehicle 1000 may travel on a road or a track. The vehicle 1000 may move in a selectable direction according to rotation of at least one wheel. Examples of, the vehicle 1000 may include a three-wheeled or four-wheeled vehicle, a construction machine, a two-wheeled vehicle, a prime mover device, a bicycle, and a train running on a track.

The vehicle 1000 may include a body of the vehicle 1000 having an interior and an exterior, and a chassis that is a portion excluding the body in which mechanical apparatuses necessary for driving are installed. The exterior of the body of the vehicle 1000 may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear left and right wheels, and the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400. The second side window glass 1120 may be arranged adjacent to the passenger seat dashboard 1600.

In an embodiment, the side window glasses 1100 may be spaced apart from each other in the x-direction or the −x-direction. For example, the first side window glass 1110 and the second side window glass 1120 may be spaced apart from each other in the x-direction or the −x-direction. For example, a virtual straight line L connecting the side window glasses 1100 may extend in the x-direction or the −x-direction. For example, a virtual straight line L connecting the first side window glass 1110 and the second side window glass 1120 to each other may extend in the x-direction or the −x-direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the body of the vehicle 1000. In an embodiment, multiple side mirrors 1300 may be provided. For example, one of the side mirrors 1300 may be arranged outside the first side window glass 1110, and another one of the side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which buttons for adjusting an audio device, an air conditioning device, and a seat heater are arranged. The center fascia 1500 may be arranged on a side of the cluster 1400.

The passenger seat dashboard 1600 may be spaced apart from the cluster 1400, and the center fascia 1500 may be arranged between the cluster 1400 and the passenger seat dashboard 1600. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged on at least one of the cluster 1400, the center fascia 1500, and the passenger seat dashboard 1600.

The display apparatus 2 may include an organic light-emitting display apparatus, an inorganic light-emitting display apparatus, a quantum dot display apparatus, and the like. Hereinafter, an organic light-emitting display apparatus including the light-emitting device according to an embodiment will be described as an example of the display apparatus 2, but various types of display apparatuses as described above may be used in embodiments.

Referring to FIG. 6A, the display apparatus 2 may be arranged on the center fascia 1500. In an embodiment, the display apparatus 2 may display navigation information. In an embodiment, the display apparatus 2 may display information regarding audio settings, video settings, or vehicle settings.

Referring to FIG. 6B, the display apparatus 2 may be arranged on the cluster 1400. In an embodiment, when the display apparatus 2 is arranged on the cluster 1400, the cluster 1400 may display driving information and the like through the display apparatus 2. For example, the cluster 1400 may digitally implement driving information and the like. The cluster 1400 may digitally display vehicle information and driving information as images. For example, a needle and a gauge of a tachometer and various warning lights or icons may be displayed by a digital signal.

Referring to FIG. 6C, the display apparatus 2 may be arranged on the passenger seat dashboard 1600. The display apparatus 2 may be embedded in the passenger seat dashboard 1600 or arranged on the passenger seat dashboard 1600.

In an embodiment, the display apparatus 2 arranged on the passenger seat dashboard 1600 may display an image that is related to information displayed on the cluster 1400 and/or information displayed on the center fascia 1500. In an embodiment, the display apparatus 2 arranged on the passenger seat dashboard 1600 may display information that is different from information displayed on the cluster 1400 and/or information displayed on the center fascia 1500.

### [Manufacturing Method]

The layers constituting the hole transport region, the emission layer, and the layers constituting the electron transport region may be formed in a certain region by using various methods such as vacuum deposition, spin coating, casting, Langmuir-Blodgett (LB) deposition, ink-jet printing, laser-printing, laser-induced thermal imaging, and the like.

When the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having 3 to 60 carbon atoms, and the term “C₁-C₆₀ heterocyclic group” as used herein may be a cyclic group that has 1 to 60 carbon atoms and further includes, in addition to carbon atoms, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, the C₁-C₆₀ heterocyclic group may have 3 to 61 ring-forming atoms.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety, and the term “π electron-deficient nitrogen-containing C₁-C₆₀ cyclic group” as used herein may be a heterocyclic group that has 1 to 60 carbon atoms and may include *—N═*′ as a ring-forming moiety.

In an embodiment,
a C₃-C₆₀ carbocyclic group may be a T1 group or a group in which two or more T1 groups are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which at least one T2 group and at least one T1 group are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (e.g., a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
a π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
a T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
a T3 group may be a furan group, a thiophene group, a 1H-pyrrole group, a silole group, or a borole group, and
a T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, and “π electron-deficient nitrogen-containing C₁-C₆₀ cyclic group” as used herein may each be a group condensed to any cyclic group, a monovalent group, or a polyvalent group (e.g., a divalent group, a trivalent group, a tetravalent group, etc.) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group,

Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched monovalent aliphatic hydrocarbon group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of the C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of the C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that has 1 to 10 carbon atoms and further includes, in addition to carbon atoms, at least one heteroatom as a ring-forming atom, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms, at least one carbon-carbon double bond in the cyclic structure thereof, and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has 1 to 10 carbon atoms, further includes, in addition to carbon atoms, at least one heteroatom as a ring-forming atom, and has at least one carbon-carbon double bond in the cyclic structure thereof. Examples of a C₁-C₁ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the two or more respective rings may be condensed with each other.

The term “C₁-C₆₀ heteroaryl group” as used herein may be a monovalent group having a heterocyclic aromatic system that has 1 to 60 carbon atoms and further includes, in addition to carbon atoms, at least one heteroatom as a ring-forming atom. The term “C₁-C₆₀ heteroarylene group” as used herein may be a divalent group having a heterocyclic aromatic system that has 1 to 60 carbon atoms and further includes, in addition to carbon atoms, at least one heteroatom as a ring-forming atom. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the two or more respective rings may be condensed with each other.

The term “monovalent non-aromatic condensed polycyclic group” as used herein may be a monovalent group having two or more rings condensed with each other, only carbon atoms (e.g., 8 to 60 carbon atoms) as ring-forming atoms, and no aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like. The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group that has two or more rings condensed with each other, further includes, in addition to carbon atoms (e.g., 1 to 60 carbon atoms), at least one heteroatom as a ring-forming atom, and has no aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group “R₁₀ₐ” may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

The term “heteroatom” as used herein may be any atom other than a carbon atom or a hydrogen atom. Examples of a heteroatom may include B, O, S, N, P, Si, B, Ge, Se, or any combination thereof.

The term “transition metal” as used herein may include hafnium (Hf), tantalum (Ta), tungsten (W), rhenium (Re), osmium (Os), iridium (Ir), platinum (Pt), gold (Au), and the like.

In the specification, the term “Ph” refers to a phenyl group, the term “Me” refers to a methyl group, the term “Et” refers to an ethyl group, the term “tert-Bu” or “Bu^{t}” refers to a tert-butyl group, and the term “OMe” refers to a methoxy group.

The term “biphenyl group” as used herein may be a “phenyl group substituted with a phenyl group”. For example, the “biphenyl group” may be a substituted phenyl group having a C₆-C₆₀ aryl group as a substituent.

The term “terphenyl group” as used herein may be a “phenyl group substituted with a biphenyl group”. For example, the “terphenyl group” may be a substituted phenyl group having, as a substituent, a C₆-C₆₀ aryl group substituted with a C₆-C₆₀ aryl group.

The symbols *, *′, and *″ as used herein, unless defined otherwise, each indicate a binding site to a neighboring atom in a corresponding formula or moiety.

Hereinafter, compounds according to embodiments and light-emitting devices according to embodiments will be described in detail with reference to the Synthesis Examples and Examples. The wording “B was used instead of A” used in describing the Synthesis Examples means that an identical molar equivalent of B was used in place of A.

### SYNTHESIS EXAMPLES AND EXAMPLES

### Synthesis Example 1: Synthesis of Compound 1

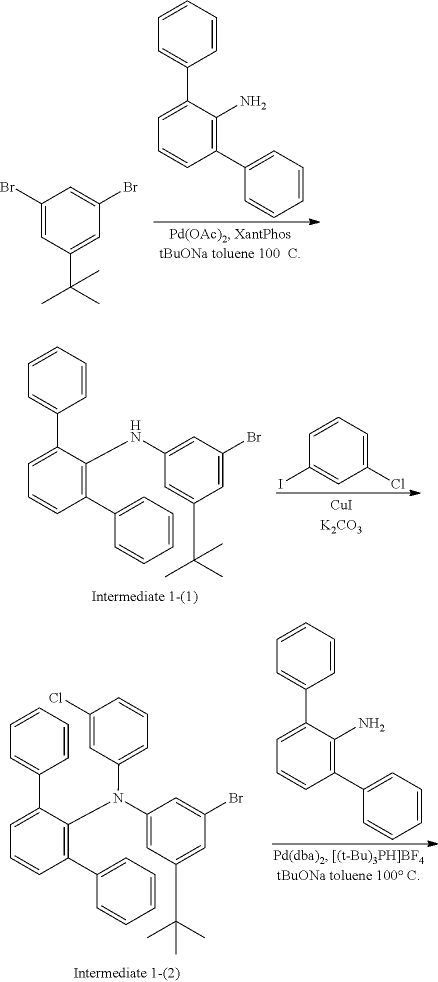

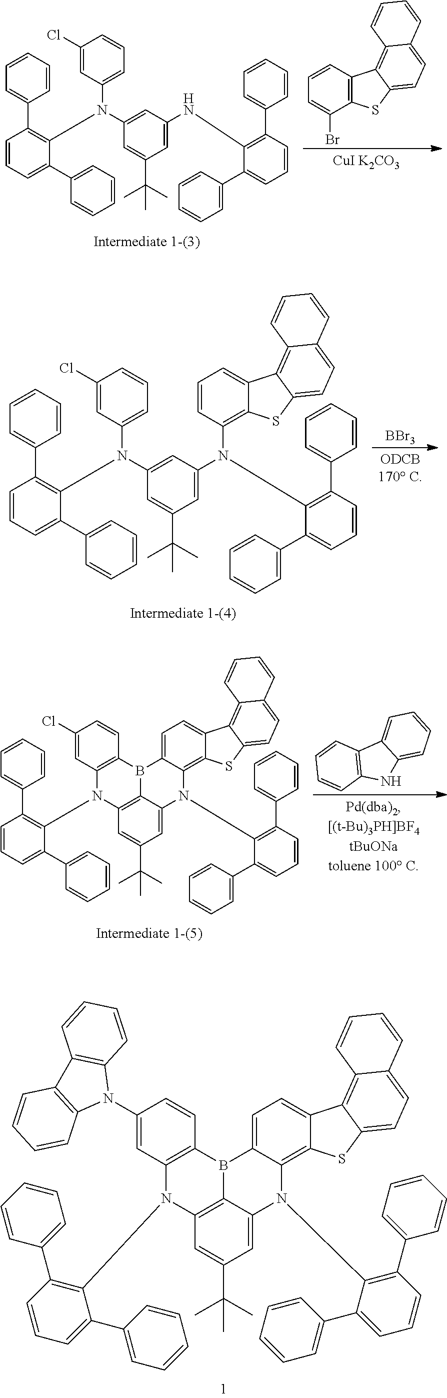

In an argon (Ar) atmosphere, 1,3-dibromo-5-(tert-butyl)benzene (8.02 g, 27.46 mmol), [1,1′:3′,1″-terphenyl]-2′-amine (13.48 g, 54.95 mmol), Pd(OAc)₂ (0.18 g, 0.80 mmol), XantPhos (0.95 g, 1.65 mmol), and tBuONa (3.17 g, 32.99 mmol) were added to toluene (137 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 1-(1) (10.66 g, yield of 85%). In FAB MS measurement, the molecular weight of Intermediate 1-(1) was 456.

### Synthesis of Intermediate 1-(2)

Intermediate 1-(1) (10.05 g, 22.02 mmol), 1-chloro-3-iodobenzene (78.76 g, 330.30 mmol), CuI (8.81 g, 46.26 mmol), and K₂CO₃ (24.35 g, 176.19 mmol) were added to a small amount of toluene (10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 1-(2) (10.99 g, yield of 88%). In FAB MS measurement, the molecular weight of Intermediate 1-(2) was 567.

### Synthesis of Intermediate 1-(3)

In an Ar atmosphere, Intermediate 1-(2) (10.55 g, 18.61 mmol), [1,1′:3′,1″-terphenyl]-2′-amine (9.13 g, 37.22 mmol), Pd(dba)₂ (1.07 g, 1.86 mmol), [(t-Bu)₃PH]BF₄ (1.08 g, 3.72 mmol), and tBuONa (4.11 g, 42.8 mmol) were added to toluene (93 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 1-(3) (12.25 g, yield of 90%). In FAB MS measurement, the molecular weight of Intermediate 1-(3) was 731.

### Synthesis of Intermediate 1-(4)

Intermediate 1-(3) (5.01 g, 6.85 mmol), 8-bromobenzo[b]naphtho[1,2-d]thiophene (10.73 g, 34.25 mmol), CuI (2.74 g, 14.39 mmol), and K₂CO₃ (11.36 g, 82.2 mmol) were added to a small amount of toluene (about 10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 1-(4) (4.29 g, yield of 65%). In FAB MS measurement, the molecular weight of Intermediate 1-(4) was 964.

### Synthesis of Intermediate 1-(5)

In an Ar atmosphere, Intermediate 1-(4) (4.11 g, 4.26 mmol) was dissolved in orthodichlorobenzene (ODCB) (43 ml), BBr₃ (2.14 g, 8.54 mmol) was added thereto, and the resultant reaction solution was heated and stirred at 170° C. for 10 hours. The reaction solution was cooled to room temperature, N,N-diisopropylethylamine (DIPEA) (6.6 g, 51.06 mmol) was added thereto, water was added thereto, the reaction solution was filtered through Celite and aliquoted, and the resultant organic layer was concentrated and purified by silica gel column chromatography, to thereby obtain Intermediate 1-(5) (1.33 g, yield of 32%). In FAB MS measurement, the molecular weight of Intermediate 1-(5) was 971.

### Synthesis of Compound 1

In an Ar atmosphere, Intermediate 1-(5) (1.25 g, 1.29 mmol), 9H-carbazole (0.43 g, 2.57 mmol), Pd(dba)₂ (0.07 g, 0.12 mmol), [(t-Bu)₃PH]BF₄ (0.07 g, 0.24 mmol), and tBuONa (0.28 g, 2.91 mmol) were added to toluene (6 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Compound 1 (1.28 g, yield of 90%). In FAB MS measurement, the molecular weight of Compound 1 was 1102.

Compound 1 was purified by sublimation and subjected to light-emitting device evaluation (360° C., 3.2×10⁻³ Pa).

### Synthesis Example 2: Synthesis of Compound 7

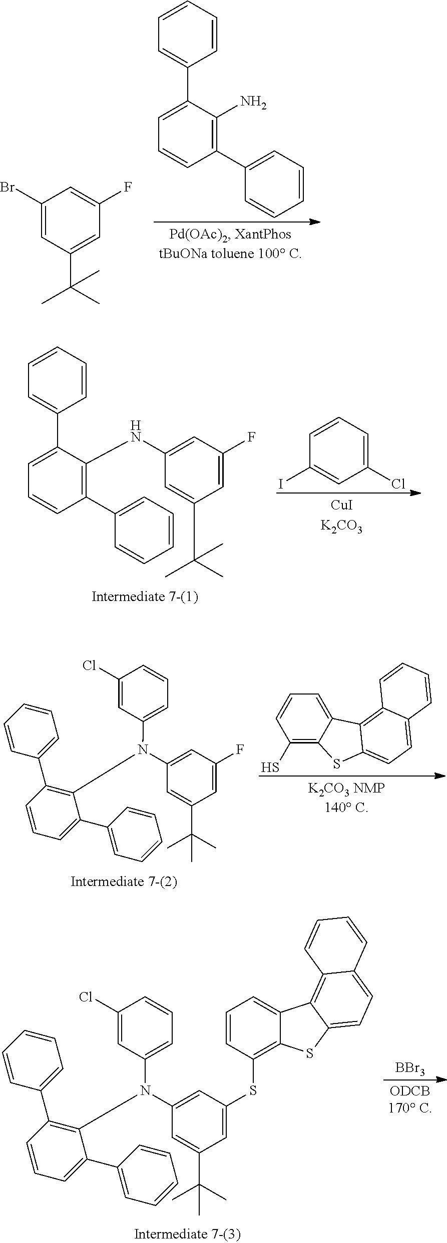

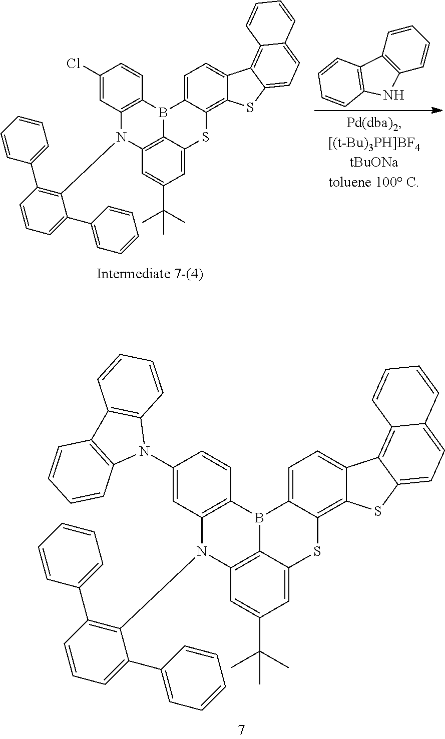

### Synthesis of Intermediate 7-(1)

In an Ar atmosphere, 1-bromo-3-(tert-butyl)-5-fluorobenzene (10.04 g, 43.44 mmol), [1,1′:3′,1″-terphenyl]-2′-amine (9.28 g, 37.83 mmol), Pd(OAc)₂ (0.23 g, 1.02 mmol), XantPhos (1.19 g, 2.06 mmol), and tBuONa (3.96 g, 41.21 mmol) were added to toluene (171 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 7-(1) (11.56 g, yield of 85%). In FAB MS measurement, the molecular weight of Intermediate 7-(1) was 396.

### Synthesis of Intermediate 7-(2)

Intermediate 7-(1) (10.88 g, 27.51 mmol), 1-chloro-3-iodobenzene (52.47 g, 220.05 mmol), CuI (11 g, 57.76 mmol), and K₂CO₃ (45.62 g, 330.1 mmol) were added to a small amount of toluene (about 10 ml), and the resultant reaction solution was heated for 24 hours while the external temperature was maintained at 215° C. After the reaction solution was diluted with CH₂Cl₂ and water was added thereto, the reaction solution was filtered through Celite and aliquoted, and the resultant organic layer was concentrated and purified by silica gel column chromatography, to thereby obtain Intermediate 7-(2) (12.11 g, yield of 87%). In FAB MS measurement, the molecular weight of Intermediate 7-(2) was 506.

### Synthesis of Intermediate 7-(3)

In an Ar atmosphere, Intermediate 7-(2) (6.42 g, 12.69 mmol), benzo[b]naphtho[1,2-d]thiophene-8-thiol (4.06 g, 15.24 mmol), and K₂CO₃ (7.89 g, 57.09 mmol) were added to N-methyl-2-pyrrolidone (NMP) (64 ml), and the resultant reaction solution was heated for 24 hours while the external temperature was maintained at 140° C. After the reaction solution was diluted with CH₂Cl₂ and water was added thereto, the reaction solution was filtered through Celite and aliquoted, and the resultant organic layer was concentrated and purified by silica gel column chromatography, to thereby obtain Intermediate 7-(3) (8.02 g, yield of 84%). In FAB MS measurement, the molecular weight of Intermediate 7-(3) was 752.

### Synthesis of Intermediate 7-(4)

In an Ar atmosphere, Intermediate 7-(3) (4.11 g, 5.46 mmol) was dissolved in ODCB (55 ml), BBr₃ (2.74 g, 10.94 mmol) was added thereto, and the resultant reaction solution was heated and stirred at 170° C. for 10 hours. The reaction solution was cooled to room temperature, DIPEA (8.46 g, 65.55 mmol) was added thereto, water was added thereto, the reaction solution was filtered through Celite and aliquoted, and the resultant organic layer was concentrated and purified by silica gel column chromatography, to thereby obtain Intermediate 7-(4) (1.29 g, yield of 31%). In FAB MS measurement, the molecular weight of Intermediate 7-(4) was 760.

### Synthesis of Compound 7

In an Ar atmosphere, Intermediate 7-(4) (1.11 g, 1.46 mmol), 9H-carbazole (0.49 g, 2.93 mmol), Pd(dba)₂ (0.08 g, 0.14 mmol), [(t-Bu)₃PH]BF₄ (0.08 g, 0.28 mmol), and tBuONa (0.32 g, 3.33 mmol) were added to toluene (7 ml), and the resultant reaction solution was heated and stirred at 100° C. for 8 hours. After water was added thereto, the reaction solution was filtered through Celite and aliquoted, and the resultant organic layer was concentrated and purified by silica gel column chromatography, to thereby obtain Compound 7 (1.21 g, yield of 93%). In FAB MS measurement, the molecular weight of Compound 7 was 891.

Compound 7 was purified by sublimation and subjected to light-emitting device evaluation (360° C., 3.2×10⁻³ Pa).

### Synthesis Example 3: Synthesis of Compound 67

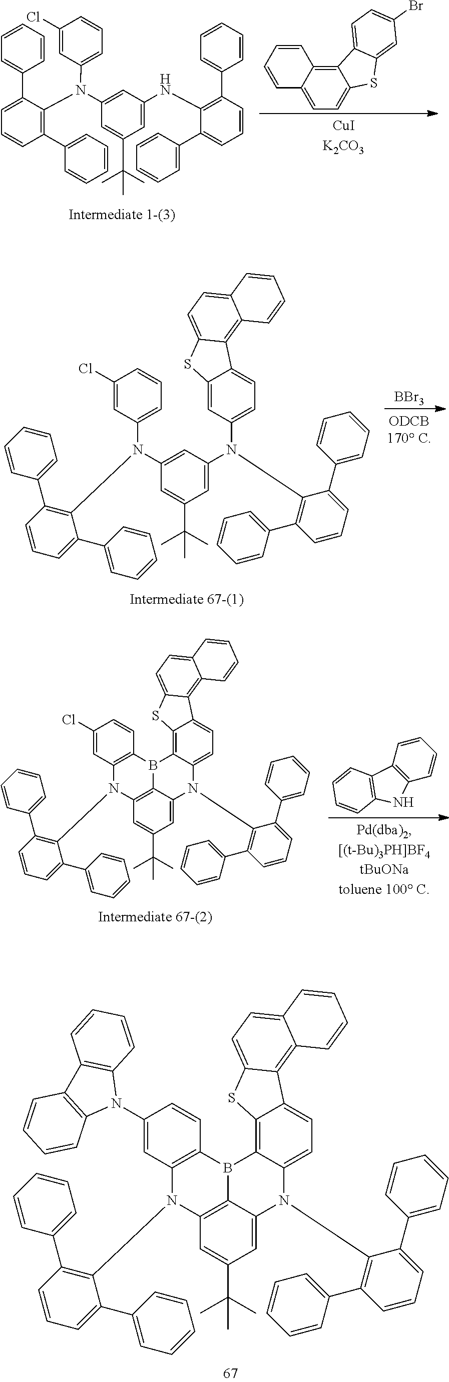

### Synthesis of Intermediate 67-(1)

Intermediate 1-(3) (8.03 g, 10.98 mmol), 9-bromobenzo[b]naphtho[1,2-d]thiophene (17.19 g, 54.9 mmol), CuI (4.39 g, 23.05 mmol), and K₂CO₃ (15.17 g, 109.76 mmol) were added to a small amount of toluene (about 10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 67-(1) (7.83 g, yield of 74%). In FAB MS measurement, the molecular weight of Intermediate 67-(1) was 964.

### Synthesis of Intermediate 67-(2)

In an Ar atmosphere, Intermediate 64-(1) (7.55 g, 7.83 mmol) was dissolved in ODCB (78 ml), BBr₃ (3.93 g, 15.69 mmol) was added thereto, and the resultant reaction solution was heated and stirred at 170° C. for 10 hours. The reaction solution was cooled to room temperature, DIPEA (12.13 g, 94.01 mmol) was added thereto, water was added thereto, the reaction solution was filtered through Celite and aliquoted, and the resultant organic layer was concentrated and purified by silica gel column chromatography, to thereby obtain Intermediate 64-(2) (1.22 g, yield of 16%). In FAB MS measurement, the molecular weight of Intermediate 64-(2) was 971.

### Synthesis of Compound 67

In an Ar atmosphere, Intermediate 67-(2) (1.11 g, 1.14 mmol), 9H-carbazole (0.38 g, 2.27 mmol), Pd(dba)₂ (0.07 g, 0.12 mmol), [(t-Bu)₃PH]BF₄ (0.07 g, 0.24 mmol), and tBuONa (0.25 g, 2.60 mmol) were added to toluene (5 ml), and the resultant reaction solution was heated and stirred at 100° C. for 8 hours. After water was added thereto, the reaction solution was filtered through Celite and aliquoted, and the resultant organic layer was concentrated and purified by silica gel column chromatography, to thereby obtain Compound 67 (1.11 g, yield of 88%). In FAB MS measurement, the molecular weight of Compound 67 was 1102.

Compound 67 was purified by sublimation and subjected to light-emitting device evaluation (360° C., 3.2×10⁻³ Pa).

### Synthesis Example 4: Synthesis of Compound 345

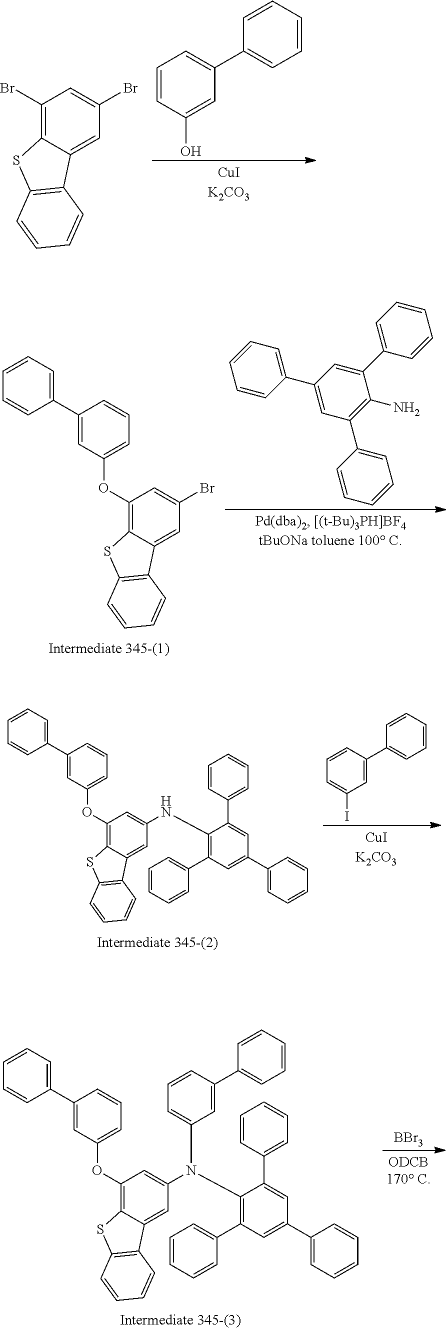

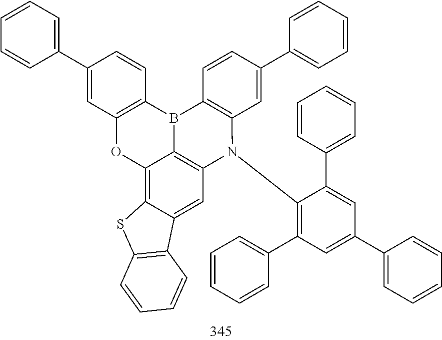 [SMILES: c1ccc(-c2ccc3c(c2)Oc2c4c(cc5c2sc2ccccc25)N(c2c(-c5ccccc5)cc(-c5ccccc5)cc2-c2ccccc2)c2cc(-c5ccccc5)ccc2B34)cc1]

### Synthesis of Intermediate 345-(1)

2,4-dibromodibenzo[b,d]thiophene (15.05 g, 44 mmol), [1,1′-biphenyl]-3-ol (11.23 g, 66 mmol), CuI (9.22 g, 48.4 mmol), K₂CO₃ (24.32 g, 176 mmol), and dipivaloylmethane (92.18 g, 0.5 mol) were added to DMF (921 ml), and the resultant reaction solution was heated for 24 hours while the external temperature was maintained at 100° C. After the reaction solution was diluted with CH₂Cl₂ and water was added thereto, the reaction solution was filtered through Celite and aliquoted, and the resultant organic layer was concentrated and purified by silica gel column chromatography, to thereby obtain Intermediate 345-(1) (6.07 g, yield of 32%). In FAB MS measurement, the molecular weight of Intermediate 345-(1) was 431.

### Synthesis of Intermediate 345-(2)

In an Ar atmosphere, Intermediate 345-(1) (5.83 g, 13.52 mmol), 5′-phenyl-[1,1′:3′,1″-terphenyl]-2′-amine (10.86 g, 33.79 mmol), Pd(dba)₂ (0.78 g, 1.36 mmol), [(t-Bu)₃PH]BF₄ (0.78 g, 2.7 mmol), and tBuONa (2.99 g, 31.11 mmol) were added to toluene (67 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 345-(2) (8.08 g, yield of 89%). In FAB MS measurement, the molecular weight of Intermediate 345-(2) was 672.

### Synthesis of Intermediate 345-(3)

Intermediate 345-(2) (7.78 g, 11.58 mmol), 3-iodo-1,1′-biphenyl (16.22 g, 57.9 mmol), CuI (4.63 g, 24.31 mmol), and K₂CO₃ (16 g, 115.8 mmol) were added to a small amount of toluene (about 10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 345-(3) (7.73 g, yield of 81%). In FAB MS measurement, the molecular weight of Intermediate 345-(3) was 824.

### Synthesis of Compound 345

In an Ar atmosphere, Intermediate 345-(3) (7.52 g, 9.1 mmol) was dissolved in ODCB (78 ml), BBr₃ (3.91 g, 15.61 mmol) was added thereto, and the resultant reaction solution was heated and stirred at 170° C. for 10 hours. The reaction solution was cooled to room temperature, DIPEA (12.08 g, 93.46 mmol) was added thereto, water was added thereto, the reaction solution was filtered through Celite and aliquoted, and the resultant organic layer was concentrated and purified by silica gel column chromatography, to thereby obtain Compound 345 (2.73 g, yield of 36%). In FAB MS measurement, the molecular weight of Compound 345 was 971.

Compound 345 was purified by sublimation and subjected to light-emitting device evaluation (360° C., 3.2×10⁻³ Pa).

### Synthesis Example 5: Synthesis of Compound 360

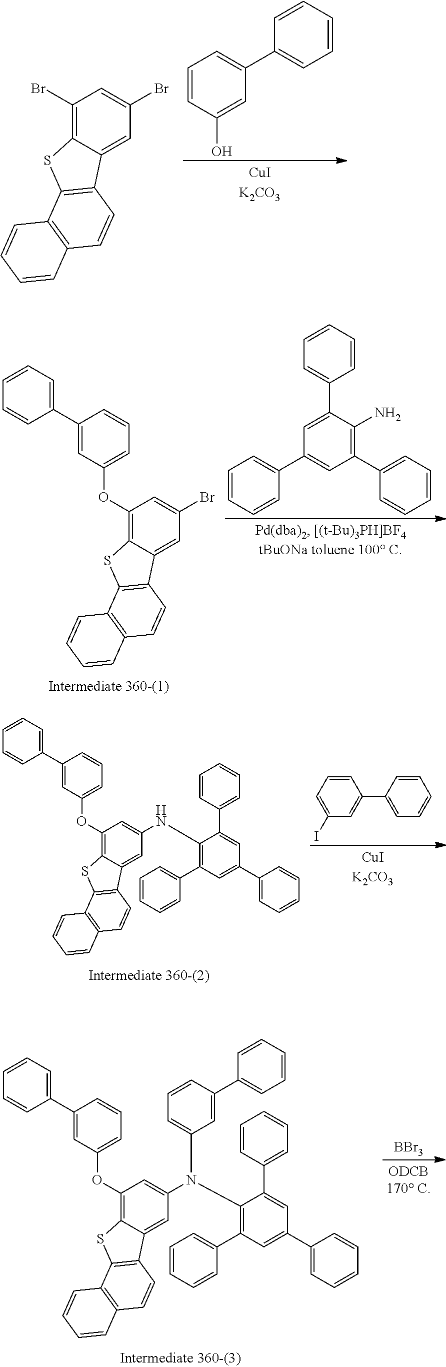

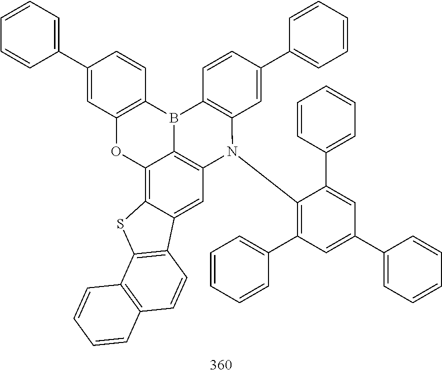 [SMILES: c1ccc(-c2ccc3c(c2)Oc2c4c(cc5c2sc2c6ccccc6ccc52)N(c2c(-c5ccccc5)cc(-c5ccccc5)cc2-c2ccccc2)c2cc(-c5ccccc5)ccc2B34)cc1]

### Synthesis of Intermediate 360-(1)

8,10-dibromobenzo[b]naphtho[2,1-d]thiophene (20.23 g, 51.59 mmol), [1,1′-biphenyl]-3-ol (11.79 g, 69.27 mmol), CuI (10.81 g, 56.76 mmol), K₂CO₃ (28.52 g, 206.36 mmol), and dipivaloylmethane (108.08 g, 0.59 mol) were added to DMF (1080 ml), and the resultant reaction solution was heated for 24 hours while the external temperature was maintained at 100° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 360-(1) (10.43 g, yield of 28%). In FAB MS measurement, the molecular weight of Intermediate 360-(1) was 481.

### Synthesis of Intermediate 360-(2)

In an Ar atmosphere, Intermediate 360-(1) (10.22 g, 21.23 mmol), 5′-phenyl-[1,1′:3′,1″-terphenyl]-2′-amine (17.06 g, 53.08 mmol), Pd(dba)₂ (1.22 g, 2.12 mmol), [(t-Bu)₃PH]BF₄ (1.23 g, 4.23 mmol), and tBuONa (4.69 g, 48.80 mmol) were added to toluene (106 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 360-(2) (13.03 g, yield of 85%). In FAB MS measurement, the molecular weight of Intermediate 357-(2) was 722.

### Synthesis of Intermediate 360-(3)

Intermediate 360-(2) (12.55 g, 17.38 mmol), 3-iodo-1,1′-biphenyl (24.35 g, 86.93 mmol), CuI (6.95 g, 36.5 mmol), and K₂CO₃ (24.03 g, 173.87 mmol) were added to a small amount of toluene (about 10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 360-(3) (13.07 g, yield of 86%). In FAB MS measurement, the molecular weight of Intermediate 360-(3) was 874.

### Synthesis of Compound 360

In an Ar atmosphere, Intermediate 360-(3) (6.52 g, 7.46 mmol) was dissolved in ODCB (75 ml), BBr₃ (3.74 g, 14.93 mmol) was added thereto, and the resultant reaction solution was heated and stirred at 170° C. for 10 hours. The reaction solution was cooled to room temperature, DIPEA (11.55 g, 89.36 mmol) was added thereto, water was added thereto, the reaction solution was filtered through Celite and aliquoted, and the resultant organic layer was concentrated and purified by silica gel column chromatography, to thereby obtain Compound 360 (2.10 g, yield of 32%). In FAB MS measurement, the molecular weight of Compound 360 was 882.

Compound 360 was purified by sublimation and subjected to light-emitting device evaluation (360° C., 3.2×10⁻³ Pa).

### Synthesis Example 6: Synthesis of Compound 480

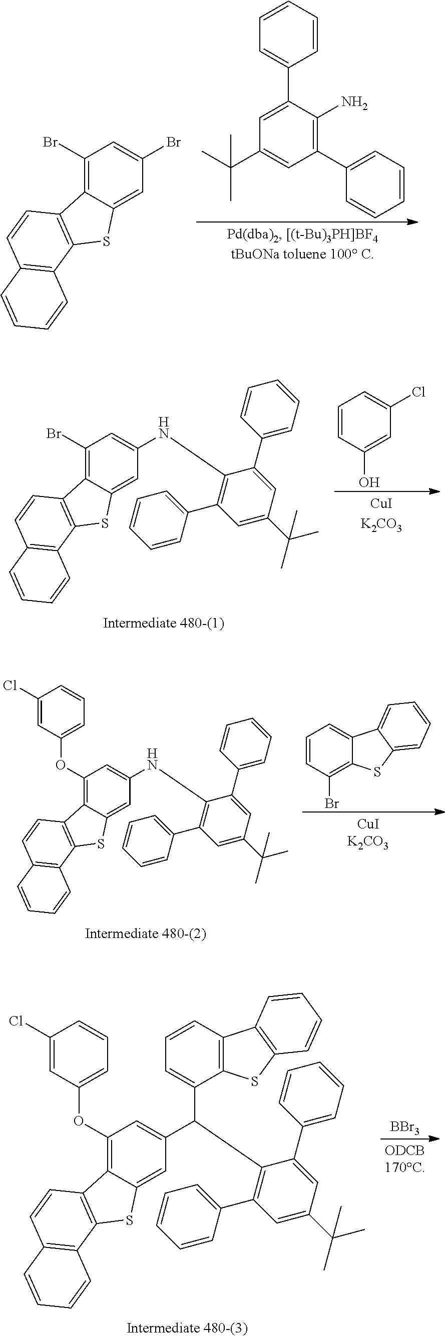

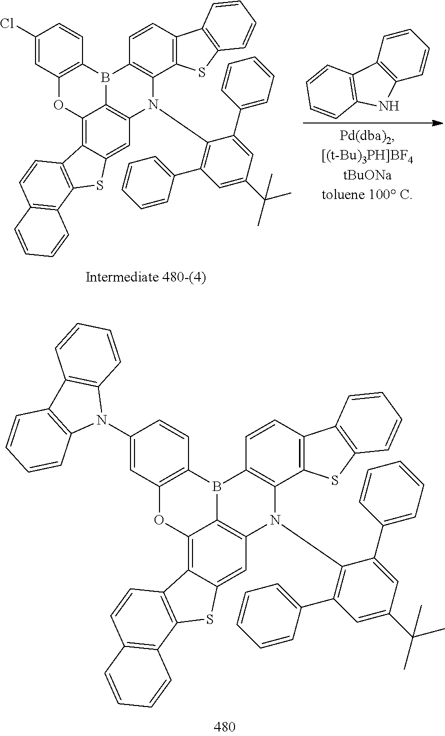

### Synthesis of Intermediate 480-(1)

In an Ar atmosphere, 7,9-dibromobenzo[b]naphtho[2,1-d]thiophene (10.11 g, 25.78 mmol), 5′-(tert-butyl)-[1,1′:3′,1″-terphenyl]-2′-amine (19.43 g, 64.46 mmol), Pd(dba)₂ (1.48 g, 2.57 mmol), [(t-Bu)₃PH]BF₄ (1.5 g, 5.17 mmol), and tBuONa (5.7 g, 59.3 mmol) were added to toluene (128 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Intermediate 480-(1) (13.9 g, yield of 88%). In FAB MS measurement, the molecular weight of Intermediate 480-(1) was 613.

### Synthesis of Intermediate 480-(2)

Intermediate 480-(1) (11.15 g, 18.2 mmol), 3-chlorophenol (4.16 g, 32.36 mmol), CuI (3.81 g, 20.01 mmol), K₂CO₃ (10.06 g, 72.8 mmol), and dipivaloylmethane (38.13 g, 0.21 mol) were added to DMF (381 ml), and the resultant reaction solution was heated for 24 hours while the external temperature was maintained at 100° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 480-(2) (9.25 g, yield of 77%). In FAB MS measurement, the molecular weight of Intermediate 480-(2) was 660.

### Synthesis of Intermediate 480-(3)

Intermediate 480-(2) (12.55 g, 19.01 mmol), 4-bromodibenzo[b,d]thiophene (25.01 g, 95.04 mmol), CuI (7.6 g, 39.91 mmol), and K₂CO₃ (26.27 g, 190.08 mmol) were added to a small amount of toluene (about 10 ml), and the resultant reaction solution was heated for 24 hours while the external temperature was maintained at 215° C. The reaction solution was diluted with CH₂Cl₂, water was added thereto, the reaction solution was filtered through Celite and aliquoted, and the resultant organic layer was concentrated and purified by silica gel column chromatography, to thereby obtain Intermediate 480-(3) (11.85 g, yield of 74%). In FAB MS measurement, the molecular weight of Intermediate 480-(3) was 843.

### Synthesis of Intermediate 480-(4)

In an Ar atmosphere, Intermediate 480-(3) (11.15 g, 13.23 mmol) was dissolved in ODCB (132 ml), BBr₃ (6.63 g, 26.46 mmol) was added thereto, and the resultant reaction solution was heated and stirred at 170° C. for 10 hours. The reaction solution was cooled to room temperature, DIPEA (20.49 g, 158.53 mmol) was added thereto, water was added thereto, the reaction solution was filtered through Celite and aliquoted, and the resultant organic layer was concentrated and purified by silica gel column chromatography, to thereby obtain Intermediate 480-(4) (3.71 g, yield of 33%). In FAB MS measurement, the molecular weight of Intermediate 480-(4) was 850.

### Synthesis of Compound 480

In an Ar atmosphere, Intermediate 480-(4) (3.52 g, 4.14 mmol), 9H-carbazole (1.38 g, 8.25 mmol), Pd(dba)₂ (0.24 g, 0.42 mmol), [(t-Bu)₃PH]BF₄ (0.24 g, 0.83 mmol), and tBuONa (0.92 g, 9.57 mmol) were added to toluene (20 ml), and the resultant reaction solution was heated and stirred at 100° C. for 8 hours. Water was added thereto, the reaction solution was filtered through Celite and aliquoted, and the resultant organic layer was concentrated and purified by silica gel column chromatography, to thereby obtain Compound 480 (3.37 g, yield of 83%). In FAB MS measurement, the molecular weight of Compound 480 was 981.

Compound 480 was purified by sublimation and subjected to light-emitting device evaluation (360° C., 3.2×10⁻³ Pa).

### Example 1

As an anode, a glass substrate (product of Corning Inc.) with a 15 Ω/cm² (1,200 Å) ITO electrode formed thereon was cut to a size of 50 mm×50 mm×0.7 mm, sonicated by using isopropyl alcohol and pure water each for 5 minutes, cleaned by irradiation of ultraviolet rays and exposure of ozone thereto for 30 minutes, and mounted on a vacuum deposition apparatus.

HAT-CN was deposited on the anode to form a hole injection layer having a thickness of 100 Å, α-NPD was deposited on the hole injection layer to form a hole transport layer having a thickness of 800 Å, and mCP was deposited on the hole transport layer to form an emission auxiliary layer having a thickness of 50 Å.

mCBP (host) and Compound 1 (dopant) were co-deposited at a weight ratio of 99:1 on the emission auxiliary layer to form an emission layer having a thickness of 200 Å.

TPBi was deposited on the emission layer to form an electron transport layer having a thickness of 300 Å, LiF was deposited on the electron transport layer to form an electron injection layer having a thickness of 5 Å, and A₁ was deposited on the electron injection layer to form a cathode having a thickness of 1,000 Å, thereby completing the manufacture of a light-emitting device.

### Examples 2 to 6 and Comparative Examples 1 to 12

Light-emitting devices of Examples 2 to 6 and Comparative Examples 1 to 12 were manufactured in the same manner as in Example 1, except that the compounds shown in Table 1 were each used as a dopant in forming an emission layer.

Evaluation Example. Evaluation of characteristics of light-emitting devices

To evaluate characteristics of the light-emitting devices manufactured according to Examples 1 to 6 and Comparative Examples 1 to 12, the maximum emission wavelength, roll-off ratio, and lifespan (T₅₀) thereof at a current density of 10 mA/cm² were measured, and the results are shown in Table 1.

In Table 1, the lifespan represents the time taken for the luminance to become 50% of the initial luminance, based on Comparative Example 3. The roll-off ratio was calculated according to Equation 20.

$$Roll - off ratio = \{ 1 - ( external quantum efficiency ( at 1 , 000 cd / {m}^{3} ) ) / external quantum efficiency ( at 1 cd / {m}^{3} ) ) \} \times 100 \% \qquad [ Equation 20 ]$$

TABLE 1

| | | Maximum emission | Roll-off | Lifespan |
|---|---|---|---|---|
| | Dopant | wavelength (nm) | ratio (%) | (T₅₀) |
| Example 1 | 1 | 463 | 12.1 | 4.2 |
| Example 2 | 7 | 462 | 11.6 | 3.8 |
| Example 3 | 67 | 463 | 10.7 | 4.5 |
| Example 4 | 345 | 458 | 13.3 | 3.8 |
| Example 5 | 360 | 460 | 12.4 | 4.1 |
| Example 6 | 480 | 459 | 10.6 | 4.8 |
| Comparative | CE1 | 457 | 33.2 | 0.3 |
| Example 1 | | | | |
| Comparative | CE2 | 446 | 30.5 | 0.2 |
| Example 2 | | | | |
| Comparative | CE3 | 467 | 13.5 | 1.0 |
| Example 3 | | | | |
| Comparative | CE4 | 472 | 42.5 | 0.33 |
| Example 4 | | | | |
| Comparative | CE5 | 465 | 40.3 | 0.35 |
| Example 5 | | | | |
| Comparative | CE6 | 463 | 55.5 | 0.17 |
| Example 6 | | | | |
| Comparative | CE7 | 458 | 58.7 | 0.35 |
| Example 7 | | | | |
| Comparative | CE8 | 472 | 60.2 | 0.21 |
| Example 8 | | | | |
| Comparative | CE9 | 473 | 62.4 | 0.32 |
| Example 9 | | | | |
| Comparative | CE10 | 460 | 55.2 | 0.11 |
| Example 10 | | | | |
| Comparative | CE11 | 465 | 35.4 | 0.25 |
| Example 11 | | | | |
| Comparative | CE12 | 463 | 20.4 | 1.75 |
| Example 12 | | | | |

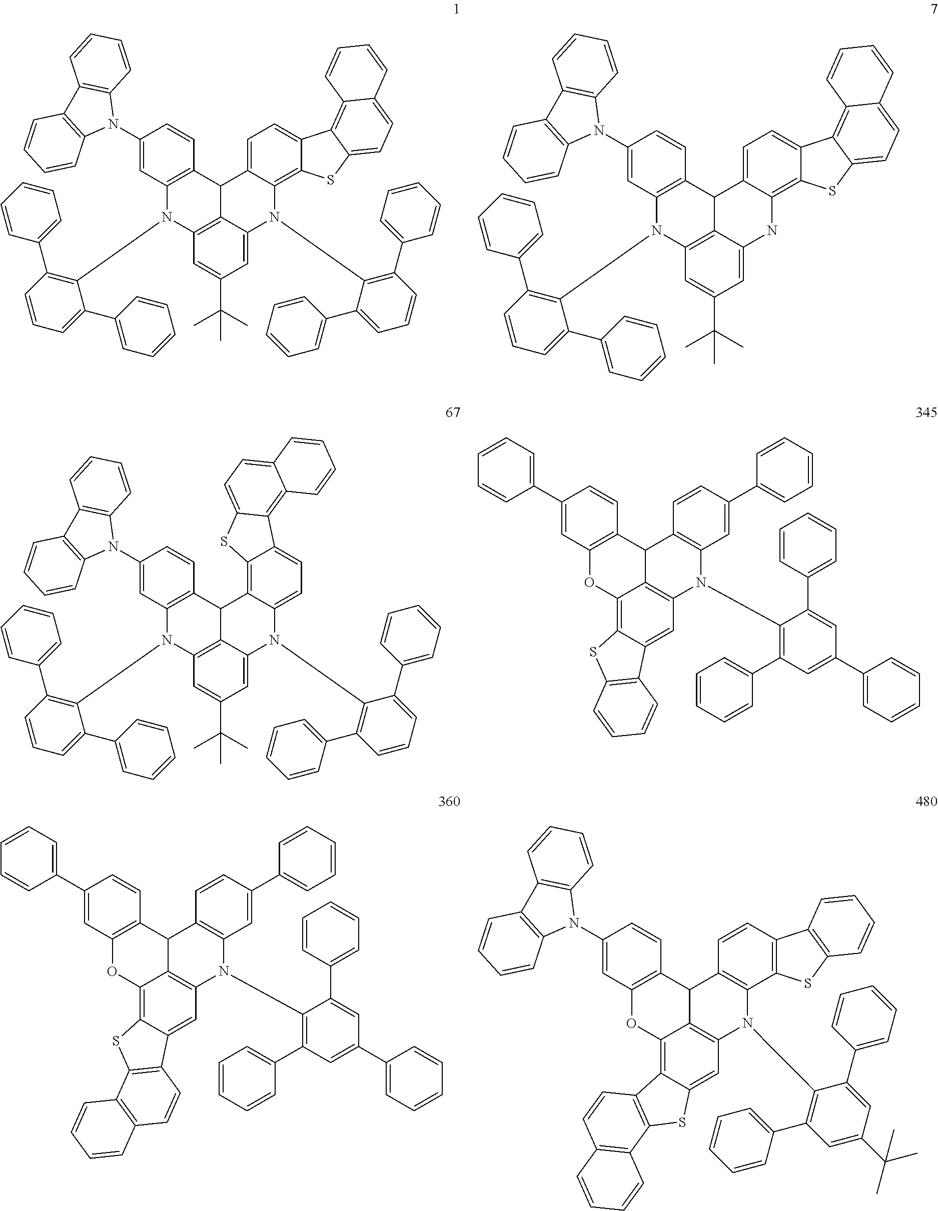

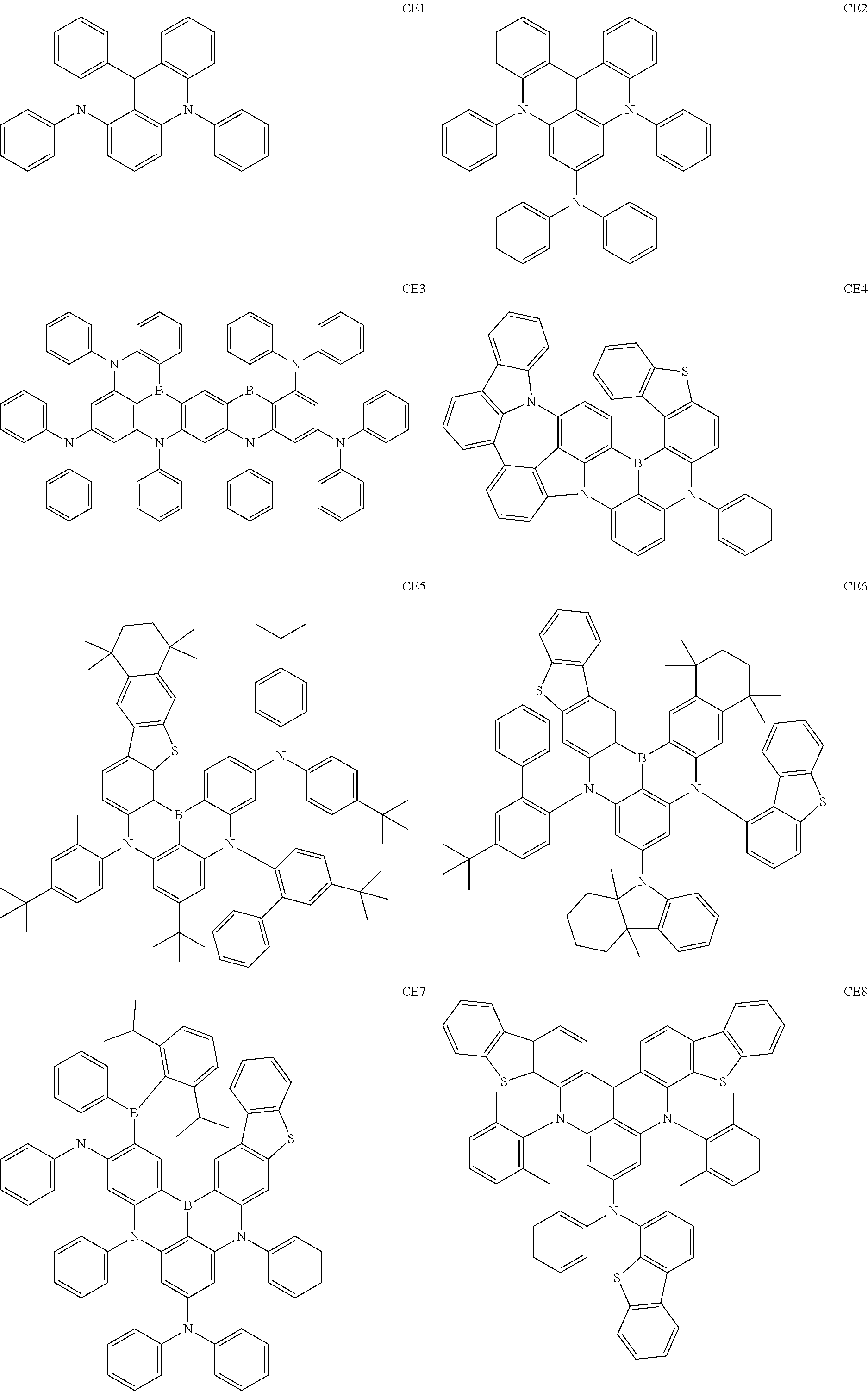

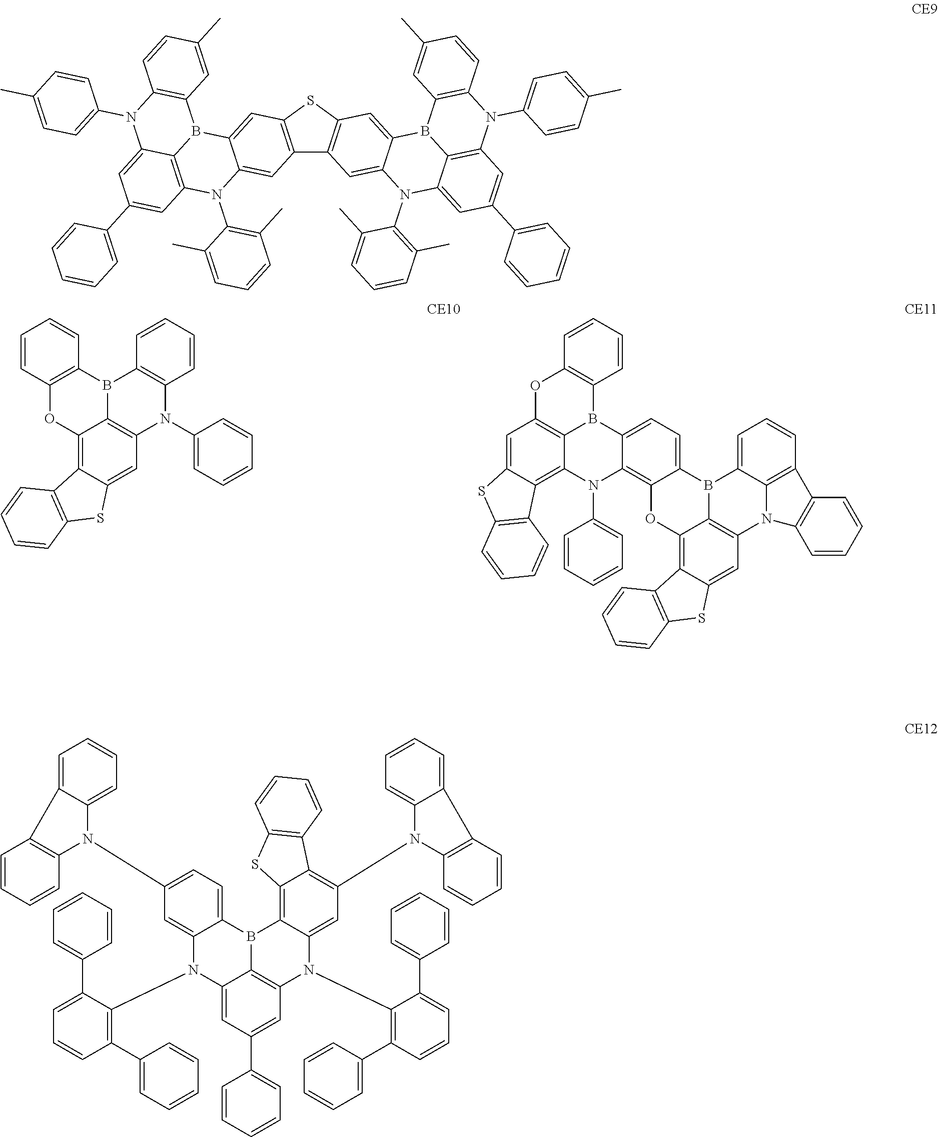

Referring to Table 1, it was confirmed that the light-emitting devices according to Examples 1 to 6 had low roll-off ratio and long lifespan characteristics.

Referring to Table 1, it was confirmed that the light-emitting devices according to Examples 1 to 6 had lower roll-off ratio and longer lifespan characteristics than those of the light-emitting devices according to Comparative Examples 1 to 12.

According to the embodiments, a light-emitting device may have excellent roll-off ratio and lifespan characteristics by including a condensed cyclic compound represented by Formula 1, and a high-quality electronic apparatus may be manufactured by using the light-emitting device.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light-emitting device comprising:
a first electrode;
a second electrode facing the first electrode; and
an interlayer between the first electrode and the second electrode, wherein the interlayer includes:
an emission layer; and
a condensed cyclic compound represented by Formula 1: 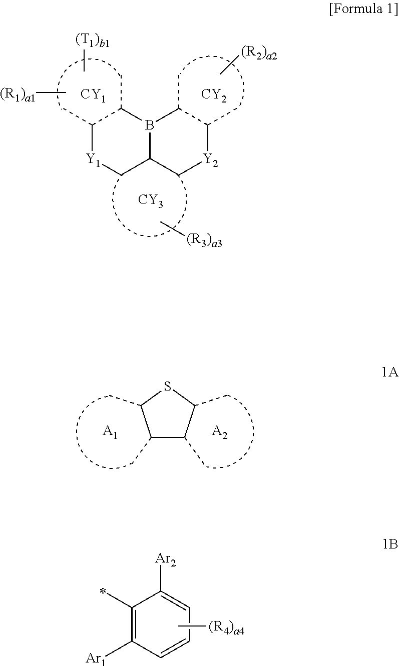
wherein in Formulae 1, 1A, and 1B,
ring CY₁ to ring CY₃, ring A₁, and ring A₂ are each independently a C₅-C₆₀ carbocyclic group or a C₁-C₆₀ heterocyclic group,
at least one of ring CY₂ and ring CY₃ is each independently a group represented by Formula 1A,
when ring CY₂ is a group represented by Formula 1A and ring CY₃ is not a group represented by Formula 1A, ring A₂ in Formula 1A is a condensed polycyclic group in which two or more rings are condensed with each other,
Y₁ is O, S, or N(R₁ₐ),
Y₂ is O, S, or N(R₂ₐ),
T₁ is a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ,
b1 is an integer from 1 to 10,
R₁ to R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁ₐ and R₂ₐ are each independently a group represented by Formula 11B, hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₁ and Ar₂ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
a1 to a3 are each independently an integer from 0 to 10,
a4 is an integer from 0 to 3,
* indicates a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof, and
the condensed cyclic compound satisfies at least one of Conditions 1 and 2:
Y₁ is N(R₁ₐ), and R₁ₐ is a group represented by Formula 1B [Condition 1]
Y₂ is N(R₂ₐ), and R₂ₐ is a group represented by Formula 1B. [Condition 2]

2. The light-emitting device of claim 1, wherein
the first electrode is an anode,
the second electrode is a cathode,
the interlayer further includes:
a hole transport region between the first electrode and the emission layer; and
an electron transport region between the emission layer and the second electrode,
the hole transport region includes a hole injection layer, a hole transport layer, an emission auxiliary layer, an electron-blocking layer, or a combination thereof, and
the electron transport region includes a hole-blocking layer, an electron transport layer, an electron injection layer, or a combination thereof.

3. The light-emitting device of claim 1, wherein the emission layer includes the condensed cyclic compound.

4. The light-emitting device of claim 3, wherein
the condensed cyclic compound in the emission layer is a thermally activated delayed fluorescence (TADF) emitter, and
the emission layer emits delayed fluorescence.

5. The light-emitting device of claim 3, wherein the emission layer emits blue light.

6. The light-emitting device of claim 3, wherein
the emission layer further includes a host,
the condensed cyclic compound in the emission layer is a dopant, and
an amount of the host in the emission layer is greater than an amount of the condensed cyclic compound in the emission layer.

7. An electronic apparatus comprising the light-emitting device of claim 1.

8. The electronic apparatus of claim 7, further comprising:
a thin-film transistor, wherein
the thin-film transistor includes a source electrode and a drain electrode, and
the first electrode of the light-emitting device is electrically connected to the source electrode or the drain electrode.

9. The electronic apparatus of claim 8, further comprising:
a color filter, a color conversion layer, a touch screen layer, a polarizing layer, or a combination thereof.

10. A condensed cyclic compound represented by Formula 1: 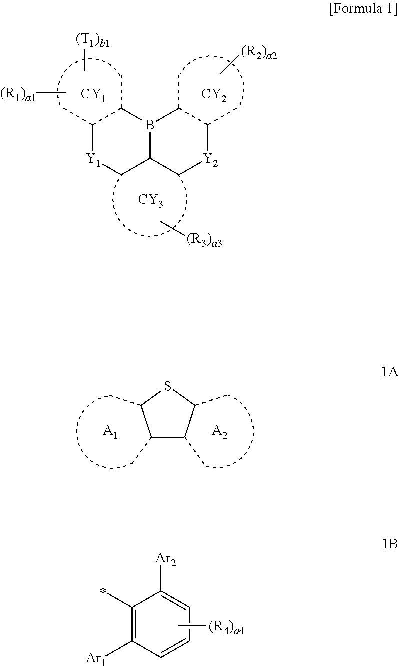
wherein in Formulae 1, 1A, and 1B,
ring CY₁ to ring CY₃, ring A₁, and ring A₂ are each independently a C₅-C₆₀ carbocyclic group or a C₁-C₆₀ heterocyclic group,
at least one of ring CY₂ and ring CY₃ is each independently a group represented by Formula 1A,
when ring CY₂ is a group represented by Formula 1A and ring CY₃ is not a group represented by Formula 1A, ring A₂ in Formula 1A is a condensed polycyclic group in which two or more rings are condensed with each other,
Y₁ is O, S, or N(R₁ₐ),
Y₂ is O, S, or N(R₂ₐ),
T₁ is a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ,
b1 is an integer from 1 to 10,
R₁ to R₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁ₐ and R₂ₐ are each independently a group represented by Formula 1B, hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
Ar₁ and Ar₂ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
a1 to a3 are each independently an integer from 0 to 10,
a4 is an integer from 0 to 3,
* indicates a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof, and
the condensed cyclic compound satisfies at least one of Conditions 1 and 2:
Y₁ is N(R₁ₐ), and R₁ₐ is a group represented by Formula 1B [Condition 1]
Y₂ is N(R₂ₐ), and R₂ₐ is a group represented by Formula 1B. [Condition 2]

11. The condensed cyclic compound of claim 10, wherein ring CY₁ to ring CY₃ are each independently a group represented by Formula 1A, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

12. The condensed cyclic compound of claim 10, wherein ring A₁ and ring A₂ are each independently a benzene group, a pyridine group, a pyrimidine group, a pyrazine group, a pyridazine group, a naphthalene group, a quinoline group, an isoquinoline group, a quinoxaline group, a quinazoline group, an anthracene group, or a phenanthrene group.

13. The condensed cyclic compound of claim 10, wherein the group represented by Formula 1A is a group represented by one of Formulae 1A-1 to 1A-4:

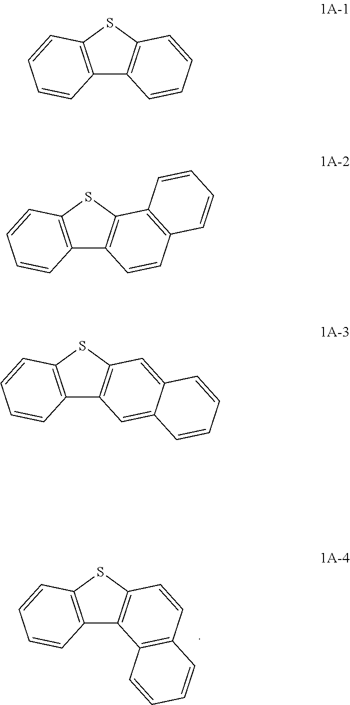 [SMILES: c1ccc2c(c1)sc1ccccc12 ; c1ccc2c(c1)ccc1c3ccccc3sc21 ; c1ccc2cc3c(cc2c1)sc1ccccc13 ; c1ccc2c(c1)ccc1sc3ccccc3c12]

14. The condensed cyclic compound of claim 10, wherein the condensed cyclic compound is represented by one of Formulae 1(1) to 1(3): 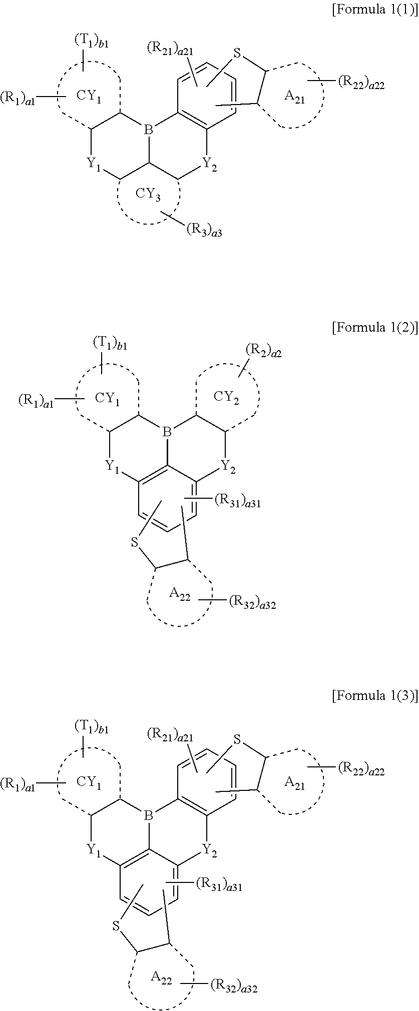
wherein in Formulae 1(1) to 1(3),
ring CY₁ to ring CY₃, T₁, b1, Y₁, Y₂, R₁ to R₃, and a1 to a3 are each the same as defined in Formula 1,
ring A₂₁ is a C₅-C₆₀ carbocyclic group or a C₁-C₆₀ heterocyclic group, and is a condensed polycyclic group in which two or more rings are condensed with each other,
ring A₂₂ and ring A₂₃ are each independently a C₅-C₆₀ carbocyclic group or a C₁-C₆₀ heterocyclic group,
R₂₁ and R₂₂ are each independently the same as defined as in connection with R₂ in Formula 1,
R₃₁ and R₃₂ are each independently the same as defined as in connection with R₃ in Formula 1,
a21 is an integer from 0 to 2,
a31 is 0 or 1, and
a22 and a32 are each independently an integer from 0 to 10.

15. The condensed cyclic compound of claim 10, wherein the condensed cyclic compound is represented by one of Formulae 1(1)-1 to 1(1)-6 and 1(2)-1 to 1(2)-4: 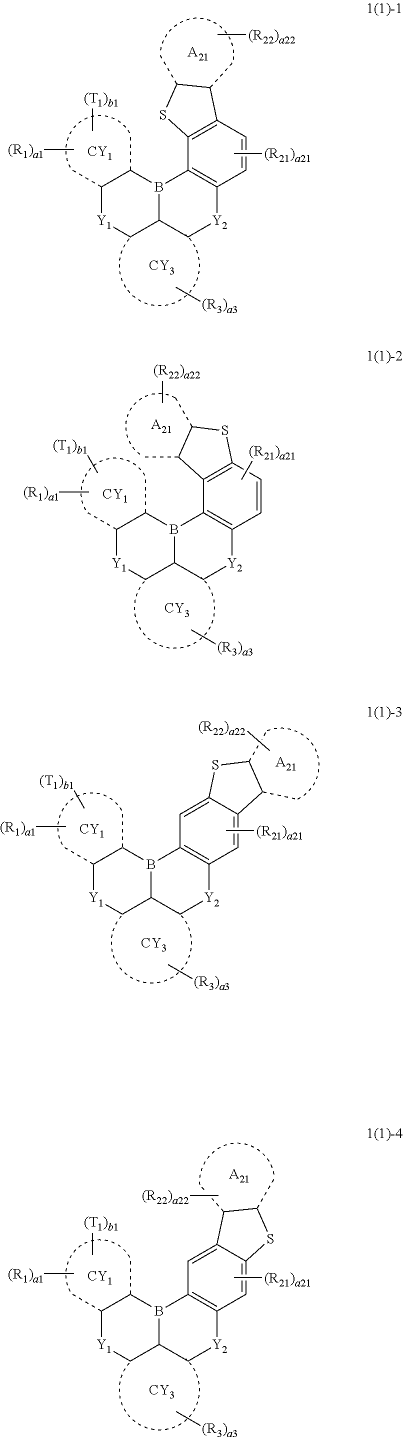 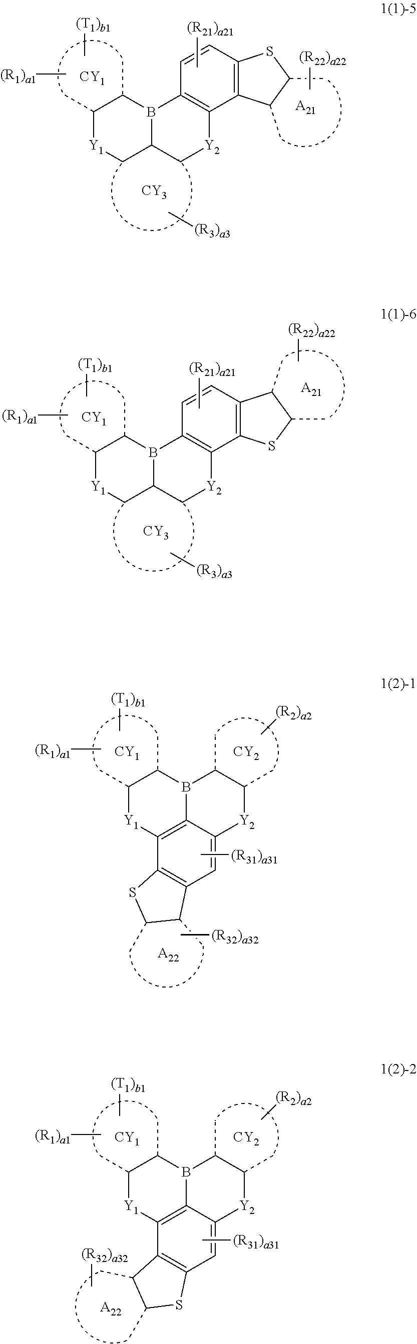 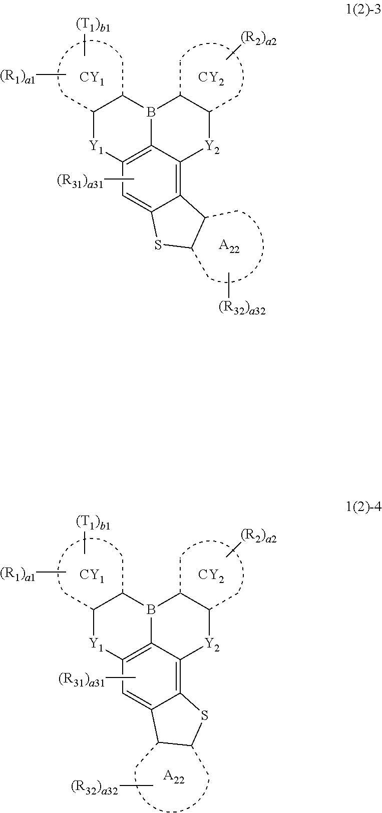
wherein in Formulae 1(1)-1 to 1(1)-6 and 1(2)-1 to 1(2)-4,
ring CY₁ to ring CY₃, T₁, b1, Y₁, Y₂, R₁ to R₃, and a1 to a3 are each the same as defined in Formula 1,
ring A₂₁ is a C₅-C₆₀ carbocyclic group or a C₁-C₆₀ heterocyclic group, and is a condensed polycyclic group in which two or more rings are condensed with each other,
ring A₂₂ is a C₅-C₆₀ carbocyclic group or a C₁-C₆₀ heterocyclic group,
R₂₁ and R₂₂ are each independently the same as defined as in connection with R₂ in Formula 1,
R₃₁ and R₃₂ are each independently the same as defined as in connection with R₃ in Formula 1,
a21 is an integer from 0 to 2,
a31 is 0 or 1, and
a22 and a32 are each independently an integer from 0 to 10.

16. The condensed cyclic compound of claim 10, wherein
Y₁ is O or S, Y₂ is N(R₂ₐ), and R₂ₐ is a group represented by Formula 1B; or
Y₁ is N(R₁ₐ), Y₂ is O or S, and R₁ₐ is a group represented by Formula 1B; or
Y₁ is N(R₁ₐ), Y₂ is N(R₂ₐ), and R₁ₐ and R₂ₐ are each independently a group represented by Formula 1B.

17. The condensed cyclic compound of claim 10, wherein Ar and Ar₂ in Formula 1B are each independently a C₆-C₆₀ aryl group unsubstituted or substituted with at least one R₁₀ₐ or a C₁-C₆₀ heteroaryl group unsubstituted or substituted with at least one R₁₀ₐ.

18. The condensed cyclic compound of claim 10, wherein the group represented by Formula 1B is a group represented by Formula 1B(1): 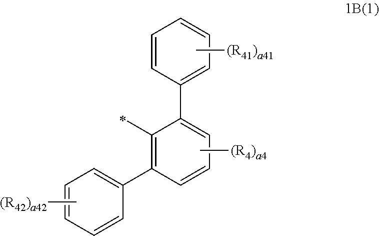
wherein in Formula 1B(1),
R₄ and a4 are each the same as defined in Formula 1,
R₄₁ and R₄₂ are each independently hydrogen or the same as defined in connection with R₁₀ₐ in Formula 1, and
a41 and a42 are each independently an integer from 1 to 5.

19. The condensed cyclic compound of claim 10, wherein T₁ is a group represented by one of Formulae 1T-1 to 1T-9: 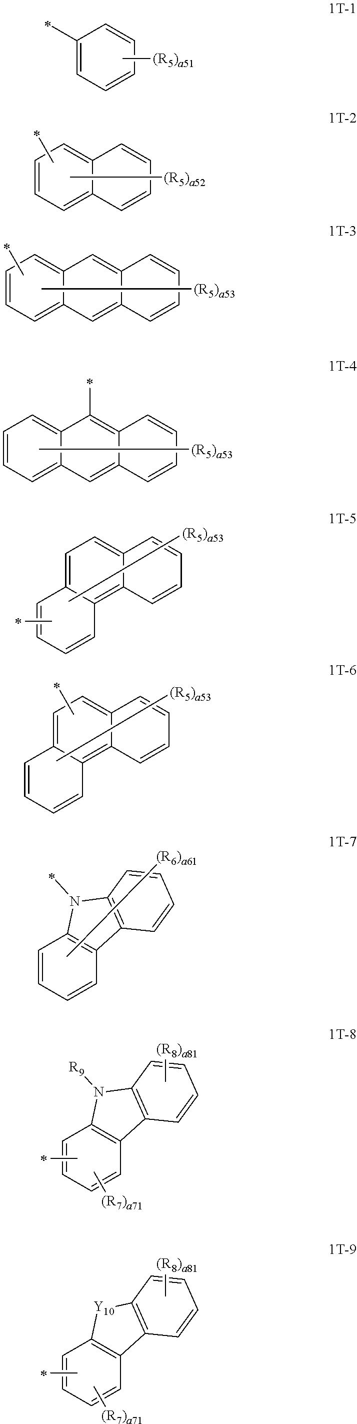
wherein in Formulae 1T-1 to 1T-9,
Y₁₀ is O, S, or Se,
R₅ to R₉ are each independently hydrogen or the same as defined in connection with R₁₀ₐ in Formula 1,
a51 is an integer from 1 to 5,
a52 is an integer from 1 to 7,
a53 is an integer from 1 to 9,
a61 is an integer from 1 to 8,
a71 is an integer from 1 to 3,
a81 is an integer from 1 to 4, and
* indicates a binding site to a neighboring atom.

20. The condensed cyclic compound of claim 10, wherein R₁ to R₄ are each independently:
hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂); or
—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ are each independently:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, and a triazinyl group.
